(19) United States
(12) Patent Application Publication
(10) Pub. No.: US 2026/0143815 A1
(43) Pub. Date: May 21, 2026

(54) SEMICONDUCTOR DEVICE AND METHOD FOR MANUFACTURING SEMICONDUCTOR DEVICE

(71) Applicant: SEMICONDUCTOR ENERGY LABORATORY CO., LTD., Atsugi-shi, Kanagawa-ken (JP)

(72) Inventors: Hajime KIMURA, Atsugi, Kanagawa (JP); Shunpei YAMAZAKI, Setagaya, Tokyo (JP)

(21) Appl. No.: 19/114,900

(22) PCT Filed: Sep. 25, 2023
(86) PCT No.: PCT/IB2023/059428

§ 371 Date: Mar. 25, 2025

(30) Foreign Application Priority Data
Sep. 30, 2022 (JP) 2022-157401

(51) Int. Cl. H10D 86/40; H10D 86/01; H10K 59/121

(52) U.S. Cl. CPC H10D 86/441; H10D 86/0231; H10K 59/1213

(57) ABSTRACT

A semiconductor device including a transistor having a minute size is provided. First and second transistors are included. The first transistor includes first to third conductive layers, a first semiconductor layer, and a first insulating layer. The second conductive layer is provided over the first conductive layer. The first semiconductor layer is in contact with the top surface of the first conductive layer and the second conductive layer. The first insulating layer is in contact with the top surface of the first semiconductor layer. The third conductive layer is provided over first semiconductor layer and the first insulating layer. The second transistor includes fourth to sixth conductive layers, a second semiconductor layer, and the first insulating layer. The fifth conductive layer is provided over the fourth conductive layer. The second semiconductor layer is in contact with the top surface of the fourth conductive layer and the fifth conductive layer. The first insulating layer is in contact with the top surface of the second semiconductor layer. The sixth conductive layer is provided over second semiconductor layer and the first insulating layer. A second insulating layer is included between the first and second conductive layers and between the fourth and fifth conductive layers. The thickness of the second insulating layer between the first and second conductive layers is different from that between the fourth and fifth conductive layers.

### TECHNICAL FIELD

One embodiment of the present invention relates to a semiconductor device, a display apparatus, a display module, and an electronic device. One embodiment of the present invention relates to a method for manufacturing a semiconductor device and a method for manufacturing a display apparatus.

Note that one embodiment of the present invention is not limited to the above technical field. Examples of the technical field of one embodiment of the present invention include a semiconductor device, a display apparatus, a light-emitting apparatus, a power storage device, a memory device, a lighting device, an input device (e.g., a touch sensor), an input/output device (e.g., a touch panel), an electronic device including any of them, a method for driving any of them, and a method for manufacturing any of them.

### BACKGROUND ART

Semiconductor devices including transistors have been widely used in display apparatuses and electronic devices, and the semiconductor devices have been required increasingly to achieve high integration and high-speed operation. In the case where semiconductor devices are used for high-resolution display apparatuses, highly integrated semiconductor devices are required, for example. The development of transistors having minute sizes is ongoing as one way of increasing the degree of integration of transistors.

In recent years, display apparatuses applicable to virtual reality (VR), augmented reality (AR), substitutional reality (SR), or mixed reality (MR) have been needed. VR, AR, SR, and MR are collectively referred to as XR (Extended Reality). Display apparatuses for XR have been desired to have higher resolution and higher color reproducibility so that realistic feeling and the sense of immersion can be enhanced. Examples of devices applicable to such display apparatuses include a liquid crystal display apparatus and a light-emitting apparatus including a light-emitting device (also referred to as a light-emitting element) such as an organic EL (Electro Luminescence) device or a light-emitting diode (LED).

Patent Document 1 discloses a display apparatus for VR using an organic EL device (also referred to as an organic EL element).

### REFERENCE

### Patent Document

[Patent Document 1] PCT International Publication No. 2018/087625

### SUMMARY OF THE INVENTION

### Problems to Be Solved by the Invention

An object of one embodiment of the present invention is to provide a semiconductor device including a transistor having a minute size and a manufacturing method thereof. Another object of one embodiment of the present invention is to provide a small semiconductor device and a manufacturing method thereof. Another object of one embodiment of the present invention is to provide a semiconductor device including a transistor with a high on-state current and a manufacturing method thereof. Another object of one embodiment of the present invention is to provide a high-performance semiconductor device and a manufacturing method thereof. Another object of one embodiment of the present invention is to provide a highly reliable semiconductor device and a manufacturing method thereof. Another object of one embodiment of the present invention is to provide a method for manufacturing a semiconductor device with high productivity. Another object of one embodiment of the present invention is to provide a novel semiconductor device and a manufacturing method thereof.

Note that the description of these objects does not preclude the existence of other objects. One embodiment of the present invention does not need to achieve all of these objects. Other objects can be derived from the description of the specification, the drawings, the claims, and the like.

### Means for Solving the Problems

One embodiment of the present invention is a semiconductor device including a first transistor and a second transistor. The first transistor includes a first conductive layer, a second conductive layer, a third conductive layer, a first semiconductor layer, and a first insulating layer. The second conductive layer is provided over the first conductive layer. The first semiconductor layer is in contact with a top surface of the first conductive layer and the second conductive layer. The first insulating layer is in contact with a top surface of the first semiconductor layer. The third conductive layer is provided over the first insulating layer to include a region overlapping with the first semiconductor layer. The second transistor includes a fourth conductive layer, a fifth conductive layer, a sixth conductive layer, a second semiconductor layer, and the first insulating layer. The fifth conductive layer is provided over the fourth conductive layer. The second semiconductor layer is in contact with a top surface of the fourth conductive layer and the fifth conductive layer. The first insulating layer is in contact with a top surface of the second semiconductor layer. The sixth conductive layer is provided over the first insulating layer to include a region overlapping with the second semiconductor layer. A second insulating layer is provided between the first conductive layer and the second conductive layer and between the fourth conductive layer and the fifth conductive layer. The thickness of the second insulating layer between the first conductive layer and the second conductive layer and the thickness of the second insulating layer between the fourth conductive layer and the fifth conductive layer are different from each other.

In the above, each of the first semiconductor layer and the second semiconductor layer preferably includes a metal oxide.

In the above, it is preferable that the second insulating layer include a third insulating layer and a fourth insulating layer, the third insulating layer be provided in an island shape over the fourth conductive layer, and the fourth insulating layer be provided over the first conductive layer and the third insulating layer.

In the above, it is preferable that the second insulating layer include a third insulating layer and a fourth insulating layer, the third insulating layer be provided over the first conductive layer and the fourth conductive layer, and the fourth insulating layer be provided over the third insulating layer to include an opening in a region overlapping with the first conductive layer.

In the above, it is preferable that the second insulating layer include a third insulating layer and a fourth insulating layer, the third insulating layer be provided in an island shape, the first conductive layer be provided over the third insulating layer, and the fourth insulating layer be provided over the first conductive layer and the fourth conductive layer.

One embodiment of the present invention is a method for manufacturing a semiconductor device, including: forming a first conductive film; processing the first conductive film to form a first conductive layer and a second conductive layer; forming a first insulating film over the first conductive layer and the second conductive layer; processing the first insulating film to form a first insulating layer overlapping with the second conductive layer; forming a second insulating layer over the first conductive layer, the second conductive layer, and the first insulating layer; forming a second conductive film over the second insulating layer; processing the second conductive film to form a third conductive layer overlapping with the first conductive layer and to form a fourth conductive layer overlapping with the second conductive layer; removing part of the third conductive layer and part of the fourth conductive layer to form a fifth conductive layer having a first opening and to form a sixth conductive layer having a second opening; removing the second insulating layer in a region overlapping with the first opening and removing the first insulating layer and the second insulating layer in a region overlapping with the second opening to form a third opening and a fourth opening; forming a metal oxide film in contact with a top surface of the first conductive layer, a top surface of the second conductive layer, a top surface and a side surface of the fifth conductive layer, a top surface and a side surface of the sixth conductive layer, a side surface of the first insulating layer, and a side surface of the second insulating layer so as to cover the first opening, the second opening, the third opening, and the fourth opening; processing the metal oxide film into an island shape to form a first semiconductor layer in contact with the top surface of the first conductive layer, the side surface of the second insulating layer, and the top surface and the side surface of the fifth conductive layer and to form a second semiconductor layer in contact with the top surface of the second conductive layer, the side surface of the first insulating layer, the side surface of the second insulating layer, and the top surface and the side surface of the sixth conductive layer; forming a third insulating layer over the first semiconductor layer, the second semiconductor layer, the fifth conductive layer, the sixth conductive layer, and the second insulating layer; forming a third conductive film over the third insulating layer; and processing the third conductive film to form a seventh conductive layer overlapping with the first conductive layer and the first semiconductor layer and to form an eighth conductive layer overlapping with the second conductive layer and the second semiconductor layer.

One embodiment of the present invention is a method for manufacturing a semiconductor device, including: forming a first conductive film; processing the first conductive film to form a first conductive layer and a second conductive layer; forming, over the first conductive layer and the second conductive layer, a first insulating layer and a first insulating film over the first insulating layer; processing the first insulating film to form a second insulating layer having a first opening in a region overlapping with the first conductive layer; forming a second conductive film over the first insulating layer and the second insulating layer; processing the second conductive film to form a third conductive layer overlapping with the first conductive layer and to form a fourth conductive layer overlapping with the second conductive layer; removing part of the third conductive layer and part of the fourth conductive layer to form a fifth conductive layer having a second opening and to form a sixth conductive layer having a third opening; removing the first insulating layer in a region overlapping with the second opening and removing the first insulating layer and the second insulating layer in a region overlapping with the third opening to form a fourth opening and a fifth opening; forming a metal oxide film in contact with a top surface of the first conductive layer, a top surface of the second conductive layer, a top surface and a side surface of the fifth conductive layer, a top surface and a side surface of the sixth conductive layer, a side surface of the first insulating layer, and a side surface of the second insulating layer so as to cover the second opening, the third opening, the fourth opening, and the fifth opening; processing the metal oxide film into an island shape to form a first semiconductor layer in contact with the top surface of the first conductive layer, the side surface of the first insulating layer, and the top surface and the side surface of the fifth conductive layer and to form a second semiconductor layer in contact with the top surface of the second conductive layer, the side surface of the first insulating layer, the side surface of the second insulating layer, and the top surface and the side surface of the sixth conductive layer; forming a third insulating layer over the first semiconductor layer, the second semiconductor layer, the fifth conductive layer, the sixth conductive layer, and the second insulating layer; forming a third conductive film over the third insulating layer; and processing the third conductive film to form a seventh conductive layer overlapping with the first conductive layer and the first semiconductor layer and to form an eighth conductive layer overlapping with the second conductive layer and the second semiconductor layer.

One embodiment of the present invention is a method for manufacturing a semiconductor device, including: forming a first insulating film; processing the first insulating film to form a first insulating layer; forming a first conductive film over the first insulating layer; processing the first conductive film to form a first conductive layer over the first insulating layer and to form a second conductive layer over a region different from the first insulating layer; forming a second insulating film over the first insulating layer, the first conductive layer, and the second conductive layer; processing the second insulating film to form a second insulating layer having a flat or substantially flat surface; forming a second conductive film over the second insulating layer; processing the second conductive film to form a third conductive layer overlapping with the first conductive layer and to form a fourth conductive layer overlapping with the second conductive layer; removing part of the third conductive layer and part of the fourth conductive layer to form a fifth conductive layer having a first opening and to form a sixth conductive layer having a second opening; removing the second insulating layer in a region overlapping with the first opening and removing the second insulating layer in a region overlapping with the second opening to form a third opening and a fourth opening; forming a metal oxide film in contact with a top surface of the first conductive layer, a top surface of the second conductive layer, a top surface and a side surface of the fifth conductive layer, a top surface and a side surface of the sixth conductive layer, and a side surface of the second insulating layer so as to cover the first opening, the second opening, the third opening, and the fourth opening; processing the metal oxide film into an island shape to form a first semiconductor layer in contact with the top surface of the first conductive layer, the side surface of the second insulating layer, and the top surface and the side surface of the fifth conductive layer and to form a second semiconductor layer in contact with the top surface of the second conductive layer, the side surface of the second insulating layer, and the top surface and the side surface of the sixth conductive layer; forming a third insulating layer over the first semiconductor layer, the second semiconductor layer, the fifth conductive layer, the sixth conductive layer, and the second insulating layer; forming a third conductive film over the third insulating layer; and processing the third conductive film to form a seventh conductive layer overlapping with the first conductive layer and the first semiconductor layer and to form an eighth conductive layer overlapping with the second conductive layer and the second semiconductor layer.

### Effect of the Invention

One embodiment of the present invention can provide a semiconductor device including a transistor having a minute size and a manufacturing method thereof. Alternatively, one embodiment of the present invention can provide a small semiconductor device and a manufacturing method thereof. Alternatively, one embodiment of the present invention can provide a semiconductor device including a transistor with a high on-state current and a manufacturing method thereof. Alternatively, one embodiment of the present invention can provide a high-performance semiconductor device and a manufacturing method thereof. Alternatively, one embodiment of the present invention can provide a highly reliable semiconductor device and a manufacturing method thereof. Alternatively, one embodiment of the present invention can provide a method for manufacturing a semiconductor device with high productivity. Alternatively, one embodiment of the present invention can provide a novel semiconductor device and a manufacturing method thereof.

Note that the description of these effects does not preclude the existence of other effects. One embodiment of the present invention does not need to have all of these effects. Other effects can be derived from the description of the specification, the drawings, the claims, and the like.

### BRIEF DESCRIPTION OF THE DRAWINGS

FIG. 1A and FIG. 1B are cross-sectional views illustrating examples of a semiconductor device.

FIG. 2A is a block diagram illustrating a structure example of a display apparatus. FIG. 2B is a plan view illustrating a structure example of a pixel. FIG. 2C and FIG. 2D are circuit diagrams illustrating structure examples of a pixel.

FIG. 3A is a block diagram illustrating a structure example of a display apparatus. FIG. 3B is a circuit diagram illustrating a structure example of a pixel.

FIG. 4A to FIG. 4C are circuit diagrams illustrating structure examples of a pixel.

FIG. 5A is a block diagram illustrating a structure example of a memory device. FIG. 5B to FIG. 5E are circuit diagrams illustrating structure examples of a memory cell.

FIG. 6A is a plan view illustrating an example of a semiconductor device. FIG. 6B is a cross-sectional view illustrating an example of a semiconductor device.

FIG. 7A is a plan view illustrating an example of a transistor. FIG. 7B is a cross-sectional view illustrating an example of a transistor.

FIG. 8A is a plan view illustrating an example of a semiconductor device. FIG. 8B is a cross-sectional view illustrating an example of a semiconductor device.

FIG. 9A is a plan view illustrating an example of a semiconductor device. FIG. 9B is a cross-sectional view illustrating an example of a semiconductor device.

FIG. 10A is a plan view illustrating an example of a semiconductor device. FIG. 10B is a cross-sectional view illustrating an example of a semiconductor device.

FIG. 11A is a plan view illustrating an example of a semiconductor device. FIG. 11B is a cross-sectional view illustrating an example of a semiconductor device.

FIG. 12 is a cross-sectional view illustrating an example of a semiconductor device.

FIG. 13 is a cross-sectional view illustrating an example of a semiconductor device.

FIG. 14 is a cross-sectional view illustrating an example of a semiconductor device.

FIG. 15 is a cross-sectional view illustrating an example of a semiconductor device.

FIG. 16 is a cross-sectional view illustrating an example of a semiconductor device.

FIG. 17A is a plan view illustrating an example of a semiconductor device. FIG. 17B is a cross-sectional view illustrating an example of a semiconductor device.

FIG. 18A is a plan view illustrating an example of a semiconductor device. FIG. 18B is a cross-sectional view illustrating an example of a semiconductor device.

FIG. 19A is a plan view illustrating an example of a semiconductor device. FIG. 19B is a cross-sectional view illustrating an example of a semiconductor device.

FIG. 20A is a plan view illustrating an example of a semiconductor device. FIG. 20B is a cross-sectional view illustrating an example of a semiconductor device.

FIG. 21A is a plan view illustrating an example of a semiconductor device. FIG. 21B is a cross-sectional view illustrating an example of a semiconductor device.

FIG. 22A is a plan view illustrating an example of a semiconductor device. FIG. 22B is a cross-sectional view illustrating an example of a semiconductor device.

FIG. 23A is a plan view illustrating an example of a semiconductor device. FIG. 23B is a cross-sectional view illustrating an example of a semiconductor device.

FIG. 24A is a plan view illustrating an example of a transistor. FIG. 24B is a cross-sectional view illustrating an example of a transistor. FIG. 24C is a circuit diagram illustrating a transistor.

FIG. 25A is a plan view illustrating an example of a semiconductor device. FIG. 25B is a cross-sectional view illustrating an example of a semiconductor device.

FIG. 26A is a plan view illustrating an example of a semiconductor device. FIG. 26B is a cross-sectional view illustrating an example of a semiconductor device.

FIG. 27A is a plan view illustrating an example of a semiconductor device. FIG. 27B is a cross-sectional view illustrating an example of a semiconductor device.

FIG. 28A is a plan view illustrating an example of a semiconductor device. FIG. 28B is a cross-sectional view illustrating an example of a semiconductor device.

FIG. 29A and FIG. 29B are cross-sectional views illustrating examples of a transistor. FIG. 29C is a circuit diagram illustrating a transistor.

FIG. 30A and FIG. 30B are cross-sectional views illustrating examples of a transistor. FIG. 30C is a circuit diagram illustrating a transistor.

FIG. 31A and FIG. 31B are cross-sectional views illustrating examples of a transistor. FIG. 31C is a circuit diagram illustrating a transistor.

FIG. 32A is a plan view illustrating an example of a semiconductor device. FIG. 32B is a cross-sectional view illustrating an example of a semiconductor device.

FIG. 33A is a plan view illustrating an example of a semiconductor device. FIG. 33B is a cross-sectional view illustrating an example of a semiconductor device.

FIG. 34A is a plan view illustrating an example of a semiconductor device. FIG. 34B is a cross-sectional view illustrating an example of a semiconductor device.

FIG. 35A is a circuit diagram illustrating a structure example including a pixel circuit. FIG. 35B is a plan view illustrating a structure example including a pixel circuit. FIG. 35C and FIG. 35D are cross-sectional views illustrating a structure example including a pixel circuit.

FIG. 36A is a plan view illustrating a structure example including a pixel circuit. FIG. 36B is a cross-sectional view illustrating a structure example including a pixel circuit.

FIG. 37 is a plan view illustrating a structure example including a pixel circuit.

FIG. 38A is a plan view illustrating a structure example of a display apparatus. FIG. 38B is a cross-sectional view illustrating a structure example of a display apparatus.

FIG. 39A is a plan view illustrating a structure example of a display apparatus. FIG. 39B is a cross-sectional view illustrating a structure example of a display apparatus.

FIG. 40A to FIG. 40C are plan views illustrating structure examples of a display apparatus.

FIG. 41A to FIG. 41C are plan views illustrating structure examples of a display apparatus.

FIG. 42A and FIG. 42B are plan views illustrating structure examples of a display apparatus.

FIG. 43A to FIG. 43C are cross-sectional views illustrating an example of a method for manufacturing a semiconductor device.

FIG. 44A to FIG. 44C are cross-sectional views illustrating an example of a method for manufacturing a semiconductor device.

FIG. 45A to FIG. 45C are cross-sectional views illustrating an example of a method for manufacturing a semiconductor device.

FIG. 46A to FIG. 46C are cross-sectional views illustrating an example of a method for manufacturing a semiconductor device.

FIG. 47A to FIG. 47C are cross-sectional views illustrating an example of a method for manufacturing a semiconductor device.

FIG. 48A to FIG. 48C are cross-sectional views illustrating an example of a method for manufacturing a semiconductor device.

FIG. 49A to FIG. 49C are cross-sectional views illustrating an example of a method for manufacturing a semiconductor device.

FIG. 50A to FIG. 50C are cross-sectional views illustrating an example of a method for manufacturing a semiconductor device.

FIG. 51A to FIG. 51D are cross-sectional views illustrating an example of a method for manufacturing a semiconductor device.

FIG. 52A to FIG. 52C are cross-sectional views illustrating an example of a method for manufacturing a semiconductor device.

FIG. 53A to FIG. 53C are cross-sectional views illustrating an example of a method for manufacturing a semiconductor device.

FIG. 54A to FIG. 54C are cross-sectional views illustrating an example of a method for manufacturing a semiconductor device.

FIG. 55 is a perspective view illustrating a structure example of a display apparatus.

FIG. 56 is a cross-sectional view illustrating a structure example of a display apparatus.

FIG. 57 is a cross-sectional view illustrating a structure example of a display apparatus.

FIG. 58 is a cross-sectional view illustrating a structure example of a display apparatus.

FIG. 59 is a cross-sectional view illustrating a structure example of a display apparatus.

FIG. 60 is a cross-sectional view illustrating a structure example of a display apparatus.

FIG. 61A to FIG. 61D are diagrams illustrating examples of electronic devices.

FIG. 62A to FIG. 62F are diagrams illustrating examples of electronic devices.

FIG. 63A to FIG. 63G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”.

In this specification and the like, a light-emitting device includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In this specification and the like, a tapered shape refers to such a shape that at least part of a side surface of a component is inclined with respect to a substrate surface or a formation surface. For example, a tapered shape refers to a shape including a region where the angle formed by the inclined side surface and the substrate surface or the formation surface (also referred to as a taper angle) is less than 90°. Note that the side surface of the component, the substrate surface, and the formation surface are not necessarily completely flat, and may have a substantially planar shape with a slight curvature or a substantially planar shape with slight unevenness.

In this specification and the like, step disconnection refers to a phenomenon in which a layer, a film, or an electrode is split because of the shape of the formation surface (e.g., a step).

In this specification and the like, the expression “top surface shapes (also referred to as shapes in a plan view or outline shapes) are substantially the same” means that outlines of stacked layers at least partly overlap with each other. For example, the case of processing the upper layer and the lower layer with use of the same mask pattern or mask patterns that are partly the same is included. Note that, in some cases, the outlines do not strictly overlap with each other and the upper layer is positioned inward from the lower layer or the upper layer is positioned outward from the lower layer; such cases are also represented by the expression “top surface shapes are substantially the same”.

Note that in this specification and the like, the top surface shape of a component means an outline shape of the component in a plan view. A plan view means a view to observe the component from a normal direction of a surface where the component is formed or from a normal direction of a surface of a support (e.g., a substrate) where the component is formed.

In this specification and the like, the expression “substantially level” indicates a structure in which levels from a reference surface (e.g., a flat surface such as a substrate surface) are substantially the same in a cross-sectional view.

### Embodiment 1

A semiconductor device of one embodiment of the present invention includes at least two or more transistors. Each of the transistors has a structure in which a source electrode and a drain electrode are positioned at different levels with respect to a substrate surface and drain current flows in a height direction (vertical direction). The thickness of an insulating layer positioned between the source electrode and the drain electrode of the transistor differs between the transistors included in the semiconductor device. That is, the semiconductor device of one embodiment of the present invention includes two or more transistors that differ in the distance between the source electrode and the drain electrode (i.e., the channel length).

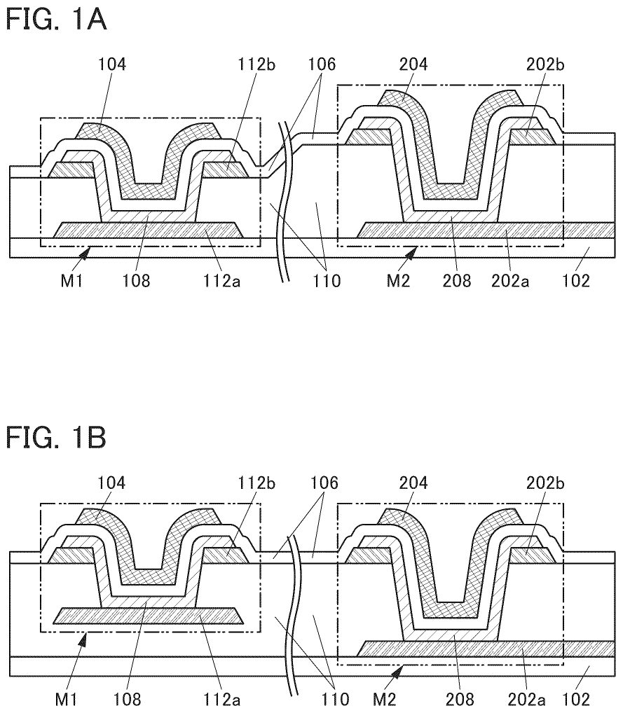

FIG. 1A and FIG. 1B are cross-sectional views each illustrating a superordinate concept of the semiconductor device of one embodiment of the present invention.

As illustrated in FIG. 1A and FIG. 1B, the semiconductor device of one embodiment of the present invention includes two transistors: a transistor M1 and a transistor M2. Although FIG. 1A and FIG. 1B each illustrate only two transistors, one embodiment of the present invention is not limited thereto. The semiconductor device of one embodiment of the present invention may include three or more transistors.

The transistor M1 and the transistor M2 are provided over a substrate 102. The transistor M1 includes a conductive layer 112a over the substrate 102, a conductive layer 112b over the conductive layer 112a, a semiconductor layer 108 including regions in contact with the top surfaces of the conductive layer 112a and the conductive layer 112b, an insulating layer 106 over the semiconductor layer 108, and a conductive layer 104 over the insulating layer 106.

In the transistor M1, the conductive layer 112a functions as one of a source electrode and a drain electrode. The conductive layer 112b functions as the other of the source electrode and the drain electrode. The insulating layer 106 functions as a gate insulating layer. The conductive layer 104 functions as a gate electrode. A region of the semiconductor layer 108 that is between the conductive layer 112a and the conductive layer 112b and overlaps with the conductive layer 104 with the insulating layer 106 therebetween functions as a channel formation region.

The transistor M2 includes a conductive layer 202a over the substrate 102 (over a region different from the conductive layer 112a), a conductive layer 202b over the conductive layer 202a, a semiconductor layer 208 including regions in contact with the top surfaces of the conductive layer 202a and the conductive layer 202b, the insulating layer 106 over the semiconductor layer 208, and a conductive layer 204 over the insulating layer 106.

In the transistor M2, the conductive layer 202a functions as one of a source electrode and a drain electrode. The conductive layer 202b functions as the other of the source electrode and the drain electrode. The insulating layer 106 functions as a gate insulating layer. The conductive layer 204 functions as a gate electrode. A region of the semiconductor layer 208 that is between the conductive layer 202a and the conductive layer 202b and overlaps with the conductive layer 204 with the insulating layer 106 therebetween functions as a channel formation region.

An insulating layer 110 is provided between the source electrode and the drain electrode of the transistor M1 and between the source electrode and the drain electrode of the transistor M2.

Here, in the semiconductor device illustrated in FIG. 1A, the conductive layer 112a and the conductive layer 202a are each provided in contact with the top surface of the substrate 102, and the formation surfaces of the conductive layer 112a and the conductive layer 202a are substantially level with each other. However, the formation surfaces of the conductive layer 112b and the conductive layer 202b are at different levels with reference to the top surface of the substrate 102.

In the semiconductor device illustrated in FIG. 1B, on the other hand, the formation surfaces of the conductive layer 112b and the conductive layer 202b are substantially level with each other. However, while the conductive layer 202a is provided in contact with the top surface of the substrate 102, the conductive layer 112a is provided to be embedded in the insulating layer 110; thus, the level of the formation surface of the conductive layer 112a and the level of the formation surface of the conductive layer 202a are different from each other.

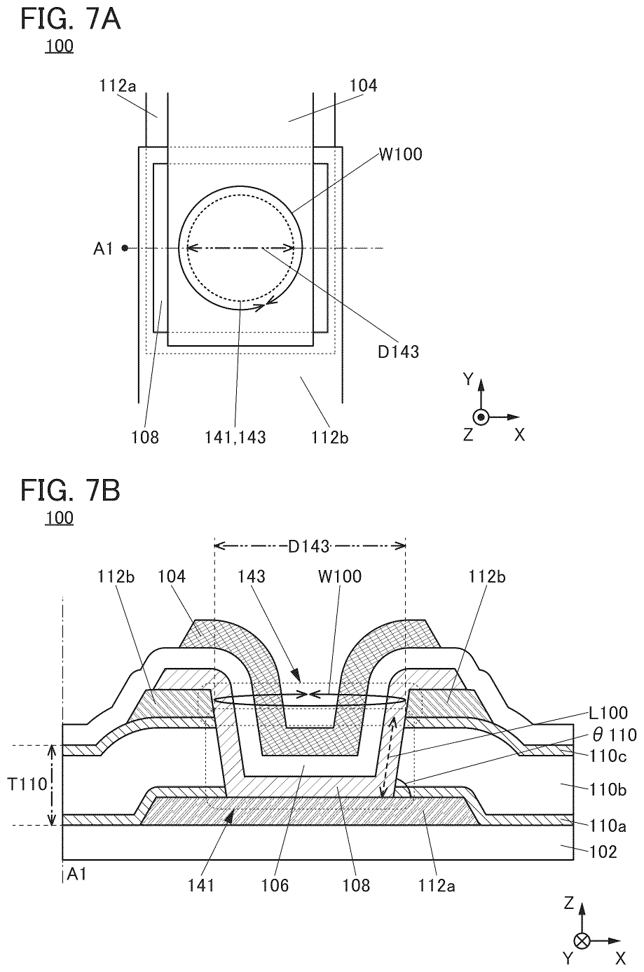

That is, in each of the semiconductor devices illustrated in FIG. 1A and FIG. 1B, the thickness of the insulating layer 110 between the conductive layer 112a and the conductive layer 112b is different from the thickness of the insulating layer 110 between the conductive layer 202a and the conductive layer 202b. Although the details will be described with reference to FIG. 7B and the like, in each of the transistors included in the semiconductor device of one embodiment of the present invention, the thickness of the insulating layer between the source electrode and the drain electrode corresponds to the channel length. Thus, the channel length of the transistor M1 and the channel length of the transistor M2 are different from each other in the semiconductor device of one embodiment of the present invention.

As the channel length of a transistor becomes shorter, the on-state current and the field-effect mobility can be increased. By contrast, as the channel length of the transistor becomes longer, the saturation characteristics of current flowing when the transistor operates in a saturation region can be improved (i.e., the amount of drain current hardly changes with respect to an increase in drain voltage). In one embodiment of the present invention, the thickness of the insulating layer 110 varies within the substrate plane, whereby the transistor M1 having a short channel length and the transistor M2 having a long channel length can be formed over the same substrate by sharing some of the formation steps. Thus, the transistor M1 is used as a transistor required to have a high on-state current and the transistor M2 is used as a transistor required to have favorable saturation characteristics, for example, thereby providing a high-performance semiconductor device utilizing the advantages of the transistors.

The semiconductor device of one embodiment of the present invention can be used for a display apparatus, for example. The semiconductor device of one embodiment of the present invention can be used for a memory device, for example. Hereinafter, specific structure examples of a display apparatus and a memory device for each of which the semiconductor device of one embodiment of the present invention can be used are described.

### Structure Example of Display Apparatus

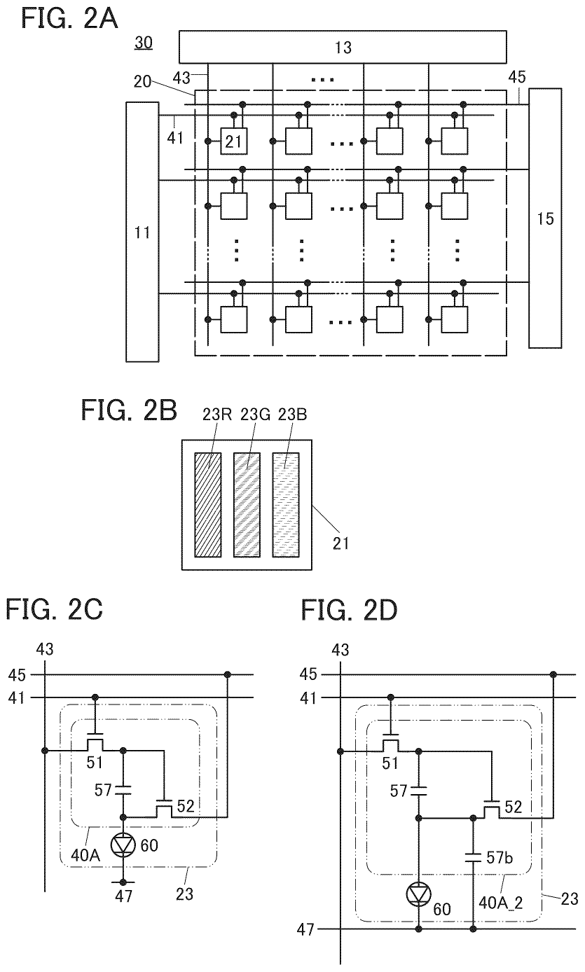

FIG. 2A is a block diagram illustrating a structure example of a display apparatus 30 that is the display apparatus of one embodiment of the present invention. The display apparatus 30 includes a display portion 20, a scan line driver circuit 11, a signal line driver circuit 13, and a power supply circuit 15. The display portion 20 includes a plurality of pixels 21 arranged in a matrix.

The scan line driver circuit 11 is electrically connected to the pixels 21 through a wiring 41. Specifically, the pixels 21 in the same row are electrically connected to the scan line driver circuit 11 through the same wiring 41.

The signal line driver circuit 13 is electrically connected to the pixels 21 through a wiring 43. Specifically, the pixels 21 in the same column are electrically connected to the signal line driver circuit 13 through the same wiring 43.

The power supply circuit 15 is electrically connected to the pixels 21 through a wiring 45. For example, the pixels 21 in the same row can be electrically connected to the power supply circuit 15 through the same wiring 45.

Each of the pixels 21 includes a display element (also referred to as a display device), and an image can be displayed on the display portion 20 with the display element. Specifically, the luminance of light emitted from the pixel 21 is controlled by the display element, whereby an image can be displayed on the display portion 20. As the display element, a light-emitting element can be used, for example; specifically, an organic EL element can be used. As the display element, a liquid crystal element (also referred to as a liquid crystal device) may also be used.

The scan line driver circuit 11 has a function of selecting the pixel 21 to which image data is to be written. Specifically, the scan line driver circuit 11 can select the pixel 21 to which image data is to be written by outputting a signal to the wiring 41. Here, the scan line driver circuit 11 can write image data to the pixel 21 by outputting the signal to the wiring 41 in the first row, outputting the signal to the wiring 41 in the second row, and outputting the signals to the wirings 41 from the following row to the last row sequentially. Thus, the signal output from the scan line driver circuit 11 to the wiring 41 is a scan signal, and the wiring 41 can be referred to as a scan line. Note that the scan line driver circuit is referred to as a gate driver in some cases. The wiring 41 is referred to as a gate line in some cases.

The signal line driver circuit 13 has a function of generating image data. The image data is supplied to the pixel 21 through the wiring 43. For example, image data can be written to all the pixels 21 included in a row selected by the scan line driver circuit 11. Here, the image data can be represented as a signal. Thus, the wiring 43 can be referred to as a signal line. Note that the signal line driver circuit is referred to as a source driver in some cases. The wiring 43 is referred to as a source line in some cases.

The power supply circuit 15 has a function of generating a power supply potential and supplying it to the wiring 45. The power supply circuit 15 has a function of generating a high power supply potential (hereinafter, also simply referred to as “high potential” or “VDD”) and supplying it to the wiring 45, for example. The power supply circuit 15 may have a function of generating a low power supply potential (hereinafter, also simply referred to as “low potential” or “VSS”). The power supply circuit 15 can output a pulsed signal by sequentially switching a high power supply potential and a low power supply potential. Alternatively, the power supply circuit 15 can output pulsed signals by row-by-row scanning. The wiring 45 is supplied with a power supply potential, thus, the wiring 45 can be referred to as a power supply line. Furthermore, current flows from the wiring 45 to a light-emitting element (e.g., a light-emitting element 60 described later) through a transistor 52 illustrated in FIG. 2C or the like. Thus, the wiring 45 is referred to as a current supply line in some cases. The wiring 45 may be supplied with a pulsed signal and thus is referred to as a pulse line in some cases. By supplying a pulsed potential to the wiring 45, variation in the threshold voltage and mobility of the transistor 52 illustrated in FIG. 2C or the like can be corrected.

A constant potential signal, a pulse signal, or the like is supplied to the wiring 41, the wiring 43, and the wiring 45.

FIG. 2B is a plan view illustrating a structure example of the pixel 21. The pixel 21 includes a plurality of subpixels 23. FIG. 2B illustrates an example in which the pixel 21 includes a subpixel 23R, a subpixel 23G, and a subpixel 23B. Here, in the case where the pixel 21 includes a light-emitting element as the display element, for example, the top surface shape of each of the subpixels illustrated in FIG. 2B corresponds to the top surface shape of a light-emitting region of the light-emitting element. Although FIG. 2B illustrates the subpixel 23R, the subpixel 23G, and the subpixel 23B that have the same or substantially the same aperture ratio or light-emitting region size, one embodiment of the present invention is not limited thereto. The aperture ratio of each of the subpixel 23R, the subpixel 23G, and the subpixel 23B can be determined as appropriate. The subpixel 23R, the subpixel 23G, and the subpixel 23B may have different aperture ratios, or two or more of the subpixels may have the same or substantially the same aperture ratio.

In this specification and the like, for example, matters common to the subpixel 23R, the subpixel 23G, and the subpixel 23B are sometimes described using the collective term “subpixel 23” without letters of the alphabet distinguishing them from each other. As for other components that are distinguished from each other using letters of the alphabet, matters common to the components are sometimes described using reference numerals without the letters of the alphabet.

The pixel 21 illustrated in FIG. 2B employs stripe arrangement as the arrangement method of the subpixels 23. Note that S-stripe arrangement, matrix arrangement, delta arrangement, Bayer arrangement, PenTile arrangement, or the like may be employed as the arrangement method of the subpixels 23.

The subpixel 23R, the subpixel 23G, and the subpixel 23B emit light of different colors. The subpixel 23R, the subpixel 23G, and the subpixel 23B can be subpixels of three colors of red (R), green (G), and blue (B) or subpixels of three colors of yellow (Y), cyan (C), and magenta (M), for example. The pixel 21 may include four or more subpixels 23. For example, the pixel 21 may include subpixels of four colors of R, G, B, and white (W). Alternatively, the pixel 21 may include subpixels of four colors of R, G, B, and infrared light (IR). Accordingly, the display apparatus 30 can display a full-color image on the display portion 20.

FIG. 2C is a circuit diagram illustrating a structure example of the subpixel 23. The subpixel 23 illustrated in FIG. 2C includes a pixel circuit 40A and the light-emitting element 60.

The pixel circuit 40A includes a transistor 51, the transistor 52, and a capacitor 57. That is, the pixel circuit 40A is a 2Tr1C-type pixel circuit.

In the pixel circuit 40A, one of a source and a drain of the transistor 51 is electrically connected to the wiring 43. The other of the source and the drain of the transistor 51 is electrically connected to a gate of the transistor 52. The gate of the transistor 52 is electrically connected to one electrode of the capacitor 57. A gate of the transistor 51 is electrically connected to the wiring 41.

One of a source and a drain of the transistor 52 is electrically connected to the wiring 45. The other of the source and the drain of the transistor 52 is electrically connected to the other electrode of the capacitor 57. The other electrode of the capacitor 57 is electrically connected to one electrode of the light-emitting element 60. The other electrode of the light-emitting element 60 is electrically connected to a wiring 47. Here, the one electrode of the light-emitting element 60 is also referred to as a pixel electrode. The wiring 47 can be shared between all the pixels 21, for example. Thus, the other electrode of the light-emitting element 60 can also be referred to as a common electrode.

As described above, the wiring 41 functions as a scan line, the wiring 43 functions as a signal line, and the wiring 45 functions as a power supply line. The wiring 47 functions as a power supply line; for example, when the wiring 45 is supplied with a high power supply potential, the wiring 47 is supplied with a low power supply potential. The wiring 47 can be electrically connected to the power supply circuit 15, for example.

The transistor 51 has a function of a switch and has a function of controlling electrical continuity or discontinuity between the wiring 43 and the gate of the transistor 52 on the basis of the potential of the wiring 41. When the transistor 51 is brought into an on state, image data is written to the pixel circuit 40A, and when the transistor 51 is brought into an off state, the written image data is retained. The transistor 51 is also referred to as a selection transistor.

The transistor 52 has a function of controlling the amount of current flowing through the light-emitting element 60 and is also referred to as a driving transistor. The capacitor 57 has a function of retaining a gate potential of the transistor 52. The emission luminance of the light-emitting element 60 is controlled in accordance with a potential that corresponds to image data and is supplied to the gate of the transistor 52. Specifically, in the case where the wiring 45 is supplied with a high power supply potential and the wiring 47 is supplied with a low power supply potential, the amount of current flowing from the wiring 45 to the wiring 47 is controlled in accordance with the gate potential of the transistor 52, whereby the emission luminance of the light-emitting element 60 is controlled.

As the transistor 51 and the transistor 52, transistors including an oxide semiconductor (OS) in semiconductor layers (hereinafter referred to as OS transistors) are preferably used. An OS transistor has higher field-effect mobility than a transistor including amorphous silicon in a semiconductor layer, for example. Thus, with the use of OS transistors as the transistor 51 and the transistor 52, the display apparatus 30 can be driven at high speed.

An OS transistor has an extremely low leakage current between a source and a drain in an off state (hereinafter, also referred to as off-state current). Thus, with the use of an OS transistor as the transistor 51, charge accumulated in the capacitor 57 can be retained for a long period. Therefore, image data written to the subpixel 23 can be retained for a long period and thus the frequency of the refresh operation (image data rewriting to the subpixel 23) can be reduced. Thus, the power consumption of the display apparatus 30 can be reduced.

To increase the emission luminance of the light-emitting element 60, it is necessary to increase the amount of current flowing through the light-emitting element 60. To increase the current amount, it is necessary to increase the source-drain voltage of the transistor 52 which is a driving transistor. Since an OS transistor has a higher withstand voltage between a source and a drain than a transistor including silicon in a semiconductor layer (also referred to as a Si transistor), a high voltage can be applied between the source and the drain of the OS transistor. Accordingly, when an OS transistor is used as the transistor 52, the amount of current flowing through the light-emitting element 60 can be increased, so that the emission luminance of the light-emitting element 60 can be increased.

In the case where transistors are driven in a saturation region, a change in source-drain current relative to a change in gate-source voltage can be smaller in an OS transistor than in a Si transistor. Thus, when an OS transistor is used as the transistor 52, current flowing between the source and the drain can be set minutely by a change in gate-source voltage; hence, the amount of current flowing through the light-emitting element 60 can be controlled. Accordingly, the luminance of light emitted from the subpixel 23 can be controlled minutely. As a result, the number of gray levels represented by the subpixel 23 can be increased.

Regarding saturation characteristics of current flowing when transistors are driven in a saturation region, even in the case where source-drain voltage of an OS transistor increases gradually, more stable current (saturation current) can be made to flow through an OS transistor than through a Si transistor. Thus, with the use of an OS transistor as the transistor 52, stable current can be made to flow through the light-emitting element 60, for example, even when a variation in current-voltage characteristics of the light-emitting element 60 occurs. In other words, when an OS transistor is driven in a saturation region, source-drain current hardly changes with an increase in source-drain voltage; hence, the emission luminance of the light-emitting element 60 can be stable.

As described above, with the use of an OS transistor as the transistor 52, it is possible to achieve “inhibition of black-level degradation”, “increase in emission luminance”, “increase in the number of gray levels”, “inhibition of variation in emission luminance”, and the like.

As the light-emitting element 60, an OLED (Organic Light Emitting Diode) or a QLED (Quantum-dot Light Emitting Diode) is preferably used, for example. Examples of a light-emitting substance contained in the light-emitting element 60 include a substance that emits fluorescent light (a fluorescent material), a substance that emits phosphorescent light (a phosphorescent material), a substance that exhibits thermally activated delayed fluorescence (a thermally activated delayed fluorescent (TADF) material), and an inorganic compound (e.g., a quantum dot material). An LED such as a micro-LED (Light Emitting Diode) can also be used as the light-emitting element 60.

Among the transistors included in the semiconductor devices illustrated in FIG. 1A and FIG. 1B, the transistor M1 having a short channel length can be used as the transistor 51 in the pixel circuit 40A illustrated in FIG. 2C, for example. Furthermore, among the transistors included in the semiconductor devices illustrated in FIG. 1A and FIG. 1B, the transistor M2 having a long channel length can be used as the transistor 52, for example.

The subpixel 23 illustrated in FIG. 2D includes a pixel circuit 40A_2 and the light-emitting element 60. The pixel circuit 40A_2 includes a capacitor 57b in addition to the components of the pixel circuit 40A. That is, the pixel circuit 40A_2 is a 2Tr2C-type pixel circuit. One electrode of the capacitor 57b is electrically connected to the other of the source and the drain of the transistor 52. The other electrode of the capacitor 57b is electrically connected to the wiring 47. The capacitor 57b is provided and the capacitance value of the capacitor is adjusted, whereby variation in the threshold voltage and mobility of the transistor 52 can be corrected more appropriately.

Among the transistors included in the semiconductor devices illustrated in FIG. 1A and FIG. 1B, the transistor M1 having a short channel length can be used as the transistor 51 in the pixel circuit 40A_2 illustrated in FIG. 2D, for example. Furthermore, among the transistors included in the semiconductor devices illustrated in FIG. 1A and FIG. 1B, the transistor M2 having a long channel length can be used as the transistor 52, for example.

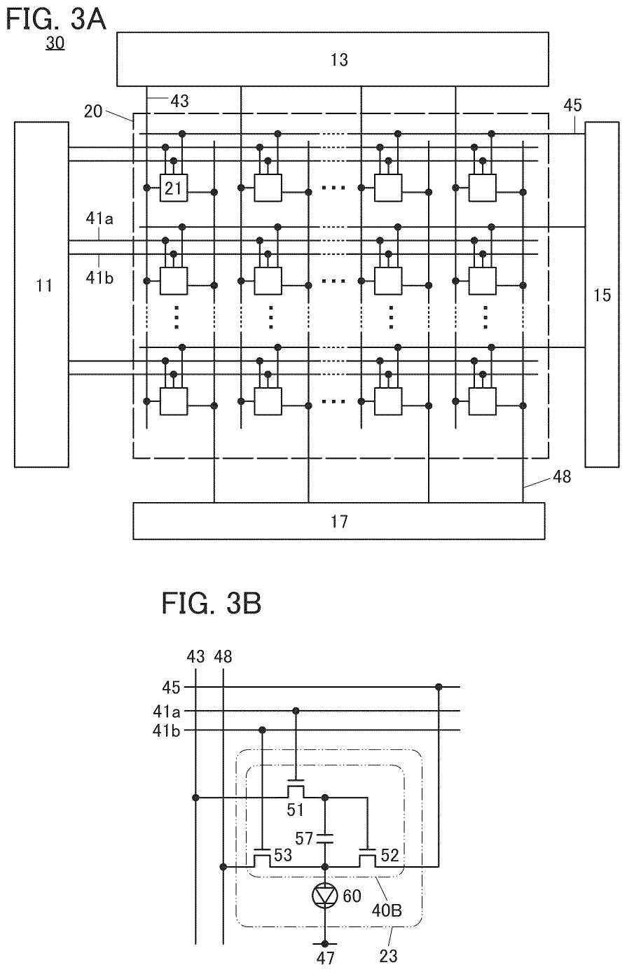

FIG. 3A is a block diagram illustrating a structure example of the display apparatus 30 and is a variation example of the display apparatus 30 illustrated in FIG. 2A. The display apparatus 30 illustrated in FIG. 3A is different from the display apparatus 30 illustrated in FIG. 2A in including a wiring 41a and a wiring 41b as the wiring 41 and including a reference potential generation circuit 17.

The reference potential generation circuit 17 is electrically connected to the pixels 21 through a wiring 48. For example, all the pixels 21 can be electrically connected to the reference potential generation circuit 17 through the wiring 48. The reference potential generation circuit 17 has a function of generating a reference potential and supplying it to the wiring 48. Since the potential of the wiring 48 is a reference potential, the wiring 48 can be referred to as a reference potential line. Note that the electrical characteristics of the pixels may be read out to the reference potential generation circuit 17 outside the pixels through the wiring 48. That is, the reference potential generation circuit 17 may have a function of sensing the electrical characteristics of the pixels. The reference potential generation circuit 17 may sense deterioration, variation, and the like of elements (transistors, light-emitting elements, or the like) in each pixel by reading the electrical characteristics of the pixels. Then, the read characteristics may be fed back to a video signal to correct deterioration and variation of image quality.

FIG. 3B is a circuit diagram illustrating a structure example of the subpixel 23 included in the pixel 21 illustrated in FIG. 3A. The subpixel 23 illustrated in FIG. 3B includes a pixel circuit 40B and the light-emitting element 60. The pixel circuit 40B has a structure in which a transistor 53 is added to the pixel circuit 40A. That is, the pixel circuit 40B is a 3Tr1C-type pixel circuit.

In the pixel circuit 40B, the gate of the transistor 51 is electrically connected to the wiring 41a. One of a source and a drain of the transistor 53 is electrically connected to the other of the source and the drain of the transistor 52, the other electrode of the capacitor 57, and one electrode of the light-emitting element 60. The other of the source and the drain of the transistor 53 is electrically connected to the wiring 48. A gate of the transistor 53 is electrically connected to the wiring 41b.

The transistor 53 has a function of a switch and has a function of controlling electrical continuity or discontinuity between the wiring 48 and the one electrode of the light-emitting element 60 on the basis of the potential of the wiring 41b. A reference potential is supplied to the wiring 48, for example. Variations in the gate source voltage of the transistor 53 can be reduced by the reference potential of the wiring 48 supplied through the transistor 52.

A current value that can be used for setting pixel parameters can be obtained with the use of the wiring 48. Specifically, the wiring 48 can function as a monitor line for outputting current flowing through the transistor 52 or current flowing through the light-emitting element 60 to the outside of the pixel 21. Current output to the wiring 48 can be converted into a potential by a source follower circuit, for example. Alternatively, the current can be converted into a digital signal by an A-D converter, for example. In the case where the wiring 48 functions as a monitor line, the display apparatus 30 does not necessarily include the reference potential generation circuit 17. In the case where the wiring 48 functions as a monitor line, the pixels 21 can be electrically connected to a different wiring 48 for each column.

As the transistor 53, an OS transistor is preferably used. As described above, an OS transistor has higher field-effect mobility than a transistor including amorphous silicon in a semiconductor layer, for example. Thus, with the use of an OS transistor as the transistor 53, the display apparatus 30 can be driven at high speed.

Among the transistors included in the semiconductor devices illustrated in FIG. 1A and FIG. 1B, the transistor M1 having a short channel length can be used as the transistor 51 or the transistor 53 in the pixel circuit 40B illustrated in FIG. 3B, for example. Furthermore, among the transistors included in the semiconductor devices illustrated in FIG. 1A and FIG. 1B, the transistor M2 having a long channel length can be used as the transistor 52, for example.

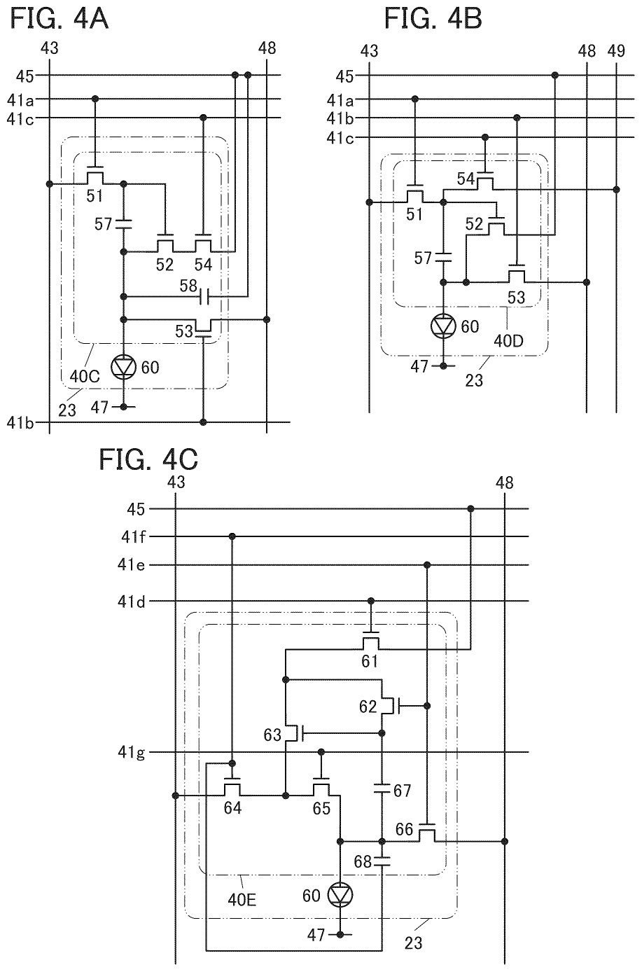

FIG. 4A, FIG. 4B, and FIG. 4C are each a circuit diagram illustrating a structure example of the subpixel 23 included in the pixel 21 illustrated in FIG. 3A. The subpixel 23 illustrated in FIG. 4A includes a pixel circuit 40C and the light-emitting element 60. The pixel circuit 40C has a structure in which a transistor 54 and a capacitor 58 are added to the pixel circuit 40B. That is, the pixel circuit 40C is a 4Tr2C-type pixel circuit.

In the pixel circuit 40C, one of the source and the drain of the transistor 52 is electrically connected to one of a source and a drain of the transistor 54. The other of the source and the drain of the transistor 54 is electrically connected to the wiring 45. A gate of the transistor 54 is electrically connected to the wiring 41c. One electrode of the capacitor 58 is electrically connected to the other of the source and the drain of the transistor 52, one of the source and the drain of the transistor 53, the other electrode of the capacitor 57, and one electrode of the light-emitting element 60. The other electrode of the capacitor 58 is electrically connected to the wiring 45.

The wiring 41c is electrically connected to the scan line driver circuit 11. In other words, in the case where the subpixel 23 included in the pixel 21 has the structure illustrated in FIG. 4A, the wiring 41a, the wiring 41b, and the wiring 41c are provided as the wiring 41 in the display apparatus 30.

The transistor 54 has a function of a switch and has a function of controlling electrical continuity or discontinuity between the wiring 45 and the one of the source and the drain of the transistor 52 on the basis of the potential of the wiring 41c.

When the transistor 54 is brought into an on state, current having a level corresponding to the gate potential of the transistor 52 flows from the wiring 45 to the wiring 47, for example. Thus, the light-emitting element 60 emits light with luminance corresponding to the gate potential of the transistor 52. When the transistor 54 is brought into an off state, on the other hand, current can be prevented from flowing through the light-emitting element 60; thus, the light-emitting element 60 can be prevented from emitting light.

As the transistor 54, an OS transistor is preferably used. As described above, an OS transistor has higher field-effect mobility than a transistor including amorphous silicon in a semiconductor layer, for example. Thus, with the use of an OS transistor as the transistor 54, the display apparatus 30 can be driven at high speed.

Among the transistors included in the semiconductor devices illustrated in FIG. 1A and FIG. 1B, the transistor M1 having a short channel length can be used as the transistor 51 or the transistor 53 in the pixel circuit 40C illustrated in FIG. 4A, for example. Furthermore, among the transistors included in the semiconductor devices illustrated in FIG. 1A and FIG. 1B, the transistor M2 having a long channel length can be used as the transistor 52 or the transistor 54, for example.

The subpixel 23 illustrated in FIG. 4B includes a pixel circuit 40D and the light-emitting element 60. The pixel circuit 40D has a structure in which the transistor 54 is added to the pixel circuit 40B. That is, the pixel circuit 40D is a 4Tr1C-type pixel circuit.

In the pixel circuit 40D, one of the source and the drain of the transistor 54 is electrically connected to the other of the source and the drain of the transistor 51, the gate of the transistor 52, and one electrode of the capacitor 57. The other of the source and the drain of the transistor 54 is electrically connected to a wiring 49. The gate of the transistor 54 is electrically connected to the wiring 41c. In the case where the subpixel 23 has the structure illustrated in FIG. 4B, the wiring 41a, the wiring 41b, and the wiring 41c are provided as the wiring 41 in the display apparatus 30.

When the transistor 54 is brought into an on state, the gate potential of the transistor 52 can be the potential of the wiring 49. Accordingly, current can be prevented from flowing through the light-emitting element 60, for example; thus, the light-emitting element 60 can be prevented from emitting light.

Among the transistors included in the semiconductor devices illustrated in FIG. 1A and FIG. 1B, the transistor M1 having a short channel length can be used as the transistor 51 or the transistor 54 in the pixel circuit 40D illustrated in FIG. 4B, for example. Furthermore, among the transistors included in the semiconductor devices illustrated in FIG. 1A and FIG. 1B, the transistor M2 having a long channel length can be used as the transistor 52 or the transistor 53, for example.

The subpixel 23 illustrated in FIG. 4C includes a pixel circuit 40E and the light-emitting element 60.

The pixel circuit 40E includes a transistor 61, a transistor 62, a transistor 63, a transistor 64, a transistor 65, a transistor 66, a capacitor 67, and a capacitor 68. That is, the pixel circuit 40E is a 6Tr2C-type pixel circuit.

In the pixel circuit 40E, one of a source and a drain of the transistor 61 is electrically connected to the wiring 45. The other of the source and the drain of the transistor 61 is electrically connected to one of a source and a drain of the transistor 62. The one of the source and the drain of the transistor 62 is electrically connected to one of a source and a drain of the transistor 63. A gate of the transistor 61 is electrically connected to a wiring 41d.

The other of the source and the drain of the transistor 62 is electrically connected to a gate of the transistor 63. The gate of the transistor 63 is electrically connected to one electrode of the capacitor 67. A gate of the transistor 62 is electrically connected to a wiring 41e.

One of a source and a drain of the transistor 64 is electrically connected to the wiring 43. The other of the source and the drain of the transistor 64 is electrically connected to the other of the source and the drain of the transistor 63. The other of the source and the drain of the transistor 63 is electrically connected to one of a source and a drain of the transistor 65. A gate of the transistor 64 is electrically connected to a wiring 41f.

The other of the source and the drain of the transistor 65 is electrically connected to one of a source and a drain of the transistor 66. The one of the source and the drain of the transistor 66 is electrically connected to the other electrode of the capacitor 67. The other electrode of the capacitor 67 is electrically connected to one electrode of the capacitor 68. The one electrode of the capacitor 68 is electrically connected to one electrode of the light-emitting element 60. A gate of the transistor 65 is electrically connected to a wiring 41g.

The other of the source and the drain of the transistor 66 is electrically connected to the wiring 48. A gate of the transistor 66 is electrically connected to the wiring 41e.

The other electrode of the capacitor 68 is electrically connected to the wiring 41f. The other electrode of the light-emitting element 60 is electrically connected to the wiring 47.

The wiring 41d, the wiring 41e, the wiring 41f, and the wiring 41g are electrically connected to the scan line driver circuit 11. In other words, in the case where the subpixel 23 included in the pixel 21 has the structure illustrated in FIG. 4C, the wiring 41d, the wiring 41e, the wiring 41f, and the wiring 41g are provided as the wiring 41 in the display apparatus 30.

The transistor 61, the transistor 62, the transistor 64, the transistor 65, and the transistor 66 each have a function of a switch. The transistor 61 has a function of controlling electrical continuity or discontinuity between the wiring 45 and the one of the source and the drain of the transistor 62 and the one of the source and the drain of the transistor 63 on the basis of the potential of the wiring 41d. The transistor 62 has a function of controlling electrical continuity or discontinuity between the other of the source and the drain of the transistor 61 and the one of the source and the drain of the transistor 63 and the gate of the transistor 63 and the one electrode of the capacitor 67 on the basis of the potential of the wiring 41e. The transistor 64 has a function of controlling electrical continuity or discontinuity between the wiring 43 and the other of the source and the drain of the transistor 63 and the one of the source and the drain of the transistor 65 on the basis of the potential of the wiring 41f. The transistor 65 has a function of controlling electrical continuity or discontinuity between the one electrode of the light-emitting element 60 and the other of the source and the drain of source of the transistor 63 and the other of the source and the drain of the transistor 64 on the basis of the potential of the wiring 41g. The transistor 66 has a function of controlling electrical continuity or discontinuity between the wiring 48 and the one electrode of the light-emitting element 60 on the basis of the potential of the wiring 41e.

As the transistor 61 to the transistor 66, OS transistors are preferably used. An OS transistor has higher field-effect mobility than a transistor including amorphous silicon in a semiconductor layer, for example. Thus, with the use of OS transistors as the transistor 61 to the transistor 66, the display apparatus 30 can be driven at high speed.

Among the transistors included in the semiconductor devices illustrated in FIG. 1A and FIG. 1B, the transistor M1 having a short channel length can be used as the transistor 61, the transistor 62, the transistor 63, the transistor 64, or the transistor 65 in the pixel circuit 40E illustrated in FIG. 4C, for example. Furthermore, among the transistors included in the semiconductor devices illustrated in FIG. 1A and FIG. 1B, the transistor M2 having a long channel length can be used as the transistor 66, for example.

### Structure Example of Memory Device

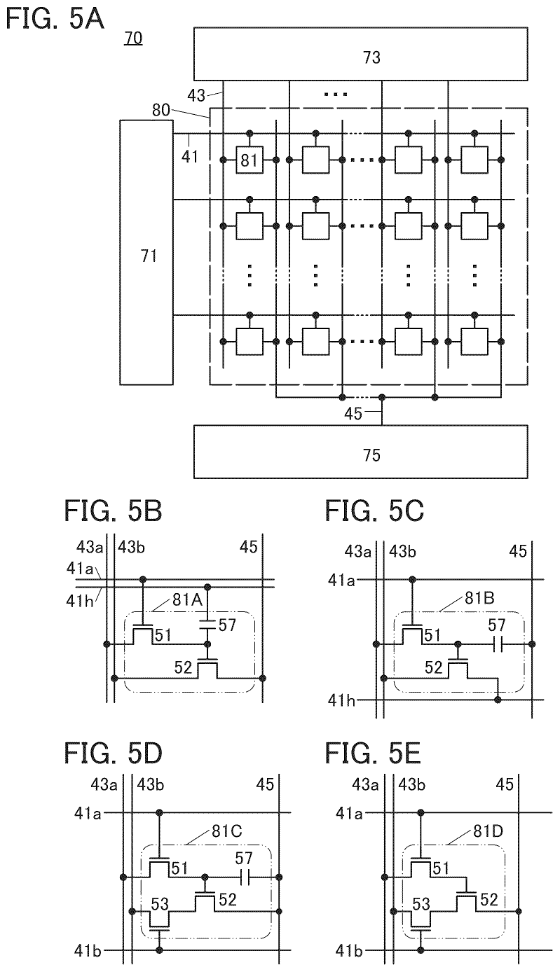

FIG. 5A is a block diagram illustrating a structure example of a memory device 70 in which the semiconductor device of one embodiment of the present invention can be used. The memory device 70 includes a memory portion 80, a word line driver circuit 71, a bit line driver circuit 73, and a power supply circuit 75. The memory portion 80 includes a plurality of memory cells 81 arranged in a matrix. Note that the power supply circuit 75 may be provided outside the memory device 70.

The word line driver circuit 71 is electrically connected to the memory cells 81 through the wiring 41. As in the display apparatus 30 illustrated in FIG. 2A, for example, the wiring 41 extends in the row direction of the matrix, for example. In the memory device 70, the wiring 41 functions as a word line.

The bit line driver circuit 73 is electrically connected to the memory cells 81 through the wiring 43. As in the display apparatus 30 illustrated in FIG. 2A, for example, the wiring 43 extends in the column direction of the matrix, for example. In the memory device 70, the wiring 43 functions as a bit line.

The power supply circuit 75 is electrically connected to the memory cells 81 through the wiring 45. For example, all the memory cells 81 can be electrically connected to the power supply circuit 75 through the same wiring 45. The wiring 45 functions as a power supply line.

The word line driver circuit 71 has a function of selecting, row by row, the memory cell 81 to which data is to be written. The word line driver circuit 71 has a function of selecting, row by row, the memory cell 81 from which data is to be read. Specifically, by outputting a signal to the wiring 41, the word line driver circuit 71 can select the memory cell 81 to which data is to be written or the memory cell 81 from which data is to be read.

The bit line driver circuit 73 has a function of writing data through the wiring 43 to the memory cell 81 selected by the word line driver circuit 71. The bit line driver circuit 73 has a function of reading data retained in the memory cell 81 by amplifying data output from the memory cell 81 to the wiring 43 and outputting the data to, for example, the outside of the memory device 70. Furthermore, the bit line driver circuit 73 has a function of precharging the wiring 43 before data is read from the memory cell 81.

The power supply circuit 75 has a function of generating a power supply potential and supplying it to the wiring 45. The power supply circuit 75 has a function of generating a high potential or a low potential and supplying it to the wiring 45, for example.

FIG. 5B, FIG. 5C, FIG. 5D, and FIG. 5E are circuit diagrams illustrating structure examples of the memory cell 81. Here, the memory cells 81 illustrated in FIG. 5B, FIG. 5C, FIG. 5D, and FIG. 5E are a memory cell 81A, a memory cell 81B, a memory cell 81C, and a memory cell 81D, respectively.

The memory cell 81A illustrated in FIG. 5B includes the transistor 51, the transistor 52, and the capacitor 57. That is, the memory cell 81A is a 2Tr1C-type memory cell.

To the memory cell 81A, the wiring 41a and a wiring 41h are electrically connected as the wiring 41 and a wiring 43a and a wiring 43b are electrically connected as the wiring 43. Specifically, one of the source and the drain of the transistor 51 is electrically connected to the wiring 43a. The other of the source and the drain of the transistor 51 is electrically connected to one electrode of the capacitor 57. The one electrode of the capacitor 57 is electrically connected to the gate of the transistor 52. The gate of the transistor 51 is electrically connected to the wiring 41a. The other electrode of the capacitor 57 is electrically connected to the wiring 41h. One of the source and the drain of the transistor 52 is electrically connected to the wiring 43b. The other of the source and the drain of the transistor 52 is electrically connected to the wiring 45.

In the memory cell 81A, when the transistor 51 is brought into an on state, data is written to the memory cell 81A through the wiring 43a, and when the transistor 51 is brought into an off state, the written data is retained. Thus, in the memory cell 81A, the wiring 41a can be referred to as a write word line and the wiring 43a can be referred to as a write bit line. Control of the potential of the wiring 41h enables the gate potential of the transistor 52 to be changed by capacitive coupling and the potential of the wiring 43b to be a potential corresponding to the data retained in the memory cell 81A. Thus, the bit line driver circuit 73 can read the data retained in the memory cell 81A. Accordingly, in the memory cell 81A, the wiring 41h can be referred to as a read word line and the wiring 43b can be referred to as a read bit line.

In the case where an OS transistor is used as the transistor 51 in the memory cell 81A, a structure in which the capacitor 57 is not included may be employed. In that case, the memory cell 81A is a 2TrOC-type memory cell.

Among the transistors included in the semiconductor devices illustrated in FIG. 1A and FIG. 1B, the transistor M1 having a short channel length can be used as the transistor 51 in the memory cell 81A, for example. Furthermore, among the transistors included in the semiconductor devices illustrated in FIG. 1A and FIG. 1B, the transistor M2 having a long channel length can be used as the transistor 52, for example. Note that a structure in which the transistor M2 is used as the transistor 51 and the transistor M1 is used as the transistor 52 may be employed.

The memory cell 81B illustrated in FIG. 5C is a variation example of the memory cell 81A, in which the other of the source and the drain of the transistor 52 is electrically connected to the wiring 41h and the other electrode of the capacitor 57 is electrically connected to the wiring 45. The word line driver circuit 71 controls the potential of the other of the source and the drain of the transistor 52 in the memory cell 81B, whereby data retained in the memory cell 81B can be output to the wiring 43b.

In the case where an OS transistor is used as the transistor 51 in the memory cell 81B, a structure in which the capacitor 57 is not included may be employed. In that case, the memory cell 81B is a 2TrOC-type memory cell.

Among the transistors included in the semiconductor devices illustrated in FIG. 1A and FIG. 1B, the transistor M1 having a short channel length can be used as the transistor 51 in the memory cell 81B, for example. Furthermore, among the transistors included in the semiconductor devices illustrated in FIG. 1A and FIG. 1B, the transistor M2 having a long channel length can be used as the transistor 52, for example. Note that a structure in which the transistor M2 is used as the transistor 51 and the transistor M1 is used as the transistor 52 may be employed.

The memory cell 81C illustrated in FIG. 5D is a variation example of the memory cell 81B and is different from the memory cell 81B in including the transistor 53. That is, the memory cell 81C is a 3Tr1C-type memory cell.

To the memory cell 81C, the wiring 41a and the wiring 41b are electrically connected as the wiring 41. Specifically, the gate of the transistor 53 is electrically connected to the wiring 41b. One of the source and the drain of the transistor 52 is electrically connected to one of the source and the drain of the transistor 53. The other of the source and the drain of the transistor 52 is electrically connected to the wiring 45. The other of the source and the drain of the transistor 53 is electrically connected to the wiring 43b.

The transistor 53 has a function of a switch and has a function of controlling electrical continuity or discontinuity between the one of the source and the drain of the transistor 52 and the wiring 43b on the basis of the potential of the wiring 41b. When the transistor 53 is brought into an on state, the potential of the wiring 43b can be a potential corresponding to data retained in the memory cell 81C. Thus, the bit line driver circuit 73 can read the data retained in the memory cell 81C. Accordingly, in the memory cell 81C, the wiring 41b can be referred to as a read word line.

Among the transistors included in the semiconductor devices illustrated in FIG. 1A and FIG. 1B, the transistor M1 having a short channel length can be used as the transistor 51 or the transistor 53 in the memory cell 81C, for example. Furthermore, among the transistors included in the semiconductor devices illustrated in FIG. 1A and FIG. 1B, the transistor M2 having a long channel length can be used as the transistor 52, for example. Note that a structure in which the transistor M2 is used as the transistor 51 or the transistor 53 and the transistor M1 is used as the transistor 52 may be employed.

The memory cell 81D illustrated in FIG. 5E is a variation example of the memory cell 81C and is different from the memory cell 81C in not including the capacitor 57. That is, the memory cell 81D is a 3TrOC-type memory cell. In the memory cell 81D, the wiring 45 is electrically connected to the other of the source and the drain of the transistor 52.

In the case where parasitic capacitance such as the gate capacitance of the transistor 52 is sufficiently high, for example, data can be retained in the memory cell even without the capacitor 57.

Among the transistors included in the semiconductor devices illustrated in FIG. 1A and FIG. 1B, the transistor M1 having a short channel length can be used as the transistor 51 or the transistor 53 in the memory cell 81D, for example. Furthermore, among the transistors included in the semiconductor devices illustrated in FIG. 1A and FIG. 1B, the transistor M2 having a long channel length can be used as the transistor 52, for example. Note that a structure in which the transistor M2 is used as the transistor 51 or the transistor 53 and the transistor M1 is used as the transistor 52 may be employed.

An OS transistor is preferably used as the transistor 51 included in each of the memory cell 81A to the memory cell 81D. As described above, an OS transistor has an extremely low off-state current. Thus, with the use of an OS transistor as the transistor 51, charge accumulated in the capacitor 57 can be retained for a long period. In addition, the gate potential of the transistor 52 can be retained for a long period. Accordingly, data written to the memory cell 81 can be retained for a long period and therefore the frequency of the refresh operation (data rewriting to the memory cell 81) can be reduced. Thus, the power consumption of the memory device 70 can be reduced.

An OS transistor is preferably used as each of the transistor 52 and the transistor 53 as well. As described above, an OS transistor has higher field-effect mobility than a transistor including amorphous silicon in a semiconductor layer, for example. Thus, with the use of an OS transistor as each of the transistor 51 to the transistor 53, the memory device 70 can be driven at high speed.

The memory cell 81A to the memory cell 81D can each be referred to as a NOSRAM (registered trademark). NOSRAM is an abbreviation for “Nonvolatile Oxide Semiconductor Random Access Memory (RAM)”. The NOSRAM is capable of reading retained data without destruction (non-destructive reading). Thus, the NOSRAM is suitable for arithmetic processing in which only a data reading operation is repeated many times.

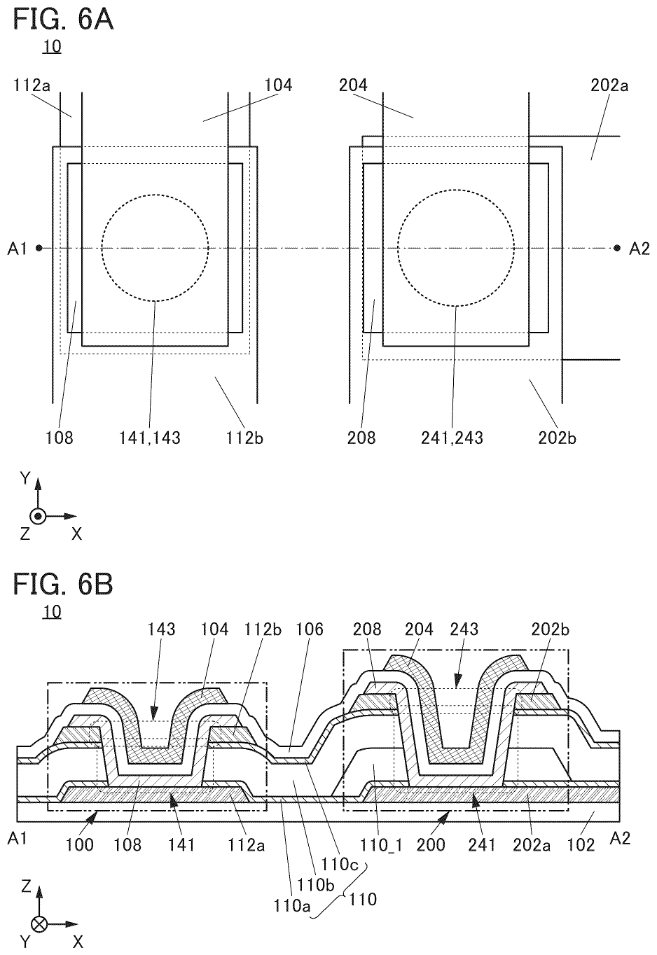

Hereinafter, specific structure examples of a semiconductor device of one embodiment of the present invention will be described with reference to FIG. 6A to FIG. 42B.

### Structure Example 1

FIG. 6A is a plan view of a semiconductor device 10. FIG. 6B is a cross-sectional view along dashed-dotted line A1-A2 in FIG. 6A. Some components (e.g., an insulating layer) of the semiconductor device 10 are not illustrated in FIG. 6A. In plan views of semiconductor devices in the following drawings, some components are not illustrated as in FIG. 6A.

The semiconductor device 10 includes a transistor 100 and a transistor 200. The transistor 100 and the transistor 200 are provided over the substrate 102. In the semiconductor device 10, the transistor 100 corresponds to the transistor M1 in FIG. 1A and FIG. 1B, and the transistor 200 corresponds to the transistor M2 in FIG. 1A and FIG. 1B.

The transistor 100 includes the conductive layer 104, the insulating layer 106, the semiconductor layer 108, the conductive layer 112a, and the conductive layer 112b. The conductive layer 104 functions as a gate electrode. Part of the insulating layer 106 functions as a gate insulating layer. The conductive layer 112a functions as one of a source electrode and a drain electrode, and the conductive layer 112b functions as the other of the source electrode and the drain electrode. In the semiconductor layer 108, the whole region that is between the source electrode and the drain electrode and overlaps with the gate electrode with the gate insulating layer therebetween functions as a channel formation region. In the semiconductor layer 108, a region in contact with the source electrode functions as a source region, and a region in contact with the drain electrode functions as a drain region.

The transistor 200 includes the conductive layer 204, the insulating layer 106, the semiconductor layer 208, the conductive layer 202a, and the conductive layer 202b. The conductive layer 204 functions as a gate electrode. Part of the insulating layer 106 functions as a gate insulating layer. The conductive layer 202a functions as one of a source electrode and a drain electrode, and the conductive layer 202b functions as the other of the source electrode and the drain electrode. In the semiconductor layer 208, the whole region that is between the source electrode and the drain electrode and overlaps with the gate electrode with the gate insulating layer therebetween functions as a channel formation region. In the semiconductor layer 208, a region in contact with the source electrode functions as a source region, and a region in contact with the drain electrode functions as a drain region.

The conductive layer 112a and the conductive layer 202a are provided over the substrate 102. The conductive layer 112a and the conductive layer 202a can be formed using the same material in the same step.

The insulating layer 110 (an insulating layer 110a, an insulating layer 110b, and an insulating layer 110c) is provided over the conductive layer 112a. Although FIG. 6B illustrates the insulating layer 110 having a three-layer structure of the insulating layer 110a, the insulating layer 110b, and the insulating layer 110c, the insulating layer 110a and the insulating layer 110c are not necessarily provided. The same applies to other structure examples described in this specification. The conductive layer 112b is provided over the insulating layer 110. The insulating layer 110 includes a region sandwiched between the conductive layer 112a and the conductive layer 112b. The conductive layer 112a includes a region overlapping with the conductive layer 112b with the insulating layer 110 therebetween. The insulating layer 110 has an opening 141 in a region overlapping with the conductive layer 112a. The conductive layer 112a is exposed in the opening 141. The conductive layer 112b has an opening 143 in a region overlapping with the conductive layer 112a. The opening 143 is provided in a region overlapping with the opening 141.

The semiconductor layer 108 is provided to cover the opening 141 and the opening 143. The semiconductor layer 108 includes a region in contact with the top surface and a side surface of the conductive layer 112b, a side surface of the insulating layer 110, and the top surface of the conductive layer 112a. The semiconductor layer 108 is electrically connected to the conductive layer 112a via the opening 141 and the opening 143. The semiconductor layer 108 has a shape along the top surface and the side surface of the conductive layer 112b, the side surface of the insulating layer 110, and the top surface of the conductive layer 112a.

The insulating layer 110a, an insulating layer 110_1 over the insulating layer 110a, the insulating layer 110b over the insulating layer 110_1, and the insulating layer 110c over the insulating layer 110b are provided over the conductive layer 202a. The conductive layer 202b is provided over the insulating layer 110c. Each of the insulating layer 110a, the insulating layer 110_1, the insulating layer 110b, and the insulating layer 110c includes a region sandwiched between the conductive layer 202a and the conductive layer 202b. The conductive layer 202a includes a region overlapping with the conductive layer 202b with the insulating layer 110a, the insulating layer 110_1, the insulating layer 110b, and the insulating layer 110c therebetween. The insulating layer 110a, the insulating layer 110_1, the insulating layer 110b, and the insulating layer 110c have an opening 241 in a region overlapping with the conductive layer 202a. The conductive layer 202a is exposed in the opening 241. The conductive layer 202b has an opening 243 in a region overlapping with the conductive layer 202a. The opening 243 is provided in a region overlapping with the opening 241.

The semiconductor layer 208 is provided to cover the opening 241 and the opening 243. The semiconductor layer 208 includes a region in contact with the top surface and a side surface of the conductive layer 202b, a side surface of the insulating layer 110c, a side surface of the insulating layer 110b, a side surface of the insulating layer 110_1, a side surface of the insulating layer 110a, and the top surface of the conductive layer 202a. The semiconductor layer 208 is electrically connected to the conductive layer 202a via the opening 241 and the opening 243. The semiconductor layer 208 has a shape along the top surface and the side surface of the conductive layer 202b, the side surface of the insulating layer 110c, the side surface of the insulating layer 110b, the side surface of the insulating layer 110_1, the side surface of the insulating layer 110a, and the top surface of the conductive layer 202a.

The conductive layer 202b can be formed using the same material in the same step as the conductive layer 112b. The semiconductor layer 208 can be formed using the same material in the same step as the semiconductor layer 108.

The insulating layer 106 functioning as the gate insulating layer of the transistor 100 is provided to cover the opening 141 and the opening 143 with the semiconductor layer 108 therebetween. The insulating layer 106 functioning also as the gate insulating layer of the transistor 200 is provided to cover the opening 241 and the opening 243 with the semiconductor layer 208 therebetween. The insulating layer 106 is provided over the semiconductor layer 108, the conductive layer 112b, the semiconductor layer 208, the conductive layer 202b, and the insulating layer 110c. The insulating layer 106 includes a region in contact with the top surface of the semiconductor layer 108, a side surface of the conductive layer 112b, the top surface of the semiconductor layer 208, a side surface of the conductive layer 202b, and the top surface of the insulating layer 110c. The insulating layer 106 has a shape along the top surface of the insulating layer 110c, the side surface of the conductive layer 112b, the top surface of the semiconductor layer 108, the side surface of the conductive layer 202b, and the top surface of the semiconductor layer 208.

The conductive layer 104 functioning as the gate electrode of the transistor 100 is provided in contact with the top surface of the insulating layer 106. The conductive layer 104 includes a region overlapping with the semiconductor layer 108 with the insulating layer 106 therebetween. In the region, the conductive layer 104 has a shape along the top surface of the insulating layer 106.

The conductive layer 204 functioning as the gate electrode of the transistor 200 is provided in contact with the top surface of the insulating layer 106. The conductive layer 204 includes a region overlapping with the semiconductor layer 208 with the insulating layer 106 therebetween. In the region, the conductive layer 204 has a shape along the top surface of the insulating layer 106.

The conductive layer 204 can be formed using the same material in the same step as the conductive layer 104.

The transistor 100 and the transistor 200 include the gate electrodes above the semiconductor layer 108 and the semiconductor layer 208 and are thus what are called top-gate transistors. Furthermore, since the bottom surface of the semiconductor layer 108 (the surface on the substrate 102 side) is in contact with the source electrode and the drain electrode of the transistor 100 and the bottom surface of the semiconductor layer 208 (the surface on the substrate 102 side) is in contact with the source electrode and the drain electrode of the transistor 200, each of the transistor 100 and the transistor 200 can be referred to as a TGBC (Top Gate Bottom Contact) transistor.

In each of the transistor 100 and the transistor 200, the source electrode and the drain electrode are positioned at different levels with respect to the substrate surface, so that drain current flows in the height direction (vertical direction). Accordingly, each of the transistor 100 and the transistor 200 can also be referred to as a vertical transistor, a vertical-channel transistor, VFET (vertical field-effect transistor), or the like.

As described above, the transistor 100 includes the insulating layer 110a, the insulating layer 110b, and the insulating layer 110c sandwiched between the source electrode and the drain electrode, and the transistor 200 includes the insulating layer 110a, the insulating layer 110_1, the insulating layer 110b, and the insulating layer 110c sandwiched between the source electrode and the drain electrode. Thus, the transistor 200 can be regarded as a transistor having a longer channel length than that of the transistor 100 by the thickness of the insulating layer 110_1. In other words, the transistor 100 can be regarded as a transistor having a shorter channel length than that of the transistor 200 by the thickness of the insulating layer 110_1.

The channel length of the transistor 100 can be controlled by the thickness of the insulating layer (the insulating layer 110a, the insulating layer 110b, and the insulating layer 110c) provided between the conductive layer 112a and the conductive layer 112b. Similarly, the channel length of the transistor 200 can be controlled by the thickness of the insulating layer (the insulating layer 110a, the insulating layer 110_1, the insulating layer 110b, and the insulating layer 110c) provided between the conductive layer 202a and the conductive layer 202b. Accordingly, a transistor with a channel length smaller than the resolution limit of a light exposure apparatus used for manufacturing the transistor can be manufactured with high accuracy. In addition, since an extremely small channel length can be formed, a transistor having a high on-state current can be achieved.

The channel length of each of the transistor 100 and the transistor 200 can be controlled only by adjusting the thickness of the insulating layer between the source electrode and the drain electrode; thus, in the case of manufacturing a plurality of the transistors 100 and a plurality of the transistors 200, characteristic variations among the transistors 100 and among the transistors 200 in the substrate plane can be reduced. This allows the semiconductor device including the transistors 100 and the transistors 200 to operate stably and to have high reliability. When the characteristic variations are reduced, the circuit design flexibility is increased and the operation voltage of the semiconductor device can be reduced. As a result, power consumption of the semiconductor device can be reduced.

The transistor 100 having a short channel length and the transistor 200 having a long channel length can be formed over the same substrate by sharing some of the formation steps, as described above. For example, the transistor 100 is used as a transistor required to have a high on-state current and the transistor 200 is used as a transistor required to have favorable saturation characteristics, thereby providing the semiconductor device 10 with high performance.

In the case where the semiconductor device 10 of one embodiment of the present invention is used for a display apparatus, for example, the transistor 100 can be used as a selection transistor included in a pixel circuit included in the display apparatus, and the transistor 200 can be used as a driving transistor included in the pixel circuit included in the display apparatus. The transistor 100 can be used as a transistor included in a driver circuit (e.g., a scan line driver circuit or a signal line driver circuit) included in the display apparatus, and the transistor 200 can be used as a transistor included in the pixel circuit included in the display apparatus. Examples of the display apparatus in which the semiconductor device of one embodiment of the present invention can be used are as described with reference to FIG. 2A to FIG. 4C.

Although the shapes of the opening 141 and the opening 143 in a plan view and the shapes of the opening 241 and the opening 243 in a plan view are each illustrated as a circle in FIG. 6A, one embodiment of the present invention is not limited thereto. The shape of each opening in a plan view can be a circle or an ellipse, for example. The shape of each opening in a plan view may be a polygon such as a triangle, a tetragon (including a rectangle, a rhombus, and a square), or a pentagon; or the polygon with rounded corners.

Components of the transistor 100 and the transistor 200 are described in detail.

In the transistor 100, an end portion of the conductive layer 112b on the opening 143 side is preferably aligned or substantially aligned with an end portion of the insulating layer 110c on the opening 141 side. It can be said that the shape of the opening 143 in a plan view matches or substantially matches the shape of the opening 141 in a plan view. In this specification and the like, the end portion of the conductive layer 112b on the opening 143 side refers to an end portion of the bottom surface of the conductive layer 112b on the opening 143 side. The bottom surface of the conductive layer 112b refers to a surface thereof on the insulating layer 110c side. The end portion of the insulating layer 110c on the opening 141 side refers to an end portion of the top surface of the insulating layer 110c on the opening 141 side. The top surface of the insulating layer 110c refers to a surface thereof on the conductive layer 112b side. The shape of the opening 143 in a plan view refers to the shape of the end portion of the bottom surface of the conductive layer 112b on the opening 143 side. The shape of the opening 141 in a plan view refers to the shape of the end portion of the top surface of the insulating layer 110c on the opening 141 side.

The opening 141 can be formed using a resist mask used for the formation of the opening 143, for example. Specifically, an insulating film to be the insulating layer 110, a conductive film to be the conductive layer 112b over the insulating film, and a resist mask over the conductive film are formed. After that, the opening 143 is formed in the conductive film to be the conductive layer 112b using the resist mask and then the opening 141 is formed in the insulating film to be the insulating layer 110 using the resist mask, whereby an end portion of the opening 141 and an end portion of the opening 143 can be aligned or substantially aligned with each other. With such a structure, a process can be simplified.

The opening 141 may be formed in a step different from that of the opening 143 after the opening 143 is formed. There is no particular limitation on the formation order of the opening 141 and the opening 143. For example, after the opening 141 is formed in the insulating film to be the insulating layer 110, the conductive film to be the conductive layer 112b may be formed and the opening 143 may be formed in the conductive film.

When the conductive layer 112b, the opening 143, and the opening 141 in the above description of the transistor 100 are replaced with the conductive layer 202b, the opening 243, and the opening 241, respectively, the same description can be applied to the transistor 200.

The opening 143 and the opening 243 can be formed in parallel in the same step. The opening 141 and the opening 241 can be formed in parallel in the same step.

In the transistor 100, the end portion of the conductive layer 112b on the opening 143 side is not necessarily aligned with the end portion of the insulating layer 110c on the opening 141 side. That is, the shape of the opening 143 in a plan view does not need to match the shape of the opening 141 in a plan view. In a plan view, the opening 143 preferably encompasses the opening 141. The end portion of the conductive layer 112b on the opening 143 side may be located outward from the end portion of the insulating layer 110c on the opening 141 side. In that case, the semiconductor layer 108 includes a region in contact with the top surface and the side surface of the conductive layer 112b, the top surface and the side surface of the insulating layer 110, and the top surface of the conductive layer 112a. With such a structure, a step on the formation surface of a layer (e.g., the semiconductor layer 108) formed over the conductive layer 112a, the insulating layer 110, and the conductive layer 112b can be small. Accordingly, the coverage with the layer formed over the conductive layer 112a, the insulating layer 110, and the conductive layer 112b can be improved, which can inhibit defects such as step disconnection or a void from being generated in the layer.

The above description can also be applied to the transistor 200 when the conductive layer 112b, the opening 143, the opening 141, the semiconductor layer 108, and the conductive layer 112a in the transistor 100 are replaced with the conductive layer 202b, the opening 243, the opening 241, the semiconductor layer 208, and the conductive layer 202a, respectively.

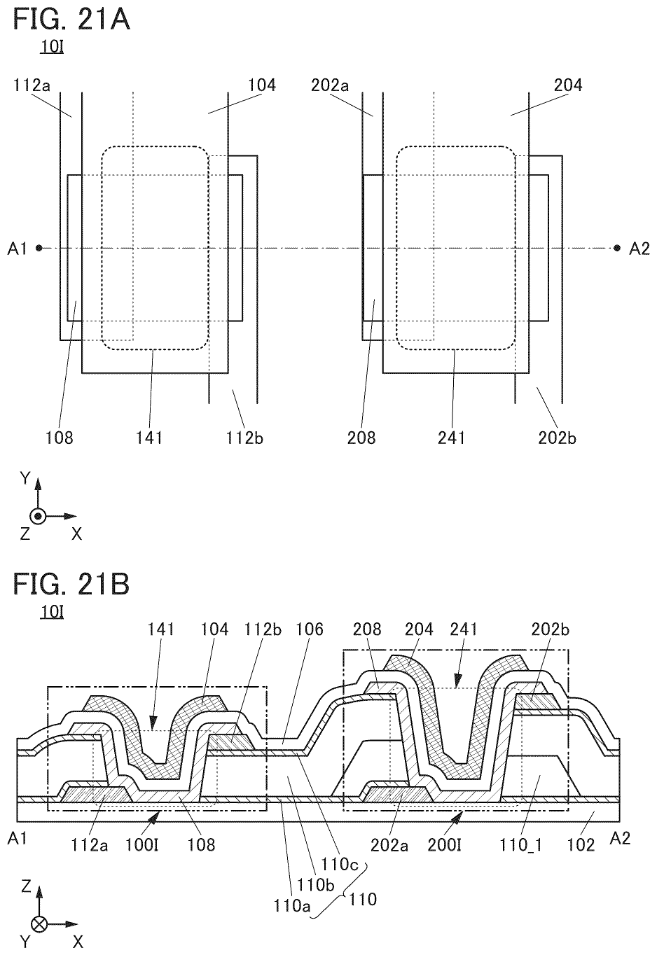

Although this embodiment describes the structure in which the opening 141 and the opening 143 are provided in the insulating layer 110 and the conductive layer 112b, respectively, and the semiconductor layer 108 is provided to cover the opening 141 and the opening 143, one embodiment of the present invention is not limited thereto. In one embodiment of the present invention, the transistor 100 includes a first region where the insulating layer 110 is provided over the conductive layer 112a and a second region where the insulating layer 110 is not provided over the conductive layer 112a. In the transistor 100, the semiconductor layer 108 is provided at a step generated by the first region and the second region. The insulating layer 106 is provided over the semiconductor layer 108, and the conductive layer 104 is provided to overlap with the semiconductor layer 108 with the insulating layer 106 therebetween (see FIG. 21A to FIG. 23B).

Similarly, although this embodiment describes the structure in which the opening 241 and the opening 243 are provided in the insulating layer 110 and the conductive layer 202b, respectively, and the semiconductor layer 208 is provided to cover the opening 241 and the opening 243, one embodiment of the present invention is not limited thereto. In one embodiment of the present invention, the transistor 200 includes a first region where the insulating layer 110 is provided over the conductive layer 202a and a second region where the insulating layer 110 is not provided over the conductive layer 202a. In the transistor 200, the semiconductor layer 208 is provided at a step generated by the first region and the second region. The insulating layer 106 is provided over the semiconductor layer 208, and the conductive layer 204 is provided to overlap with the semiconductor layer 208 with the insulating layer 106 therebetween (see FIG. 21A to FIG. 23B).

In the transistor 100, the semiconductor layer 108 preferably covers the end portion of the conductive layer 112b on the opening 143 side. FIG. 6B and the like illustrate a structure in which an end portion of the semiconductor layer 108 is positioned over the conductive layer 112b. In other words, the end portion of the semiconductor layer 108 is in contact with the top surface of the conductive layer 112b. The semiconductor layer 108 may extend to and cover an end portion of the conductive layer 112b on the side that does not face the opening 143. The end portion of the semiconductor layer 108 may be in contact with the top surface of the insulating layer 110c.

The semiconductor layer 108 is provided to cover the opening 141 and the opening 143. As illustrated in FIG. 6B and the like, the semiconductor layer 108 includes a region in contact with the top surface of the conductive layer 112a in the opening 141.

The above description can also be applied to the transistor 200 when the semiconductor layer 108, the conductive layer 112b, the opening 143, the opening 141, and the conductive layer 112a in the transistor 100 are replaced with the semiconductor layer 208, the conductive layer 202b, the opening 243, the opening 241, and the conductive layer 202a, respectively.

Although the semiconductor layer 108 and the semiconductor layer 208 each have a single-layer structure in FIG. 6B and the like, one embodiment of the present invention is not limited thereto. The semiconductor layer 108 and the semiconductor layer 208 may each have a stacked-layer structure of two or more layers.

The insulating layer 106 is provided over the semiconductor layer 108 and the semiconductor layer 208.

The conductive layer 104 is provided to cover the opening 141 and the opening 143 with the insulating layer 106 therebetween. The conductive layer 204 is provided to cover the opening 241 and the opening 243 with the insulating layer 106 therebetween.

As illustrated in FIG. 6B and the like, in the transistor 100, the conductive layer 104 includes the region overlapping with the semiconductor layer 108 with the insulating layer 106 therebetween in the opening 141 and the opening 143. The conductive layer 104 includes a region overlapping with the conductive layer 112a and a region overlapping with the conductive layer 112b with the insulating layer 106 and the semiconductor layer 108 therebetween. The conductive layer 104 preferably covers the end portion of the conductive layer 112b on the opening 143 side. With such a structure, in the semiconductor layer 108, the whole region that is between the source electrode and the drain electrode and overlaps with the gate electrode with the gate insulating layer therebetween can function as a channel formation region. The conductive layer 104 may extend to and cover the end portion of the conductive layer 112b on the side that does not face the opening 143. The conductive layer 104 may extend to and cover the end portion of the semiconductor layer 108.

The above description can also be applied to the transistor 200 when the conductive layer 104, the opening 141, the opening 143, the semiconductor layer 108, the conductive layer 112a, and the conductive layer 112b in the transistor 100 are replaced with the conductive layer 204, the opening 241, the opening 243, the semiconductor layer 208, the conductive layer 202a, and the conductive layer 202b, respectively.

In the transistor 100, the conductive layer 112a, the conductive layer 112b, and the conductive layer 104 can each function as a wiring. Similarly, in the transistor 200, the conductive layer 202a, the conductive layer 202b, and the conductive layer 204 can each function as a wiring. Each of the transistor 100 and the transistor 200 can be provided in a region where these wirings overlap with each other; thus, the area occupied by the transistor 100, the transistor 200, and the wirings can be reduced in a circuit including the transistor 100, the transistor 200, and the wirings. Accordingly, the area occupied by the circuit can be reduced, which makes it possible to provide a small semiconductor device. In the case where the semiconductor device 10 of one embodiment of the present invention is used for a pixel circuit of a display apparatus, for example, the area occupied by the pixel circuit can be reduced and a high-resolution display apparatus can be provided. In the case where the semiconductor device 10 of one embodiment of the present invention is used for a driver circuit (e.g., a scan line driver circuit or a signal line driver circuit) of a display apparatus, the area occupied by the driver circuit can be reduced and the display apparatus can have a narrow bezel. In the case where the semiconductor device 10 of one embodiment of the present invention is used for a memory cell of a memory device, the area occupied by the memory cell can be reduced and a minute memory device can be provided.

In the semiconductor device 10 of one embodiment of the present invention, the conductive layer 112a and the conductive layer 202a, the conductive layer 112b and the conductive layer 202b, and the conductive layer 104 and the conductive layer 204, which also function as wirings, are provided in different layers. Accordingly, the wirings can be placed in their respective layers, leading to high layout flexibility and a reduction in the area occupied by a circuit.

Here, the channel length and the channel width of the transistor 100 are described with reference to FIG. 7A and FIG. 7B. FIG. 7A is a plan view of the transistor 100. FIG. 7B is an enlarged view of the transistor 100 illustrated in FIG. 6B.

The description of the channel length and the channel width of the transistor 100 below can also be applied to the transistor 200, which is a vertical-channel transistor like the transistor 100.

In the semiconductor layer 108, the region in contact with the conductive layer 112a functions as one of the source region and the drain region, and the region in contact with the conductive layer 112b functions as the other of the source region and the drain region. In the semiconductor layer 108, a region between the source region and the drain region functions as a channel formation region.

The channel length of the transistor 100 is a distance between the source region and the drain region. In FIG. 7B, a channel length L100 of the transistor 100 is indicated by a dashed double-headed arrow. In a cross-sectional view, the channel length L100 is a distance between an end portion of the region where the semiconductor layer 108 is in contact with the conductive layer 112a and an end portion of the region where the semiconductor layer 108 is in contact with the conductive layer 112b.

Here, the channel length L100 of the transistor 100 corresponds to the length of the side surface of the insulating layer 110 (the insulating layer 110a, the insulating layer 110b, and the insulating layer 110c) on the opening 141 side in a cross-sectional view. That is, the channel length L100 is determined depending on a thickness T110 of the insulating layer 110 and an angle θ110 formed by the side surface of the insulating layer 110 on the opening 141 side and the formation surface of the insulating layer 110 (here, the top surface of the conductive layer 112a), and is not affected by the performance of a light exposure apparatus used for manufacturing the transistor. Thus, the channel length L100 can be a value smaller than the resolution limit of the light exposure apparatus, which enables the transistor to have a minute size. For example, the length L100 is preferably greater than or equal to 0.010 μm and less than 3.0 μm, further preferably greater than or equal to 0.050 μm and less than 3.0 μm, still further preferably greater than or equal to 0.10 μm and less than 3.0 μm, yet still further preferably greater than or equal to 0.15 μm and less than 3.0 μm, yet still further preferably greater than or equal to 0.20 μm and less than 3.0 μm, yet still further preferably greater than or equal to 0.20 μm and less than or equal to 2.5 μm, yet still further preferably greater than or equal to 0.20 μm and less than or equal to 2.0 μm, yet still further preferably greater than or equal to 0.20 μm and less than or equal to 1.5 μm, yet still further preferably greater than or equal to 0.30 μm and less than or equal to 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm. In FIG. 7B, the thickness T110 of the insulating layer 110 is indicated by a dashed-dotted double-headed arrow.

When the channel length L100 is small, the transistor 100 can have a high on-state current. With the use of the transistor 100 with a small channel length L100, a circuit capable of high-speed operation can be manufactured. Furthermore, the area occupied by the circuit can be reduced. Thus, a small semiconductor device can be obtained. For example, when the semiconductor device 10 of one embodiment of the present invention is used in a large display apparatus or a high-resolution display apparatus, signal delay in wirings can be reduced and display unevenness can be inhibited even when the number of wirings is increased. In addition, since the area occupied by the circuit can be reduced, the bezel of the display apparatus can be narrowed.

By contrast, when the channel length L100 is large, the transistor 100 can be a transistor having favorable saturation characteristics. When the channel length of the transistor is increased, the withstand voltage between the source and the drain is improved; thus, the use of the transistor 100 with a small channel length L100 enables manufacture of a circuit required to have high withstand voltage. In the case where the transistor 100 with a large channel length L100 is used in a display apparatus, for example, the transistor 100 can be suitably used as a driving transistor included in a pixel circuit by taking advantage of the favorable saturation characteristics.

By adjusting the thickness T110 and the angle θ110 of the insulating layer 110, the channel length L100 can be controlled.

The thickness T110 of the insulating layer 110 is preferably greater than or equal to 0.010 μm and less than 3.0 μm, greater than or equal to 0.050 μum and less than or equal to 2.5 μm, greater than or equal to 0.10 μm and less than or equal to 2.0 μm, greater than or equal to 0.15 μm and less than or equal to 1.5 μm, greater than or equal to 0.20 μm and less than or equal to 1.2 μm, greater than or equal to 0.30 μm and less than or equal to 1.0 μm, greater than or equal to 0.40 μm and less than or equal to 1.0 μm, or greater than or equal to 0.50 μm and less than or equal to 1.0 μm.

The side surface of the insulating layer 110 on the opening 141 side preferably has a tapered shape. The angle θ110 formed by the side surface of the insulating layer 110 on the opening 141 side and the formation surface of the insulating layer 110 (here, the top surface of the conductive layer 112a) is preferably less than 90°. By reducing the angle θ110, the coverage with a layer (e.g., the semiconductor layer 108) provided over the insulating layer 110 can be improved. However, reducing the angle θ110 might reduce the contact area between the semiconductor layer 108 and the conductive layer 112a to increase the contact resistance between the semiconductor layer 108 and the conductive layer 112a. The angle θ110 can be, for example, greater than or equal to 30° and less than 90°, greater than or equal to 35° and less than or equal to 85°, greater than or equal to 40° and less than or equal to 80°, greater than or equal to 45° and less than or equal to 80°, greater than or equal to 50° and less than or equal to 80°, greater than or equal to 55° and less than or equal to 80°, greater than or equal to 60° and less than or equal to 80°, greater than or equal to 65° and less than or equal to 80°, or greater than or equal to 70° and less than or equal to 80°. When the angle θ110 is in the above range, the coverage with the layer (e.g., the semiconductor layer 108) formed over the conductive layer 112a and the insulating layer 110 can be improved, which can inhibit defects such as step disconnection or a void from being generated in the layer. In addition, the contact resistance between the semiconductor layer 108 and the conductive layer 112a can be reduced.

Although FIG. 7B and the like illustrate the structure in which the side surface of the insulating layer 110 on the opening 141 side is linear in a cross-sectional view, one embodiment of the present invention is not limited thereto. In a cross-sectional view, the side surface of the insulating layer 110 on the opening 141 side may be curved, or the side surface may include both a linear region and a curved region.

It is preferable that the conductive layer 112b not be provided in the opening 141. Specifically, it is preferable that the conductive layer 112b not include a region in contact with the side surface of the insulating layer 110 on the opening 141 side. In the case where the conductive layer 112b is also provided inside the opening 141, the channel length L100 of the transistor 100 is shorter than the length of the side surface of the insulating layer 110 on the opening 141 side and the channel length L100 is difficult to control in some cases. Accordingly, it is preferable that the plan-view shape of the opening 143 match the plan-view shape of the opening 141, or the opening 143 encompass the opening 141 in a plan view.

The channel width of the transistor 100 is the length of the channel formation region in a direction orthogonal to the channel length direction. In other words, the channel width is the length of the source region or the length of the drain region in the direction orthogonal to the channel length direction. That is, the channel width is the length of the region where the semiconductor layer 108 is in contact with the conductive layer 112a or the length of the region where the semiconductor layer 108 is in contact with the conductive layer 112b in the direction orthogonal to the channel length direction. Here, the channel width of the transistor 100 is described as the length of the region where the semiconductor layer 108 is in contact with the conductive layer 112b in the direction orthogonal to the channel length direction. In FIG. 7A and FIG. 7B, a channel width W100 of the transistor 100 is indicated by a solid double-headed arrow. The channel width W100 is the length of the perimeter of the opening 143 in a plan view. Specifically, the channel width W100 is the length of the end portion of the bottom surface of the conductive layer 112b (the surface on the insulating layer 110 side) on the opening 143 side in a plan view.

Although the channel width of the transistor 100 is defined in FIG. 7A and FIG. 7B as the length of the end portion of the bottom surface of the conductive layer 112b (the surface on the insulating layer 110 side) on the opening 143 side in a plan view, one embodiment of the present invention is not limited thereto. For example, the length of the outer perimeter of a portion where the top surface of the conductive layer 112a and the semiconductor layer 108 are in contact with each other in a plan view may be defined as the channel width of the transistor 100. The intermediate value of the above two lengths may be defined as the channel width of the transistor 100.

The channel width W100 is determined by the shape of the opening 143 in a plan view. In FIG. 7A and FIG. 7B, a width D143 of the opening 143 is indicated by the dashed double-dotted double-headed arrow. The width D143 is the length of the short side of the smallest rectangle that is circumscribed around the opening 143 in a plan view. In the case where the opening 143 is formed by a photolithography method, the width D143 of the opening 143 is larger than or equal to the resolution limit of a light exposure apparatus. The width D143 is, for example, preferably greater than or equal to 0.01 μm and less than 5.0 μm, further preferably greater than or equal to 0.01 μm and less than 4.5 μm, still further preferably greater than or equal to 0.01 μm and less than 4.0 μm, yet still further preferably greater than or equal to 0.01 μm and less than 3.5 μm, yet still further preferably greater than or equal to 0.01 μm and less than 3.0 μm, yet still further preferably greater than or equal to 0.01 μm and less than or equal to 2.5 μm, yet still further preferably greater than or equal to 0.01 μm and less than or equal to 2.0 μm, yet still further preferably greater than or equal to 0.01 μm and less than or equal to 1.5 μm, yet still further preferably greater than or equal to 0.30 μm and less than or equal to 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm. In the case where the shape of the opening 143 in a plan view is a circle, the width D143 corresponds to the diameter of the opening 143, and the channel width W100 can be calculated to be “D143×π”.

As described above, the channel length L100 of the transistor 100 can be a value smaller than the resolution limit of the light exposure apparatus. On the other hand, when the thickness of the insulating layer sandwiched between the source electrode and the drain electrode of the transistor 100 is large, the channel length L100 of the transistor 100 can have a value larger than or equal to the resolution limit of the light exposure apparatus. In the semiconductor device of one embodiment of the present invention, a vertical-channel transistor is used and the thickness of an insulating layer sandwiched between a source electrode and a drain electrode of the transistor is adjusted as described above, whereby the channel length of the transistor can be determined. Furthermore, in the semiconductor device of one embodiment of the present invention, two or more vertical-channel transistors are used and the thickness of an insulating layer sandwiched between source electrodes and drain electrodes of the transistors is varied in the substrate plane, whereby a transistor with a short channel length and a transistor with a long channel length can be separately formed in the substrate plane. For example, the transistor 100 having a short channel length and the transistor 200 having a long channel length can be separately formed in the substrate plane. The transistor 100 is used as a transistor required to have a high on-state current and the transistor 200 is used as a transistor required to have favorable saturation characteristics, thereby providing the semiconductor device 10 with high performance utilizing the advantages of the transistors.

In the semiconductor device 10 of one embodiment of the present invention, the transistor 100 and the transistor 200 having different channel lengths can be formed over the substrate 102 by the formation steps some of which are shared. Specifically, the conductive layer 112a and the conductive layer 202a can be formed in the same step. The conductive layer 112b and the conductive layer 202b can be formed in the same step. The semiconductor layer 108 and the semiconductor layer 208 can be formed in the same step. The conductive layer 104 and the conductive layer 204 can be formed in the same step. Thus, the manufacturing cost of the semiconductor device 10 can be made low.

Components included in the semiconductor device of this embodiment will be described below.

### Components of Semiconductor Device

### Semiconductor Layer 108 and Semiconductor Layer 208

A semiconductor material that can be used for each of the semiconductor layer 108 and the semiconductor layer 208 is not particularly limited. For example, a single-element semiconductor or a compound semiconductor can be used. As the single-element semiconductor, silicon or germanium can be used, for example. As the compound semiconductor, gallium arsenide and silicon germanium can be used, for example. As the compound semiconductor, an organic substance having semiconductor characteristics or a metal oxide having semiconductor characteristics (also referred to as an oxide semiconductor) can be used. These semiconductor materials may contain an impurity as a dopant.

There is no particular limitation on the crystallinity of a semiconductor material used for each of the semiconductor layer 108 and the semiconductor layer 208, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case degradation of the transistor characteristics can be inhibited.

For each of the semiconductor layer 108 and the semiconductor layer 208, silicon can be used. Examples of silicon include single crystal silicon, polycrystalline silicon, microcrystalline silicon, and amorphous silicon. As the polycrystalline silicon, low-temperature polysilicon (LTPS) can be given.

A transistor including amorphous silicon in its semiconductor layer can be formed over a large glass substrate, and can be manufactured at low cost. A transistor including polycrystalline silicon in its semiconductor layer has high field-effect mobility and enables high-speed operation. A transistor including microcrystalline silicon in its semiconductor layer has higher field-effect mobility and enables higher speed operation than the transistor including amorphous silicon.

The semiconductor layer 108 and the semiconductor layer 208 may each include a layered material functioning as a semiconductor. The layered material generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

Each of the semiconductor layer 108 and the semiconductor layer 208 preferably includes a metal oxide (also referred to as an oxide semiconductor). Examples of the metal oxide that can be used for the semiconductor layer 108 and the semiconductor layer 208 include indium oxide, gallium oxide, and zinc oxide. The metal oxide preferably contains at least indium (In) or zinc (Zn). The metal oxide preferably contains two or three selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, for each of the semiconductor layer 108 and the semiconductor layer 208, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (In—Ga—Sn oxide), a gallium zinc oxide (also referred to as a Ga—Zn oxide or GZO), an aluminum zinc oxide (Al—Zn oxide), an indium aluminum zinc oxide (also referred to as an In—Al—Zn oxide or IAZO), an indium tin zinc oxide (In—Sn—Zn oxide), an indium titanium zinc oxide (In—Ti—Zn oxide), an indium gallium zinc oxide (also referred to as an In—Ga—Zn oxide or IGZO), an indium gallium tin zinc oxide (also referred to as an In—Ga—Sn—Zn oxide or IGZTO), or an indium gallium aluminum zinc oxide (also referred to as an In—Ga—Al—Zn oxide, IGAZO, or IAGZO) can be used. Alternatively, an indium tin oxide containing silicon, a gallium tin oxide (Ga—Sn oxide), an aluminum tin oxide (Al—Sn oxide), or the like can be used.

Here, the compositions of the metal oxide in the semiconductor layer 108 and the semiconductor layer 208 greatly affect the electrical characteristics and reliability of the transistor 100 and the transistor 200.

For example, by increasing the proportion of the number of indium atoms in the total number of atoms of all the metal elements contained in the metal oxide, a transistor having a high on-state current or high field-effect mobility can be provided. By using such a transistor as a transistor requiring a high on-state current, a semiconductor device having excellent electrical characteristics can be provided.

Note that the metal oxide may contain, instead of or in addition to indium, one or more kinds selected from metal elements belonging to a period of a higher number in the periodic table. The larger the overlap between orbits of metal elements is, the more likely it is that the metal oxide will have high carrier conductivity. Thus, when the transistor includes metal elements with larger period numbers, the field-effect mobility of the transistor can be increased in some cases. As examples of the metal element with a large period number, the metal elements belonging to Period 5 and those belonging to Period 6 are given. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

In the case of using an In-Zn oxide for the semiconductor layer, a metal oxide in which the atomic proportion of indium is higher than or equal to that of zinc is preferably used. For example, a metal oxide in which the atomic ratio of metal elements is In:Zn=1:1, In:Zn=2:1, In:Zn=3:1, In:Zn=4:1, In:Zn=5:1, In:Zn=7:1, In:Zn=10:1, or the neighborhood thereof can be used.

In the case where an In—Sn oxide is used for the semiconductor layer, a metal oxide in which the atomic proportion of indium is higher than or equal to that of tin is preferably used. For example, a metal oxide in which the atomic ratio of metal elements is In: Sn=1:1, In:Sn=2:1, In:Sn=3:1, In:Sn=4:1, In:Sn=5:1, In:Sn=7:1, In:Sn=10:1, or the neighborhood thereof can be used.

In the case of using an In-M-Zn oxide for the semiconductor layer, a metal oxide in which the atomic proportion of indium with respect to the total number of atoms of all the contained metal elements is higher than the atomic proportion of the element M can be used. It is further preferable to use a metal oxide in which the atomic proportion of zinc is higher than the atomic proportion of the element M. For example, a metal oxide with metal elements in any of the following atomic ratios can be used for the semiconductor layer: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the neighborhood thereof.

In the case where a plurality of metal elements are contained as the element M, the sum of the proportions of the numbers of atoms of the metal elements can be the proportion of the number of the element M atoms. In the case of an In—Ga—Al—Zn oxide in which gallium and aluminum are contained as the element M, for example, the sum of the proportion of the number of gallium atoms and the proportion of the number of aluminum atoms can be the proportion of the number of the element M atoms. The atomic ratio between indium, the element M, and zinc is preferably within the ranges described above. In the case of an In—Ga—Sn—Zn oxide in which gallium and tin are contained as the element M, for example, the sum of the proportion of the number of gallium atoms and the proportion of the number of tin atoms can be the proportion of the number of the element M atoms. The atomic ratio between indium, the element M, and zinc is preferably within the ranges described above.

It is preferable to use a metal oxide in which the atomic proportion of indium with respect to the total number of atoms of all the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, in the case of using an In—Ga—Zn oxide for the semiconductor layer, the proportion of the number of indium atoms in the sum of the numbers of atoms of indium, the element M, and zinc is preferably within the ranges given above.

In this specification and the like, the proportion of the number of indium atoms in the total number of atoms of all the metal elements contained is sometimes referred to as indium content percentage. The same applies to other metal elements.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A composition in the neighborhood in this specification and the like includes the range of ±30% of an intended atomic ratio. For example, in the case of describing an atomic ratio of In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. In the case of describing an atomic ratio of In:M:Zn=5:1:6 or a composition in the neighborhood thereof, the case is included where the atomic ratio of M is greater than 0.1 and less than or equal to 2 and the atomic ratio of zinc is greater than or equal to 5 and less than or equal to 7 with the atomic ratio of indium being 5. In the case of describing an atomic ratio of In:M:Zn=1:1:1 or a composition in the neighborhood thereof, the case is included where the atomic ratio of M is greater than 0.1 and less than or equal to 2 and the atomic ratio of zinc is greater than 0.1 and less than or equal to 2 with the atomic ratio of indium being 1.

For the formation of a metal oxide, a sputtering method or an atomic layer deposition (ALD) method can be suitably used. In the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately 40% to 90% of the atomic ratio of zinc contained in the target.

Here, the reliability of a transistor is described. One of indexes for evaluating the reliability of a transistor is a GBT (Gate Bias Temperature) stress test in which the transistor is kept at a high temperature with an electric field applied to its gate. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation with light is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state (a state where a current flows); thus, the amount of change in the threshold voltage in the PBTS test is one important item to be focused on as an indicator of the reliability of the transistor.

With use of a metal oxide that does not contain gallium or has a low gallium content percentage in the semiconductor layer, the transistor can be highly reliable against positive bias application. In other words, the amount of change in the threshold voltage of the transistor in the PBTS test can be small. In the case of using a metal oxide that contains gallium, the gallium content percentage is preferably lower than the indium content percentage. Thus, a highly reliable transistor can be achieved.

One of the factors in change in the threshold voltage in the PBTS test is carrier (here, electron) trapping by defect states at the interface between a semiconductor layer and a gate insulating layer or in the vicinity of the interface. As the density of defect states increases, the amount of carrier traps by defect states increases; thus, degradation in the PBTS test becomes more significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, when, at the interface between a metal oxide containing a large amount of gallium and the gate insulating layer, gallium is bonded to excess oxygen in the gate insulating layer, trap sites of carriers (here, electrons) are probably generated easily. This might cause the change in the threshold voltage when a positive potential is supplied to a gate and carriers are trapped at the interface between the semiconductor layer and the gate insulating layer.

Specifically, in the case where an In—Ga—Zn oxide is used for the semiconductor layer, a metal oxide in which the atomic proportion of indium is higher than that of gallium can be used as the semiconductor layer. It is further preferable to use a metal oxide in which the atomic proportion of zinc is higher than the atomic proportion of gallium. In other words, a metal oxide in which the atomic ratios of metal elements satisfy In>Ga and Zn>Ga is preferably used as the semiconductor layer.

For example, a metal oxide with metal elements in any of the following atomic ratios can be used for the semiconductor layer: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the neighborhood thereof.

The semiconductor layer is preferably formed using a metal oxide having the following compositions; the atomic proportion of gallium with respect to the total number of atoms of all the contained metal elements is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content percentage in the semiconductor layer enables the transistor to be highly resistant to the PBTS test. Note that an oxygen vacancy (V_{O}) is less likely to be generated in the metal oxide when the metal oxide contains gallium.

A metal oxide not containing gallium may be used as the semiconductor layer. For example, an In—Zn oxide can be used as the semiconductor layer. In this case, when the atomic proportion of indium with respect to the total number of atoms of all the metal elements contained in the metal oxide is increased, the field-effect mobility of the transistor can be increased. By contrast, when the atomic proportion of zinc with respect to the total number of atoms of all the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used as the semiconductor layer. The use of a metal oxide not containing gallium can make a change in the threshold voltage particularly in the PBTS test extremely small.

For example, an oxide containing indium and zinc can be used as the semiconductor layer. At that time, for example, a metal oxide with metal elements in an atomic ratio of In:Zn=2:3, In:Zn=4:1, or the neighborhood thereof can be used.

Although the case of using gallium is described as a typical example, the same applies to the case where the element M is used instead of gallium. A metal oxide in which the atomic proportion of indium is higher than the atomic proportion of the element M is preferably used as the semiconductor layer. Furthermore, a metal oxide in which the atomic proportion of zinc is higher than the atomic proportion of the element M is preferably used.

The use of a metal oxide having a low content percentage of the element M for the semiconductor layer enables the transistor to be highly reliable against positive bias application. With the use of the transistor as a transistor that is required to have high reliability against positive bias application, a highly reliable semiconductor device can be provided.

Next, the reliability of a transistor against light is described.

Light incidence on a transistor may change electrical characteristics of the transistor. In particular, a transistor provided in a region on which light can be incident preferably exhibits a small change in electrical characteristics under light irradiation and has high reliability against light. The reliability against light can be evaluated with the amount of change in threshold voltage in an NBTIS test, for example.

The high content percentage of the element M in the metal oxide enables the transistor to be highly reliable against light. In other words, the amount of change in the threshold voltage of the transistor in the NBTIS test can be small. Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide in the semiconductor layer is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, a metal oxide with metal elements in any of the following atomic ratios can be used for the semiconductor layer: In:M:Zn=1:1:1, In:M:Zn=1:1:1.2, In:M:Zn=1:3:2, In:M:Zn=1:3:3, In:M:Zn=1:3:4, and the neighborhood thereof.

For the semiconductor layer, in particular, it is preferable to use a metal oxide in which the atomic proportion of the element M with respect to the total number of atoms of all the contained metal elements is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic %.

The use of a metal oxide having a high content percentage of the element M for the semiconductor layer enables the transistor to be highly reliable against light. With the use of the transistor as a transistor that is required to have high reliability against light, a highly reliable semiconductor device can be provided.

An increase in the content percentage of the element M can inhibit the formation of oxygen vacancies (V_{O}) in the metal oxide. Accordingly, when a metal oxide with a high content percentage of the element M is used for the semiconductor layer, generation of carriers due to oxygen vacancies (V_{O}) is inhibited, so that the transistor can have a low off-state current. Furthermore, a change in electrical characteristics of the transistor can be inhibited, and the reliability of the transistor can be improved.

Furthermore, a metal oxide having a high zinc content percentage has high crystallinity, whereby diffusion of impurities can be inhibited. Accordingly, when a metal oxide with a high zinc content percentage is used for the semiconductor layer, a change in electrical characteristics of the transistor can be inhibited and the reliability can be increased.

As described above, electrical characteristics and reliability of a transistor depend on the composition of the metal oxide used for the semiconductor layer. Thus, by changing the composition of the metal oxide in accordance with the electrical characteristics and reliability required for the transistor, the semiconductor device can have both excellent electrical characteristics and high reliability.

The semiconductor layer may have a stacked-layer structure including two or more metal oxide layers. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer may have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being formed over the first metal oxide layer can be suitably employed. In particular, gallium or aluminum is preferably used as the element M. A stacked-layer structure of one selected from an indium oxide, an indium gallium oxide, and IGZO, and one selected from IAZO, IAGZO, and ITZO (registered trademark) may be employed, for example.

The two or more metal oxide layers included in the semiconductor layer may be a stacked-layer structure of a metal oxide layer not including the element M and a metal oxide layer including the element M. For example, a stacked-layer structure of a first metal oxide layer having a composition of In:M:Zn=4:0:1 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. A structure in which a metal oxide layer not including the element M is stacked over a metal oxide layer including the element M may be employed.

It is preferable to use a metal oxide layer having crystallinity as the semiconductor layer. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer, the density of defect states in the semiconductor layer can be reduced, which enables the semiconductor device to have high reliability.

The higher the crystallinity of the metal oxide layer used as the semiconductor layer is, the lower the density of defect states in the semiconductor layer can be. By contrast, the use of a metal oxide layer having low crystallinity enables a transistor to flow a large amount of current.

In the case where the metal oxide layer is formed by a sputtering method, the higher the substrate temperature (the stage temperature) in the formation is, the higher the crystallinity of the metal oxide layer can be. The crystallinity of the metal oxide layer can be increased as the proportion of a flow rate of an oxygen gas to the whole deposition gas (hereinafter, also referred to as oxygen flow rate ratio) used in formation is higher.

The semiconductor layer may have a stacked-layer structure of two or more metal oxide layers having different crystallinities. For example, a stacked-layer structure of a first metal oxide layer and a second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with the use of the same sputtering target and different oxygen flow rate ratios, a stacked-layer structure of two or more metal oxide layers having different crystallinities can be formed. The two or more metal oxide layers included in the semiconductor layer may have different compositions.

The thickness of each of the semiconductor layer 108 and the semiconductor layer 208 is preferably larger than or equal to 3 nm and smaller than or equal to 100 nm, further preferably larger than or equal to 5 nm and smaller than or equal to 100 nm, further preferably larger than or equal to 10 nm and smaller than or equal to 100 nm, further preferably larger than or equal to 10 nm and smaller than or equal to 70 nm, further preferably larger than or equal to 15 nm and smaller than or equal to 70 nm, further preferably larger than or equal to 15 nm and smaller than or equal to 50 nm, further preferably larger than or equal to 20 nm and smaller than or equal to 50 nm, further preferably larger than or equal to 20 nm and smaller than or equal to 40 nm, further preferably larger than or equal to 25 nm and smaller than or equal to 40 nm.

The substrate temperature at the time of forming each of the semiconductor layer 108 and the semiconductor layer 208 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be inhibited in the case where a large-area glass substrate is used.

Here, oxygen vacancies that might be formed in the semiconductor layer will be described.

In the case where an oxide semiconductor is used for the semiconductor layer, hydrogen contained in the oxide semiconductor reacts with oxygen bonded to a metal atom to be water, and thus sometimes forms oxygen vacancy (V_{O}) in the oxide semiconductor. In some cases, a defect that is an oxygen vacancy into which hydrogen enters (hereinafter referred to as V_{O}H) functions as a donor and generates an electron serving as a carrier. In other cases, bonding of part of hydrogen to oxygen bonded to a metal atom generates electrons serving as carriers. Thus, a transistor using an oxide semiconductor that contains a large amount of hydrogen is likely to have normally-on characteristics. Moreover, hydrogen in an oxide semiconductor is easily transferred by stress such as heat or an electric field; thus, the reliability of the transistor might be reduced when the oxide semiconductor includes a large amount of hydrogen.

V_{O}H can function as a donor of the oxide semiconductor. However, it is difficult to evaluate the defect quantitatively. Thus, the oxide semiconductor is sometimes evaluated not by its donor concentration but by its carrier concentration. Therefore, in this specification and the like, the carrier concentration assuming the state where an electric field is not applied is sometimes used as the parameter of the oxide semiconductor, instead of the donor concentration. That is, “carrier concentration” described in this specification and the like can be replaced with “donor concentration” in some cases.

Accordingly, in the case where an oxide semiconductor is used as the semiconductor layer, the amount of V_{O}H in the semiconductor layer is preferably reduced as much as possible so that the semiconductor layer becomes a highly purified intrinsic or substantially highly purified intrinsic semiconductor layer. In order to obtain such an oxide semiconductor with sufficiently reduced V_{O}H, it is important to remove impurities (e.g., water and hydrogen) in the oxide semiconductor (this treatment is sometimes referred to as dehydration or dehydrogenation treatment) and supply oxygen to the oxide semiconductor to fill oxygen vacancy (V_{O}). When an oxide semiconductor with sufficiently reduced oxygen vacancy (V_{O}), V_{O}H, impurities is used for a channel formation region of a transistor, the transistor can have stable electrical characteristics. Supplying oxygen to an oxide semiconductor to fill an oxygen vacancy (V_{O}) is sometimes referred to as oxygen adding treatment.

When an oxide semiconductor is used for the semiconductor layer, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

The electric resistance of the channel formation region in a state where the channel is not formed is preferably as high as possible. For example, the sheet resistance of the channel formation region is preferably higher than or equal to 1×10⁹ Ω/square, further preferably higher than or equal to 5×10⁹ Ω/square, still further preferably higher than or equal to 1×10¹⁰ Ω/square.

Since the electric resistance of the channel formation region in a state where the channel is not formed is preferably as high as possible, it is not necessary to set its upper limit. If the upper limit is set, the sheet resistance of the channel formation region is preferably higher than or equal to 1×10⁹ Ω/square and lower than or equal to 1×10¹² Ω/square, further preferably higher than or equal to 5×10⁹ Ω/square and lower than or equal to 1×10¹² Ω/square, still further preferably higher than or equal to 1×10¹⁰ Ω/square and lower than or equal to 1×10¹² Ω/square, for example.

A transistor including an oxide semiconductor (OS transistor) in its semiconductor layer has much higher field-effect mobility than a transistor including amorphous silicon in its semiconductor layer. In addition, an OS transistor has an extremely low leakage current between a source and a drain in an off state (hereinafter, also referred to as off-state current), and charge accumulated in a capacitor that is connected in series to the transistor can be retained for a long period. With the use of the OS transistor in a semiconductor device, the power consumption of the semiconductor device can be reduced.

The semiconductor device of one embodiment of the present invention can be used for a display apparatus, for example. To increase the emission luminance of a light-emitting device included in a pixel circuit in the display apparatus, it is necessary to increase the amount of current flowing through the light-emitting device. To increase the amount of current, the source-drain voltage of a driving transistor included in the pixel circuit needs to be increased. Since an OS transistor has a higher withstand voltage between a source and a drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased. In the case where the semiconductor device 10 illustrated in FIG. 6A and FIG. 6B is used for a display apparatus, for example, the transistor 200 having a long channel length and having a high withstand voltage between the source and the drain can be suitably used as a driving transistor included in a pixel circuit. Alternatively, the transistor 100 having a short channel length may be used as the driving transistor included in the pixel circuit. In that case, the amount of current flowing through a light-emitting device can be increased with no need to increase source-drain voltage.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of a current flowing between the source and the drain can be finely set by a change in gate-source voltage; thus, the amount of a current flowing through the light-emitting device can be controlled. Therefore, the number of gray levels in the pixel circuit can be increased. In the case where the semiconductor device 10 illustrated in FIG. 6A and FIG. 6B is used for a display apparatus, for example, the transistor 200 having a long channel length and having favorable saturation characteristics can be suitably used as a driving transistor included in a pixel circuit.

Regarding saturation characteristics of a current flowing when a transistor operates in a saturation region, even in the case where the source-drain voltage of an OS transistor increases gradually, a more stable current (saturation current) can be made flow through the OS transistor than through a Si transistor. Thus, with the use of an OS transistor as a driving transistor, a current can be made flow stably to the light-emitting device, for example, even when a variation in current-voltage characteristics of the light-emitting device occurs. In other words, when the OS transistor operates in the saturation region, the source-drain current hardly changes even with an increase in the source-drain voltage; thus, the emission luminance of the light-emitting device can be stable. In the case where the semiconductor device 10 illustrated in FIG. 6A and FIG. 6B is used for a display apparatus, for example, the transistor 200 having a long channel length and having favorable saturation characteristics can be suitably used as a driving transistor included in a pixel circuit.

As described above, by using an OS transistor as the driving transistor included in the pixel circuit, it is possible to achieve “inhibition of black floating”, “increase in emission luminance”, “increase in the number of gray levels”, “inhibition of variation in emission luminance”, and the like.

A change in electrical characteristics of an OS transistor due to irradiation with radiation is small, i.e., an OS transistor has high resistance to radiation; thus, an OS transistor can be suitably used even in an environment where radiation might enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

### Insulating Layer 110 and Insulating Layer 110_1

For the insulating layer 110 (the insulating layer 110a, the insulating layer 110b, and the insulating layer 110c), an inorganic insulating material or an organic insulating material can be used. The insulating layer 110 may have a stacked-layer structure of an inorganic insulating material and an organic insulating material.

For the insulating layer 110, an inorganic insulating material can be suitably used. As the inorganic insulating material, one or more of an oxide, an oxynitride, a nitride oxide, and a nitride can be used. For the insulating layer 110, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

Note that in this specification and the like, an oxynitride refers to a material that contains more oxygen than nitrogen in its composition. A nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The oxygen content and the nitrogen content can be analyzed by secondary ion mass spectrometry (SIMS) or XPS. When the content percentage of a target element is high (e.g., higher than or equal to 0.5 atomic %, or higher than or equal to 1 atomic %), XPS is suitable. By contrast, when the content percentage of a target element is low (e.g., lower than or equal to 0.5 atomic %, or lower than or equal to 1 atomic %), SIMS is suitable. To compare the contents of elements, analysis with a combination of SIMS and XPS is preferably used.

The insulating layer 110 may have a stacked-layer structure of two or more layers. FIG. 6B and the like illustrate a structure in which the insulating layer 110 has a stacked-layer structure of the insulating layer 110a, the insulating layer 110b over the insulating layer 110a, and the insulating layer 110c over the insulating layer 110b. For each of the insulating layer 110a, the insulating layer 110b, and the insulating layer 110c, the material that can be used for the insulating layer 110 can be used. For the insulating layer 110a, the insulating layer 110b, and the insulating layer 110c, the same material or different materials may be used. Note that the insulating layer 110a, the insulating layer 110b, and the insulating layer 110c may each have a stacked-layer structure of two or more layers.

The thickness of the insulating layer 110b can be larger than the thickness of the insulating layer 110a. The thickness of the insulating layer 110b can be larger than the thickness of the insulating layer 110c. The formation speed of the insulating layer 110b is preferably high. In particular, the formation speed of the insulating layer 110b is preferably high in the case where the thickness of the insulating layer 110b is large. By increasing the formation speed of the insulating layer 110b, the productivity can be increased. For example, by increasing power at the time of forming the insulating layer 110b, the formation speed can be increased.

The insulating layer 110b may have a stacked-layer structure of two or more layers. For example, the insulating layer 110b has high stress when the insulating layer 110b has a large thickness, which might cause warpage of the substrate. In some cases, the formation of the insulating layer 110b in a plurality of steps can inhibit occurrence of problems during the process caused by stress. Note that in a cross-sectional transmission electron microscopy (TEM) image or the like, a boundary between the layers included in the insulating layer 110b is unclear in some cases.

The stress of the insulating layer 110b is preferably low. The insulating layer 110b has high stress when the insulating layer 110b has a large thickness, which might cause warpage of the substrate. The low stress of the insulating layer 110b can inhibit occurrence of problems during the process caused by stress such as warpage of the substrate.

The insulating layer 110a and the insulating layer 110c each function as a blocking film that inhibit release of gas from the insulating layer 110b. For each of the insulating layer 110a and the insulating layer 110c, a material in which gas is hardly diffused is preferably used. The insulating layer 110a and the insulating layer 110c each preferably include a region having a higher film density than the insulating layer 110b. Each of the insulating layer 110a and the insulating layer 110c having a high film density can have a high blocking property against an impurity (e.g., oxygen and hydrogen). The insulating layer 110a and the insulating layer 110c may have different film densities. For each of the insulating layer 110a and the insulating layer 110c, a material containing more nitrogen than the insulating layer 110b can be used, for example. The insulating layer 110a and the insulating layer 110c in each of which the nitrogen content is high can have a high blocking property against an impurity. The insulating layer 110a and the insulating layer 110c may have different nitrogen contents.

The insulating layer 110a and the insulating layer 110c have thicknesses with which the insulating layers function as blocking films that inhibit release of gas from the insulating layer 110b, and can be thinner than the insulating layer 110b. Note that the insulating layer 110a and the insulating layer 110c may have different thicknesses. The formation speed of each of the insulating layer 110a and the insulating layer 110c is preferably lower than the formation speed of the insulating layer 110b. Each of the insulating layer 110a and the insulating layer 110c formed at a low speed has a high film density and can have a high blocking property against an impurity. Similarly, each of the insulating layer 110a and the insulating layer 110c formed at a high substrate temperature has a high film density and can have a high blocking property against an impurity.

The film density can be evaluated by Rutherford backscattering spectrometry (RBS) or X-ray reflection (XRR), for example. A difference in film density can be evaluated using a cross-sectional TEM image in some cases. In TEM observation, a transmission electron (TE) image is dark-colored (dark) when the film density is high, and a transmission electron (TE) image is pale (bright) when the film density is low. Thus, in a transmission electron (TE) image, the insulating layer 110a and the insulating layer 110c are each sometimes shown as a dark-colored (dark) image compared to the insulating layer 110b. Since the insulating layer 110a, the insulating layer 110b, and the insulating layer 110c have different film densities even when including the same materials, it is sometimes possible to identify the boundary between the insulating layers by a difference in contrast in a TEM image of a cross section.

A difference in nitrogen content between the insulating layer 110a, the insulating layer 110b, and the insulating layer 110c can be confirmed by EDX, for example. In the case where silicon nitride is used for the insulating layer 110a and silicon oxynitride is used for the insulating layer 110b, for example, the ratio of the peak intensity of nitrogen to the peak intensity of silicon in the insulating layer 110a is higher than the ratio of the peak intensity of nitrogen to the peak intensity of silicon in the insulating layer 110b. In the case where silicon nitride is used for the insulating layer 110c and silicon oxynitride is used for the insulating layer 110b, the ratio of the peak intensity of nitrogen to the peak intensity of silicon in the insulating layer 110c is higher than the ratio of the peak intensity of nitrogen to the peak intensity of silicon in the insulating layer 110b. Note that in EDX, the peak of a certain element refers to a point at which the number of counts of the element reaches a local maximum value in a spectrum where the horizontal axis represents the energy of characteristic X-rays and the vertical axis represents the number of counts (the detected value) of characteristic X-rays. Alternatively, the number of counts at an energy of a characteristic X-ray unique to the element may be used to confirm a difference in nitrogen content with the ratio of the number of counts of nitrogen to the number of counts of silicon. For example, the number of counts at 1.739 keV (Si—Kα) can be used for silicon, and the number of counts at 0.392 keV (N—Kα) can be used for nitrogen. The ratio of the number of counts of nitrogen to the number of counts of silicon in the insulating layer 110a is higher than the ratio of the number of counts of nitrogen to the number of counts of silicon in the insulating layer 110b. The ratio of the number of counts of nitrogen to the number of counts of silicon in the insulating layer 110c is higher than the ratio of the number of counts of nitrogen to the number of counts of silicon in the insulating layer 110b.

The insulating layer 110a and the insulating layer 110c may each include a region having a higher hydrogen concentration in the film than the insulating layer 110b. The difference in hydrogen concentration between the insulating layer 110a, the insulating layer 110b, and the insulating layer 110c can be examined by SIMS, for example.

Here, the insulating layer 110 (the insulating layer 110a, the insulating layer 110b, and the insulating layer 110c) is specifically described using a structure in which a metal oxide is used for a semiconductor layer of a transistor as an example.

In the case where an oxide semiconductor is used for the semiconductor layer, an inorganic insulating material can be suitably used for each of the insulating layer 110a, the insulating layer 110b, and the insulating layer 110c.

It is preferable to use an oxide or an oxynitride for the insulating layer 110b. A film from which oxygen is released by heating is preferably used as the insulating layer 110b. For example, silicon oxide or silicon oxynitride can be suitably used for the insulating layer 110b.

When oxygen is released from the insulating layer 110b, oxygen can be supplied to the semiconductor layer from the insulating layer 110b. Supplying oxygen from the insulating layer 110b to the semiconductor layer, particularly to the channel formation region in the semiconductor layer, can allow the amount of oxygen vacancies (V_{O}) and V_{O}H to be reduced in the semiconductor layer, so that a highly reliable transistor having favorable electrical characteristics can be obtained. The insulating layer 110b preferably has a high oxygen diffusion coefficient. When the insulating layer 110b has a high oxygen diffusion coefficient, oxygen is easily diffused in the insulating layer 110b, so that oxygen can be efficiently supplied from the insulating layer 110b to the semiconductor layer. Examples of treatment for supplying oxygen to the semiconductor layer include heat treatment in an oxygen-containing atmosphere and plasma treatment in an oxygen-containing atmosphere.

It is preferable that the amount of oxygen vacancies (V_{O}) and V_{O}H be small in the channel formation region of the transistor. Particularly in the case where the channel length is short, an oxygen vacancy (V_{O}) and V_{O}H in the channel formation region greatly affect the electrical characteristics and the reliability of the transistor. For example, diffusion of V_{O}H from the source region or the drain region into the channel formation region increases the carrier concentration in the channel formation region, which might cause a change in the threshold voltage or a reduction in the reliability of the transistor. The shorter the channel length is, the more the electrical characteristics and reliability of the transistor are affected by such diffusion of V_{O}H. Supplying oxygen from the insulating layer 110b to the semiconductor layer, particularly to the channel formation region in the semiconductor layer, can allow the amount of oxygen vacancies (V_{O}) and V_{O}H to be reduced. Thus, the transistor with a short channel length can have favorable electrical characteristics and high reliability.

The amount of impurities (e.g., water and hydrogen) released from the insulating layer 110b itself is preferably small. With the insulating layer 110b from which a small amount of impurities is released, diffusion of the impurities into the semiconductor layer is inhibited, and the transistor can have favorable electrical characteristics and high reliability.

For example, silicon oxide or silicon oxynitride formed by a PECVD method can be suitably used for the insulating layer 110b. In that case, a mixed gas including a gas containing silicon and a gas containing oxygen is preferably used as a source gas. As the gas containing silicon, one or more of silane, disilane, trisilane, and silane fluoride can be used, for example. As the gas containing oxygen, one or more of oxygen (O₂), ozone (O₃), dinitrogen monoxide (N₂O), nitric oxide (NO), or nitrogen dioxide (NO₂) can be used, for example. Note that by increasing power at the time of forming the insulating layer 110b, the amount of impurities (e.g., water and hydrogen) released from the insulating layer 110b can be reduced.

Each of the insulating layer 110a and the insulating layer 110c is preferably less likely to transmit oxygen. The insulating layer 110a and the insulating layer 110c each function as a blocking film that inhibits release of oxygen from the insulating layer 110b. Moreover, each of the insulating layer 110a and the insulating layer 110c is preferably less likely to transmit hydrogen. The insulating layer 110a and the insulating layer 110c function as blocking films that inhibit diffusion of hydrogen into the semiconductor layer from the outside of the transistor. The insulating layer 110a and the insulating layer 110c preferably have high film densities. The insulating layer 110a and the insulating layer 110c having high film densities can have a high blocking property against oxygen and hydrogen. The film densities of the insulating layer 110a and the insulating layer 110c are each preferably higher than the film density of the insulating layer 110b. In the case where silicon oxide or silicon oxynitride is used for the insulating layer 110b, silicon nitride, silicon nitride oxide, or aluminum oxide can be suitably used for each of the insulating layer 110a and the insulating layer 110c, for example. The insulating layer 110a and the insulating layer 110c each preferably include a region including more nitrogen than the insulating layer 110b. For each of the insulating layer 110a and the insulating layer 110c, a material containing more nitrogen than the insulating layer 110b can be used, for example. A nitride or a nitride oxide is preferably used for each of the insulating layer 110a and the insulating layer 110c. For example, silicon nitride or silicon nitride oxide can be suitably used for each of the insulating layer 110a and the insulating layer 110c.

When oxygen included in the insulating layer 110b is diffused upward from a region of the insulating layer 110b that is not in contact with the semiconductor layer (e.g., the semiconductor layer 108), the amount of oxygen supplied from the insulating layer 110b to the semiconductor layer might be reduced. Provision of the insulating layer 110c over the insulating layer 110b can inhibit upward diffusion of oxygen included in the insulating layer 110b from the region of the insulating layer 110b that is not in contact with the semiconductor layer. Similarly, provision of the insulating layer 110a under the insulating layer 110b can inhibit downward diffusion of oxygen included in the insulating layer 110b from the region of the insulating layer 110b that is not in contact with the semiconductor layer. Accordingly, the amount of oxygen supplied from the insulating layer 110b to the semiconductor layer is increased, whereby the amount of oxygen vacancies (V_{O}) and V_{O}H in the semiconductor layer can be reduced. Consequently, a transistor with favorable electrical characteristics and high reliability can be obtained.

The conductive layer 112a and the conductive layer 112b of the transistor 100 are oxidized by oxygen included in the insulating layer 110b and have high resistance in some cases. Moreover, when the conductive layer 112a and the conductive layer 112b are oxidized by oxygen included in the insulating layer 110b, the amount of oxygen supplied from the insulating layer 110b to the semiconductor layer (the semiconductor layer 108) might be reduced. Providing the insulating layer 110a between the insulating layer 110b and the conductive layer 112a can inhibit the conductive layer 112a from being oxidized and having high resistance. Similarly, providing the insulating layer 110c between the insulating layer 110b and the conductive layer 112b can inhibit the conductive layer 112b from being oxidized and having high resistance. In addition, the amount of oxygen supplied from the insulating layer 110b to the semiconductor layer is increased and the amount of oxygen vacancies (V_{O}) and V_{O}H in the semiconductor layer can be reduced, whereby the transistor can have favorable electric characteristics and high reliability.

Hydrogen diffusing into the semiconductor layer reacts with an oxygen atom contained in an oxide semiconductor to be water, and thus sometimes forms an oxygen vacancy (V_{O}). Furthermore, V_{O}H is formed and the carrier concentration is increased in some cases. Provision of the insulating layer 110a and the insulating layer 110c can allow the amount of oxygen vacancies (V_{O}) and V_{O}H to be reduced in the semiconductor layer, whereby the transistor can have favorable electric characteristics and high reliability.

The insulating layer 110a and the insulating layer 110c preferably have thicknesses with which the insulating layers function as blocking films against oxygen and hydrogen. When each of the insulating layer 110a and the insulating layer 110c is thin, the function of a blocking film might deteriorate. Meanwhile, when each of the insulating layer 110a and the insulating layer 110c is thick, a region where the semiconductor layer (e.g., the semiconductor layer 108) is in contact with the insulating layer 110b is narrowed and the amount of oxygen supplied from the insulating layer 110b to the semiconductor layer might be reduced. The insulating layer 110a and the insulating layer 110c may each be thinner than the insulating layer 110b. The thicknesses of the insulating layer 110a and the insulating layer 110c are each preferably larger than or equal to 5 nm and smaller than or equal to 100 nm, further preferably larger than or equal to 5 nm and smaller than or equal to 70 nm, further preferably larger than or equal to 10 nm and smaller than or equal to 70 nm, further preferably larger than or equal to 10 nm and smaller than or equal to 50 nm, further preferably larger than or equal to 20 nm and smaller than or equal to 50 nm, further preferably larger than or equal to 20 nm and smaller than or equal to 40 nm. The thickness of each of the insulating layer 110a and the insulating layer 110c in the above range can allow the amount of oxygen vacancies (V_{O}) and V_{O}H to be reduced in the semiconductor layer, particularly in the channel formation region, whereby the transistor can have favorable electric characteristics and high reliability.

The amount of impurities (e.g., water and hydrogen) released from the insulating layer 110a and the insulating layer 110c themselves is preferably small. With the insulating layer 110a and the insulating layer 110c from which a small amount of impurities is released, diffusion of the impurities into the semiconductor layer is inhibited, and the transistor can have favorable electrical characteristics and high reliability.

By reducing the amount of impurities (e.g., water and hydrogen) released from the insulating layer 110a and the insulating layer 110c, the semiconductor layer in a region in contact with the insulating layer 110a and the semiconductor layer in a region in contact with the insulating layer 110c can each also function as the channel formation region. Note that when a material that releases impurities (e.g., water and hydrogen) is used for the insulating layer 110a, the semiconductor layer in the region in contact with the insulating layer 110a can function as the source region or the drain region. The same applies to the insulating layer 110c.

Oxygen is supplied from the insulating layer 110b to the semiconductor layer, whereby the amount of oxygen vacancies (V_{O}) and V_{O}H in the channel formation region is reduced. Consequently, a transistor with favorable electrical characteristics and high reliability can be obtained.

Due to heat applied in a step after the formation of the semiconductor layer, oxygen might be released from the semiconductor layer. However, supply of oxygen from the insulating layer 110 to the semiconductor layer can inhibit an increase in the amount of oxygen vacancies (V_{O}) and V_{O}H in the semiconductor layer. Furthermore, in a step after the formation of the semiconductor layer, the flexibility of the treatment temperature can be increased. Specifically, also in a step after the formation of the semiconductor layer, the treatment temperature can be high. Consequently, the transistor with favorable electrical characteristics and high reliability can be obtained.

A structure may be employed in which one or more of the insulating layer 110a and the insulating layer 110c are not necessarily provided. A structure in which neither the insulating layer 110a nor the insulating layer 110c is provided may be employed.

For the insulating layer 110_1, a material that can be used for the insulating layer 110b can be used. Although the insulating layer 110_1 has a single-layer structure in FIG. 6B and the like, one embodiment of the present invention is not limited thereto. The insulating layer 110_1 may have a stacked-layer structure of two or more layers.

### Conductive Layer 112a, Conductive Layer 112b, Conductive Layer 104, Conductive Layer 202a, Conductive Layer 202b, and Conductive Layer 204

The conductive layer 112a, the conductive layer 112b, the conductive layer 104, the conductive layer 202a, the conductive layer 202b, and the conductive layer 204 each functioning as a source electrode, a drain electrode, or a gate electrode can each be formed using one or more of chromium, copper, aluminum, gold, silver, zinc, tantalum, titanium, tungsten, manganese, nickel, iron, cobalt, molybdenum, and niobium; or an alloy containing one or more of these metals as its components. For each of the conductive layer 112a, the conductive layer 112b, the conductive layer 104, the conductive layer 202a, the conductive layer 202b, and the conductive layer 204, a conductive material with low electrical resistance that contains one or more of copper, silver, gold, and aluminum can be suitably used. Copper or aluminum is particularly preferable because of its high mass-productivity.

As the conductive layer 112a, the conductive layer 112b, the conductive layer 104, the conductive layer 202a, the conductive layer 202b, and the conductive layer 204, metal oxide films (also referred to as oxide conductors) can be used. Examples of the oxide conductor (OC) include an In—Sn oxide (ITO), an In—W oxide, an In—W—Zn oxide, an In—Ti oxide, an In—Ti—Sn oxide, an In—Zn oxide, an In—Sn—Si oxide (ITSO), and an In—Ga—Zn oxide.

Here, an oxide conductor (OC) is described. For example, when an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 112a, the conductive layer 112b, the conductive layer 104, the conductive layer 202a, the conductive layer 202b, and the conductive layer 204 may have a stacked-layer structure of a conductive film the above-described oxide conductor (metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, the conductive layer 104, the conductive layer 202a, the conductive layer 202b, and the conductive layer 204. The use of a Cu—X alloy film enables the manufacturing cost to be reduced because a wet etching process can be used in the processing.

The conductive layer 112a, the conductive layer 112b, the conductive layer 104, the conductive layer 202a, the conductive layer 202b, and the conductive layer 204 may be formed using the same material or different materials.

Here, the conductive layer 112a, the conductive layer 112b, the conductive layer 202a, and the conductive layer 202b will be specifically described using a structure in which a metal oxide is used for the semiconductor layer 108 and the semiconductor layer 208 as an example.

When an oxide semiconductor is used for the semiconductor layer 108 and the semiconductor layer 208, the conductive layer 112a, the conductive layer 112b, the conductive layer 202a, and the conductive layer 202b are oxidized by oxygen included in the semiconductor layer 108 and the semiconductor layer 208 and have high resistance in some cases. Furthermore, the conductive layer 112a, the conductive layer 112b, the conductive layer 202a, and the conductive layer 202b are oxidized by oxygen included in the insulating layer 110b or the like and have high resistance in some cases. Moreover, when the conductive layer 112a, the conductive layer 112b, the conductive layer 202a, and the conductive layer 202b are oxidized by oxygen included in the semiconductor layer 108 and the semiconductor layer 208, the amount of oxygen vacancy (V_{O}) in the semiconductor layer 108 and the semiconductor layer 208 is increased in some cases. Moreover, when the conductive layer 112a, the conductive layer 112b, the conductive layer 202a, and the conductive layer 202b are oxidized by oxygen included in the insulating layer 110b or the like, the amount of oxygen supplied from the insulating layer 110b or the like to the semiconductor layer 108 and the semiconductor layer 208 might be reduced.

In each of the transistor 100 and the transistor 200, diffusion of V_{O}H from the source region or the drain region into the channel formation region increases the carrier concentration in the channel formation region, which causes a change in the threshold voltage or a reduction in the reliability of each of the transistor 100 and the transistor 200, in some cases. The shorter the channel length is, the more the electrical characteristics and reliability of the transistor are affected by such diffusion of V_{O}H. Thus, a material that is less likely to be oxidized is preferably used for each of the conductive layer 112a and the conductive layer 112b each including a region in contact with the semiconductor layer 108, and the conductive layer 202a and the conductive layer 202b each include a region in contact with the semiconductor layer 208. An oxide conductor is preferably used for each of the conductive layer 112a, the conductive layer 112b, the conductive layer 202a, and the conductive layer 202b. For example, an In-Sn oxide (ITO) or an In—Sn—Si oxide (ITSO) can be suitably used. A nitride conductor may be used for each of the conductive layer 112a, the conductive layer 112b, the conductive layer 202a, and the conductive layer 202b. Examples of the nitride conductor include tantalum nitride and titanium nitride. The conductive layer 112a, the conductive layer 112b, the conductive layer 202a, and the conductive layer 202b may each have a stacked-layer structure of the above-described materials. The conductive layer 112a and the conductive layer 112b may be formed using the same material or different materials. The conductive layer 202a and the conductive layer 202b may be formed using the same material or different materials.

When a material that is less likely to be oxidized is used for the conductive layer 112a, the conductive layer 112b, the conductive layer 202a, and the conductive layer 202b, the conductive layers can be inhibited from being oxidized by oxygen included in the semiconductor layer 108, oxygen included in the semiconductor layer 208, or oxygen included in the insulating layer 110b or the like and from having high resistance. Furthermore, it is possible to increase the amount of oxygen supplied from the insulating layer 110b or the like to the semiconductor layer 108 and the semiconductor layer 208 while an increase in the amount of oxygen vacancies (V_{O}) in the semiconductor layer 108 and the semiconductor layer 208 is inhibited. Accordingly, the amount of oxygen vacancies (V_{O}) and V_{O}H in the semiconductor layer 108 and the semiconductor layer 208 can be reduced, whereby the transistor 100 and the transistor 200 with favorable electric characteristics and high reliability can be obtained.

One or more of an oxide conductor and a nitride conductor can be suitably used for each of the conductive layer 112a functioning as one of the source electrode and the drain electrode of the transistor 100 and the conductive layer 202a functioning as one of the source electrode and the drain electrode of the transistor 200. The conductive layer 112a and the conductive layer 202a may each have a two-layer stacked structure, and the above-described material may be used for the first layer and a material having lower resistance than the material may be used for the second layer. For the second layer, one or more of copper, aluminum, titanium, tungsten, and molybdenum or an alloy containing one or more of these metals as its components can be suitably used, for example. Specifically, in the case where the conductive layer 112a and the conductive layer 202a each have a two-layer stacked structure, an In-Sn-Si oxide (ITSO) and tungsten can be suitably used for the first layer and the second layer, respectively.

The structure of the conductive layer 112a and the conductive layer 202a are determined in accordance with wiring resistance required for the conductive layer 112a and the conductive layer 202a. For example, when the wirings (the conductive layer 112a and the conductive layer 202a) are short and requires relatively high wiring resistance, the conductive layer 112a and the conductive layer 202a may have a single-layer structure using a material that is less likely to be oxidized. Meanwhile, when the wirings (the conductive layer 112a and the conductive layer 202a) are long and requires relatively low wiring resistance, the conductive layer 112a and the conductive layer 202a preferably have a stacked-layer structure using a material that is less likely to be oxidized and a low-resistance material.

In the transistor 100, for example, the conductive layer 112a has a stacked-layer structure of a first conductive layer and a second conductive layer over the first conductive layer, and part of the second conductive layer is removed so that a region where the first conductive layer is exposed is provided. A structure may be employed in which the first conductive layer and the semiconductor layer 108 are in contact with each other in the region. Similarly, in the transistor 200, the conductive layer 202a has a stacked-layer structure of a first conductive layer and a second conductive layer over the first conductive layer, and part of the second conductive layer is removed so that a region where the first conductive layer is exposed is provided. A structure may be employed in which the first conductive layer and the semiconductor layer 208 are in contact with each other in the region. The structures of the conductive layer 112a and the conductive layer 202a can be employed for other conductive layers.

### Insulating layer 106

The insulating layer 106 functioning as a gate insulating layer of each of the transistor 100 and the transistor 200 preferably has low defect density. With the insulating layer 106 having low defect density, the transistor 100 and the transistor 200 can have favorable electrical characteristics. In addition, the insulating layer 106 preferably has a high breakdown voltage. With the insulating layer 106 having high breakdown voltage, the transistor 100 and the transistor 200 can have high reliability.

For the insulating layer 106, one or more of an insulating oxide, an insulating oxynitride, an insulating nitride oxide, and an insulating nitride can be used, for example. For the insulating layer 106, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga—Zn oxide can be used. The insulating layer 106 may be either a single layer or a stacked layer. The insulating layer 106 may have a stacked-layer structure of an oxide and a nitride.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 106 itself is preferably small. With the insulating layer 106 from which a small amount of impurities is released, diffusion of impurities into the semiconductor layer 108 and the semiconductor layer 208 is inhibited, and the transistor 100 and the transistor 200 can have favorable electrical characteristics and high reliability.

The insulating layer 106 is formed over each of the semiconductor layer 108 and the semiconductor layer 208, and thus is preferably a film formed under conditions where damage to the semiconductor layer 108 and the semiconductor layer 208 is small. For example, the insulating layer 106 is preferably formed under conditions where the film formation speed (also referred to as film formation rate) is sufficiently low. For example, when the insulating layer 106 is formed by a PECVD method under a low-power condition, damage to the semiconductor layer 108 and the semiconductor layer 208 can be extremely small.

Here, the insulating layer 106 will be described in detail with use of a structure in which a metal oxide is used for each of the semiconductor layer 108 and the semiconductor layer 208 as an example.

In order to improve properties of the interface between the insulating layer 106 and the semiconductor layer 108 and the interface between the insulating layer 106 and the semiconductor layer 208, an oxide or an oxynitride is preferably used at least for the side of the insulating layer 106 that is in contact with the semiconductor layer 108 and the semiconductor layer 208. For example, one or more of silicon oxide and silicon oxynitride can be suitably used for the insulating layer 106. A film from which oxygen is released by heating is further preferably used as the insulating layer 106.

Note that the insulating layer 106 may have a stacked-layer structure. The insulating layer 106 can have a stacked-layer structure of an oxide film on the side in contact with the semiconductor layer 108 and the semiconductor layer 208 and a nitride film on the side in contact with the conductive layer 104 and the conductive layer 204. For example, one or more of silicon oxide and silicon oxynitride can be suitably used for the oxide film. Silicon nitride can be suitably used for the nitride film.

### Substrate 102

There is no particular limitation on the properties of the material of the substrate 102 as long as the material has heat resistance high enough to withstand at least heat treatment to be performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. Alternatively, any of these substrates over which a semiconductor element is provided may be used as the substrate 102. Note that the shape of the semiconductor substrate and an insulating substrate may be circular or square.

A flexible substrate may be used as the substrate 102, and the transistor 100, the transistor 200, and the like may be formed directly on the flexible substrate. Alternatively, a separation layer may be provided between the substrate 102 and the transistor 100, the transistor 200, and the like. The separation layer can be used for separation of part or the whole of a semiconductor device completed thereover from the substrate 102 and transferring the part or the whole of the semiconductor device onto another substrate. In that case, the transistor 100, the transistor 200, and the like can be transferred onto a substrate having low heat resistance or a flexible substrate as well.

FIG. 6B and the like illustrate the structure of the transistor 100 in which the thickness of a region of the conductive layer 112a that is in contact with the semiconductor layer 108 and the thickness of a region of the conductive layer 112a that is not in contact with the semiconductor layer 108 are equal to or substantially equal to each other; however, one embodiment of the present invention is not limited thereto. The thickness of the region of the conductive layer 112a that is in contact with the semiconductor layer 108 may be smaller than the thickness of the region of the conductive layer 112a that is not in contact with the semiconductor layer 108.

Similarly, FIG. 6B and the like illustrate the structure of the transistor 200 in which the thickness of a region of the conductive layer 202a that is in contact with the semiconductor layer 208 and the thickness of a region of the conductive layer 202a that is not in contact with the semiconductor layer 208 are equal to or substantially equal to each other; however, one embodiment of the present invention is not limited thereto. The thickness of the region of the conductive layer 202a that is in contact with the semiconductor layer 208 may be smaller than the thickness of the region of the conductive layer 202a that is not in contact with the semiconductor layer 208.

The above is the description of the components.

A structure example of a semiconductor device whose structure is partly different from that of <Structure example 1> shown above will be described below. Note that description of the same portions as those in <Structure example 1> shown above is omitted below in some cases. Furthermore, in drawings that are referred to later, the same hatching pattern is applied to portions having functions similar to those in <Structure example 1> shown above, and the portions are not denoted by reference numerals in some cases.

### Structure Example 2

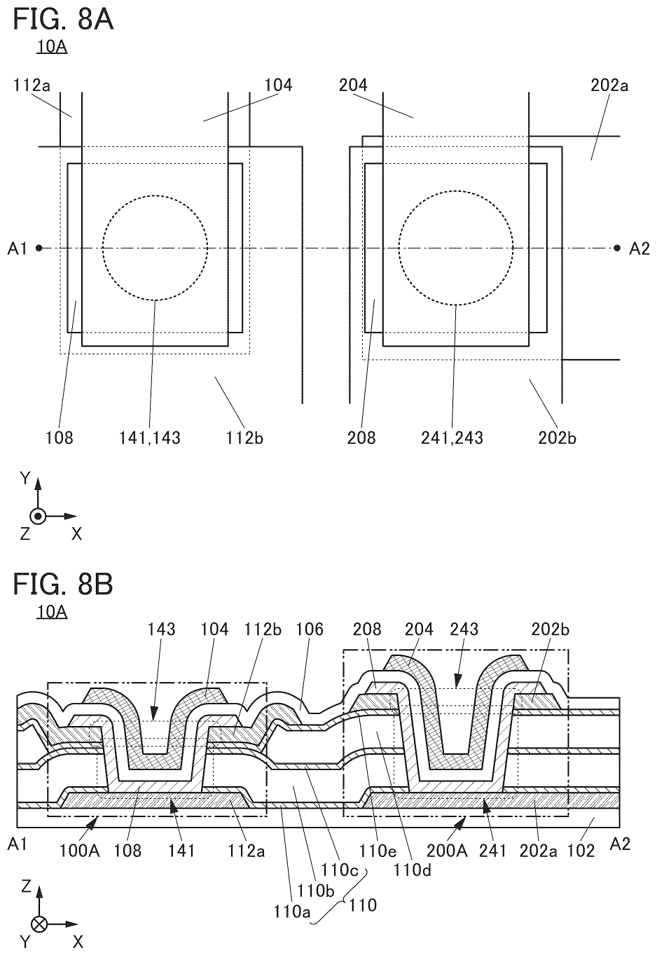

FIG. 8A is a plan view of a semiconductor device 10A. FIG. 8B is a cross-sectional view along dashed-dotted line A1-A2 in FIG. 8A.

The semiconductor device 10A includes a transistor 100A and a transistor 200A. The transistor 100A is different from the transistor 100 included in the semiconductor device 10 described in <Structure example 1> in that an insulating layer sandwiched between the conductive layer 112a and the conductive layer 112b has a four-layer stacked structure including an insulating layer 110e over the insulating layer 110c in addition to the insulating layer 110a, the insulating layer 110b, and the insulating layer 110c. The transistor 200A is different from the transistor 200 included in the semiconductor device 10 described in <Structure example 1> in that an insulating layer sandwiched between the conductive layer 202a and the conductive layer 202b has a five-layer stacked structure including an insulating layer 110d over the insulating layer 110c and the insulating layer 110e over the insulating layer 110d in addition to the insulating layer 110a, the insulating layer 110b, and the insulating layer 110c. In FIG. 8B, the insulating layer 110a, the insulating layer 110c, and the insulating layer 110e are not necessarily provided. The same applies to other structure examples described in this specification.

Furthermore, in the transistor 100A, an end portion of the conductive layer 112b extends to the outside of the transistor 100 (the side opposite to the opening 143), and the end portion is positioned over the five-layer stack of the insulating layer 110a, the insulating layer 110b, the insulating layer 110c, the insulating layer 110d, and the insulating layer 110e, as illustrated in FIG. 8B.

In the semiconductor device 10A, the insulating layer 110d has a function of supplying oxygen to the semiconductor layer 208. Thus, the insulating layer 110d can be formed using the same material as the aforementioned insulating layer 110b. The insulating layer 110e has a function of inhibiting entry of impurities (e.g., water and hydrogen) into the insulating layer 110d from above the insulating layer 110d, and a function of inhibiting release of oxygen included in the insulating layer 110d to above the insulating layer 110d. Thus, the insulating layer 110e can be formed using the same material as the aforementioned insulating layer 110a and insulating layer 110c.

As illustrated in FIG. 6B, the transistor 200 included in the semiconductor device 10 described in <Structure example 1> has a structure in which the insulating layer 110_1 that is the first layer of oxygen-supplying insulating layers (i.e., the insulating layer 110_1 and the insulating layer 110b) sandwiched between the conductive layer 202a and the conductive layer 202b is formed in an island shape and the insulating layer 110b that is the second layer is formed over the island-shaped insulating layer 110_1.

By contrast, as illustrated in FIG. 8B, the transistor 200A included in the semiconductor device 10A has a structure in which the insulating layer 110d that is the second layer of oxygen-supplying insulating layers (i.e., the insulating layer 110b and the insulating layer 110d) sandwiched between the conductive layer 202a and the conductive layer 202b is formed over the insulating layer 110b that is the first layer formed over the substrate 102.

That is, the different point is that, in the transistor 200 included in the semiconductor device 10 described in <Structure example 1>, the first insulating layer of the two oxygen-supplying insulating layers is processed into an island shape, whereas in the transistor 200A included in the semiconductor device 10A, the second insulating layer of the two oxygen-supplying insulating layers is processed into an island shape.

In the semiconductor device of one embodiment of the present invention, any layer of a stacked insulating layers (oxygen-supplying insulating layers) sandwiched between a source electrode and a drain electrode of a vertical-channel transistor is processed into an island shape as described above, whereby the channel length of the vertical-channel transistor can be adjusted. As a result, two or more transistors included in the semiconductor device can have different channel lengths. The details of examples of methods for manufacturing the semiconductor device 10 described in <Structure example 1> and the semiconductor device 10A will be described in Embodiment 2.

The descriptions of the transistor 100 and the transistor 200 included in the semiconductor device 10 described in <Structure example 1> can be referred to for the transistor 100A and the transistor 200A included in the semiconductor device 10A except for the aforementioned differences; thus, the detailed description is omitted.

The semiconductor device 10A can enjoy a similar effect as the semiconductor device 10 described in <Structure example 1>.

### Structure Example 3

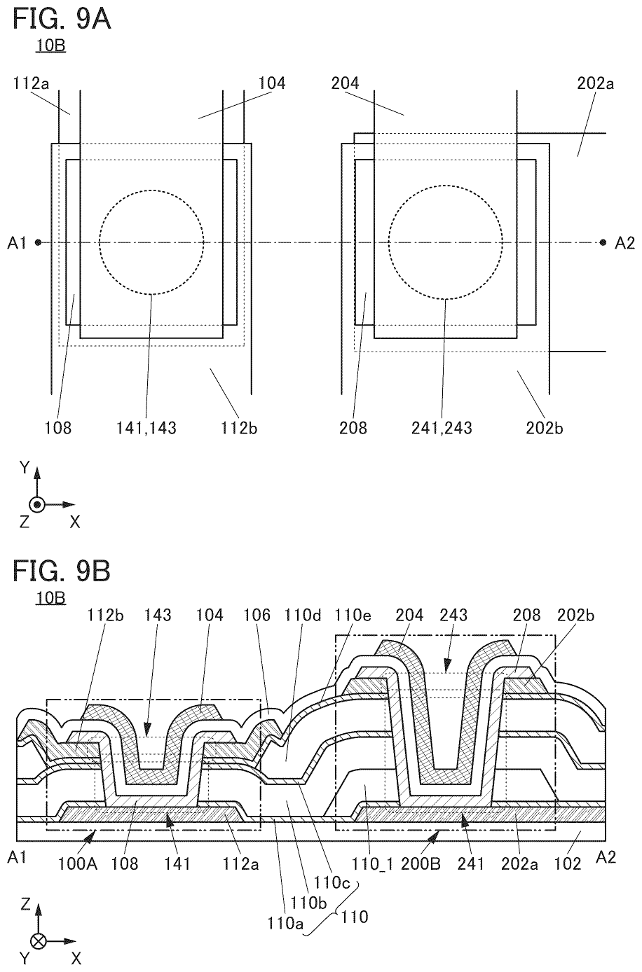

FIG. 9A is a plan view of a semiconductor device 10B. FIG. 9B is a cross-sectional view along dashed-dotted line A1-A2 in FIG. 9A.

The semiconductor device 10B includes the transistor 100A and a transistor 200B. The above description can be referred to for the transistor 100A. The transistor 200B is different from the transistor 200 included in the semiconductor device 10 described in <Structure example 1> in that an insulating layer sandwiched between the conductive layer 202a and the conductive layer 202b has a six-layer stacked structure including the insulating layer 110a, the insulating layer 110_1 over the insulating layer 110a, the insulating layer 110b over the insulating layer 110_1, the insulating layer 110c over the insulating layer 110b, the insulating layer 110d over the insulating layer 110c, and the insulating layer 110e over the insulating layer 110d.

As illustrated in FIG. 9B, the transistor 200B included in the semiconductor device 10B has a structure in which the insulating layer 110_1 that is the first layer of oxygen-supplying insulating layers (i.e., the insulating layer 110_1, the insulating layer 110b, and the insulating layer 110d) sandwiched between the conductive layer 202a and the conductive layer 202b is formed in an island shape, the insulating layer 110b that is the second layer is formed over the island-shaped insulating layer 110_1, and the insulating layer 110d that is the third layer is formed in an island shape over the insulating layer 110b.

That is, it can be said that the transistor 200B included in the semiconductor device 10B has a combined structure of the transistor 200 (see FIG. 6B) included in the semiconductor device 10 described in <Structure example 1> and the transistor 200A (see FIG. 8B) included in the semiconductor device 10A described in <Structure example 2>. Accordingly, the transistor 200B included in the semiconductor device 10B includes three insulating layers (the insulating layer 110_1, the insulating layer 110b, and the insulating layer 110d) that can supply oxygen to the semiconductor layer 208.

The descriptions of the transistor 200 included in the semiconductor device 10 described in <Structure example 1> and the transistor 200A included in the semiconductor device 10A described in <Structure example 2> can be referred to for the transistor 200B included in the semiconductor device 10B except for the aforementioned difference; thus, the detailed description is omitted.

The channel length and the thickness of the insulating layers sandwiched between the source electrode and the drain electrode are larger in the transistor 200B included in the semiconductor device 10B than in the transistor 200 included in the semiconductor device 10 and in the transistor 200A included in the semiconductor device 10A. Thus, the semiconductor device 10B can be suitably used for a circuit required to have favorable saturation characteristics and high source-drain withstand voltage.

### Structure Example 4

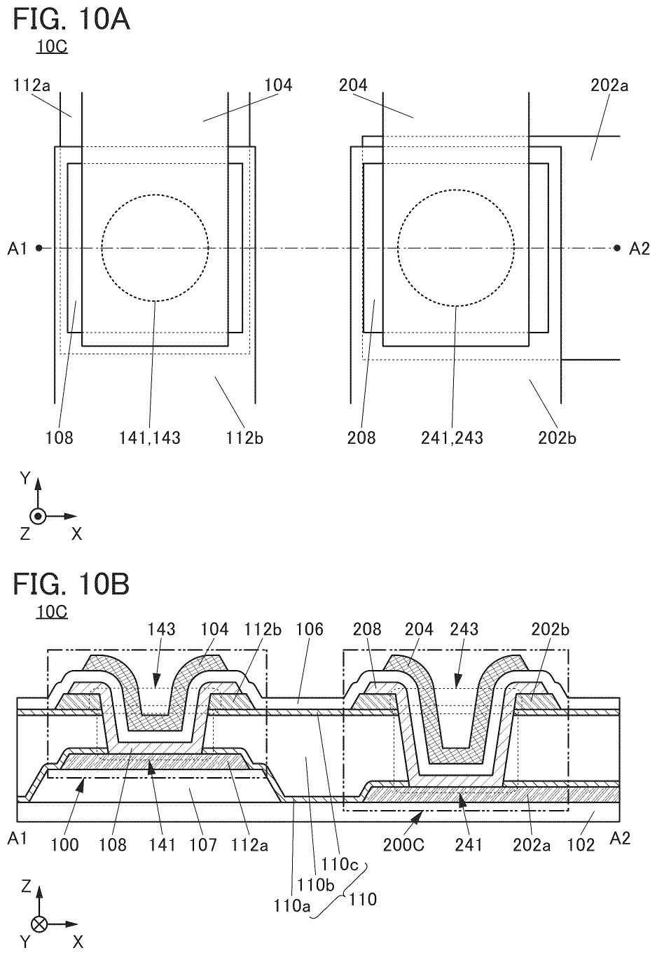

FIG. 10A is a plan view of a semiconductor device 10C. FIG. 10B is a cross-sectional view along dashed-dotted line A1-A2 in FIG. 10A.

The semiconductor device 10C includes the transistor 100 and a transistor 200C. The above description can be referred to for the transistor 100. The transistor 200C is different from the transistor 200 included in the semiconductor device 10 described in <Structure example 1> in that an insulating layer sandwiched between the conductive layer 202a and the conductive layer 202b has a three-layer stacked structure (the insulating layer 110a, the insulating layer 110b, and the insulating layer 110c). In both the transistor 100 and the transistor 200C, only the insulating layer 110b is an insulating layer that supplies oxygen to the corresponding semiconductor layer.

As illustrated in FIG. 10B, the transistor 100 included in the semiconductor device 10C is provided over an island-shaped insulating layer 107 formed over the substrate 102. In the semiconductor device 10C, the insulating layer 110a is provided to cover part of the top surface of the substrate 102, a side surface of the insulating layer 107, a side surface and part of the top surface of the conductive layer 112a, and a side surface and part of the top surface of the conductive layer 202a.

As illustrated in FIG. 10B, the conductive layer 112b functioning as the other of the source electrode and the drain electrode of the transistor 100 included in the semiconductor device 10C and the conductive layer 202b functioning as the other of a source electrode and a drain electrode of the transistor 200C are provided to be substantially level with each other over the insulating layer 110c.

Thus, it can be said that the channel length of the transistor 100 included in the semiconductor device 10C (i.e., the thickness of the insulating layer 110a, the insulating layer 110b, and the insulating layer 110c in a region sandwiched between the conductive layer 112a and the conductive layer 112b) is shorter than the channel length of the transistor 200C (i.e., the thickness of the insulating layer 110a, the insulating layer 110b, and the insulating layer 110c in a region sandwiched between the conductive layer 202a and the conductive layer 202b) by the thickness of the insulating layer 107.

In the semiconductor device of one embodiment of the present invention, an island-shaped insulating layer is provided over a substrate and a plurality of vertical-channel transistors are formed over the substrate over which the island-shaped insulating layer is formed as described above, whereby the transistors can be formed at the same time to have different channel lengths. The details of an example of a method for manufacturing the semiconductor device 10C will be described in Embodiment 2.

The description of the transistor 200 included in the semiconductor device 10 described in <Structure example 1> can be referred to for the transistor 200C included in the semiconductor device 10C except for the aforementioned difference; thus, the detailed description is omitted.

The semiconductor device 10C can enjoy a similar effect as the semiconductor device 10 described in <Structure example 1>.

### Structure Example 5

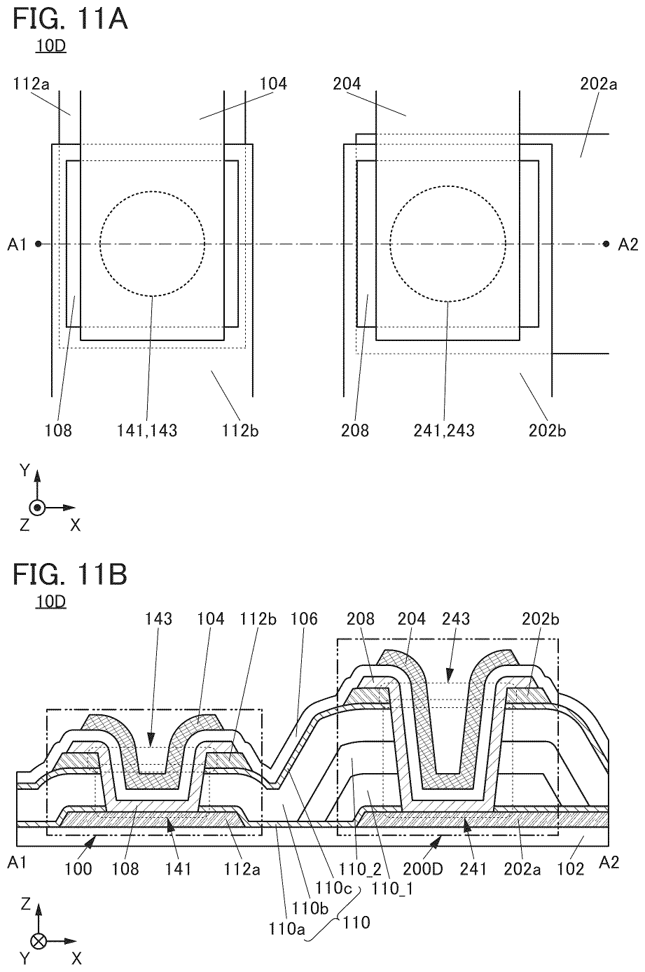

FIG. 11A is a plan view of a semiconductor device 10D. FIG. 11B is a cross-sectional view along dashed-dotted line A1-A2 in FIG. 11A.

The semiconductor device 10D includes the transistor 100 and a transistor 200D. The above description can be referred to for the transistor 100. The transistor 200D is different from the transistor 200 included in the semiconductor device 10 described in <Structure example 1> in that an insulating layer sandwiched between the conductive layer 202a and the conductive layer 202b has a five-layer stacked structure (the insulating layer 110a, the insulating layer 110_1, an insulating layer 110_2, the insulating layer 110b, and the insulating layer 110c).

As illustrated in FIG. 11B, the transistor 200D included in the semiconductor device 10D includes, between the conductive layer 202a and the conductive layer 202b, the insulating layer 110a, the insulating layer 110_1 formed in an island shape over the insulating layer 110a, the insulating layer 110_2 formed in an island shape to cover the insulating layer 110_1, the insulating layer 110b formed over the insulating layer 110_2, and the insulating layer 110c formed over the insulating layer 110b.

In the semiconductor device 10D, the insulating layer 110_2 has a function of supplying oxygen to the semiconductor layer 208. Thus, the insulating layer 110_2 can be formed using the same material as the aforementioned insulating layer 110b and insulating layer 110_1. Accordingly, the transistor 200D included in the semiconductor device 10D includes three insulating layers (the insulating layer 110_1, the insulating layer 110_2, and the insulating layer 110b) that can supply oxygen to the semiconductor layer 208.

The description of the transistor 200 included in the semiconductor device 10 described in <Structure example 1> can be referred to for the transistor 200D included in the semiconductor device 10D except for the aforementioned difference; thus, the detailed description is omitted.

The channel length and the thickness of the insulating layers sandwiched between the source electrode and the drain electrode are larger in the transistor 200D included in the semiconductor device 10D than in the transistor 200 included in the semiconductor device 10. Thus, the semiconductor device 10D can be suitably used for a circuit required to have favorable saturation characteristics and high source-drain withstand voltage.

### Structure Example 6

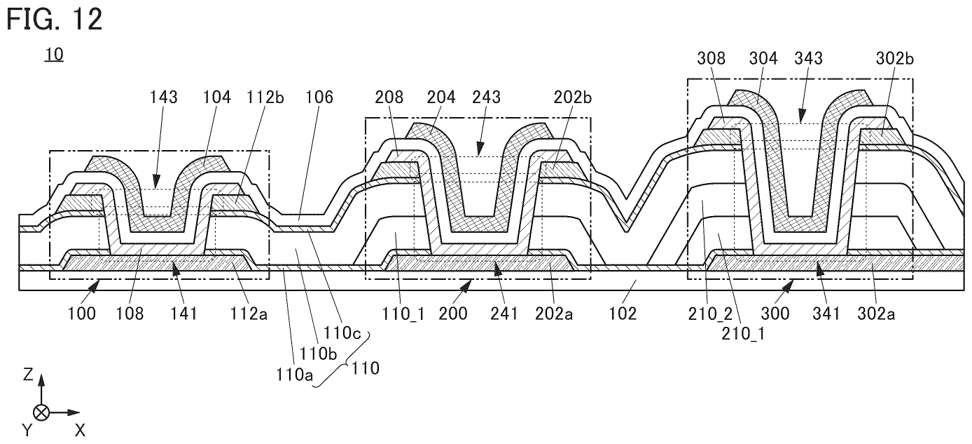

FIG. 12 is a cross-sectional view of a variation example of the semiconductor device 10 described in <Structure example 1>.

The semiconductor device 10 may have a structure including three or more vertical-channel transistors having different channel lengths. FIG. 12 illustrates a structure in which the semiconductor device 10 includes a transistor 300 in addition to the transistor 100 and the transistor 200 illustrated in FIG. 6B.

The above description can be referred to for the transistor 100 and the transistor 200 included in the semiconductor device 10 illustrated in FIG. 12.

The transistor 300 included in the semiconductor device 10 illustrated in FIG. 12 includes a conductive layer 304, the insulating layer 106, a semiconductor layer 308, a conductive layer 302a, and a conductive layer 302b. The conductive layer 304 functions as a gate electrode. Part of the insulating layer 106 functions as a gate insulating layer. The conductive layer 302a functions as one of a source electrode and a drain electrode, and the conductive layer 302b functions as the other of the source electrode and the drain electrode. In the semiconductor layer 308, the whole region that is between the source electrode and the drain electrode and overlaps with the gate electrode with the gate insulating layer therebetween functions as a channel formation region. In the semiconductor layer 308, a region in contact with the source electrode functions as a source region, and a region in contact with the drain electrode functions as a drain region.

The conductive layer 302a is provided over the substrate 102 in a region different from the conductive layer 112a and the conductive layer 202a. The conductive layer 302a can be formed using the same material and the same step as the conductive layer 112a and the conductive layer 202a.

The insulating layer 110a, an insulating layer 210_1 over the insulating layer 110a, an insulating layer 210_2 over the insulating layer 210_1, the insulating layer 110b over the insulating layer 210_2, and the insulating layer 110c over the insulating layer 110b are provided over the conductive layer 302a. The conductive layer 302b is provided over the insulating layer 110c. Each of the insulating layer 110a, the insulating layer 210_1, the insulating layer 210_2, the insulating layer 110b, and the insulating layer 110c includes a region sandwiched between the conductive layer 302a and the conductive layer 302b. The conductive layer 302a includes a region overlapping with the conductive layer 302b with the insulating layer 110a, the insulating layer 210_1, the insulating layer 210_2, the insulating layer 110b, and the insulating layer 110c therebetween. The insulating layer 110a, the insulating layer 210_1, the insulating layer 210_2, the insulating layer 110b, and the insulating layer 110c have an opening 341 in a region overlapping with the conductive layer 302a. The conductive layer 302a is exposed in the opening 341. The conductive layer 302b has an opening 343 in a region overlapping with the conductive layer 302a. The opening 343 is provided in a region overlapping with the opening 341.

In the transistor 300, an insulating layer that supplies oxygen to the semiconductor layer 308 is composed of three layers, the insulating layer 210_1, the insulating layer 210_2, and the insulating layer 110b. Thus, for the insulating layer 210_1 and the insulating layer 210_2, the same material as the aforementioned insulating layer 110b and insulating layer 110_1 can be used. The insulating layer 210_2 can be formed in the same step as the insulating layer 110_1.

The semiconductor layer 308 is provided to cover the opening 341 and the opening 343. The semiconductor layer 308 includes a region in contact with the top surface and a side surface of the conductive layer 302b, a side surface of the insulating layer 110c, a side surface of the insulating layer 110b, a side surface of the insulating layer 210_2, a side surface of the insulating layer 210_1, a side surface of the insulating layer 110a, and the top surface of the conductive layer 302a. The semiconductor layer 308 is electrically connected to the conductive layer 302a via the opening 341 and the opening 343. The semiconductor layer 308 has a shape along the top surface and the side surface of the conductive layer 302b, the side surface of the insulating layer 110c, the side surface of the insulating layer 110b, the side surface of the insulating layer 210_2, the side surface of the insulating layer 210_1, the side surface of the insulating layer 110a, and the top surface of the conductive layer 302a.

The conductive layer 302b can be formed using the same material and the same step as the conductive layer 112b and the conductive layer 202b. The semiconductor layer 308 can be formed using the same material and the same step as the semiconductor layer 108 and the semiconductor layer 208.

The insulating layer 106 functioning as the gate insulating layer of the transistor 300 is provided to cover the opening 341 and the opening 343 with the semiconductor layer 308 therebetween. The insulating layer 106 is provided over the semiconductor layer 108, the conductive layer 112b, the semiconductor layer 208, the conductive layer 202b, the semiconductor layer 308, the conductive layer 302b, and the insulating layer 110c. The insulating layer 106 includes a region in contact with the top surface of the semiconductor layer 108, the side surface of the conductive layer 112b, the top surface of the semiconductor layer 208, the side surface of the conductive layer 202b, the top surface of the semiconductor layer 308, a side surface of the conductive layer 302b, and the top surface of the insulating layer 110c. The insulating layer 106 has a shape along the top surface of the insulating layer 110c, the side surface of the conductive layer 112b, the top surface of the semiconductor layer 108, the side surface of the conductive layer 202b, the top surface of the semiconductor layer 208, the side surface of the conductive layer 302b, and the top surface of the semiconductor layer 308.

The conductive layer 304 functioning as the gate electrode of the transistor 300 is provided in contact with the top surface of the insulating layer 106. The conductive layer 304 includes a region overlapping with the semiconductor layer 308 with the insulating layer 106 therebetween. In the region, the conductive layer 304 has a shape along the top surface of the insulating layer 106.

The conductive layer 304 can be formed using the same material and the same step as the conductive layer 104 and the conductive layer 204.

Including three transistors having different channel lengths like the semiconductor device 10 illustrated in FIG. 12 can increase variations in characteristics of transistors included in one semiconductor device as compared with the case of including two transistors (see FIG. 6B). The number of transistors included in the semiconductor device 10 may be four or more.

### Structure Example 7

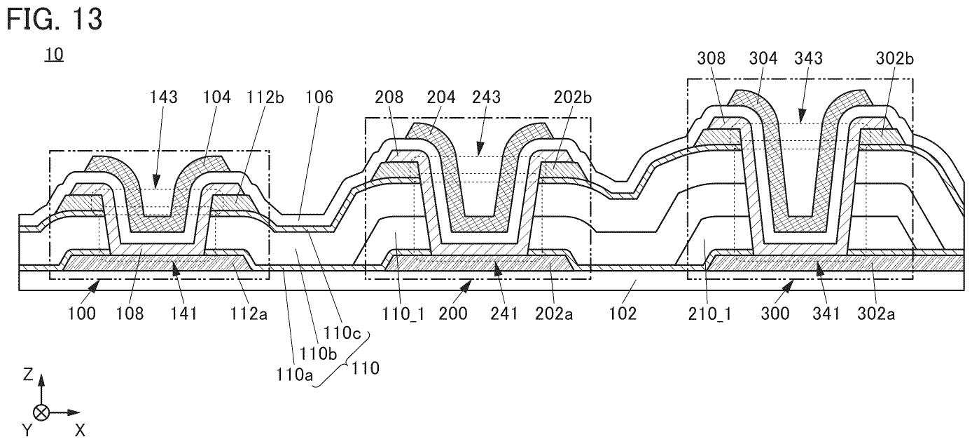

FIG. 13 is a cross-sectional view of a variation example of the semiconductor device 10 described in <Structure example 1>, which is different from that in <Structure example 6>.

The semiconductor device 10 illustrated in FIG. 13 is different from the semiconductor device 10 described in <Structure example 6> in that the transistor 300 does not include the insulating layer 210_2. Furthermore, the semiconductor device 10 is different from that described in <Structure example 6> in that the insulating layer 110_1 is provided in both the transistor 200 and the transistor 300.

Specifically, in the transistor 300 included in the semiconductor device 10 illustrated in FIG. 13, the insulating layer 110_1 extends to the transistor 300 side and is provided not only over the conductive layer 202a but also over the conductive layer 302a and the insulating layer 210_1.

### Structure Example 8

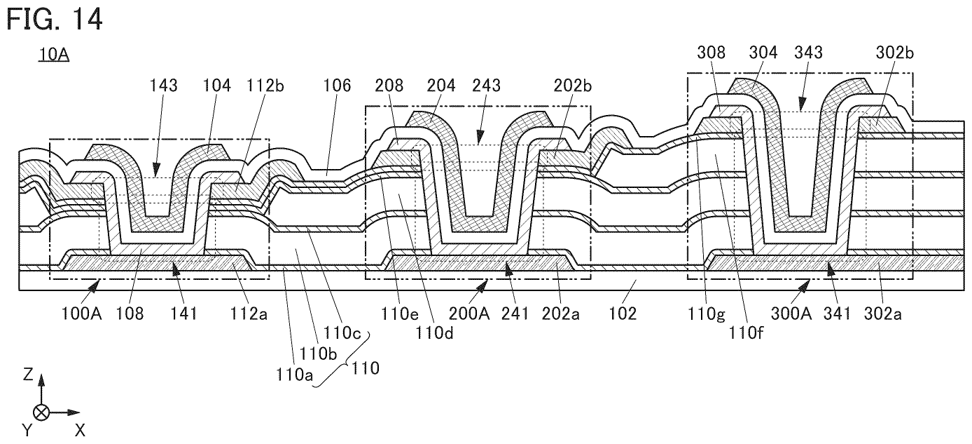

FIG. 14 is a cross-sectional view of a variation example of the semiconductor device 10A described in <Structure example 2>.

FIG. 14 illustrates a structure in which the semiconductor device 10A includes a transistor 300A in addition to the transistor 100A and the transistor 200A illustrated in FIG. 8B.

The above description can be referred to for the transistor 100A and the transistor 200A included in the semiconductor device 10A illustrated in FIG. 14.

The transistor 300A included in the semiconductor device 10A illustrated in FIG. 14 is different from the transistor 300 included in the semiconductor device 10 described in <Structure example 6> (see FIG. 12) in that an insulating layer sandwiched between the conductive layer 302a and the conductive layer 302b is composed of seven layers (the insulating layer 110a, the insulating layer 110b, the insulating layer 110c, the insulating layer 110d, the insulating layer 110e, an insulating layer 110f, and an insulating layer 110g). In FIG. 14, the insulating layer 110a, the insulating layer 110c, the insulating layer 110e, and the insulating layer 110g are not necessarily provided. The same applies to other structure examples described in this specification.

In the transistor 300A included in the semiconductor device 10A illustrated in FIG. 14, the insulating layer 110b, the insulating layer 110d, and the insulating layer 110f each have a function of supplying oxygen to the semiconductor layer 308. Thus, for the insulating layer 110f, the same material as the aforementioned insulating layer 110b and insulating layer 110d can be used. The insulating layer 110a, the insulating layer 110c, the insulating layer 110e, and the insulating layer 110g each have a function of inhibiting entry of impurities (e.g., water and hydrogen) into the insulating layer 110b, the insulating layer 110d, and the insulating layer 110f from the outside of the semiconductor device 10A, and a function of inhibiting release of oxygen included in the insulating layer 110b, the insulating layer 110d, and the insulating layer 110f to the outside of the semiconductor device 10A. Thus, for the insulating layer 110g, the same material as the aforementioned insulating layer 110a, insulating layer 110c, and insulating layer 110e can be used.

Including three transistors having different channel lengths like the semiconductor device 10A illustrated in FIG. 14 can increase variations in characteristics of transistors included in one semiconductor device as compared with the case of including two transistors (see FIG. 8B). The number of transistors included in the semiconductor device 10A may be four or more.

### Structure Example 9

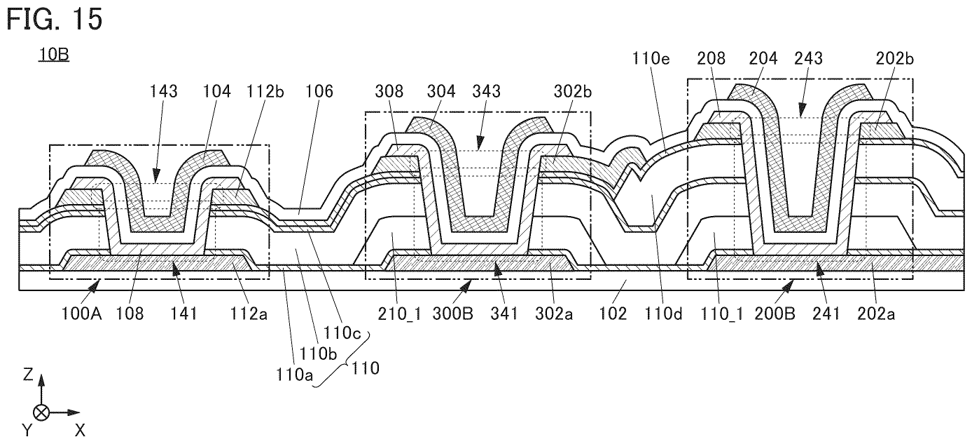

FIG. 15 is a cross-sectional view of a variation example of the semiconductor device 10B described in <Structure example 3>.

FIG. 15 illustrates a structure in which the semiconductor device 10B includes a transistor 300B in addition to the transistor 100A and the transistor 200B illustrated in FIG. 9B.

The above description can be referred to for the transistor 100A and the transistor 200B included in the semiconductor device 10B illustrated in FIG. 15.

The transistor 300B included in the semiconductor device 10B illustrated in FIG. 15 is different from the transistor 300 included in the semiconductor device 10 described in <Structure example 6> (see FIG. 12) in that an insulating layer sandwiched between the conductive layer 302a and the conductive layer 302b is composed of five layers (the insulating layer 110a, the insulating layer 210_1, the insulating layer 110b, the insulating layer 110c, and the insulating layer 110e).

In the transistor 300B included in the semiconductor device 10B illustrated in FIG. 15, the insulating layer 210_1 and the insulating layer 110b each have a function of supplying oxygen to the semiconductor layer 308. The insulating layer 110a, the insulating layer 110c, and the insulating layer 110e each have a function of inhibiting entry of impurities (e.g., water and hydrogen) into the insulating layer 210_1 and the insulating layer 110b from the outside of the semiconductor device 10B, and a function of inhibiting release of oxygen included in the insulating layer 210_1 and the insulating layer 110b to the outside of the semiconductor device 10B.

The insulating layer 210_1 can be formed in the same step as the insulating layer 110_1.

Including three transistors having different channel lengths like the semiconductor device 10B illustrated in FIG. 15 can increase variations in characteristics of transistors included in one semiconductor device as compared with the case of including two transistors (see FIG. 9B). The number of transistors included in the semiconductor device 10B may be four or more.

### Structure Example 10

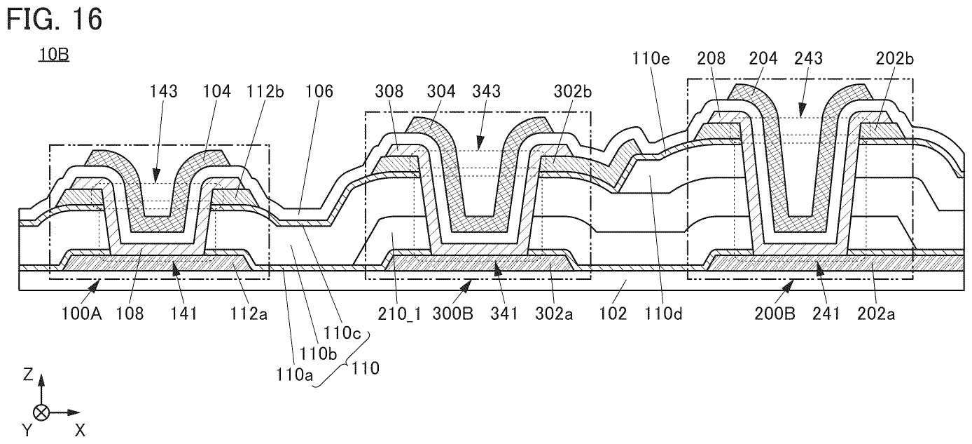

FIG. 16 is a cross-sectional view of a variation example of the semiconductor device 10B described in <Structure example 3>, which is different from that in <Structure example 9>.

The semiconductor device 10B illustrated in FIG. 16 is different from the semiconductor device 10B described in <Structure example 9> in that the transistor 200B does not include the insulating layer 110_1. Furthermore, the semiconductor device 10B is different from that described in <Structure example 9> in that the insulating layer 210_1 is provided in both the transistor 200B and the transistor 300B.

Specifically, in the transistor 200B included in the semiconductor device 10B illustrated in FIG. 16, the insulating layer 210_1 extends to the transistor 200B side and is provided not only over the conductive layer 302a but also over the conductive layer 202a.

### Structure Example 11

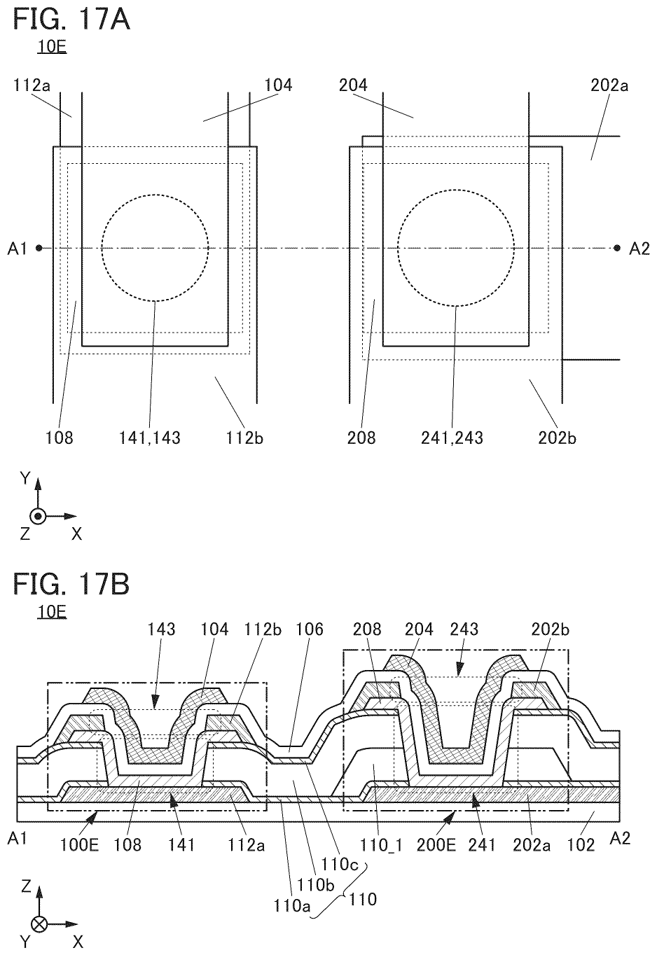

FIG. 17A is a plan view of a semiconductor device 10E. FIG. 17B is a cross-sectional view along dashed-dotted line A1-A2 in FIG. 17A.

The semiconductor device 10E includes a transistor 100E and a transistor 200E. The transistor 100E is different from the transistor 100 included in the semiconductor device 10 described in <Structure example 1> in that the conductive layer 112b functioning as the other of a source electrode and a drain electrode is in contact with the top surface of the semiconductor layer 108. The transistor 200E is different from the transistor 200 included in the semiconductor device 10 described in <Structure example 1> in that the conductive layer 202b functioning as the other of a source electrode and a drain electrode is in contact with the top surface of the semiconductor layer 208.

As described above, the semiconductor device of one embodiment of the present invention may have a structure in which the conductive layer functioning as the other of the source electrode and the drain electrode is in contact with the bottom surface of the semiconductor layer (the surface on the insulating layer 110 side) or may have a structure in which the conductive layer is in contact with the top surface of the semiconductor layer, depending on the ease of manufacturing, an object in which the semiconductor device is used, or the like.

Although FIG. 17B illustrates a structure in which the conductive layer functioning as the other of the source electrode and the drain electrode is in contact with the top surface of the semiconductor layer in both the transistor 100E and the transistor 200E included in the semiconductor device 10E, one embodiment of the present invention is not limited thereto. The semiconductor device of one embodiment of the present invention may have a structure in which the conductive layer functioning as the other of the source electrode and the drain electrode is in contact with the bottom surface of the semiconductor layer (the surface on the insulating layer 110 side) in only some of the transistors included in the semiconductor device and the conductive layer functioning as the other of the source electrode and the drain electrode is in contact with the top surface of the semiconductor layer in the other transistors.

The descriptions of the transistor 100 and the transistor 200 included in the semiconductor device 10 described in <Structure example 1> can be referred to for the transistor 100E and the transistor 200E included in the semiconductor device 10E except for the aforementioned differences; thus, the detailed description is omitted.

### Structure Example 12

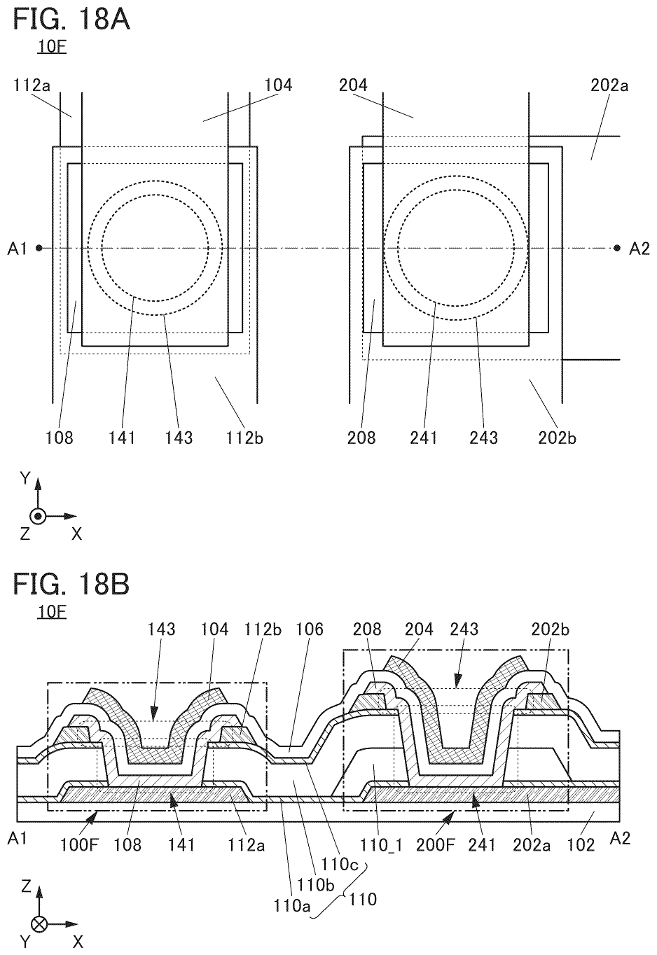

FIG. 18A is a plan view of a semiconductor device 10F. FIG. 18B is a cross-sectional view along dashed-dotted line A1-A2 in FIG. 18A.

The semiconductor device 10F includes a transistor 100F and a transistor 200F. The transistor 100F is different from the transistor 100 included in the semiconductor device 10 described in <Structure example 1> in that an end portion of the conductive layer 112b functioning as the other of a source electrode and a drain electrode on the opening 143 side is positioned outward from an end portion of the opening 141. The transistor 200F is different from the transistor 200 included in the semiconductor device 10 described in <Structure example 1> in that an end portion of the conductive layer 202b functioning as the other of a source electrode and a drain electrode on the opening 243 side is positioned outward from an end portion of the opening 241.

Since the semiconductor device 10F has the above-described structure, in a plan view of the transistor 100F (see FIG. 18(A)), an end portion of the top surface of the insulating layer 110 on the opening 141 side is not aligned with an end portion of the bottom surface of the conductive layer 112b on the opening 143 side. Similarly, an end portion of the top surface of the insulating layer 110 and the insulating layer 110_1 on the opening 241 side is not aligned with an end portion of the bottom surface of the conductive layer 202b on the opening 243 side in the transistor 200F. In a cross-sectional view of the transistor 100F (see FIG. 18(B)), a step is produced between the end portion of the top surface of the insulating layer 110 on the opening 141 side and the end portion of the bottom surface of the conductive layer 112b on the opening 143 side. Similarly, a step is produced between the end portion of the top surface of the insulating layer 110 and the insulating layer 110_1 on the opening 241 side and the end portion of the bottom surface of the conductive layer 202b on the opening 243 side in the transistor 200F.

As a result, the area of the formation surface of the semiconductor layer 108 can be larger in the transistor 100F than in the transistor 100 (see FIG. 6B) having a structure not including the above step. Similarly, the area of the formation surface of the semiconductor layer 208 can be larger in the transistor 200F than in the transistor 200 (see FIG. 6B) having a structure not including the above step. Thus, it can be said that the coverage of the formation surface with the semiconductor layer is higher in the transistor included in the semiconductor device 10F than in the transistor included in the semiconductor device 10 described in <Structure example 1>.

Although FIG. 18B illustrates a structure including, in both the transistor 100F and the transistor 200F included in the semiconductor device 10F, a step between the end portion of the top surface of the insulating layer 110 and the end portion of the bottom surface of the conductive layer functioning as the other of the source electrode and the drain electrode, one embodiment of the present invention is not limited thereto. The semiconductor device of one embodiment of the present invention may have a structure in which only some of the transistors included in the semiconductor device include a step between the end portion of the top surface of the insulating layer 110 and the end portion of the bottom surface of the conductive layer functioning as the other of the source electrode and the drain electrode.

The descriptions of the transistor 100 and the transistor 200 included in the semiconductor device 10 described in <Structure example 1> can be referred to for the transistor 100F and the transistor 200F included in the semiconductor device 10F except for the aforementioned differences; thus, the detailed description is omitted.

### Structure Example 13

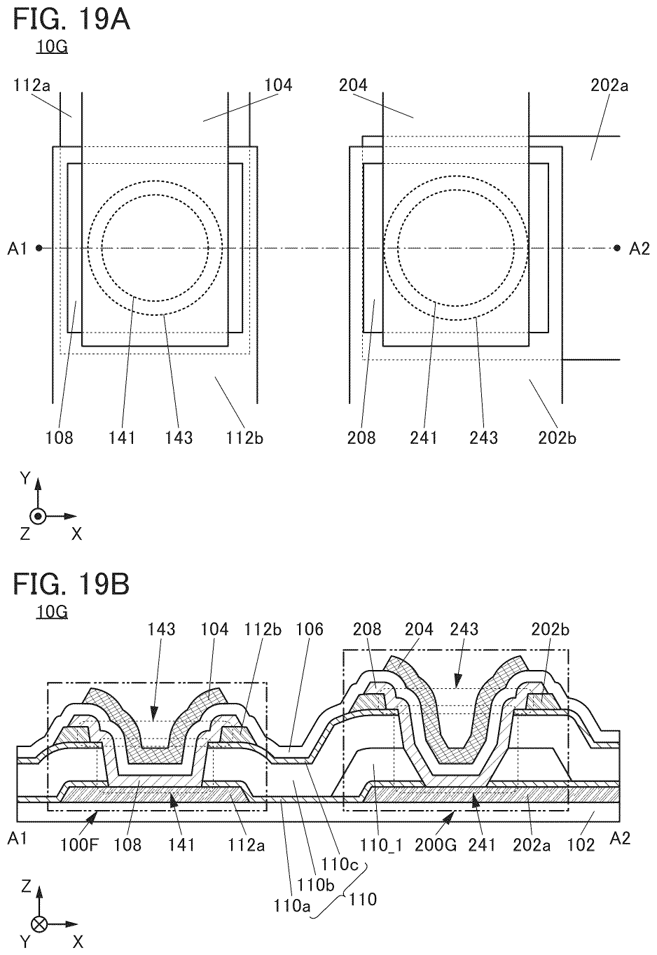

FIG. 19A is a plan view of a semiconductor device 10G. FIG. 19B is a cross-sectional view along dashed-dotted line A1-A2 in FIG. 19A.

The semiconductor device 10G includes the transistor 100F and a transistor 200G. The above description can be referred to for the transistor 100F. The transistor 200G is different from the transistor 200F included in the semiconductor device 10F described in <Structure example 12> in having a structure in which taper angles of side surfaces of the insulating layer 110a and the insulating layer 110_1 on the opening 241 side are different from taper angles of side surfaces of the insulating layer 110b and the insulating layer 110c on the opening 241 side.

Specifically, in the transistor 200F included in the semiconductor device 10F described in <Structure example 12>, taper angles of side surfaces of the insulating layer 110a, the insulating layer 110_1, the insulating layer 110b, and the insulating layer 110c on the opening 241 side are substantially the same. By contrast, the transistor 200G included in the semiconductor device 10G has a structure in which the taper angles of the side surfaces of the insulating layer 110a and the insulating layer 110_1 on the opening 241 side are smaller than the taper angles of the side surfaces of the insulating layer 110b and the insulating layer 110c on the opening 241 side.

As a result, the coverage of the formation surface with the semiconductor layer 208 can be higher in the transistor 200G included in the semiconductor device 10G than in the transistor 200F included in the semiconductor device 10F described in <Structure example 12>. In the case where the taper angles of the side surfaces of the insulating layer 110a, the insulating layer 110_1, the insulating layer 110b, and the insulating layer 110c on the opening 241 side are substantially the same as in the transistor 200F, on the other hand, the opening 241 can be formed in one step and the process can be simplified as compared to the transistor 200G.

Although FIG. 19B illustrates a structure in which the taper angles of the side surfaces of the insulating layer 110a and the insulating layer 110_1 on the opening 241 side are smaller than the taper angles of the side surfaces of the insulating layer 110b and the insulating layer 110c on the opening 241 side, one embodiment of the present invention is not limited thereto. In one embodiment of the present invention, the taper angles of the side surfaces of the insulating layer 110a and the insulating layer 110_1 on the opening 241 side may be larger than the taper angles of the side surfaces of the insulating layer 110b and the insulating layer 110c on the opening 241 side.

The description of the transistor 200F included in the semiconductor device 10F described in <Structure example 12> can be referred to for the transistor 200G included in the semiconductor device 10G except for the aforementioned difference; thus, the detailed description is omitted.

### Structure Example 14

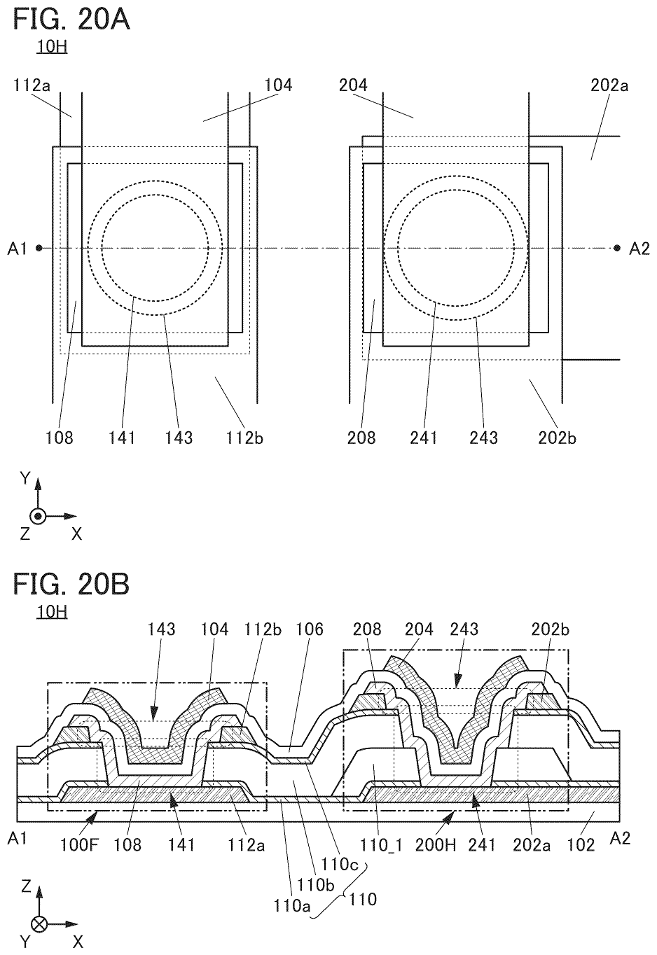

FIG. 20A is a plan view of a semiconductor device 10H. FIG. 20B is a cross-sectional view along dashed-dotted line A1-A2 in FIG. 20A.

The semiconductor device 10H includes the transistor 100F and a transistor 200H. The above description can be referred to for the transistor 100F. The transistor 200H is different from the transistor 200F included in the semiconductor device 10F described in <Structure example 12> in that side surfaces of the insulating layer 110a and the insulating layer 110_1 on the opening 241 side are positioned inward from side surfaces of the insulating layer 110b and the insulating layer 110c on the opening 241 side.

As a result, the area of the formation surface of the semiconductor layer 208 can be larger in the transistor 200H than in the transistor 200F (see FIG. 18B) included in the semiconductor device 10F described in <Structure example 12>. Thus, it can be said that the coverage of the formation surface with the semiconductor layer 208 is higher in the transistor 200H than in the transistor 200F.

The description of the transistor 200F included in the semiconductor device 10F described in <Structure example 12> can be referred to for the transistor 200H included in the semiconductor device 10H except for the aforementioned difference; thus, the detailed description is omitted.

### Structure Example 15

FIG. 21A is a plan view of a semiconductor device 10I. FIG. 21B is a cross-sectional view along dashed-dotted line A1-A2 in FIG. 21A.

The semiconductor device 10I includes a transistor 100I and a transistor 200I. The transistor 100I and the transistor 200I included in the semiconductor device 10I are different from the transistor 100 and the transistor 200 included in the semiconductor device 10 described in <Structure example 1> in the arrangement of source electrodes and drain electrodes and the sizes of the opening 141 and the opening 241.

Specifically, in the transistor 100 included in the semiconductor device 10 described in <Structure example 1>, the conductive layer 112a functioning as one of the source electrode and the drain electrode and the conductive layer 112b functioning as the other of the source electrode and the drain electrode are provided to overlap with each other in a plan view (see FIG. 6A) and are each provided to cover the opening 141. Furthermore, the opening 141 is provided to positioned within the semiconductor layer 108 in a plan view. Similarly, in the transistor 200 included in the semiconductor device 10 described in <Structure example 1>, the conductive layer 202a functioning as one of the source electrode and the drain electrode and the conductive layer 202b functioning as the other of the source electrode and the drain electrode are provided to overlap with each other in a plan view (see FIG. 6A) and are each provided to cover the opening 241. Furthermore, the opening 241 is provided to positioned within the semiconductor layer 208 in a plan view.

By contrast, in the transistor 100I included in the semiconductor device 101, the conductive layer 112a and the conductive layer 112b are provided to be spaced apart from each other in a plan view (see FIG. 21A). The opening 141 is not positioned within the semiconductor layer 108 in a plan view, and the opening 141 is longer in the Y direction than the semiconductor layer 108. Similarly, in the transistor 200I included in the semiconductor device 101, the conductive layer 202a and the conductive layer 202b are provided to be spaced apart from each other in a plan view (see FIG. 21A). The opening 241 is not positioned within the semiconductor layer 208 in a plan view, and the opening 241 is longer in the Y direction than the semiconductor layer 208.

Even though the transistor included in the semiconductor device 10I has the above-described structure, when the thickness of an insulating layer sandwiched between the source electrodes and the drain electrodes is varied in the substrate plane as in the transistors included in each of the semiconductor devices described in <Structure example 1> to <Structure example 14>, transistors having different channel lengths can be formed.

### Structure Example 16

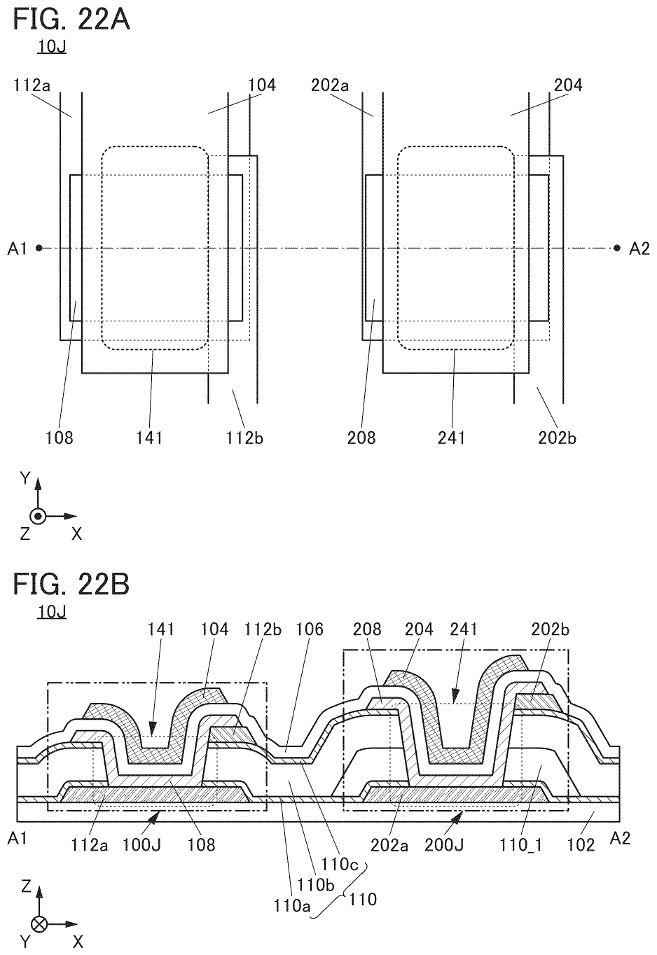

FIG. 22A is a plan view of a semiconductor device 10J. FIG. 22B is a cross-sectional view along dashed-dotted line A1-A2 in FIG. 22A.

The semiconductor device 10J includes a transistor 100J and a transistor 200J. The transistor 100J and the transistor 200J included in the semiconductor device 10J are different from the transistor 100I and the transistor 200I included in the semiconductor device 10I described in <Structure example 15>, respectively, in the size of a conductive layer functioning as one of a source electrode and a drain electrode.

Specifically, in the transistor 100I included in the semiconductor device 101, the conductive layer 112a functioning as one of the source electrode and the drain electrode includes a region overlapping with the opening 141 only on the A1 side in a plan view (see FIG. 21A). Furthermore, the conductive layer 112a and the conductive layer 112b functioning as the other of the source electrode and the drain electrode are provided to be spaced apart from each other in a plan view. Similarly, in the transistor 200I included in the semiconductor device 101, the conductive layer 202a functioning as one of the source electrode and the drain electrode includes a region overlapping with the opening 241 only on the A1 side in a plan view (see FIG. 21A). Furthermore, the conductive layer 202a and the conductive layer 202b functioning as the other of the source electrode and the drain electrode are provided to be spaced apart from each other in a plan view.

By contrast, in the transistor 100J included in the semiconductor device 10J, the conductive layer 112a is provided to include a region overlapping with the conductive layer 112b in a plan view and is longer in the X direction than the conductive layer 112a included in the transistor 100I. Similarly, in the transistor 200J included in the semiconductor device 10J, the conductive layer 202a is provided to include a region overlapping with the conductive layer 202b in a plan view and is longer in the X direction than the conductive layer 202a included in the transistor 200I.

The descriptions of the transistor 100I and the transistor 200I included in the semiconductor device 10I described in <Structure example 15> can be referred to for the transistor 100J and the transistor 200J included in the semiconductor device 10J except for the aforementioned differences; thus, the detailed description is omitted.

### Structure Example 17

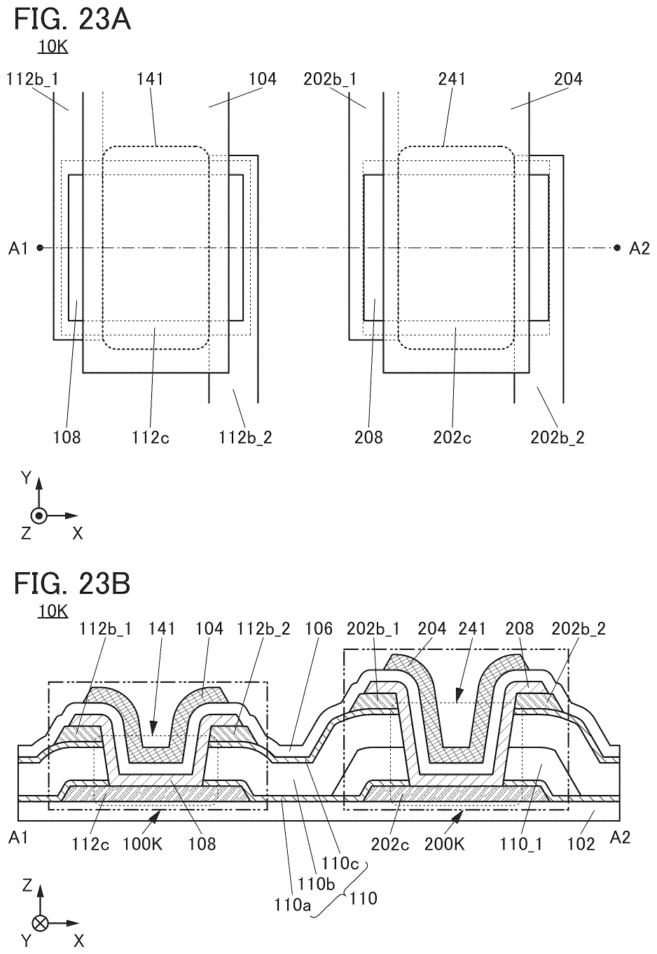

FIG. 23A is a plan view of a semiconductor device 10K. FIG. 23B is a cross-sectional view along dashed-dotted line A1-A2 in FIG. 23A.

The semiconductor device 10K includes a transistor 100K and a transistor 200K. The transistor 100K and the transistor 200K included in the semiconductor device 10K are different from the transistor 100I and the transistor 200I included in the semiconductor device 10I described in <Structure example 15>, respectively, in that a source electrode and a drain electrode are provided to be substantially level with each other over the insulating layer 110. In addition, the transistor 100K and the transistor 200K are different from the transistor 100I and the transistor 200I included in the semiconductor device 10I described in <Structure example 15> in including island-shaped conductive layers below the semiconductor layer 108 and the semiconductor layer 208 (on the substrate 102 side).

Specifically, the transistor 100K included in the semiconductor device 10K includes an island-shaped conductive layer 112c over the substrate 102 and includes a conductive layer 112b_1 and a conductive layer 112b_2 over the insulating layer 110c with the insulating layer 110 (the insulating layer 110a, the insulating layer 110b, and the insulating layer 110c) therebetween. In the transistor 100K, the conductive layer 112b_1 functions as one of the source electrode and the drain electrode. The conductive layer 112b_2 functions as the other of the source electrode and the drain electrode. The conductive layer 112c is an independent conductive layer that is not electrically connected to other conductive layers. Hereinafter, such a conductive layer is also referred to as a floating electrode in this specification.

The transistor 200K included in the semiconductor device 10K includes an island-shaped conductive layer 202c over the substrate 102 in a region different from the conductive layer 112c and includes a conductive layer 202b_1 and a conductive layer 202b_2 over the insulating layer 110c with the insulating layer 110a, the insulating layer 110_1, the insulating layer 110b, and the insulating layer 110c therebetween. In the transistor 200K, the conductive layer 202b_1 functions as one of the source electrode and the drain electrode. The conductive layer 202b_2 functions as the other of the source electrode and the drain electrode. The conductive layer 202c is an independent conductive layer (floating electrode) that is not electrically connected to other conductive layers.

The conductive layer 112b_1 in the transistor 100K included in the semiconductor device 10K corresponds to the conductive layer 112a in the transistor 100I included in the semiconductor device 10I described in <Structure example 15>. The conductive layer 112b_2 in the transistor 100K included in the semiconductor device 10K corresponds to the conductive layer 112b in the transistor 100I included in the semiconductor device 10I described in <Structure example 15>. Similarly, the conductive layer 202b_1 in the transistor 200K included in the semiconductor device 10K corresponds to the conductive layer 202a in the transistor 200I included in the semiconductor device 10I described in <Structure example 15>. Furthermore, the conductive layer 202b_2 in the transistor 200K included in the semiconductor device 10K corresponds to the conductive layer 202b in the transistor 200I included in the semiconductor device 10I described in <Structure example 15>.

The descriptions of the transistor 100I and the transistor 200I included in the semiconductor device 10I described in <Structure example 15> can be referred to for the transistor 100K and the transistor 200K included in the semiconductor device 10K except for the aforementioned differences; thus, the detailed description is omitted.

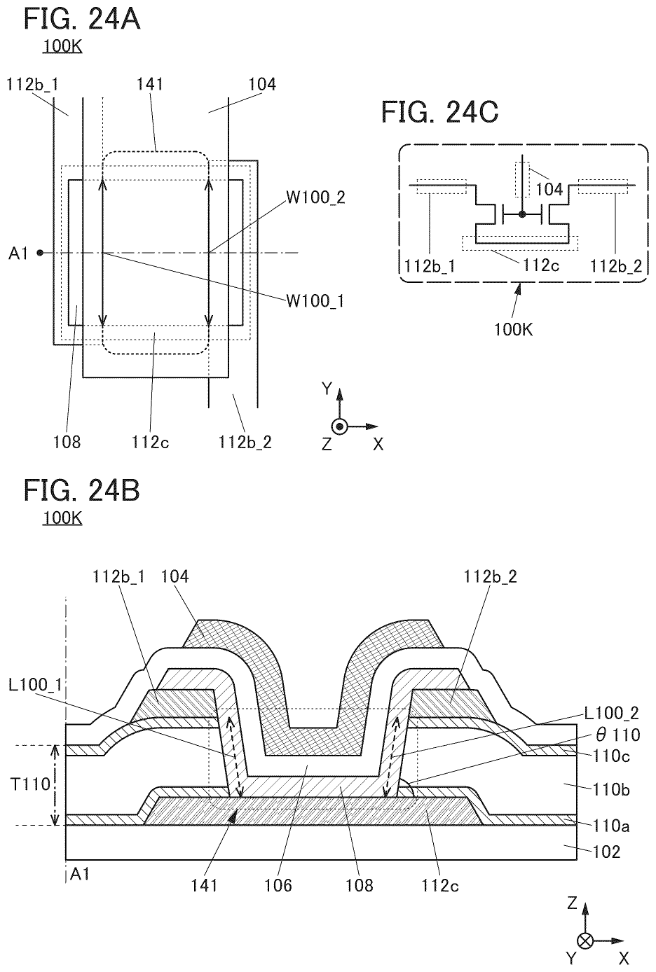

Here, the channel length and the channel width of the transistor 100K are described with reference to FIG. 24A and FIG. 24B. FIG. 24A is a plan view of the transistor 100K. FIG. 24B is an enlarged view of the transistor 100K illustrated in FIG. 23B.

The description that is common to that of the channel length and the channel width of the transistor 100 already described with reference to FIG. 7A and FIG. 7B is omitted below.

The description of the channel length and the channel width of the transistor 100K below can also be applied to the transistor 200K having the same structure as the transistor 100K.

In the semiconductor layer 108, a region in contact with the conductive layer 112b_1 functions as one of a source region and a drain region, and a region in contact with the conductive layer 112b_2 functions as the other of the source region and the drain region. Since the conductive layer 112c functions as a floating electrode as described above, a region between the conductive layer 112b_1 and the conductive layer 112c and a region between the conductive layer 112b_2 and the conductive layer 112c each function as a channel formation region in the semiconductor layer 108.

This means that the transistor 100K includes two channel formation regions between the source electrode and the drain electrode with the floating electrode therebetween. FIG. 24C illustrates a circuit diagram corresponding to the transistor 100K. As illustrated in FIG. 24C, the transistor 100K has a configuration equivalent to two transistors connected in series via the conductive layer 112c. The two transistors share the conductive layer 104 as their gate electrodes.

The channel length of the transistor 100K is a distance between the source region and the floating electrode and a distance between the drain region and the floating electrode. In FIG. 24B, a channel length L100_1 and a channel length L100_2 of the transistor 100K are each indicated by a dashed double-headed arrow. In a cross-sectional view, the channel length L100_1 is a distance between an end portion of the region where the semiconductor layer 108 is in contact with the conductive layer 112b_1 and an end portion of a region where the semiconductor layer 108 is in contact with the conductive layer 112c. In a cross-sectional view, the channel length L100_2 is a distance between an end portion of the region where the semiconductor layer 108 is in contact with the conductive layer 112b_2 and an end portion of the region where the semiconductor layer 108 is in contact with the conductive layer 112c.

The channel width of the transistor 100K is the length of the channel formation region in a direction orthogonal to the channel length direction. In other words, the channel width is the length of the source region or the length of the drain region in the direction orthogonal to the channel length direction. That is, the channel width is the length of the region where the semiconductor layer 108 is in contact with the conductive layer 112b_1 and the length of the region where the semiconductor layer 108 is in contact with the conductive layer 112b_2 in the direction orthogonal to the channel length direction. In FIG. 24A, a channel width W100_1 and a channel width W100_2 of the transistor 100K are each indicated by a solid double-headed arrow. The channel width W100_1 is the channel width of the channel formation region between the conductive layer 112b_1 and the conductive layer 112c, and the channel width W100_2 is the channel width of the channel formation region between the conductive layer 112b_2 and the conductive layer 112c. The channel width W100_1 corresponds to, in a plan view, the length of a region where the conductive layer 112b_1 and the semiconductor layer 108 overlap with each other in the Y direction, and the channel width W100_2 corresponds to, in a plan view, the length of a region where the conductive layer 112b_2 and the semiconductor layer 108 overlap with each other in the Y direction.

### Structure Example 18

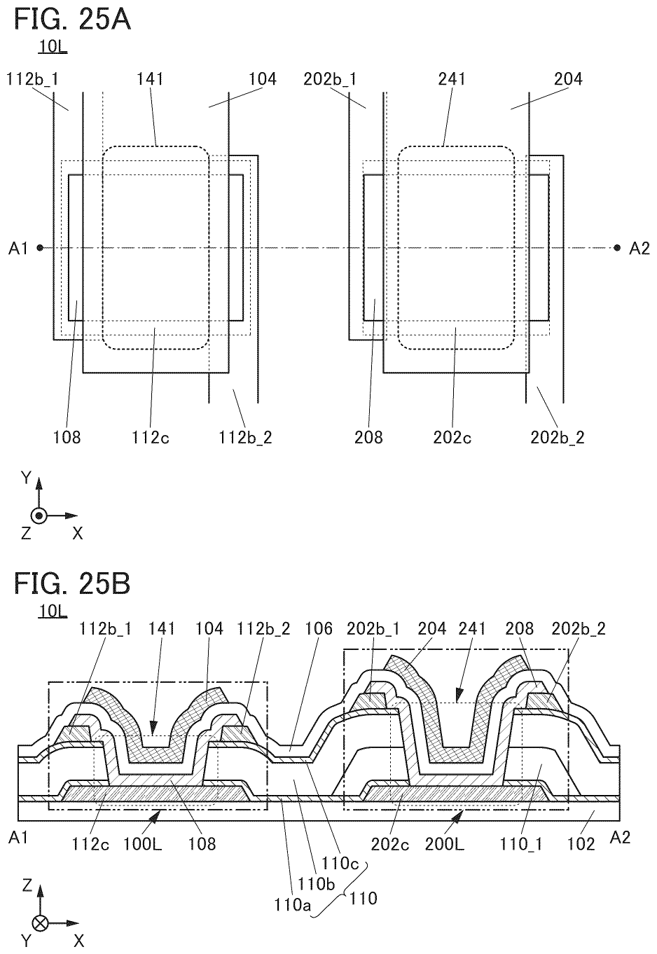

FIG. 25A is a plan view of a semiconductor device 10L. FIG. 25B is a cross-sectional view along dashed-dotted line A1-A2 in FIG. 25A.

The semiconductor device 10L includes a transistor 100L and a transistor 200L. The transistor 100L is different from the transistor 100K included in the semiconductor device 10K described in <Structure example 17> in that an end portion of the conductive layer 112b_1 functioning as one of a source electrode and a drain electrode on the opening 141 side and an end portion of the conductive layer 112b_2 functioning as the other of the source electrode and the drain electrode on the opening 141 side are each positioned outward from an end portion of the insulating layer 110c on the opening 141 side. The transistor 200L is different from the transistor 200K included in the semiconductor device 10K described in <Structure example 17> in that an end portion of the conductive layer 202b_1 functioning as one of a source electrode and a drain electrode on the opening 241 side and an end portion of the conductive layer 202b_2 functioning as the other of the source electrode and the drain electrode on the opening 241 side are each positioned outward from an end portion of the insulating layer 110c on the opening 241 side.

Since the semiconductor device 10L has the above-described structure, in a plan view of the transistor 100L (see FIG. 25A), an end portion of the top surface of the insulating layer 110 on the opening 141 side is not aligned with an end portion of the bottom surface of the conductive layer 112b_1 on the opening 141 side, and an end portion of the top surface of the insulating layer 110 on the opening 141 side is not aligned with an end portion of the bottom surface of the conductive layer 112b_2 on the opening 141 side. Similarly, in a plan view of the transistor 200L (see FIG. 25A), an end portion of the top surface of the insulating layer 110 and the insulating layer 110_1 on the opening 241 side is not aligned with an end portion of the bottom surface of the conductive layer 202b_1 on the opening 241 side, and an end portion of the top surface of the insulating layer 110 and the insulating layer 110_1 on the opening 241 side is not aligned with an end portion of the bottom surface of the conductive layer 202b_2 on the opening 241 side. In a cross-sectional view of the transistor 100L (see FIG. 25B), a step is produced between the end portion of the top surface of the insulating layer 110 on the opening 141 side and the end portion of the bottom surface of the conductive layer 112b_1 on the opening 141 side. In addition, a step is produced between the end portion of the top surface of the insulating layer 110 on the opening 141 side and the end portion of the bottom surface of the conductive layer 112b_2 on the opening 141 side. Similarly, a step is produced between the end portion of the top surface of the insulating layer 110 and the insulating layer 110_1 on the opening 241 side and the end portion of the bottom surface of the conductive layer 202b_1 on the opening 241 side in the transistor 200L. In addition, a step is produced between the end portion of the top surface of the insulating layer 110 and the insulating layer 110_1 on the opening 241 side and the end portion of the bottom surface of the conductive layer 202b_2 on the opening 241 side.

As a result, the area of the formation surface of the semiconductor layer 108 can be larger in the transistor 100L than in the transistor 100K (see FIG. 23B) having a structure not including the above step. Similarly, the area of the formation surface of the semiconductor layer 208 can be larger in the transistor 200L than in the transistor 200K (see FIG. 23B) having a structure not including the above step. Thus, it can be said that the coverage of the formation surface with the semiconductor layer is higher in the transistor included in the semiconductor device 10L than in the transistor included in the semiconductor device 10K described in <Structure example 17>.

Although FIG. 25B illustrates a structure including, in both the transistor 100L and the transistor 200L included in the semiconductor device 10L, steps between the end portions of the top surface of the insulating layer 110 and the end portions of the bottom surfaces of the conductive layers functioning as the source electrode and the drain electrode, one embodiment of the present invention is not limited thereto. The semiconductor device of one embodiment of the present invention may have a structure in which only some of the transistors included in the semiconductor device include steps between the end portions of the top surface of the insulating layer 110 and the end portions of the bottom surfaces of the conductive layers functioning as the source electrode and the drain electrode.

The descriptions of the transistor 100K and the transistor 200K included in the semiconductor device 10 described in <Structure example 17> can be referred to for the transistor 100L and the transistor 200L included in the semiconductor device 10L except for the aforementioned differences; thus, the detailed description is omitted.

### Structure Example 19

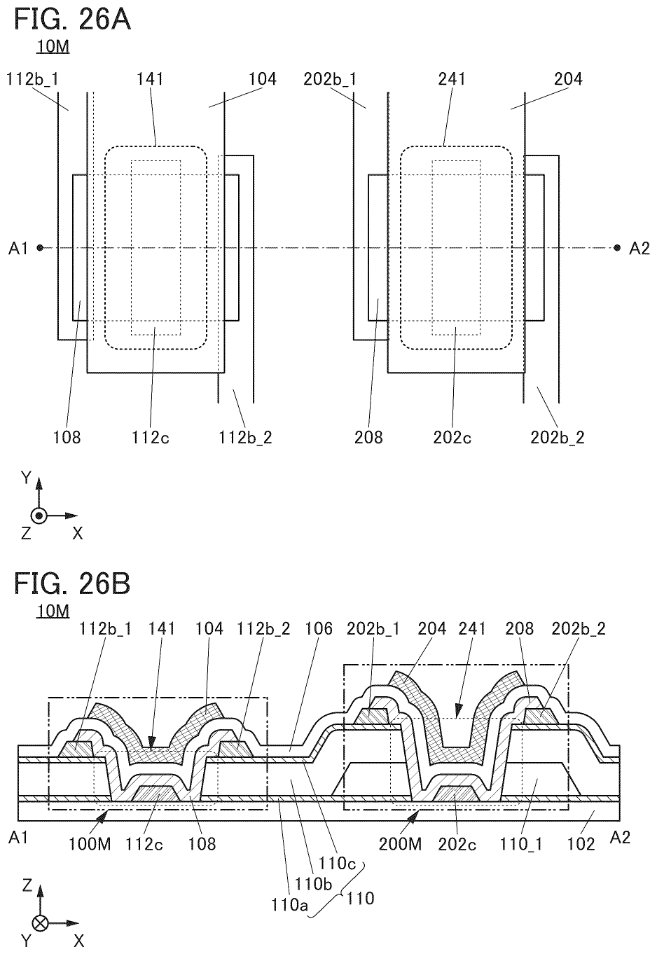

FIG. 26A is a plan view of a semiconductor device 10M. FIG. 26B is a cross-sectional view along dashed-dotted line A1-A2 in FIG. 26A.

The semiconductor device 10M includes a transistor 100M and a transistor 200M. The transistor 100M is different from the transistor 100L included in the semiconductor device 10L described in <Structure example 18> in that the conductive layer 112c functioning as a floating electrode is provided to be spaced apart from each of the conductive layer 112b_1 and the conductive layer 112b_2 functioning as a source electrode and a drain electrode in a plan view (see FIG. 26A). The transistor 200M is different from the transistor 200L included in the semiconductor device 10L described in <Structure example 18> in that the conductive layer 202c functioning as a floating electrode is provided to be spaced apart from each of the conductive layer 202b_1 and the conductive layer 202b_2 functioning as a source electrode and a drain electrode in a plan view.

When the size of the floating electrode in the transistor included in the semiconductor device 10M in the substrate surface is reduced as described above, the area occupied by the transistor in the substrate plane can be reduced. Furthermore, the semiconductor device including the transistor can be miniaturized.

The descriptions of the transistor 100L and the transistor 200L included in the semiconductor device 10L described in <Structure example 18> can be referred to for the transistor 100M and the transistor 200M included in the semiconductor device 10M except for the aforementioned differences; thus, the detailed description is omitted.

### Structure Example 20

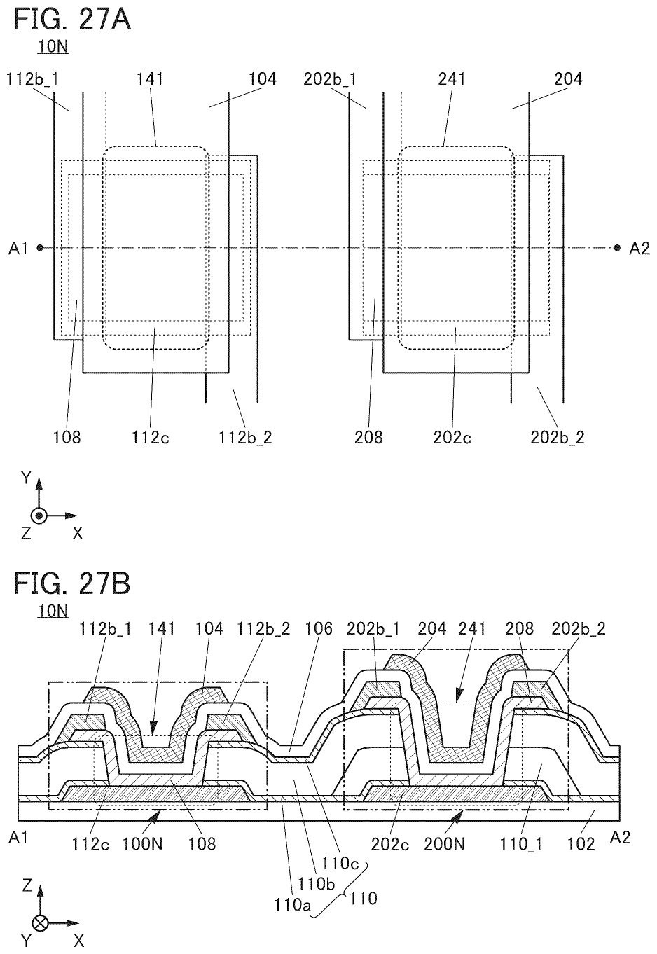

FIG. 27A is a plan view of a semiconductor device 10N. FIG. 27B is a cross-sectional view along dashed-dotted line A1-A2 in FIG. 27A.

The semiconductor device 10N includes a transistor 100N and a transistor 200N. The transistor 100N is different from the transistor 100K included in the semiconductor device 10K described in <Structure example 17> in that the conductive layer 112b_1 and the conductive layer 112b_2 functioning as a source electrode and a drain electrode are in contact with the top surface of the semiconductor layer 108. The transistor 200N is different from the transistor 200K included in the semiconductor device 10K described in <Structure example 17> in that the conductive layer 202b_1 and the conductive layer 202b_2 functioning as a source electrode and a drain electrode are in contact with the top surface of the semiconductor layer 208.

As described above, the semiconductor device of one embodiment of the present invention may have a structure in which the conductive layer functioning as the source electrode or the drain electrode is in contact with the bottom surface of the semiconductor layer (the surface on the insulating layer 110 side) or may have a structure in which the conductive layer is in contact with the top surface of the semiconductor layer, depending on the ease of manufacturing, an object in which the semiconductor device is used, or the like.

Although FIG. 27B illustrates a structure in which the conductive layer functioning as the source electrode or the drain electrode is in contact with the top surface of the semiconductor layer in both the transistor 100N and the transistor 200N included in the semiconductor device 10N, one embodiment of the present invention is not limited thereto. The semiconductor device of one embodiment of the present invention may have a structure in which the conductive layer functioning as the source electrode or the drain electrode is in contact with the bottom surface of the semiconductor layer (the surface on the insulating layer 110 side) in only some of the transistors included in the semiconductor device and the conductive layer functioning as the source electrode or the drain electrode is in contact with the top surface of the semiconductor layer in the other transistors.

The descriptions of the transistor 100K and the transistor 200K included in the semiconductor device 10K described in <Structure example 17> can be referred to for the transistor 100N and the transistor 200N included in the semiconductor device 10N except for the aforementioned differences; thus, the detailed description is omitted.

### Structure Example 21

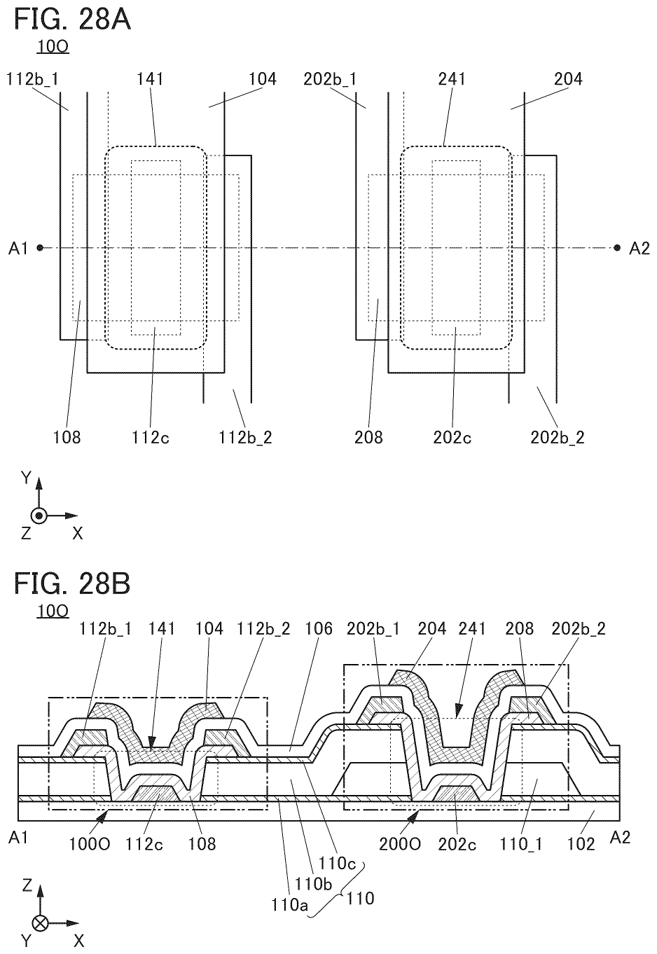

FIG. 28A is a plan view of a semiconductor device 100. FIG. 28B is a cross-sectional view along dashed-dotted line A1-A2 in FIG. 28A.

The semiconductor device 100 includes a transistor 1000 and a transistor 2000. The transistor 1000 is different from the transistor 100N included in the semiconductor device 10N described in <Structure example 20> in that the conductive layer 112c functioning as a floating electrode is provided to be spaced apart from each of the conductive layer 112b_1 and the conductive layer 112b_2 functioning as a source electrode and a drain electrode in a plan view (see FIG. 28A). The transistor 2000 is different from the transistor 200N included in the semiconductor device 10N described in <Structure example 20> in that the conductive layer 202c functioning as a floating electrode is provided to be spaced apart from each of the conductive layer 202b_1 and the conductive layer 202b_2 functioning as a source electrode and a drain electrode in a plan view.

When the size of the floating electrode in the transistor included in the semiconductor device 100 in the substrate surface is reduced as described above, the area occupied by the transistor in the substrate plane can be reduced. Furthermore, the semiconductor device including the transistor can be miniaturized.

The descriptions of the transistor 100N and the transistor 200N included in the semiconductor device 10N described in <Structure example 20> can be referred to for the transistor 1000 and the transistor 2000 included in the semiconductor device 100 except for the aforementioned differences; thus, the detailed description is omitted.

### Structure Example 22

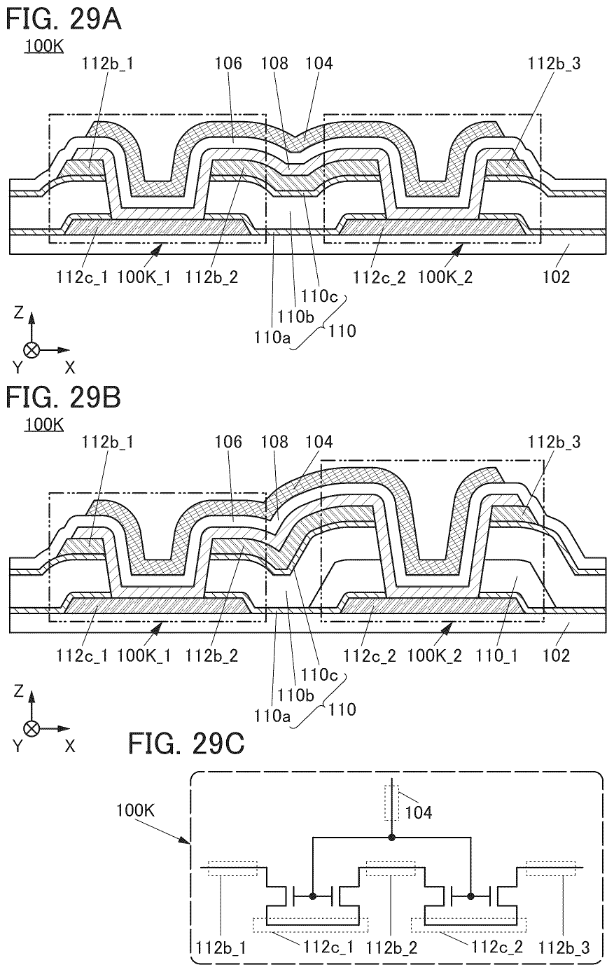

FIG. 29A and FIG. 29B are cross-sectional views of variation examples of the transistor 100K included in the semiconductor device 10K described in <Structure example 17> (see FIG. 23B). FIG. 29C is a circuit diagram corresponding to the transistor 100K illustrated in FIG. 29A and FIG. 29B.

The following description can also be applied to the transistor 200K included in the semiconductor device 10K described in <Structure example 17> (see FIG. 23B).

The transistor 100K illustrated in FIG. 29A consists of two transistors, a transistor 100K_1 and a transistor 100K_2.

The transistor 100K_1 includes a conductive layer 112c_1 provided in an island shape over the substrate 102; the conductive layer 112b_1 and the conductive layer 112b_2 provided over the conductive layer 112c_1 with the insulating layer 110 (the insulating layer 110a, the insulating layer 110b, and the insulating layer 110c) therebetween; the semiconductor layer 108 including a region in contact with the top surface of the conductive layer 112c_1, the top surface of the conductive layer 112b_1, and the top surface of the conductive layer 112b_2; the insulating layer 106 over the semiconductor layer 108; and the conductive layer 104 over the insulating layer 106.

In the transistor 100K_1, the conductive layer 112c_1 functions as a floating electrode. The conductive layer 112b_1 functions as one of a source electrode and a drain electrode. The conductive layer 112b_2 functions as the other of the source electrode and the drain electrode. In the semiconductor layer 108, each of a region between the conductive layer 112b_1 and the conductive layer 112c_1 and a region between the conductive layer 112b_2 and the conductive layer 112c_1 functions as a channel formation region. The insulating layer 106 functions as a gate insulating layer. The conductive layer 104 functions as a gate electrode.

The transistor 100K_2 includes a conductive layer 112c_2 provided in an island shape over the substrate 102; the conductive layer 112b_2 and a conductive layer 112b_3 provided over the conductive layer 112c_2 with the insulating layer 110 (the insulating layer 110a, the insulating layer 110b, and the insulating layer 110c) therebetween; the semiconductor layer 108 including a region in contact with the top surface of the conductive layer 112c_2, the top surface of the conductive layer 112b_2, and the top surface of the conductive layer 112b_3; the insulating layer 106 over the semiconductor layer 108; and the conductive layer 104 over the insulating layer 106.

In the transistor 100K_2, the conductive layer 112c_2 functions as a floating electrode. The conductive layer 112b_2 functions as one of a source electrode and a drain electrode. The conductive layer 112b_3 functions as the other of the source electrode and the drain electrode. In the semiconductor layer 108, each of a region between the conductive layer 112b_2 and the conductive layer 112c_2 and a region between the conductive layer 112b_3 and the conductive layer 112c_2 functions as a channel formation region. The insulating layer 106 functions as a gate insulating layer. The conductive layer 104 functions as a gate electrode.

Since the transistor 100K has the above-described structure, the semiconductor layer, the gate insulating layer, and the gate electrode do not need to be formed separately for the transistors; thus, the number of steps can be reduced.

FIG. 29B is a cross-sectional view of a variation example of the transistor 100K different from that in FIG. 29A.

The transistor 100K illustrated in FIG. 29B is different from the transistor 100K illustrated in FIG. 29A in that the transistor 100K_2 included in the transistor 100K includes, as an insulating layer sandwiched between the conductive layer 112c_2 and each of the conductive layer 112b_2 and the conductive layer 112b_3, the insulating layer 110_1 in addition to the insulating layer 110 (the insulating layer 110a, the insulating layer 110b, and the insulating layer 110c).

The transistor 100K illustrated in FIG. 29B has a structure in which, in the transistor 100K_1 and the transistor 100K_2 that compose the transistor 100K, the channel length of the transistor 100K_2 is thicker than the channel length of the transistor 100K_1 by the thickness of the insulating layer 110_1. The transistor 100K of one embodiment of the present invention may have a structure in which a plurality of transistors that compose the transistor 100K have different channel lengths as described above.

The transistor 100K illustrated in each of FIG. 29A and FIG. 29B has a configuration equivalent to four transistors connected in series via the conductive layer 112c_1, the conductive layer 112b_2, and the conductive layer 112c_2 as illustrated in the circuit diagram in FIG. 29C. The four transistors share the semiconductor layer 108 including a channel formation region, the insulating layer 106 functioning as a gate insulating layer, and the conductive layer 104 functioning as a gate electrode.

### Structure Example 23

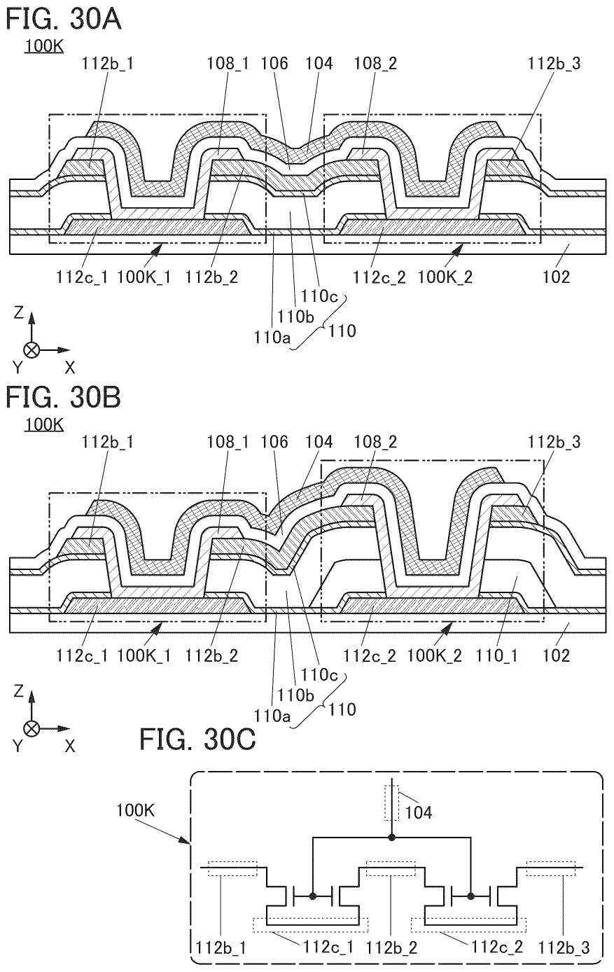

FIG. 30A and FIG. 30B are cross-sectional views of variation examples of the transistor 100K described in <Structure example 22>. FIG. 30C is a circuit diagram corresponding to the transistor 100K illustrated in FIG. 30A and FIG. 30B.

The transistor 100K illustrated in FIG. 30A is different from the transistor 100K illustrated in FIG. 29A in that the transistor 100K_1 and the transistor 100K_2 that compose the transistor 100K include different semiconductor layers.

Specifically, the transistor 100K_1 includes a semiconductor layer 108_1 as a semiconductor layer where a channel is formed, and the transistor 100K 2 includes a semiconductor layer 108_2 as a semiconductor layer where a channel is formed.

When the transistor 100K_1 and the transistor 100K_2 have the above structures, part of the conductive layer 112b_2 (specifically, a region not overlapping with the semiconductor layer 108_1 nor the semiconductor layer 108_2) can function as a floating electrode.

The description of the transistor 100K illustrated in FIG. 29A can be referred to for the transistor 100K illustrated in FIG. 30A except for the aforementioned difference.

FIG. 30B illustrates an example in which the transistor 100K_1 and the transistor 100K_2 that compose the transistor 100K illustrated in FIG. 30A have different channel lengths. The description of the transistor 100K illustrated in FIG. 29B can be referred to for specific details.

### Structure Example 24

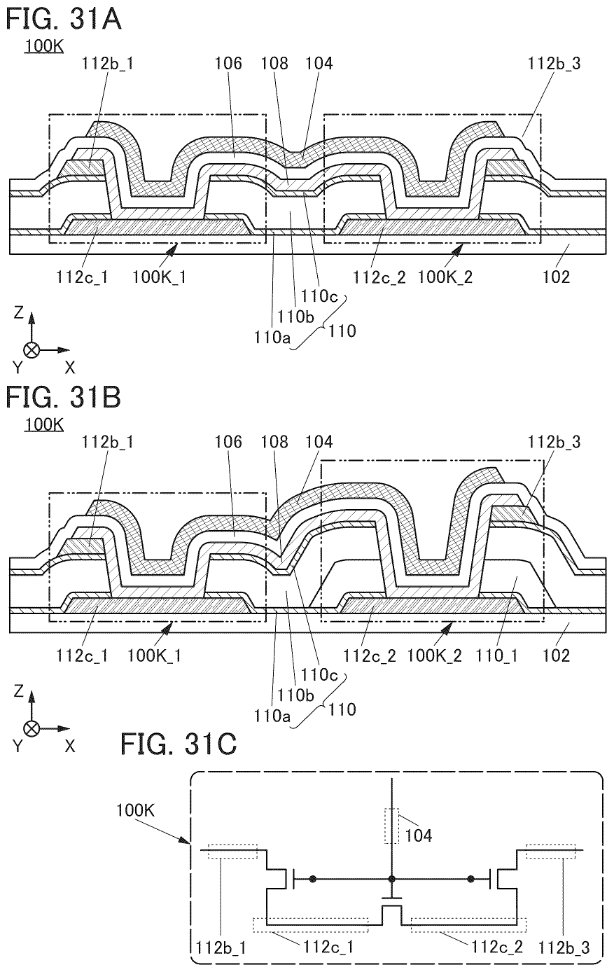

FIG. 31A and FIG. 31B are cross-sectional views of variation examples of the transistor 100K described in <Structure example 22> and <Structure example 23>. FIG. 31C is a circuit diagram corresponding to the transistor 100K illustrated in FIG. 31A and FIG. 31B.

The transistor 100K illustrated in FIG. 31A is different from the transistor 100K illustrated in FIG. 29A in that the transistor 100K_1 and the transistor 100K_2 that compose the transistor 100K do not include the conductive layer 112b_2.

When the transistor 100K has the above structure, in the semiconductor layer 108, a region between the conductive layer 112b_1 and the conductive layer 112c_1, a region between the conductive layer 112c_1 and the conductive layer 112c_2, and a region between the conductive layer 112b_3 and the conductive layer 112c_2 can each function as a channel formation region. That is, the transistor 100K illustrated in FIG. 31A has a configuration equivalent to three transistors connected in series via the conductive layer 112c_1 and the conductive layer 112c_2 as illustrated in the circuit diagram in FIG. 31C. The three transistors share the semiconductor layer 108 including a channel formation region, the insulating layer 106 functioning as a gate insulating layer, and the conductive layer 104 functioning as a gate electrode.

The description of the transistor 100K illustrated in FIG. 29A can be referred to for the transistor 100K illustrated in FIG. 31A except for the aforementioned difference.

FIG. 31B illustrates an example in which the transistor 100K_1 and the transistor 100K_2 that compose the transistor 100K illustrated in FIG. 31A have different channel lengths. The description of the transistor 100K illustrated in FIG. 29B can be referred to for specific details.

### Structure Example 25

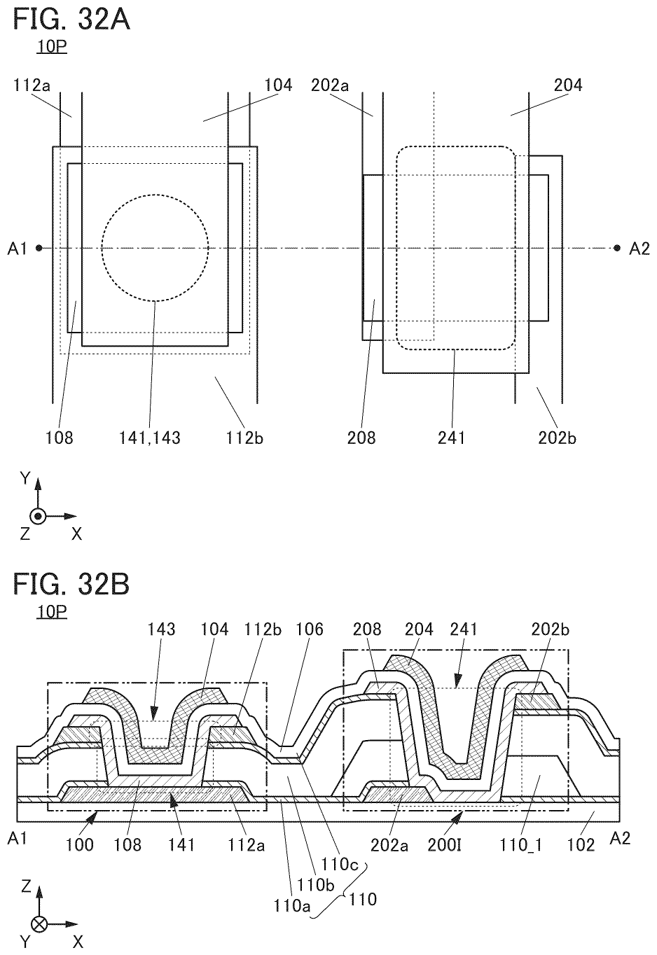

FIG. 32A is a plan view of a semiconductor device 10P. FIG. 32B is a cross-sectional view along dashed-dotted line A1-A2 in FIG. 32A.

The semiconductor device 10P includes the transistor 100 (see FIG. 6A and FIG. 6B) included in the semiconductor device 10 described in <Structure example 1> and the transistor 200I (see FIG. 21A and FIG. 21B) included in the semiconductor device 10I described in <Structure example 15>.

The description of the transistor 100 included in the semiconductor device 10 described in <Structure example 1> and the description of the transistor 200I included in the semiconductor device 10I described in <Structure example 15> can be referred to for the transistor 100 and the transistor 200I included in the semiconductor device 10P, respectively; thus, the detailed descriptions are omitted.

Like the semiconductor device 10P, the semiconductor device of one embodiment of the present invention can include two transistors having different arrangement of a source electrode and a drain electrode and different shapes of an opening formed in the insulating layer 110 or the like. Accordingly, a semiconductor device that has both the above-described advantages of the transistor 100 and the above-described advantages of the transistor 200I can be achieved.

### Structure Example 26

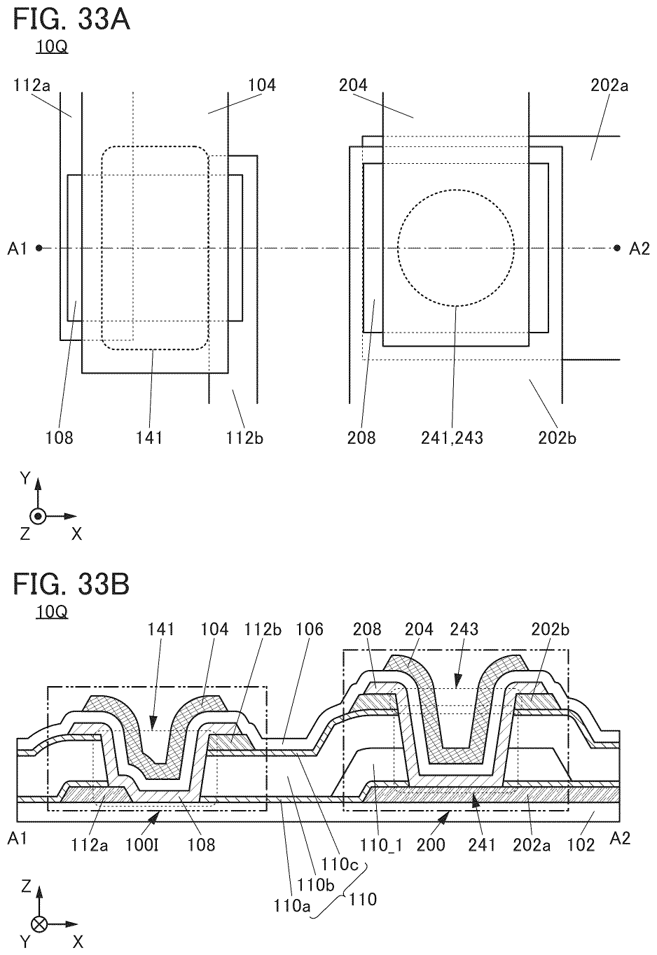

FIG. 33A is a plan view of a semiconductor device 10Q. FIG. 33B is a cross-sectional view along dashed-dotted line A1-A2 in FIG. 33A.

The semiconductor device 10Q includes the transistor 100I (see FIG. 21A and FIG. 21B) included in the semiconductor device 10I described in <Structure example 15> and the transistor 200 (see FIG. 6A and FIG. 6B) included in the semiconductor device 10 described in <Structure example 1>.

The description of the transistor 100I included in the semiconductor device 10I described in <Structure example 15> and the description of the transistor 200 included in the semiconductor device 10 described in <Structure example 1> can be referred to for the transistor 100I and the transistor 200 included in the semiconductor device 10Q; thus, the detailed descriptions are omitted.

Like the semiconductor device 10Q, the semiconductor device of one embodiment of the present invention can include two transistors having different arrangement of a source electrode and a drain electrode and different shapes of an opening formed in the insulating layer 110 or the like. Accordingly, a semiconductor device that has both the above-described advantages of the transistor 100I and the above-described advantages of the transistor 200 can be achieved.

### Structure Example 27

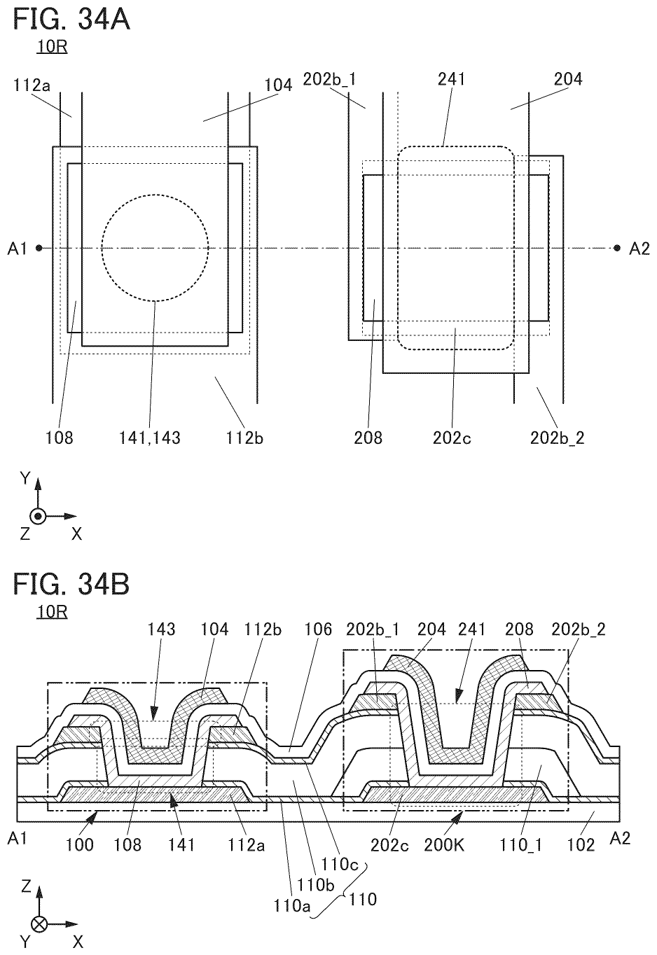

FIG. 34A is a plan view of a semiconductor device 10R. FIG. 34B is a cross-sectional view along dashed-dotted line A1-A2 in FIG. 34A.

The semiconductor device 10R includes the transistor 100 (see FIG. 6A and FIG. 6B) included in the semiconductor device 10 described in <Structure example 1> and the transistor 200K (see FIG. 23A and FIG. 23B) included in the semiconductor device 10K described in <Structure example 17>.

The description of the transistor 100 included in the semiconductor device 10 described in <Structure example 1> and the description of the transistor 200K included in the semiconductor device 10K described in <Structure example 17> can be referred to for the transistor 100 and the transistor 200K included in the semiconductor device 10R, respectively; thus, the detailed descriptions are omitted.

Like the semiconductor device 10R, the semiconductor device of one embodiment of the present invention can include two transistors having different arrangement of a source electrode and a drain electrode and different shapes of an opening formed in the insulating layer 110 or the like. Accordingly, a semiconductor device that has both the above-described advantages of the transistor 100 and the above-described advantages of the transistor 200K can be achieved.

### Structure Example Including a Plurality of Transistors

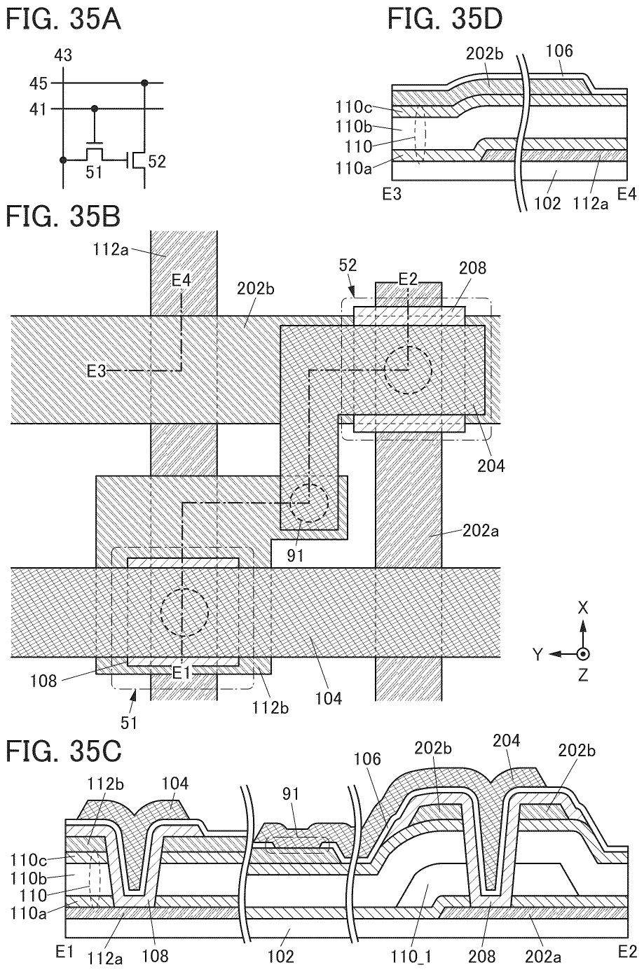

FIG. 35A is a circuit diagram selectively illustrating some of the components illustrated in FIG. 2C and the like. The circuit diagram in FIG. 35A illustrates the transistor 51, the transistor 52, the wiring 41, the wiring 43, and the wiring 45.

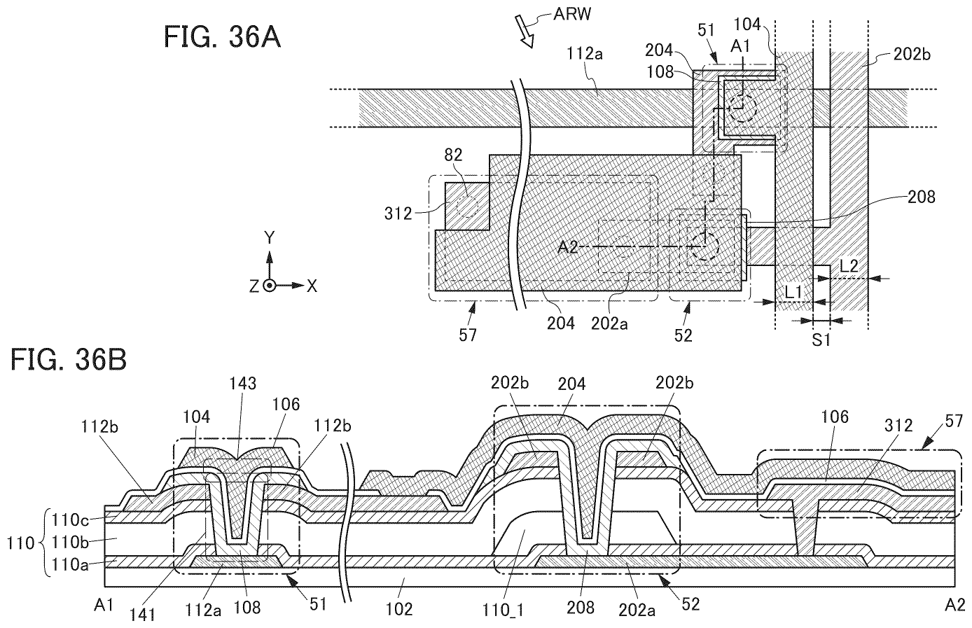

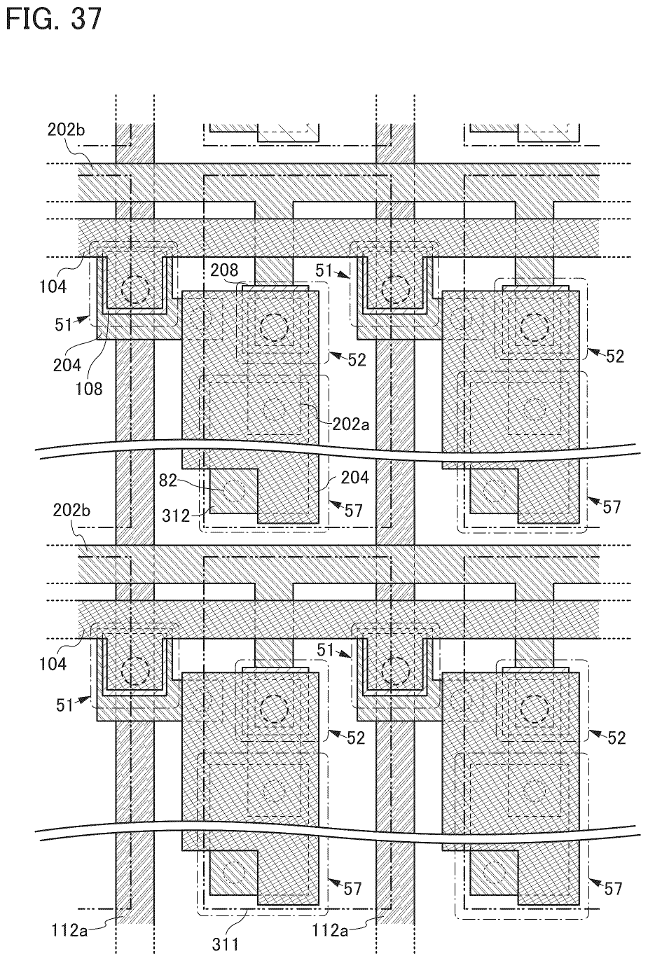

In the case where the semiconductor device 10 (see FIG. 6A and FIG. 6B) described in <Structure example 1> is taken as an example, the transistor 51 in FIG. 35A corresponds to the transistor 100. The transistor 52 in FIG. 35A corresponds to the transistor 200. The conductive layer 104 included in the transistor 100 functions as the wiring 41 in FIG. 35A. The conductive layer 112a included in the transistor 100 functions as the wiring 43 in FIG. 35A. The conductive layer 202b included in the transistor 200 functions as the wiring 45 in FIG. 35A. Thus, in plan views illustrated in FIG. 35B, FIG. 36A, and FIG. 37, a wiring corresponding to the wiring 41 is illustrated as the conductive layer 104, a wiring corresponding to the wiring 43 is illustrated as the conductive layer 112a, and a wiring corresponding to the wiring 45 is illustrated as the conductive layer 202b for easy understanding.

FIG. 35B illustrates a structure example applicable to the circuit diagram in FIG. 35A. The conductive layer 104 and the conductive layer 202b are wirings extending in the Y direction. The conductive layer 112a is a wiring extending in the X direction which intersects with the conductive layer 104 and the conductive layer 202b. FIG. 35C is a cross-sectional view along dashed-dotted line E1-E2 in FIG. 35B. FIG. 35D is a cross-sectional view along dashed-dotted line E3-E4 in FIG. 35B.

The conductive layer 112a and the conductive layer 202b are wirings at different levels and the conductive layer 202b is positioned above the conductive layer 112a. The insulating layer 110 (the insulating layer 110a, the insulating layer 110b, and the insulating layer 110c) is provided between the conductive layer 112a and the conductive layer 202b.

The conductive layer 202b and the conductive layer 104 are wirings at different levels and the conductive layer 104 is positioned above the conductive layer 202b. The conductive layer 104 includes, for example, a region positioned at a higher level than the conductive layer 202b by the thickness of the insulating layer 106. The conductive layer 104 and the conductive layer 202b are arranged parallel or substantially parallel to each other in a plan view.

The conductive layer 112a can function as one of the source electrode and the drain electrode of the transistor 51. The semiconductor layer 108 of the transistor 51 includes a region overlapping with the conductive layer 112a. The semiconductor layer 108 is provided to be in contact with the top surface of the conductive layer 112a.

The conductive layer 104 can function as the gate electrode of the transistor 51.

The insulating layer 106 is provided between the semiconductor layer 108 and the conductive layer 104. The insulating layer 106 has a function of the gate insulating layer of the transistor 51.

The conductive layer 202b can function as one of the source electrode and the drain electrode of the transistor 52. The semiconductor layer 208 of the transistor 52 is provided to be in contact with the top surface of the conductive layer 202a functioning as the other of the source electrode and the drain electrode of the transistor 52. The conductive layer 204 functions as the gate electrode of the transistor 52.

An opening 91 is provided in the insulating layer 106. In a region overlapping with the opening 91, the conductive layer 204 is preferably in contact with the top surface of the conductive layer 112b.

As described above, the descriptions of the transistor 100 and the transistor 200 illustrated in FIG. 6A and FIG. 6B are applicable to the transistor 51 and the transistor 52 in the structure example illustrated in FIG. 35B and FIG. 35C. For the components of the transistor 51 and the transistor 52, for example, the description of the corresponding components of the transistor 100 and the transistor 200 can be referred to.

As illustrated in FIG. 35D, in a region where the conductive layer 112a intersects with the conductive layer 202b, the insulating layer 110 is provided over the conductive layer 112a and the conductive layer 202b is provided over the insulating layer 110.

### Structure Example Including Pixel Circuit

FIG. 36A is a plan view illustrating a structure example including the pixel circuit 40A, the wiring 41, the wiring 43, and the wiring 45 illustrated in FIG. 2C. FIG. 36B is a cross-sectional view along dashed line A1-A2 in FIG. 36A. As described above, in the case where the semiconductor device 10 (see FIG. 6A and FIG. 6B) described in <Structure example 1> is taken as an example, the wiring 41 in the pixel circuit 40A corresponds to the conductive layer 104, the wiring 43 in the pixel circuit 40A corresponds to the conductive layer 112a, and the wiring 45 in the pixel circuit 40A corresponds to the conductive layer 202b.

In FIG. 36A and the following plan views and the like, some components, such as a conductive layer electrically connected to the light-emitting element 60, are not illustrated. Moreover, in FIG. 36A and the following plan views and the like, some components of a display apparatus, such as a substrate and an insulating layer, are not illustrated.

In a plan view, the shapes of a conductive layer, a semiconductor layer, and the like may be simplified. For easy viewing of the drawings, the position of each component differs between a plan view, a perspective view, and a cross-sectional view in some cases. Thus, the size, position, and shape of each component differ between a plan view and a cross-sectional view in some cases. Furthermore, the size, position, and shape of each component differ between a perspective view and a cross-sectional view in some cases.

The conductive layer 104 and the conductive layer 202b are wirings extending in the Y direction. The conductive layer 112a is a wiring extending in the X direction which intersects with the conductive layer 104 and the conductive layer 202b.

The conductive layer 112a and the conductive layer 202b are wirings at different levels and the conductive layer 202b is positioned above the conductive layer 112a. The insulating layer 110 (the insulating layer 110a, the insulating layer 110b, and the insulating layer 110c) is provided between the conductive layer 112a and the conductive layer 202b.

The conductive layer 202b and the conductive layer 104 are wirings at different levels and the conductive layer 104 is positioned above the conductive layer 202b. The conductive layer 104 includes, for example, a region positioned at a higher level than the conductive layer 202b by the thickness of the insulating layer 106. The conductive layer 104 and the conductive layer 202b are arranged parallel or substantially parallel to each other. A space S1 between the conductive layer 104 and the conductive layer 202b is smaller than a wiring width L1 of the conductive layer 104 and a wiring width L2 of the conductive layer 202b. Since the levels of the conductive layer 104 and the conductive layer 202b are different, the conductive layer 104 and the conductive layer 202b can be arranged with a small space S1.

The conductive layer 112a can function as one of the source electrode and the drain electrode of the transistor 51. The semiconductor layer 108 of the transistor 51 includes a region overlapping with the conductive layer 112a. The insulating layer 110 has the opening 141 reaching the conductive layer 112a. The conductive layer 112b has the opening 143 at a position overlapping with the opening 141. The semiconductor layer 108 is provided to cover the opening 141 and the opening 143 and include a region positioned in the opening 141 and the opening 143. The semiconductor layer 108 is provided to be in contact with the top surface of the conductive layer 112a. The semiconductor layer 108 includes a region positioned in the opening 143 in the conductive layer 112b functioning as the other of the source electrode and the drain electrode of the transistor 51 and a region provided to be in contact with the top surface of the conductive layer 112b.

The conductive layer 104 can function as the gate electrode of the transistor 51. The wiring width of the conductive layer 104 is large in a region overlapping with the semiconductor layer 108 of the transistor 51. In another possible expression, the conductive layer 104 has a branch in the region overlapping with the semiconductor layer 108 of the transistor 51.

The insulating layer 106 is provided between the semiconductor layer 108 and the conductive layer 104. The insulating layer 106 has a function of the gate insulating layer of the transistor 51.

The conductive layer 202b can function as one of the source electrode and the drain electrode of the transistor 52. The semiconductor layer 208 of the transistor 52 is provided to be in contact with the top surface of the conductive layer 202a functioning as the other of the source electrode and the drain electrode of the transistor 52. The conductive layer 204 functions as the gate electrode of the transistor 52 and one electrode of the capacitor 57.

A conductive layer 312 functions as the other electrode of the capacitor 57.

The conductive layer 104 and the conductive layer 204 preferably include regions level with each other. The conductive layer 104 and the conductive layer 204 include the same material, for example. In the case where the conductive layer 104 has a stacked-layer structure, the conductive layer 204 has a similar stacked-layer structure, for example. The conductive layer 104 and the conductive layer 204 can be formed by processing the same conductive film, for example. Here, the levels of the wiring, the conductive layer, the semiconductor layer, the insulating layer, and the like included in the display apparatus can each be a distance from a reference surface, for example. As the reference surface, for example, a surface of a substrate, a flat region of a film provided over the substrate, or the like can be used.

The conductive layer 112a and the conductive layer 202a preferably include regions level with each other. The conductive layer 112a and the conductive layer 202a include the same material, for example. In the case where the conductive layer 112a has a stacked-layer structure, the conductive layer 202a has a similar stacked-layer structure, for example. The conductive layer 112a and the conductive layer 202a can be formed by processing the same conductive film, for example.

The conductive layer 202b, the conductive layer 112b, and the conductive layer 312 preferably include regions level with each other. The conductive layer 202b, the conductive layer 112b, and the conductive layer 312 include the same material, for example. In the case where the conductive layer 202b has a stacked-layer structure, the conductive layer 112b and the conductive layer 312 each have a similar stacked-layer structures, for example. The conductive layer 202b, the conductive layer 112b, and the conductive layer 312 can be formed by processing the same conductive film, for example.

The conductive layer 312 includes a region provided to fill an opening in the insulating layer 110. In the region, the conductive layer 312 is preferably in contact with the conductive layer 202a. Alternatively, a plug may be provided in the opening in the insulating layer 110 so that the conductive layer 312 is electrically connected to the conductive layer 202a via the plug.

The conductive layer 204 includes a region provided to fill an opening in the insulating layer 106. In the region, the conductive layer 204 is preferably in contact with the conductive layer 112b. Alternatively, a plug may be provided in the opening in the insulating layer 106 so that the conductive layer 204 is electrically connected to the conductive layer 112b via the plug.

The insulating layer 106 is provided between the semiconductor layer 208 and the conductive layer 204 and between the conductive layer 312 and the conductive layer 204. The insulating layer 106 has a function of the gate insulating layer of the transistor 52 and a function of a dielectric layer of the capacitor 57.

In the case where a light-emitting element is provided above the capacitor 57, a pixel electrode of the light-emitting element is provided to be in contact with a region 82 of the top surface of the conductive layer 312, for example.

FIG. 37 illustrates an example in which a plurality of structures illustrated in FIG. 36A are arranged in the row direction and the column direction. In FIG. 37, a pixel electrode 311 electrically connected to the light-emitting element 60 is denoted by a dashed double-dotted line. The pixel electrode 311 is provided to be in contact with the region 82 of the top surface of the conductive layer 312, for example.

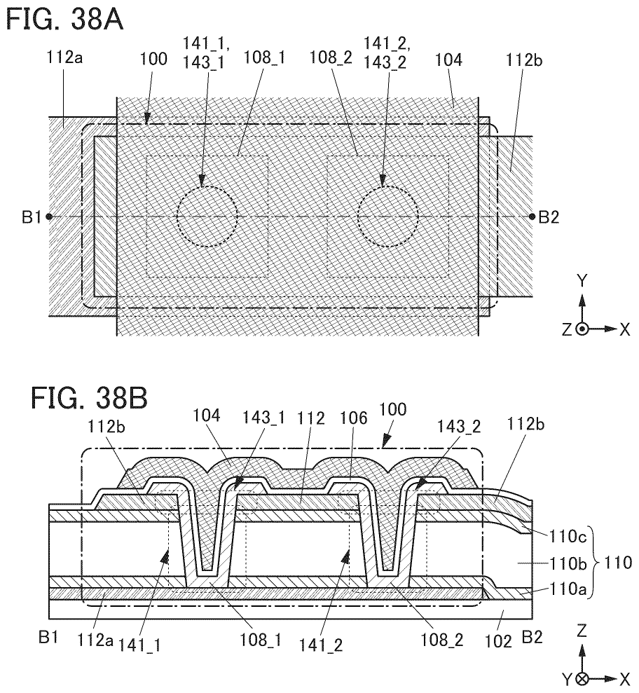

FIG. 38A and FIG. 38B illustrate a variation example of the transistor 100 included in the semiconductor device 10 illustrated in FIG. 6A and FIG. 6B. FIG. 38A is a plan view of the transistor 100. FIG. 38B is a cross-sectional view along dashed-dotted line B1-B2 in FIG. 38A.

FIG. 38A and FIG. 38B illustrate an example in which the transistor 100 includes two openings 141 and two openings 143 and the openings are arranged in the X direction.

In FIG. 38A and FIG. 38B, two openings 141 are denoted by an opening 141_1 and an opening 141_2 to be distinguished from each other, and two openings 143 are denoted by an opening 143_1 and an opening 143_2 to be distinguished from each other. FIG. 38A and FIG. 38B illustrate an example in which the semiconductor layers 108 provided in the opening 141_1 and the opening 143_1 and in the opening 141_2 and the opening 143_2 are different from each other, and the two semiconductor layers 108 are denoted by a semiconductor layer 108_1 and a semiconductor layer 108_2 to be distinguished from each other. The same applies to the following drawings.

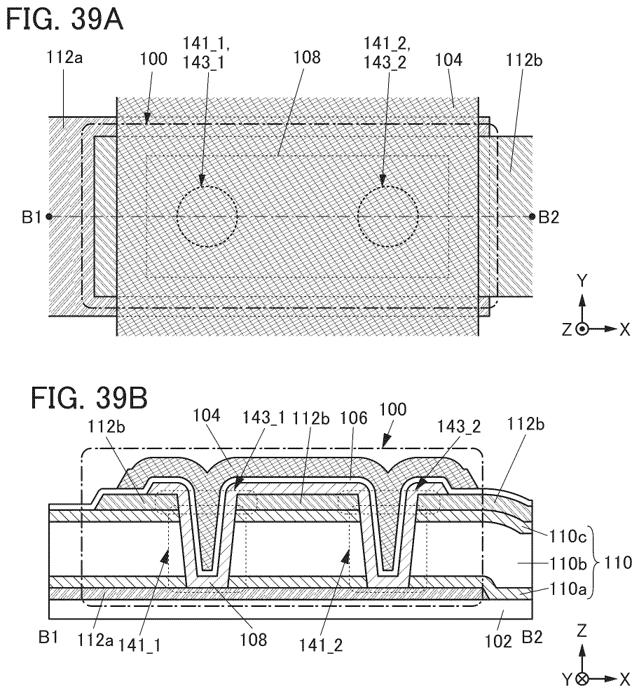

FIG. 39A is a variation example of the structure illustrated in FIG. 38A, in which the semiconductor layer 108 provided in the opening 141_1 and the opening 143_1 and the semiconductor layer 108 provided in the opening 141_2 and the opening 143_2 are the same. That is, FIG. 39A illustrates an example in which the transistor 100 includes two openings 141, two openings 143, and one semiconductor layer 108. FIG. 39B is a cross-sectional view along dashed-dotted line B1-B2 in FIG. 39A.

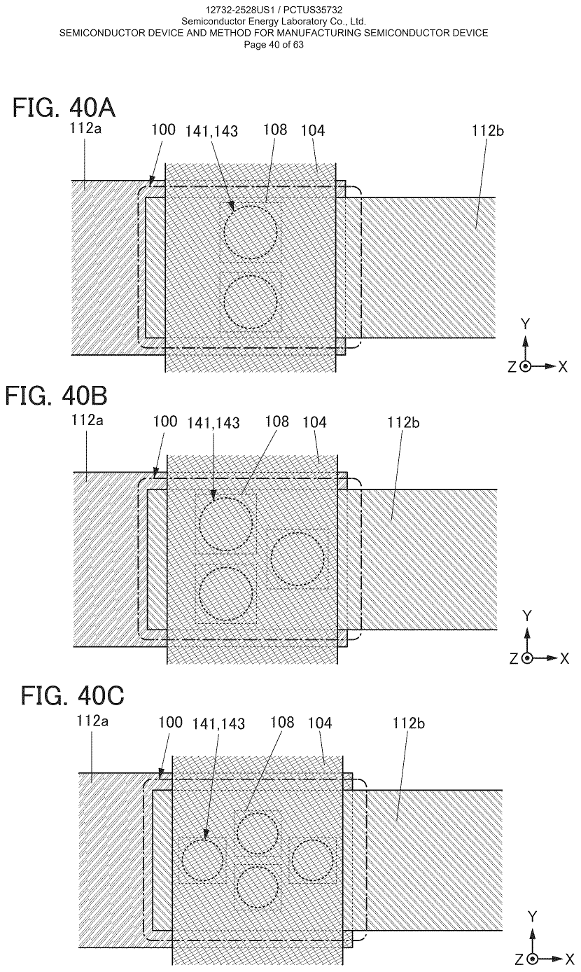

In the structure illustrated in FIG. 39A and FIG. 39B, for example, when the semiconductor layer 108 is formed by a photolithography method and an etching method, the alignment accuracy of a photomask can be lower than that in the case of the structure illustrated in FIG. 38A and FIG. 38B. Thus, the transistor 100 can be easily manufactured. In the structure illustrated in FIG. 38A and FIG. 38B, on the other hand, the surface area of the semiconductor layer 108 having higher electric resistance than the conductive layer 112b can be reduced; thus, the on-state current of the transistor 100 can be increased as compared to the structure illustrated in FIG. 39A and FIG. 39B. Also in the structures illustrated in FIG. 40A to FIG. 42B described later, the number of semiconductor layers 108 can be one.

FIG. 40A is a variation example of the structure illustrated in FIG. 38A, in which two openings 141 and two openings 143 are arranged in the Y direction. FIG. 40B is a variation example of the structure illustrated in FIG. 40A, in which one opening 141 and one opening 143 are provided on the right side of the two openings 141 and the two openings 143 arranged in the Y direction. When the two openings 141 and the two openings 143 arranged in the Y direction are provided in the first column and the one opening 141 and the one opening 143 are provided in the second column, for example, the centers of the opening 141 and the opening 143 in the second column can be positioned between the centers of the opening 141 and the opening 143 on the upper side in the first column and the centers of the opening 141 and the opening 143 on the lower side in the first column in the Y direction.

FIG. 40C is a variation example of the structure illustrated in FIG. 40A, in which one opening 141 and one opening 143 are provided on each of the left side and the right side of two openings 141 and two openings 143 arranged in the Y direction. When one opening 141 and one opening 143 are provided in each of the first column and the third column and the two openings 141 and two openings 143 arranged in the Y direction are provided in the second column, for example, the centers of the opening 141 and the opening 143 in the first column and the centers of the opening 141 and the opening 143 in the third column can be positioned between the centers of the opening 141 and the opening 143 on the upper side in the second column and the centers of the opening 141 and the opening 143 on the lower side in the second column in the Y direction.

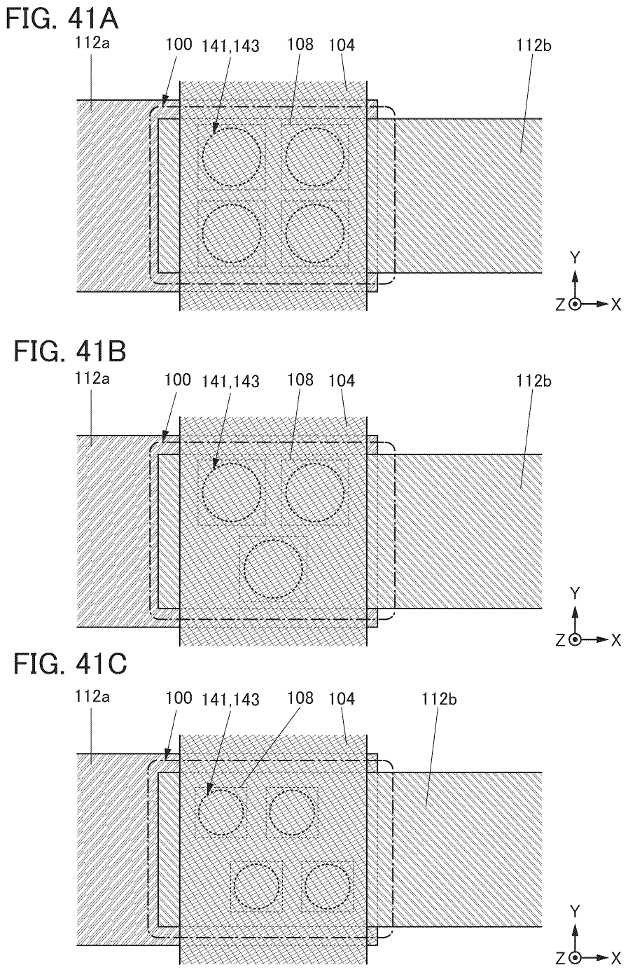

FIG. 41A is a variation example of the structure illustrated in FIG. 38A, in which four openings 141 and four openings 143 are arranged in a matrix of two rows and two columns. FIG. 41B is a variation example of the structure illustrated in FIG. 41A, in which one opening 141 and one opening 143 are provided below two openings 141 and two openings 143 arranged in the X direction. When the two openings 141 and the two openings 143 arranged in the X direction are provided in the first row and the one opening 141 and the one opening 143 are provided in the second row, for example, the centers of the opening 141 and the opening 143 in the second row can be positioned between the centers of the opening 141 and the opening 143 on the left side in the first row and the centers of the opening 141 and the opening 143 on the right side in the first row in the X direction.

FIG. 41C is a variation example of the structure illustrated in FIG. 41A, in which two openings 141 and two openings 143 on the lower side are positioned closer to the right side than those in the structure illustrated in FIG. 41A. In the structure illustrated in FIG. 41C, four openings 141 and four openings 143 are arranged in a zigzag manner.

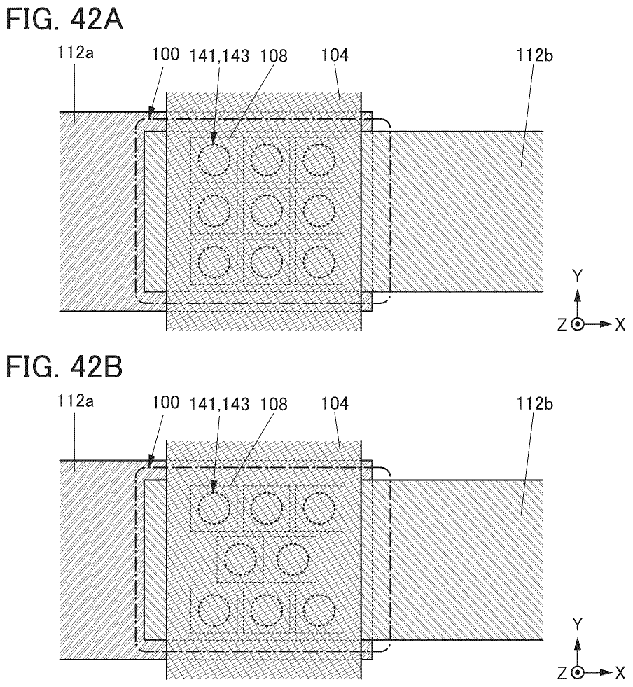

FIG. 42A is a variation example of the structure illustrated in FIG. 38A, in which nine openings 141 and nine openings 143 are arranged in a matrix of three rows and three columns. FIG. 42B is a variation example of the structure illustrated in FIG. 42A, in which the number of each of the openings 141 and the openings 143 provided in the middle row is two. In the example illustrated in FIG. 42B, the openings 141 and the openings 143 in the upper row and the openings 141 and the openings 143 in the middle row are arranged in a zigzag manner. Furthermore, in the structure illustrated in FIG. 42B, the openings 141 and the openings 143 in the lower row and the openings 141 and the openings 143 in the middle row are arranged in a zigzag manner.

When the number of each of the openings 141 and the openings 143 provided in the transistor 100 is increased, the total length of the outer perimeters of the openings 141 and the openings 143 in a plan view can be increased in some cases. As described above, the channel width of the transistor 100 can be equal to the length of the outer perimeter of the opening 143 in a plan view, for example. Thus, when the transistor 100 includes a plurality of the openings 141 and a plurality of the openings 143, the channel width of the transistor 100 can be large in some cases. By contrast, when the number of openings 141 and openings 143 provided in the transistor 100 is reduced, the transistor 100 can be manufactured easily and the transistor 100 can be miniaturized in some cases.

Although the structures illustrated in FIG. 38A to FIG. 42B are each described as a variation example of the transistor 100 among the transistors included in the semiconductor device 10 illustrated in FIG. 6A and FIG. 6B, one embodiment of the present invention is not limited thereto. Each of the structures can also be applied to the transistor 200 among the transistors included in the semiconductor device 10 illustrated in FIG. 6A and FIG. 6B.

This embodiment can be combined with the other embodiments as appropriate. In this specification, in the case where a plurality of structure examples are shown in one embodiment, the structure examples can be combined as appropriate.

### Embodiment 2

In this embodiment, a method for manufacturing the semiconductor device of one embodiment of the present invention will be described with reference to drawings.

### Manufacturing Method Example 1

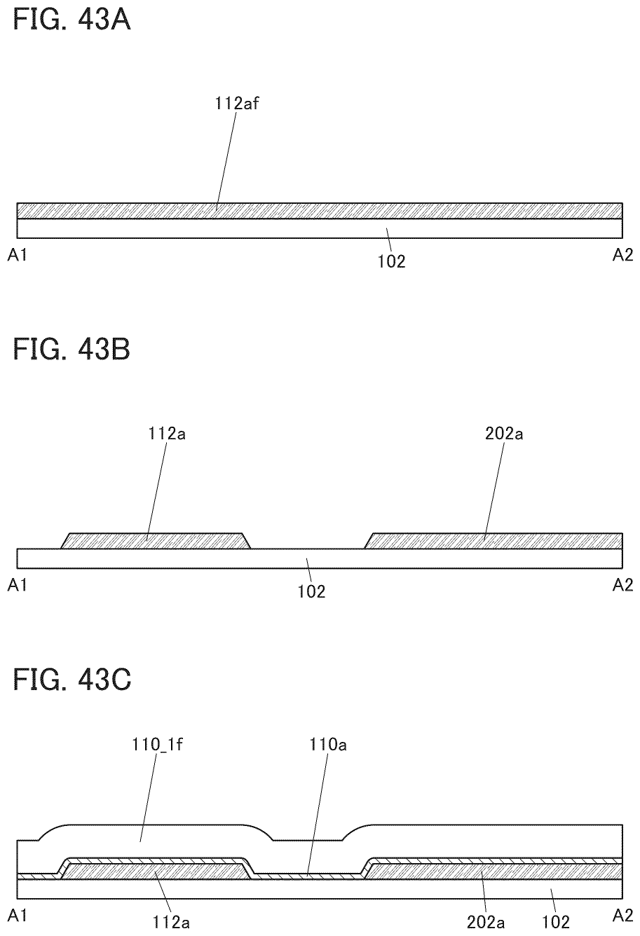

A method for manufacturing the semiconductor device 10 illustrated in FIG. 6B is described below with reference to FIG. 43A to FIG. 46C. Each drawing is a cross-sectional view along dashed-dotted line A1-A2.

Thin films that form the semiconductor device (insulating films, semiconductor films, conductive films, and the like) can be formed by a sputtering method, a chemical vapor deposition (CVD) method, a vacuum evaporation method, a pulsed laser deposition (PLD) method, an ALD method, or the like. Examples of the CVD method include a plasma-enhanced chemical vapor deposition (PECVD: Plasma Enhanced CVD) method and a thermal CVD method. An example of a thermal CVD method is a metal organic chemical vapor deposition (MOCVD: Metal Organic CVD) method.

The thin films that form the semiconductor device (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

When the thin films that form the semiconductor device are processed, a photolithography method or the like can be used. Alternatively, a nanoimprinting method, a sandblasting method, a lift-off method, or the like may be used for the processing of the thin films. Alternatively, island-shaped thin films may be directly formed by a film formation method using a blocking mask such as a metal mask.

There are the following two typical photolithography methods. In one of the methods, a resist mask is formed over a thin film to be processed, the thin film is processed by etching or the like, and then the resist mask is removed. In the other method, a photosensitive thin film is formed and then the thin film is processed into a desired shape by light exposure and development.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Ultraviolet rays, KrF laser light, ArF laser light, or the like can also be used. Light exposure may be performed by liquid immersion exposure technique. As the light used for light exposure, extreme ultraviolet (EUV) light or X-rays may also be used. Furthermore, instead of the light used for the light exposure, an electron beam can be used. It is preferable to use extreme ultraviolet light, X-rays, or an electron beam because extremely minute processing is possible. A photomask is not needed when light exposure is performed by scanning with a beam such as an electron beam.

For etching of a thin film, a dry etching method, a wet etching method, or a sandblasting method can be used, for example.

### Formation of Conductive Layer 112a and Conductive Layer 202a

A conductive film 112af to be the conductive layer 112a and the conductive layer 202a is formed over the substrate 102 (FIG. 43A). For the formation of the conductive film 112af, a sputtering method can be suitably used, for example.

Next, a resist mask (not illustrated) is formed over the conductive film 112af by a photolithography process, and then the conductive film 112af is processed, whereby the conductive layer 112a and the conductive layer 202a are formed (FIG. 43B). For the processing of the conductive film 112af, one or both of a wet etching method and a dry etching method are used. As a result, the conductive layer 112a functioning as one of the source electrode and the drain electrode of the transistor 100 and the conductive layer 202a functioning as one of the source electrode and the drain electrode of the transistor 200 are formed.

### Formation of Insulating Layer 110a, Insulating Layer 110_1, Insulating Layer 110b, and Insulating Layer 110c

Next, the insulating layer 110a and an insulating film 110_1f to be the insulating layer 110_1 are formed in this order over the substrate 102, the conductive layer 112a, and the conductive layer 202a (FIG. 43C).

For the formation of the insulating layer 110a and the insulating film 110_1f, a PECVD method can be suitably used. It is preferable that the insulating film 110_1f be formed in a vacuum successively after the formation of the insulating layer 110a, without exposure of a surface of the insulating layer 110a to the air. By forming the insulating layer 110a and the insulating film 110_1f successively, attachment of impurities derived from the air to the surface of the insulating layer 110a can be inhibited. Examples of the impurities include water and organic substances.

The substrate temperatures at the time of forming the insulating layer 110a and the insulating film 110_1f are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating layer 110a and the insulating film 110_1f are in the above range, impurities (e.g., water and hydrogen) released from the insulating layer 110a and the insulating film 110_1f themselves can be reduced, which inhibits diffusion of the impurities to a semiconductor layer formed later. Consequently, a transistor with favorable electrical characteristics and high reliability can be obtained.

Since the insulating layer 110a and the insulating film 110_1f are formed earlier than the semiconductor layer 108 and the semiconductor layer 208, there is no need to consider the probability of oxygen release from the semiconductor layer 108 and the semiconductor layer 208 due to heat applied thereto at the time of forming the insulating layer 110a and the insulating film 110 1f.

After the insulating layer 110a and the insulating film 110_1f are formed, heat treatment may be performed. By performing the heat treatment, water and hydrogen can be released from the surface and inside of each of the insulating layer 110a and the insulating film 110_1f.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400°C., yet still further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. The content of hydrogen, water, or the like in the atmosphere is preferably as low as possible. As the atmosphere, a high-purity gas with a dew point of −60° C. or lower, preferably −100° C. or lower, is preferably used. With the use of an atmosphere where the content of hydrogen, water, or the like is as low as possible, entry of hydrogen, water, or the like into the insulating layer 110a and the insulating film 110_1f can be prevented as much as possible. An oven or a rapid thermal annealing (RTA) apparatus can be used for the heat treatment, for example. With the RTA apparatus, the heat treatment time can be shortened.

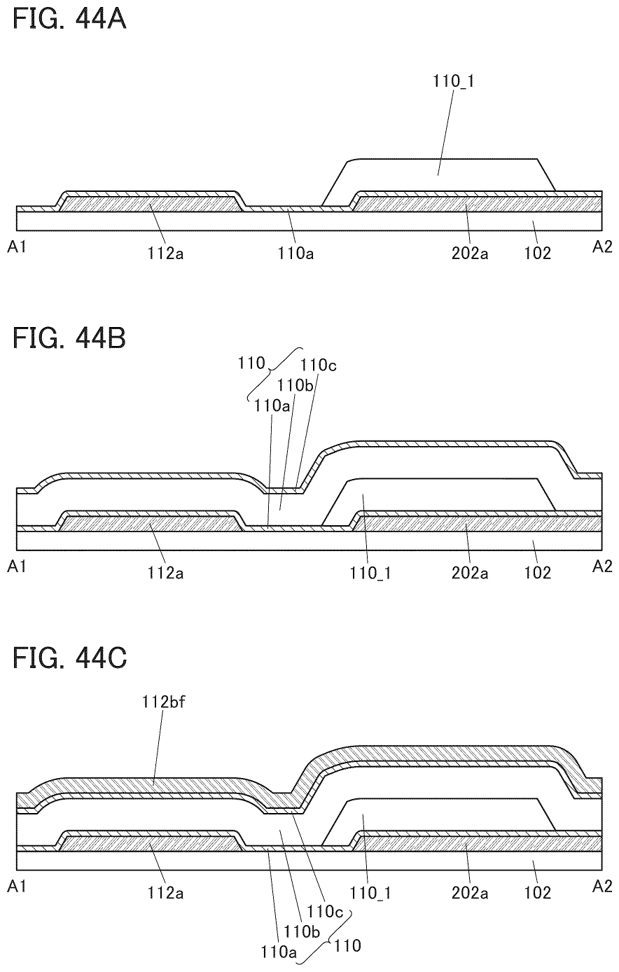

Next, a resist mask (not illustrated) is formed by a photolithography process over the insulating film 110_1f to include a region overlapping with the conductive layer 202a, and then the insulating film 110_1f is processed, whereby the insulating layer 110_1 is formed (FIG. 44A). The insulating layer 110_1 is formed in an island shape over the insulating layer 110a to include a region overlapping with the conductive layer 202a. For the processing of the insulating film 110_1f, one or both of a wet etching method and a dry etching method are used.

Next, the insulating layer 110b and the insulating layer 110c are formed in this order over the insulating layer 110a and the insulating layer 110_1 (FIG. 44B).

For the formation of the insulating layer 110b and the insulating layer 110c, a PECVD method can be suitably used. It is preferable that the insulating layer 110c be formed in a vacuum successively after the formation of the insulating layer 110b, without exposure of a surface of the insulating layer 110b to the air. By forming the insulating layer 110b and the insulating layer 110c successively, attachment of impurities derived from the air to the surface of the insulating layer 110b can be inhibited. Examples of the impurities include water and organic substances.

The above-described substrate temperatures at the time of forming the insulating layer 110a and the insulating film 110_1f can be used as the substrate temperatures at the time of forming the insulating layer 110b and the insulating layer 110c.

After the insulating layer 110b is formed, treatment for supplying oxygen to the insulating layer 110b may be performed. For example, an oxygen radical, an oxygen atom, an oxygen atomic ion, an oxygen molecular ion, or the like is supplied to the insulating layer 110b by an ion doping method, an ion implantation method, plasma treatment, or the like. Alternatively, a film that inhibits oxygen release may be formed over the insulating layer 110b, and then oxygen may be supplied to the insulating layer 110b through the film. It is preferable to remove the film after supply of oxygen. As the above film that inhibits oxygen release, a conductive film or a semiconductor film including one or more of indium, zinc, gallium, tin, aluminum, chromium, tantalum, titanium, molybdenum, nickel, iron, cobalt, and tungsten can be used. The insulating layer 110c may be formed after the above treatment is performed.

After the insulating layer 110b and the insulating layer 110c are formed, heat treatment may be performed. For the heat treatment, the conditions for the above heat treatment that can be used after the formation of the insulating layer 110a and the insulating film 110_1f can be used.

### Formation of Conductive Film 112bf

Next, a conductive film 112bf to be the conductive layer 112b and the conductive layer 202b is formed over the insulating layer 110c (FIG. 44C). For the formation of the conductive film 112bf, a sputtering method can be suitably used, for example.

### Formation of Conductive Layer 112B and Conductive Layer 202B

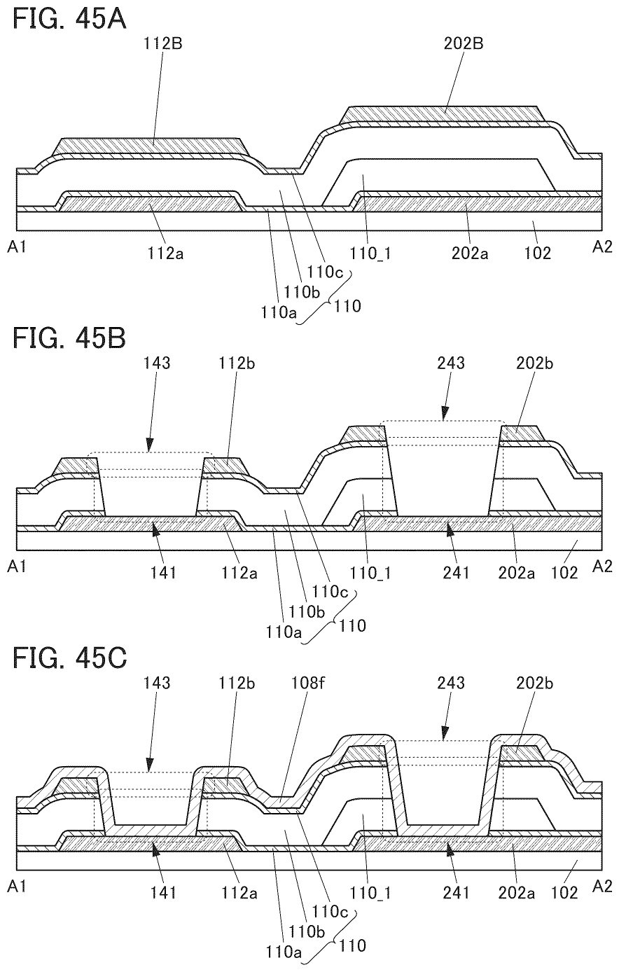

Next, the conductive film 112bf is processed to form a conductive layer 112B in a region overlapping with the conductive layer 112a and to form a conductive layer 202B in a region overlapping with the conductive layer 202a (FIG. 45A). For the formation of the conductive layer 112B and the conductive layer 202B, one or both of a wet etching method and a dry etching method can be used. For the formation of the conductive layer 112B and the conductive layer 202B, a wet etching method can be suitably used, for example.

### Formation of Opening 141, Opening 143, Opening 241, and Opening 243

Next, part of the conductive layer 112B and part of the conductive layer 202B are removed to form the conductive layer 112b including the opening 143 and the conductive layer 202b including the opening 243 (FIG. 45B). For the formation of the opening 143 and the opening 243, one or both of a wet etching method and a dry etching method can be used. For the formation of the opening 143 and the opening 243, a wet etching method can be suitably used, for example.

Next, insulating layers (the insulating layer 110a, the insulating layer 110b, and the insulating layer 110c) in a region overlapping with the opening 143 and insulating layers (the insulating layer 110a, the insulating layer 110_1, the insulating layer 110b, and the insulating layer 110c) in a region overlapping with the opening 243 are removed, whereby the opening 141 and the opening 241 are formed (FIG. 45B). For the formation of the opening 141 and the opening 241, one or both of a wet etching method and a dry etching method can be used. For the formation of the opening 141 and the opening 241, a dry etching method can be suitably used, for example. As a result of the formation, the conductive layer 112a is exposed in the opening 141 and the conductive layer 202a is exposed in the opening 241.

The opening 141 can be formed using a resist mask (not illustrated) used for the formation of the opening 143, for example. Specifically, a resist mask is formed over the conductive film 112bf, the conductive film 112bf is removed with the use of the resist mask to form the opening 143, and the insulating layer 110a, the insulating layer 110b, and the insulating layer 110c are removed with the use of the resist mask, whereby the opening 141 can be formed. The opening 141 may be formed using a resist mask that is different from the resist mask used for the formation of the opening 143.

Similarly, the opening 241 can be formed using a resist mask (not illustrated) used for the formation of the opening 243, for example. Specifically, a resist mask is formed over the conductive film 112bf, the conductive film 112bf is removed with the use of the resist mask to form the opening 243, and the insulating layer 110a, the insulating layer 110_1, the insulating layer 110b, and the insulating layer 110c are removed with the use of the resist mask, whereby the opening 241 can be formed. The opening 241 may be formed using a resist mask that is different from the resist mask used for the formation of the opening 243.

### Formation of Semiconductor Layer 108 and Semiconductor Layer 208

Next, a metal oxide film 108f is formed to cover the opening 143, the opening 141, the opening 243, and the opening 241 (FIG. 45C). The metal oxide film 108f includes a region in contact with the top surface and a side surface of the conductive layer 112b, a side surface of the insulating layer 110c, a side surface of the insulating layer 110b, a side surface of the insulating layer 110a, and the top surface of the conductive layer 112a via the opening 143 and the opening 141. The metal oxide film 108f also includes a region in contact with the top surface and a side surface of the conductive layer 202b, a side surface of the insulating layer 110c, a side surface of the insulating layer 110b, a side surface of the insulating layer 110_1, a side surface of the insulating layer 110a, and the top surface of the conductive layer 202a via the opening 243 and the opening 241.

The metal oxide film 108f is preferably formed by a sputtering method using a metal oxide target.

The metal oxide film 108f is preferably a dense film with as few defects as possible. The metal oxide film 108f is preferably a highly purified film in which impurities including hydrogen elements are reduced as much as possible. It is particularly preferable to use a metal oxide film having crystallinity as the metal oxide film 108f.

In forming the metal oxide film 108f, an oxygen gas is preferably used. In the case of using an oxygen gas at the time of forming the metal oxide film 108f, oxygen can be suitably supplied into the insulating layer 110b and the insulating layer 110_1. For example, in the case of using an oxide for the insulating layer 110b and the insulating layer 110_1, oxygen can be suitably supplied into the insulating layer 110b and the insulating layer 110_1.

By the supply of oxygen to the insulating layer 110b and the insulating layer 110_1, oxygen is supplied to the semiconductor layer 108 and the semiconductor layer 208 in a later step, so that oxygen vacancies (V_{O}) and V_{O}H in the semiconductor layer 108 and the semiconductor layer 208 can be reduced.

In forming the metal oxide film 108f, an oxygen gas and an inert gas (e.g., a helium gas, an argon gas, or a xenon gas) may be mixed. When the proportion of an oxygen gas in the whole film formation gas (an oxygen flow rate ratio) at the time of forming the metal oxide film 108f is higher, the crystallinity of the metal oxide film 108f can be higher and a transistor with higher reliability can be obtained. By contrast, the lower the oxygen flow rate ratio is, the lower the crystallinity of the metal oxide film 108f is, offering a transistor with a high on-state current. With the use of different oxygen flow rate ratios, for example, a stacked-layer structure of two or more metal oxide layers having different crystallinities can be formed.

When the substrate temperature is higher in forming the metal oxide film 108f, a denser metal oxide film having higher crystallinity can be formed. On the other hand, as the substrate temperature becomes lower, a metal oxide film having lower crystallinity and higher electric conductivity can be formed.

The substrate temperature at the time of forming the metal oxide film 108f is higher than or equal to room temperature and lower than or equal to 250° C., preferably higher than or equal to room temperature and lower than or equal to 200° C., further preferably higher than or equal to room temperature and lower than or equal to 140° C. When the substrate temperature is higher than or equal to room temperature and lower than 140° C., for example, high productivity is achieved, which is preferable. When the metal oxide film 108f is formed at a substrate temperature set to room temperature or without heating the substrate, the crystallinity can be made low.

In the case of employing an ALD method for the formation of the metal oxide film 108f, a film formation method such as a thermal ALD method or PEALD (plasma enhanced ALD) method is preferably employed. A thermal ALD method is preferable because of its capability of forming a film with extremely high step coverage. A PEALD method is preferable because of its capability of forming a film at low temperatures, in addition to its capability of forming a film with high step coverage.

For example, the metal oxide film can be formed by an ALD method using a precursor containing a metal element that is a component of the metal oxide film and an oxidizer.

In the case where an In-Ga-Zn oxide is formed, for example, three precursors of a precursor containing indium, a precursor containing gallium, and a precursor containing zinc can be used. Alternatively, two precursors of a precursor containing indium and a precursor containing gallium and zinc may be used.

Examples of the precursor containing indium include triethylindium, tris(2,2,6,6-tetramethyl-3,5-heptanedionato)indium, cyclopentadienylindium, indium(III) chloride, and (3-(dimethylamino)propyl)dimethylindium.

Examples of the precursor containing gallium include trimethylgallium, triethylgallium, gallium trichloride, tris(dimethylamido)gallium, gallium(III) acetylacetonate, tris(2,2,6,6-tetramethyl-3,5-heptanedionato)gallium, dimethylchlorogallium, diethylchlorogallium, and gallium(III) chloride.

Examples of the precursor containing zinc include dimethylzinc, diethylzinc, bis(2,2,6,6-tetramethyl-3,5-heptanedionato)zinc, and zinc chloride.

Examples of the oxidizer include ozone, oxygen, and water.

As a method for controlling the composition of a film to be obtained, adjusting one or more of the kinds of source gases, the flow rate ratio of the source gases, the flowing time of the source gases, and the order in which the source gases flow is given. By adjusting them, a film whose composition is continuously changed can be formed. Furthermore, films having different compositions can be formed successively.

In the case where each of the semiconductor layer 108 and the semiconductor layer 208 is formed to have a stacked-layer structure, an upper metal oxide film is preferably formed successively after the formation of a lower metal oxide film without exposure of a surface of the lower metal oxide film to the air.

It is preferable to perform at least one of treatment for desorbing impurities (e.g., water, hydrogen, an organic substance) adsorbed onto a surface of the insulating layer 110 and treatment for supplying oxygen into the insulating layer 110 before the formation of the metal oxide film 108f. For example, heat treatment can be performed at a temperature higher than or equal to 70° C. and lower than or equal to 200° C. in a reduced-pressure atmosphere. Alternatively, plasma treatment may be performed in an oxygen-containing atmosphere. Alternatively, oxygen may be supplied to the insulating layer 110 by plasma treatment in an atmosphere containing an oxidizing gas such as dinitrogen monoxide (N₂O). Performing plasma treatment using a dinitrogen monoxide gas can supply oxygen while suitably removing the impurities on the surface of the insulating layer 110.

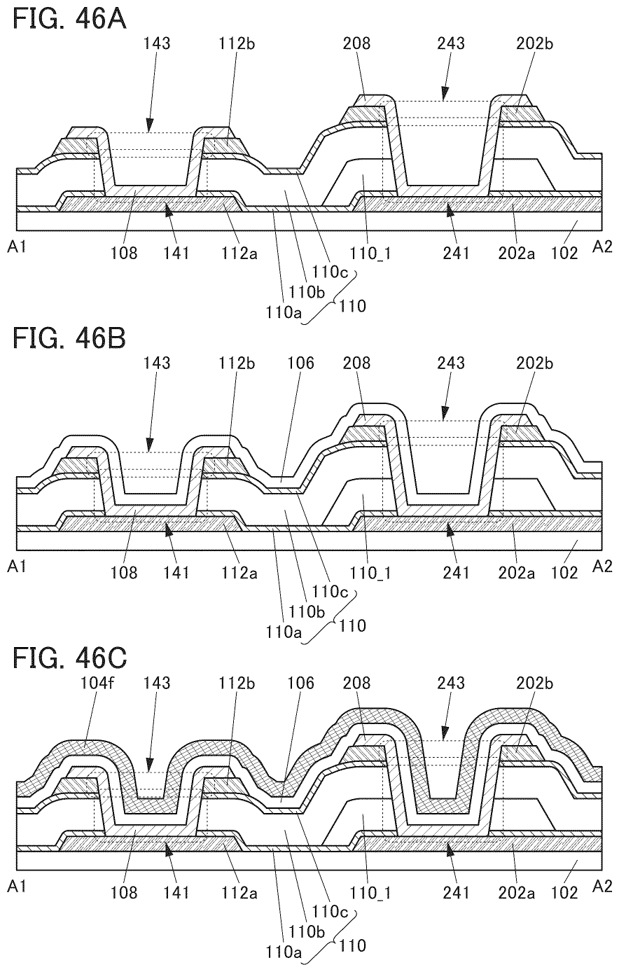

Next, the metal oxide film 108f is processed into an island shape to form the semiconductor layer 108 in a region overlapping with the conductive layer 112a and the semiconductor layer 208 in a region overlapping with the conductive layer 202a (FIG. 46A). The semiconductor layer 108 is formed to include a region in contact with the top surface of the conductive layer 112a, the side surface of the insulating layer 110a, the side surface of the insulating layer 110b, the side surface of the insulating layer 110c, and the side surface and the top surface of the conductive layer 112b. The semiconductor layer 208 is formed to include a region in contact with the top surface of the conductive layer 202a, the side surface of the insulating layer 110a, the side surface of the insulating layer 110_1, the side surface of the insulating layer 110b, the side surface of the insulating layer 110c, and the side surface and the top surface of the conductive layer 202b.

For the formation of the semiconductor layer 108 and the semiconductor layer 208, one or both of a wet etching method and a dry etching method can be used. For the formation of the semiconductor layer 108 and the semiconductor layer 208, a wet etching method can be suitably used, for example. At this time, part of the conductive layer 112b in a region not overlapping with the semiconductor layer 108 is etched and thinned in some cases. Similarly, part of the conductive layer 202b in a region not overlapping with the semiconductor layer 208 is etched and thinned in some cases. Furthermore, part of the insulating layer 110 (specifically, the insulating layer 110c) in a region not overlapping with the conductive layer 112b nor the conductive layer 202b is etched and thinned in some cases. In the etching of the metal oxide film 108f, the reduction in the thickness of the insulating layer 110c can be inhibited when a material having a high etching selectivity is used for the insulating layer 110c.

It is preferable that heat treatment be performed after the metal oxide film 108f is formed or the metal oxide film 108f is processed into the semiconductor layer 108 and the semiconductor layer 208. By the heat treatment, hydrogen and water included in the metal oxide film 108f or the semiconductor layer 108 and the semiconductor layer 208 or adsorbed onto a surface thereof can be removed. Furthermore, the film quality of the metal oxide film 108f or the semiconductor layer 108 and the semiconductor layer 208 is improved (e.g., the number of defects is reduced or crystallinity is increased) by the heat treatment in some cases.

Oxygen can be supplied from the insulating layer 110 to the metal oxide film 108f or to the semiconductor layer 108 and the semiconductor layer 208 by the heat treatment. In this case, it is further preferable that the heat treatment be performed before processing into the semiconductor layer 108 and the semiconductor layer 208. The above description can be referred to for the heat treatment; thus, the detailed description thereof is omitted.

The heat treatment is not necessarily performed when not needed. The heat treatment in this step may be omitted, and heat treatment performed in a later step may also serve as the heat treatment in this step. In some cases, treatment at high temperatures (e.g., film formation step) or the like in a later step can serve as the heat treatment in this step.

### Formation of Insulating Layer 106

Next, the insulating layer 106 is formed to cover the semiconductor layer 108, the conductive layer 112b, the semiconductor layer 208, the conductive layer 202b, and the insulating layer 110 (FIG. 46B). For the formation of the insulating layer 106, a PECVD method or an ALD method can be suitably used, for example.

In the case of using an oxide semiconductor for the semiconductor layer 108 and the semiconductor layer 208, the insulating layer 106 preferably functions as a barrier film that inhibits diffusion of oxygen. When the insulating layer 106 has a function of inhibiting diffusion of oxygen, oxygen included in the semiconductor layer 108 and the semiconductor layer 208 is inhibited from diffusing into the conductive layer 104 and the conductive layer 204, respectively, which are formed later, through the insulating layer 106, so that oxidation of the conductive layer 104 and the conductive layer 204 can be inhibited. Consequently, the transistor 100 and the transistor 200 with favorable electrical characteristics and high reliability can be obtained.

In this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

By increasing the temperature at the time of forming the insulating layer 106 serving as the gate insulating layer of each of the transistor 100 and the transistor 200, the insulating layer 106 including a small number of defects can be obtained. However, the high temperature at the time of forming the insulating layer 106 sometimes allows release of oxygen from the semiconductor layer 108 and the semiconductor layer 208, which increases the amount of oxygen vacancies (V_{O}) and V_{O}H in the semiconductor layer 108 and the semiconductor layer 208 in some cases. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the semiconductor layer 108 and the semiconductor layer 208 can be inhibited while the defects in the insulating layer 106 can be reduced. Consequently, the transistor 100 and the transistor 200 with favorable electrical characteristics and high reliability can be obtained.

Before the formation of the insulating layer 106, plasma treatment may be performed on the surface of the semiconductor layer 108 and the surface of the semiconductor layer 208. By the plasma treatment, impurities (e.g., water) adsorbed onto the surface of the semiconductor layer 108 and the surface of the semiconductor layer 208 can be reduced. Accordingly, impurities at the interface between the semiconductor layer 108 and the insulating layer 106 and the interface between the semiconductor layer 208 and the insulating layer 106 can be reduced, achieving a highly reliable transistor. The plasma treatment is particularly suitable in the case where the surfaces of the semiconductor layer 108 and the semiconductor layer 208 are exposed to the air in a period between the formation of the semiconductor layer 108 and the semiconductor layer 208 and the formation of the insulating layer 106. The plasma treatment can be performed in an atmosphere containing one or more of oxygen, ozone, nitrogen, dinitrogen monoxide, and argon, for example. The plasma treatment and the formation of the insulating layer 106 are preferably performed successively without exposure to the air.

### Formation of Conductive Layer 104 and Conductive Layer 204

Next, the conductive film 104f to be the conductive layer 104 and the conductive layer 204 is formed over the insulating layer 106 (FIG. 46C). For the formation of the conductive film 104f, a sputtering method can be suitably used, for example.

Next, a resist mask (not illustrated) is formed over the conductive film 104f by a photolithography process, and then the conductive film 104f is processed, whereby the conductive layer 104 overlapping with the conductive layer 112a and the semiconductor layer 108 and the conductive layer 204 overlapping with the conductive layer 202a and the semiconductor layer 208 are formed (FIG. 6B). For the processing of the conductive film 104f, one or both of a wet etching method and a dry etching method can be used. By the processing, the thickness of the insulating layer 106 in a portion not overlapping with the conductive layer 104 nor the conductive layer 204 sometimes becomes smaller than the thickness in a portion overlapping with the conductive layer 104 or the conductive layer 204.

Through the above steps, the transistor 100 and the transistor 200 can be manufactured.

Through the above steps, the semiconductor device 10 illustrated in FIG. 6B can be manufactured.

### Manufacturing Method Example 2

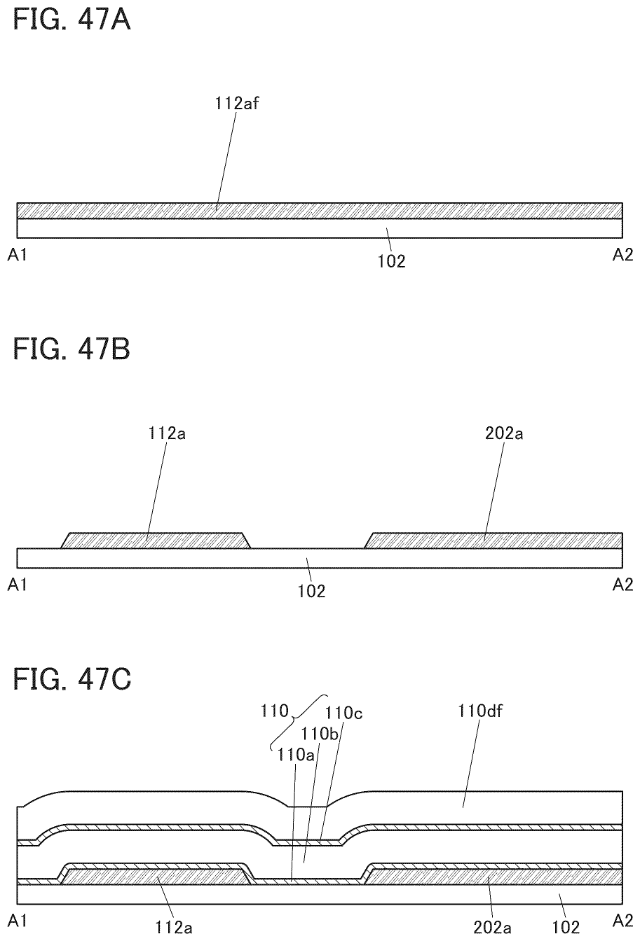

A method for manufacturing the semiconductor device 10A illustrated in FIG. 8B is described below with reference to FIG. 47A to FIG. 50C. Each drawing is a cross-sectional view along dashed-dotted line A1-A2.

The steps from the formation of the conductive film 112af to the formation of the conductive layer 112a and the conductive layer 202a (FIG. 47A and FIG. 47B) are similar to those in the manufacturing method in <Manufacturing method example 1> described above. Thus, for this step, the description of the manufacturing method of the semiconductor device 10 related to FIG. 43A and FIG. 43B can be referred to.

### Formation of Insulating Layer 110a, Insulating Layer 110b, Insulating Layer 110c, Insulating Layer 110d, and Insulating Layer 110e

Next, the insulating layer 110a, the insulating layer 110b, and the insulating layer 110c are formed in this order over the substrate 102, the conductive layer 112a, and the conductive layer 202a. After that, an insulating film 110df to be the insulating layer 110d is formed over the insulating layer 110c (FIG. 47C).

For the formation of the insulating layer 110a, the insulating layer 110b, and the insulating layer 110c, the description related to the formation of the insulating layer 110a, the insulating layer 110b, and the insulating layer 110c described in <Manufacturing method example 1> can be referred to. For the formation of the insulating film 110 df, the description related to the formation of the insulating layer 110b described in <Manufacturing method example 1> can be referred to.

After the insulating layer 110b is formed, treatment for supplying oxygen to the insulating layer 110b may be performed. For the treatment, the description related to the treatment for supplying oxygen that can be performed after the formation of the insulating layer 110 b described in <Manufacturing method example 1> can be referred to.

After the insulating layer 110a, the insulating layer 110b, the insulating layer 110c, and the insulating film 110df to be the insulating layer 110d are formed, heat treatment may be performed. For the heat treatment, the description related to the heat treatment that can be performed after the formation of the insulating layer 110a and the insulating film 110_1f described in <Manufacturing method example 1> can be referred to.

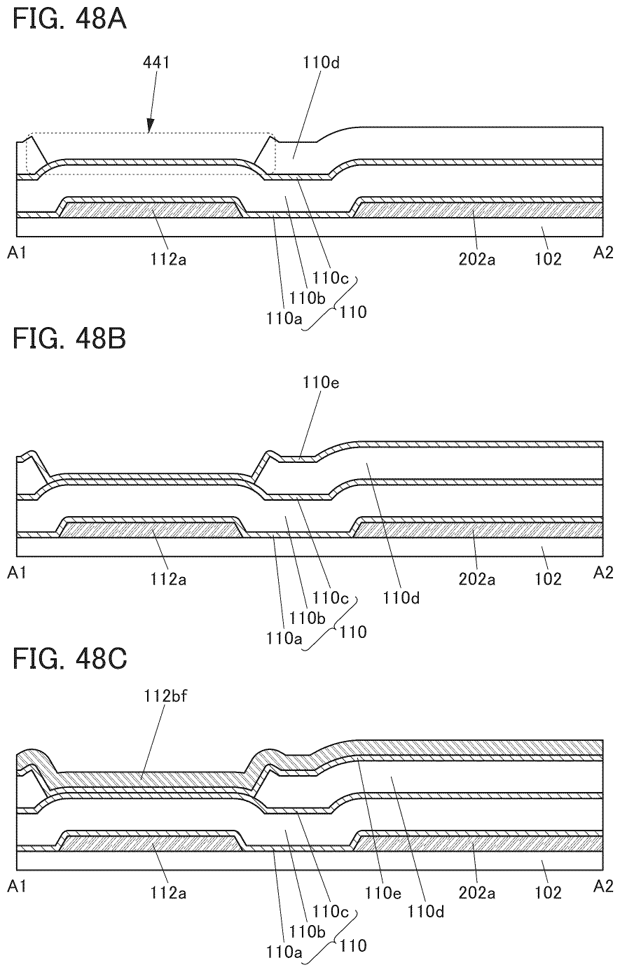

Next, a resist mask (not illustrated) is formed by a photolithography process over the insulating film 110df so as not to include a region overlapping with the conductive layer 112a, and then the insulating film 110df is processed, whereby the insulating layer 110d is formed (FIG. 48A). The insulating layer 110d is formed over the insulating layer 110c to include an opening (an opening 441) in a region overlapping with the conductive layer 112a. For the processing of the insulating film 110df, one or both of a wet etching method and a dry etching method are used.

Next, the insulating layer 110e is formed over the insulating layer 110c and the insulating layer 110d (FIG. 48B). For the formation of the insulating layer 110e, the description related to the formation of the insulating layer 110a and the insulating layer 110c described in <Manufacturing method example 1> can be referred to.

After the insulating layer 110e is formed, heat treatment may be performed. For the heat treatment, the description related to the heat treatment that can be performed after the formation of the insulating layer 110 c described in <Manufacturing method example 1> can be referred to.

### Formation of Conductive Film 112bf

Next, the conductive film 112bf to be the conductive layer 112b and the conductive layer 202b is formed over the insulating layer 110e (FIG. 48C). For the formation of the conductive film 112bf, the description related to the formation of the conductive film 112bf (FIG. 44C) described in <Manufacturing method example 1> can be referred to.

### Formation of Conductive Layer 112B and Conductive Layer 202B

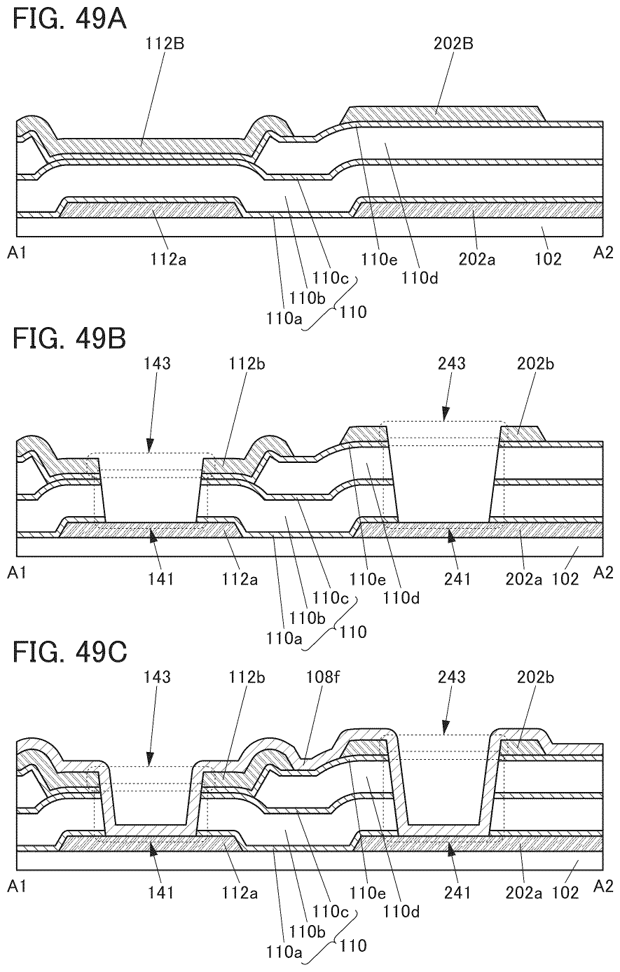

Next, the conductive film 112bf is processed to form the conductive layer 112B in a region overlapping with the conductive layer 112a and to form the conductive layer 202B in a region overlapping with the conductive layer 202a (FIG. 49A). For the formation of the conductive layer 112B and the conductive layer 202B, the description related to the formation of the conductive layer 112B and the conductive layer 202B (FIG. 45A) described in <Manufacturing method example 1> can be referred to.

### Formation of Opening 141, Opening 143, Opening 241, and Opening 243

Next, part of the conductive layer 112B is removed to form the conductive layer 112b including the opening 143. Furthermore, part of the conductive layer 202B is removed to form the conductive layer 202b including the opening 243 (FIG. 49B). For the formation of the opening 143 and the opening 243, the description related to the formation of the opening 143 and the opening 243 (FIG. 45B) described in <Manufacturing method example 1> can be referred to.

Next, insulating layers (the insulating layer 110a, the insulating layer 110b, the insulating layer 110c, and the insulating layer 110e) in a region overlapping with the opening 143 and insulating layers (the insulating layer 110a, the insulating layer 110b, the insulating layer 110c, the insulating layer 110d, and the insulating layer 110e) in a region overlapping with the opening 243 are removed, whereby the opening 141 and the opening 241 are formed (FIG. 49B). For the formation of the opening 141 and the opening 241, the description related to the formation of the opening 141 and the opening 241 (FIG. 45B) described in <Manufacturing method example 1> can be referred to. As a result of the formation, the conductive layer 112a is exposed in the opening 141 and the conductive layer 202a is exposed in the opening 241.

### Formation of Semiconductor Layer 108 and Semiconductor Layer 208

Next, the metal oxide film 108f is formed to cover the opening 143, the opening 141, the opening 243, and the opening 241 (FIG. 49C). The metal oxide film 108f includes a region in contact with the top surface and a side surface of the conductive layer 112b, a side surface of the insulating layer 110e, a side surface of the insulating layer 110c, a side surface of the insulating layer 110b, a side surface of the insulating layer 110a, and the top surface of the conductive layer 112a via the opening 143 and the opening 141. The metal oxide film 108f also includes a region in contact with the top surface and a side surface of the conductive layer 202b, a side surface of the insulating layer 110e, a side surface of the insulating layer 110d, a side surface of the insulating layer 110c, a side surface of the insulating layer 110b, a side surface of the insulating layer 110a, and the top surface of the conductive layer 202a via the opening 243 and the opening 241.

The description that can be used for the method for forming the metal oxide film 108f and the heat treatment for the metal oxide film 108f described in <Manufacturing method example 1> can be applied to the details of the method for forming the metal oxide film 108f and the heat treatment for the metal oxide film 108f.

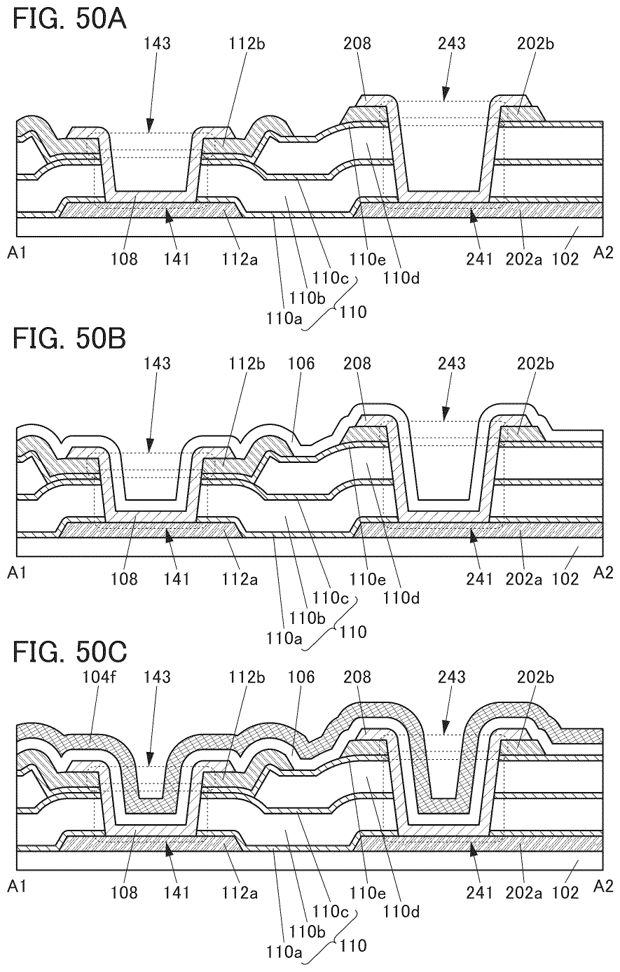

Next, the metal oxide film 108f is processed into an island shape to form the semiconductor layer 108 in a region overlapping with the conductive layer 112a and the semiconductor layer 208 in a region overlapping with the conductive layer 202a (FIG. 50A). The semiconductor layer 108 is formed to include a region overlapping with the conductive layer 112a. The semiconductor layer 208 is formed to include a region overlapping with the conductive layer 202a. The semiconductor layer 108 is formed to include a region in contact with the top surface of the conductive layer 112a, the side surface of the insulating layer 110a, the side surface of the insulating layer 110b, the side surface of the insulating layer 110c, the side surface of the insulating layer 110e, and the side surface and the top surface of the conductive layer 112b. The semiconductor layer 208 is formed to include a region in contact with the top surface of the conductive layer 202a, the side surface of the insulating layer 110a, the side surface of the insulating layer 110b, the side surface of the insulating layer 110c, the side surface of the insulating layer 110d, the side surface of the insulating layer 110e, and the side surface and the top surface of the conductive layer 202b.

The description that can be used for the method for forming the semiconductor layer 108 and the semiconductor layer 208 and the heat treatment for the semiconductor layer 108 and the semiconductor layer 208 described in <Manufacturing method example 1> can be applied to the details of the method for forming the semiconductor layer 108 and the semiconductor layer 208 and the heat treatment for the semiconductor layer 108 and the semiconductor layer 208.

### Formation of Insulating Layer 106

Next, the insulating layer 106 is formed to cover the semiconductor layer 108, the conductive layer 112b, the semiconductor layer 208, the conductive layer 202b, and the insulating layer 110 (FIG. 50B). For the formation of the insulating layer 106, the description related to the formation of the insulating layer 106 (FIG. 46B) described in <Manufacturing method example 1> can be referred to.

### Formation of Conductive Layer 104 and Conductive Layer 204

Next, the conductive film 104f to be the conductive layer 104 and the conductive layer 204 is formed over the insulating layer 106 (FIG. 50C). For the formation of the conductive film 104f, the description related to the formation of the conductive film 104f (FIG. 46C) described in <Manufacturing method example 1> can be referred to.

Next, a resist mask (not illustrated) is formed over the conductive film 104f by a photolithography process, and then the conductive film 104f is processed, whereby the conductive layer 104 overlapping with the conductive layer 112a and the semiconductor layer 108 and the conductive layer 204 overlapping with the conductive layer 202a and the semiconductor layer 208 are formed (FIG. 8B). For the formation of the conductive layer 104 and the conductive layer 204, the description related to the formation of the conductive layer 104 and the conductive layer 204 described in <Manufacturing method example 1> can be referred to. By the processing, the thickness of the insulating layer 106 in a portion not overlapping with the conductive layer 104 nor the conductive layer 204 sometimes becomes smaller than the thickness in a portion overlapping with the conductive layer 104 or the conductive layer 204.

Through the above steps, the transistor 100A and the transistor 200A can be manufactured.

Through the above steps, the semiconductor device 10A illustrated in FIG. 8B can be manufactured.

### Manufacturing Method Example 3

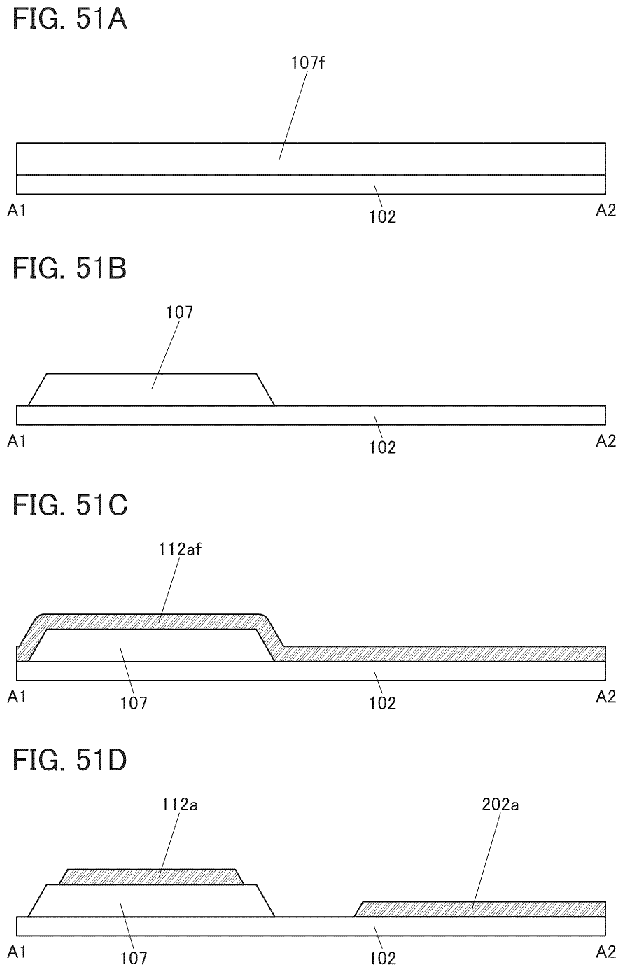

A method for manufacturing the semiconductor device 10C illustrated in FIG. 10B is described below with reference to FIG. 51A to FIG. 54C. Each drawing is a cross-sectional view along dashed-dotted line A1-A2.

### Formation of Insulating Layer 107

An insulating film 107f to be the insulating layer 107 is formed over the substrate 102 (FIG. 51A). For the formation of the insulating film 107f, the description related to the formation of the insulating film 110_1f described in <Manufacturing method example 1> can be referred to.

After the insulating film 107f is formed, heat treatment may be performed. For the heat treatment, the description related to the heat treatment that can be performed after the formation of the insulating layer 110a and the insulating film 110_1f described in <Manufacturing method example 1> can be referred to.

Next, a resist mask (not illustrated) is formed by a photolithography process over the insulating film 107f overlapping with a region where the transistor 100 is formed later, and then the insulating film 107f is processed, whereby the insulating layer 107 is formed (FIG. 51B). For the processing of the insulating film 107f, one or both of a wet etching method and a dry etching method are used.

### Formation of Conductive Layer 112a and Conductive Layer 202a

The conductive film 112af to be the conductive layer 112a and the conductive layer 202a is formed over the substrate 102 and the insulating layer 107 (FIG. 51C). For the formation of the conductive film 112af, the description related to the formation of the conductive film 112af (FIG. 43A) described in <Manufacturing method example 1> can be referred to.

Next, a resist mask (not illustrated) is formed over the conductive film 112af by a photolithography process, and then the conductive film 112af is processed, whereby the conductive layer 112a and the conductive layer 202a are formed (FIG. 51D). For the processing of the conductive film 112af, the description related to the processing of the conductive film 112af (FIG. 43B) described in <Manufacturing method example 1> can be referred to. Consequently, the conductive layer 112a is formed in a region where the transistor 100 is formed later (over the insulating layer 107), and the conductive layer 202a is formed in a region where the transistor 200C is formed later (a region which is not over the insulating layer 107).

### Formation of Insulating Layer 110a, Insulating Layer 110b, and Insulating Layer 110c

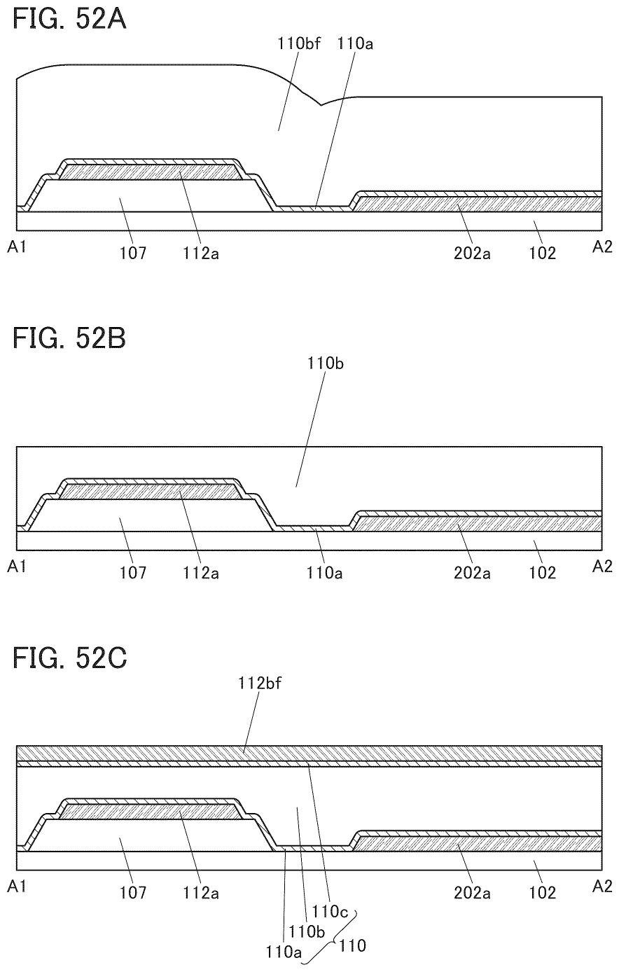

Next, the insulating layer 110a and an insulating film 110bf to be the insulating layer 110b are formed over the substrate 102, the insulating layer 107, the conductive layer 112a, and the conductive layer 202a (FIG. 52A). For the formation of the insulating layer 110a and the insulating film 110bf, the description related to the formation of the insulating layer 110a and the insulating film 110_1f (FIG. 43C) described in <Manufacturing method example 1> can be referred to.

After the insulating film 110bf is formed, treatment for supplying oxygen to the insulating film 110bf may be performed. For the treatment, the description related to the treatment for supplying oxygen that can be performed on the insulating layer 110b described in <Manufacturing method example 1> can be referred to.

After the insulating film 110bf is formed, heat treatment may be performed. For the heat treatment, the description related to the heat treatment that can be performed after the formation of the insulating layer 110a and the insulating film 110_1f described in <Manufacturing method example 1> can be referred to.

Next, planarization treatment of a surface of the insulating film 110bf is performed by a chemical mechanical polishing (CMP) method to form the insulating layer 110b having a flat or substantially flat surface (FIG. 52B).

After the insulating layer 110b is formed, treatment for supplying oxygen to the insulating layer 110b may be performed. For the treatment, the description related to the treatment for supplying oxygen that can be performed on the insulating layer 110b described in <Manufacturing method example 1> can be referred to.

After the insulating layer 110b is formed, heat treatment may be performed. For the heat treatment, the description related to the heat treatment that can be performed after the formation of the insulating layer 110a and the insulating film 110_1f described in <Manufacturing method example 1> can be referred to.

Next, the insulating layer 110c is formed over the insulating layer 110b (FIG. 52C). For the formation conditions of the insulating layer 110c, the description related to the formation of the insulating layer 110 c described in <Manufacturing method example 1> can be referred to.

After the insulating layer 110c is formed, heat treatment may be performed. For the heat treatment, the description related to the heat treatment that can be used after the formation of the insulating layer 110a and the insulating film 110_lf described in <Manufacturing method example 1> can be referred to.

### Formation of Conductive Film 112bf

Next, the conductive film 112bf to be the conductive layer 112b and the conductive layer 202b is formed over the insulating layer 110c (FIG. 52C). For the formation of the conductive film 112bf, the description related to the formation of the conductive film 112bf (FIG. 44C) described in <Manufacturing method example 1> can be referred to.

### Formation of Conductive Layer 112B and Conductive Layer 202B

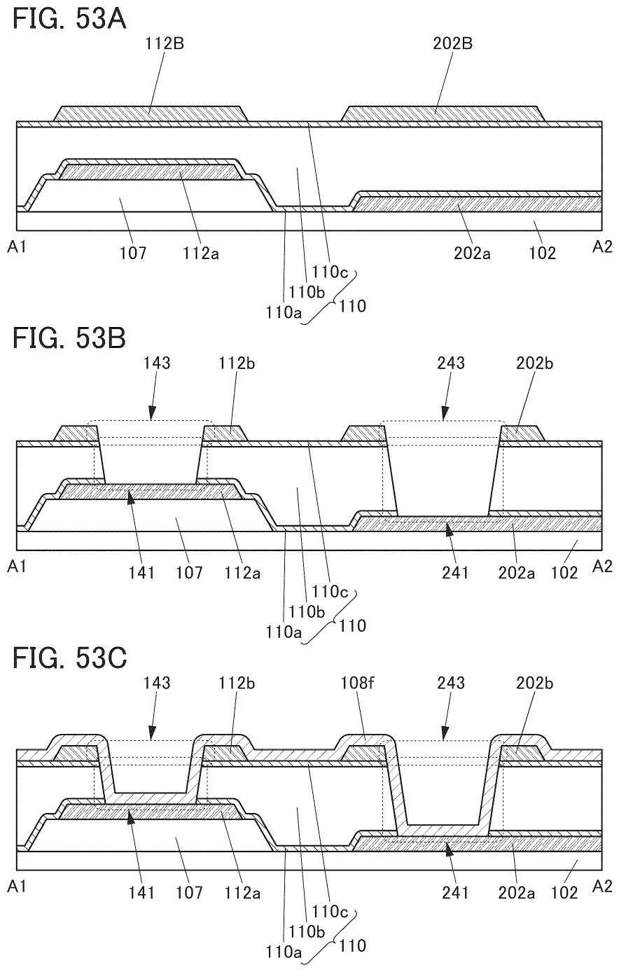

Next, the conductive film 112bf is processed to form the conductive layer 112B in a region overlapping with the conductive layer 112a and to form the conductive layer 202B in a region overlapping with the conductive layer 202a (FIG. 53A). For the formation of the conductive layer 112B and the conductive layer 202B, the description related to the formation of the conductive layer 112B and the conductive layer 202B (FIG. 45A) described in <Manufacturing method example 1> can be referred to.

### Formation of Opening 141, Opening 143, Opening 241, and Opening 243

Next, part of the conductive layer 112B is removed to form the conductive layer 112b including the opening 143. Furthermore, part of the conductive layer 202B is removed to form the conductive layer 202b including the opening 243 (FIG. 53B). For the formation of the opening 143 and the opening 243, the description related to the formation of the opening 143 and the opening 243 (FIG. 45B) described in <Manufacturing method example 1> can be referred to.

Next, insulating layers (the insulating layer 110a, the insulating layer 110b, and the insulating layer 110c) in a region overlapping with the opening 143 and insulating layers (the insulating layer 110a, the insulating layer 110b, and the insulating layer 110c) in a region overlapping with the opening 243 are removed, whereby the opening 141 and the opening 241 are formed (FIG. 53B). For the formation of the opening 141 and the opening 241, the description related to the formation of the opening 141 and the opening 241 (FIG. 45B) described in <Manufacturing method example 1> can be referred to. As a result of the formation, the conductive layer 112a is exposed in the opening 141 and the conductive layer 202a is exposed in the opening 241.

### Formation of Semiconductor Layer 108 and Semiconductor Layer 208

Next, the metal oxide film 108f is formed to cover the opening 143, the opening 141, the opening 243, and the opening 241 (FIG. 53C). The metal oxide film 108f includes a region in contact with the top surface and a side surface of the conductive layer 112b, a side surface of the insulating layer 110c, a side surface of the insulating layer 110b, a side surface of the insulating layer 110a, and the top surface of the conductive layer 112a via the opening 143 and the opening 141. The metal oxide film 108f also includes a region in contact with the top surface and a side surface of the conductive layer 202b, a side surface of the insulating layer 110c, a side surface of the insulating layer 110b, a side surface of the insulating layer 110a, and the top surface of the conductive layer 202a via the opening 243 and the opening 241.

The description that can be used for the method for forming the metal oxide film 108f and the heat treatment for the metal oxide film 108f described in <Manufacturing method example 1> can be applied to the details of the method for forming the metal oxide film 108f and the heat treatment for the metal oxide film 108f.

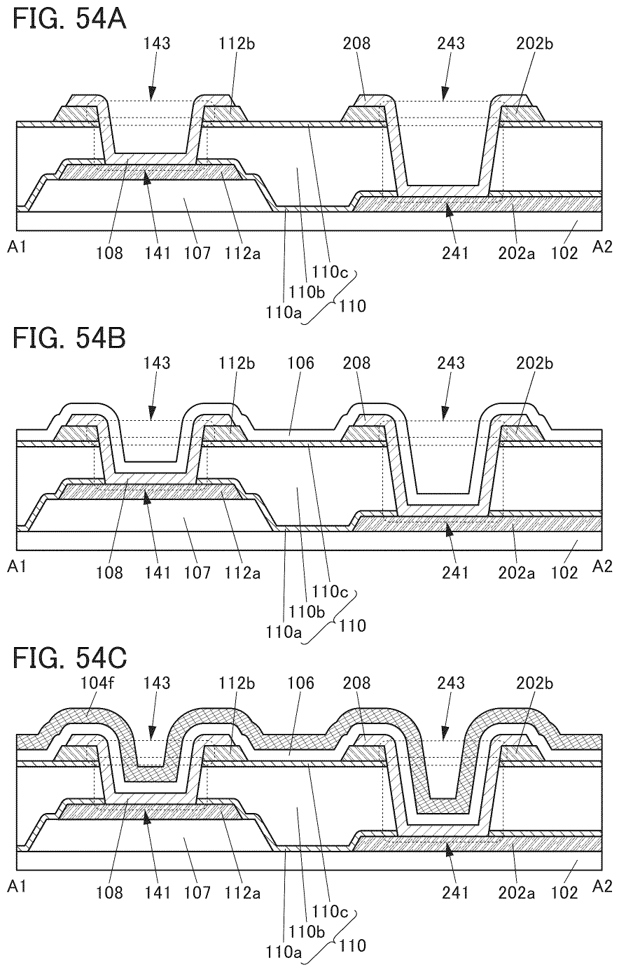

Next, the metal oxide film 108f is processed into an island shape to form the semiconductor layer 108 in a region overlapping with the conductive layer 112a and the semiconductor layer 208 in a region overlapping with the conductive layer 202a (FIG. 54A). The semiconductor layer 108 is formed to include a region overlapping with the conductive layer 112a. The semiconductor layer 208 is formed to include a region overlapping with the conductive layer 202a. The semiconductor layer 108 is formed to include a region in contact with the top surface of the conductive layer 112a, the side surface of the insulating layer 110a, the side surface of the insulating layer 110b, the side surface of the insulating layer 110c, and the side surface and the top surface of the conductive layer 112b. The semiconductor layer 208 is formed to include a region in contact with the top surface of the conductive layer 202a, the side surface of the insulating layer 110a, the side surface of the insulating layer 110b, the side surface of the insulating layer 110c, and the side surface and the top surface of the conductive layer 202b.

The description that can be used for the method for forming the semiconductor layer 108 and the semiconductor layer 208 and the heat treatment for the semiconductor layer 108 and the semiconductor layer 208 described in <Manufacturing method example 1> can be applied to the details of the method for forming the semiconductor layer 108 and the semiconductor layer 208 and the heat treatment for the semiconductor layer 108 and the semiconductor layer 208.

### Formation of Insulating Layer 106

Next, the insulating layer 106 is formed to cover the semiconductor layer 108, the conductive layer 112b, the semiconductor layer 208, the conductive layer 202b, and the insulating layer 110 (FIG. 54B). For the formation of the insulating layer 106, the description related to the formation of the insulating layer 106 (FIG. 46B) described in <Manufacturing method example 1> can be referred to.

### Formation of Conductive Layer 104 and Conductive Layer 204

Next, the conductive film 104f to be the conductive layer 104 and the conductive layer 204 is formed over the insulating layer 106 (FIG. 54C). For the formation of the conductive film 104f, the description related to the formation of the conductive film 104f (FIG. 46C) described in <Manufacturing method example 1> can be referred to.

Next, a resist mask (not illustrated) is formed over the conductive film 104f by a photolithography process, and then the conductive film 104f is processed, whereby the conductive layer 104 overlapping with the conductive layer 112a and the semiconductor layer 108 and the conductive layer 204 overlapping with the conductive layer 202a and the semiconductor layer 208 are formed (FIG. 10B). For the formation of the conductive layer 104 and the conductive layer 204, the description related to the formation of the conductive layer 104 and the conductive layer 204 described in <Manufacturing method example 1> can be referred to. By the processing, the thickness of the insulating layer 106 in a portion not overlapping with the conductive layer 104 nor the conductive layer 204 sometimes becomes smaller than the thickness in a portion overlapping with the conductive layer 104 or the conductive layer 204.

Through the above steps, the transistor 100 and the transistor 200C can be manufactured.

Through the above steps, the semiconductor device 10C illustrated in FIG. 10B can be manufactured.

This embodiment can be combined with the other embodiments as appropriate. In this specification, in the case where a plurality of structure examples are shown in one embodiment, the structure examples can be combined as appropriate.

### Embodiment 3

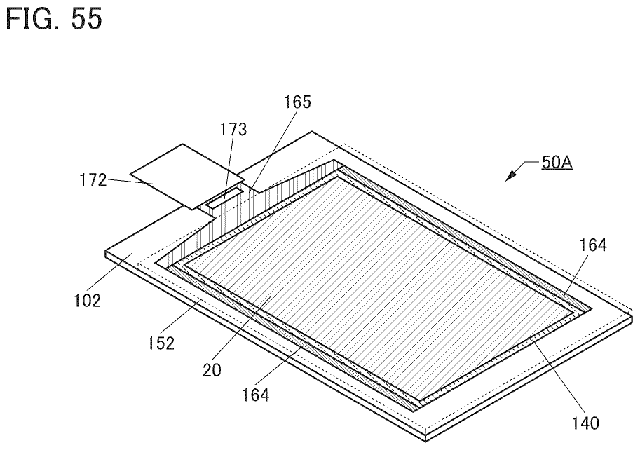

In this embodiment, display apparatuses in each of which the semiconductor device of one embodiment of the present invention can be used will be described with reference to FIG. 55 to FIG. 60.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

### Display Apparatus 50A

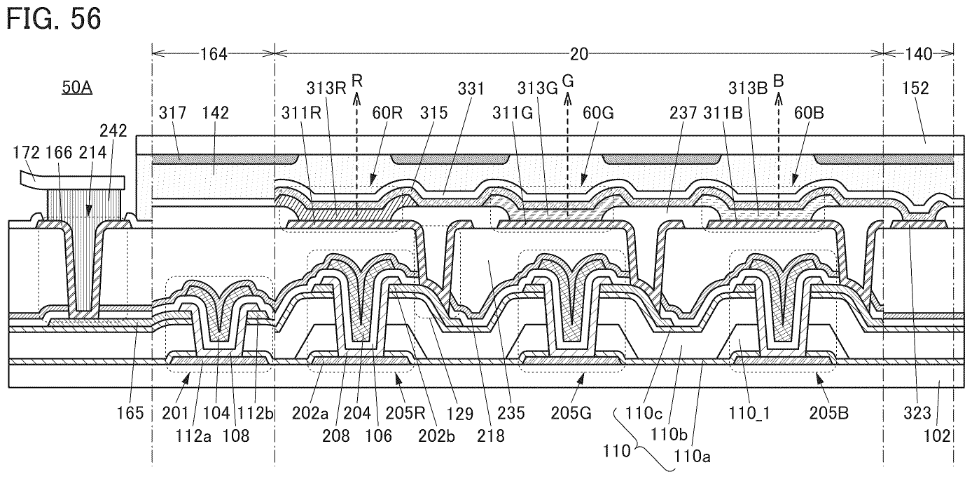

FIG. 55 is a perspective view illustrating a structure example of a display apparatus 50A and FIG. 56 is a cross-sectional view illustrating the structure example of the display apparatus 50A. The structure of the display apparatus 30 described in Embodiment 1 can be applied to the display apparatus 50A.

The display apparatus 50A has a structure in which a substrate 152 and the substrate 102 are attached to each other. In FIG. 55, the substrate 152 is denoted by a dashed line.

The display apparatus 50A includes the display portion 20, a connection portion 140, a circuit 164, a wiring 165, and the like. FIG. 55 illustrates an example in which an IC 173 and an FPC 172 are mounted on the display apparatus 50A. Thus, the structure illustrated in FIG. 55 can be regarded as a display module including the display apparatus 50A, the IC (integrated circuit), and the FPC.

In this specification and the like a display apparatus in which a substrate is equipped with a connector such as an FPC or mounted with an IC is referred to as a display module.

The connection portion 140 is provided outside the display portion 20. The connection portion 140 can be provided along one or more sides of the display portion 20. The number of connection portions 140 may be one or more. FIG. 55 illustrates an example in which the connection portion 140 is provided to surround the four sides of the display portion. A common electrode of a light-emitting element is electrically connected to a conductive layer in the connection portion 140, so that a potential can be supplied to the common electrode through the conductive layer.

The circuit 164 can include at least one of the scan line driver circuit 11, the signal line driver circuit 13, and the power supply circuit 15 illustrated in FIG. 2A and FIG. 3A and the reference potential generation circuit 17 illustrated in FIG. 3A in Embodiment 1.

The wiring 165 has a function of supplying a signal and power to the display portion 20 and the circuit 164. The signal and the power are input to the wiring 165 from the outside through the FPC 172 or input to the wiring 165 from the IC 173.

FIG. 55 illustrates an example in which the IC 173 is provided on the substrate 102 by a COG (Chip On Glass) method, a COF (Chip On Film) method, or the like. The IC 173 can include at least one of the scan line driver circuit 11, the signal line driver circuit 13, and the power supply circuit 15 illustrated in FIG. 2A and FIG. 3A and the reference potential generation circuit 17 illustrated in FIG. 3A in Embodiment 1. The display apparatus 50A and the display module may have a structure that is not provided with an IC. The IC may be mounted on the FPC by a COF method, for example.

FIG. 56 illustrates an example of cross sections of part of a region including the FPC 172, part of the circuit 164, part of the display portion 20, part of the connection portion 140, and part of a region including an end portion of the display apparatus 50A.

The display apparatus 50A illustrated in FIG. 56 includes a transistor 201, a transistor 205R, a transistor 205G, a transistor 205B, a light-emitting element 60R, a light-emitting element 60G, a light-emitting element 60B, and the like between the substrate 102 and the substrate 152. The light-emitting element 60R includes a pixel electrode 311R and a layer 313R. The light-emitting element 60G includes a pixel electrode 311G and a layer 313G. The light-emitting element 60B includes a pixel electrode 311B and a layer 313B. A common electrode 315 is provided over the layer 313R, the layer 313G, and the layer 313B. The common electrode 315 is shared by the light-emitting element 60R, the light-emitting element 60G, and the light-emitting element 60B. FIG. 56 illustrates an example in which the conductive layer 202b included in the transistor 205R is electrically connected to the pixel electrode 311R, the conductive layer 202b included in the transistor 205G is electrically connected to the pixel electrode 311G, and the conductive layer 202b included in the transistor 205B is electrically connected to the pixel electrode 311B.

An insulating layer 237 is provided to cover an end portion of the top surface of each of the pixel electrode 311R, the pixel electrode 311G, and the pixel electrode 311B. The pixel electrode 311R, the pixel electrode 311G, and the pixel electrode 311B are provided with depressed portions so as to cover openings 129 provided in the insulating layer 106, an insulating layer 218, and an insulating layer 235. The insulating layer 237 is embedded in each of the depressed portions.

Although FIG. 56 illustrates a plurality of cross sections of the insulating layer 237, the insulating layer 237 is one continuous layer when the display apparatus 50A is seen from above. In other words, the display apparatus 50A can have a structure including one insulating layer 237. The display apparatus 50A may include a plurality of the insulating layers 237 that are separated from each other.

The layer 313R, the layer 313G, and the layer 313B each include at least a light-emitting layer. For example, the layer 313R includes a light-emitting layer emitting red light, the layer 313G includes a light-emitting layer emitting green light, and the layer 313B includes a light-emitting layer emitting blue light. In other words, the layer 313R includes a light-emitting substance emitting red light, the layer 313G includes a light-emitting substance emitting green light, and the layer 313B includes a light-emitting substance emitting blue light. Accordingly, the light-emitting element 60R can emit red light, the light-emitting element 60G can emit green light, and the light-emitting element 60B can emit blue light.

The layer 313R, the layer 313G, and the layer 313B may each include one or more of a hole-injection layer, a hole-transport layer, a hole-blocking layer, a charge-generation layer, an electron-blocking layer, an electron-transport layer, and an electron-injection layer.

For example, the layer 313R, the layer 313G, and the layer 313B may each include a hole-injection layer, a hole-transport layer, a light-emitting layer, an electron-transport layer, and an electron-injection layer in this order. Alternatively, the layer 313R, the layer 313G, and the layer 313B may each include an electron-injection layer, an electron-transport layer, a light-emitting layer, a hole-transport layer, and a hole-injection layer in this order. Furthermore, an electron-blocking layer may be included between a hole-transport layer and a light-emitting layer, or a hole-blocking layer may be included between an electron-transport layer and a light-emitting layer.

For each of the light-emitting element 60R, the light-emitting element 60G, and the light-emitting element 60B, a single structure (a structure including only one light-emitting unit) may be employed, or a tandem structure (a structure including a plurality of light-emitting units) may be employed. The light-emitting unit includes at least one light-emitting layer.

In the case where the light-emitting element 60R, the light-emitting element 60G, and the light-emitting element 60B have a tandem structure, the layer 313R preferably has a structure including a plurality of light-emitting units that emit red light, the layer 313G preferably has a structure including a plurality of light-emitting units that emit green light, and the layer 313B preferably has a structure including a plurality of light-emitting units that emit blue light. A charge-generation layer is preferably provided between the light-emitting units. In the case where the light-emitting element 60R, the light-emitting element 60G, and the light-emitting element 60B have a tandem structure, for example, the layer 313R, the layer 313G, and the layer 313B can each include a first light-emitting unit, a charge-generation layer over the first light-emitting unit, and a second light-emitting unit over the charge-generation layer.

The layer 313R, the layer 313G, and the layer 313B can each be formed by a vacuum evaporation method using a fine metal mask, for example. In a vacuum evaporation method using a fine metal mask, deposition is performed in an area wider than an opening of the fine metal mask in many cases. Thus, the layer 313R, the layer 313G, and the layer 313B can be formed in the area wider than the opening of the fine metal mask. End portions of the layer 313R, the layer 313G, and the layer 313B each have a tapered shape. Here, the layer 313R, the layer 313G, and the layer 313B may also be provided not only over the pixel electrode 311 but also over the insulating layer 237. An ink-jet method or a sputtering method using a fine metal mask may be used to form the layer 313R, the layer 313G, and the layer 313B.

A protective layer 331 is provided over the light-emitting element 60R, the light-emitting element 60G, and the light-emitting element 60B. The protective layer 331 and the substrate 152 are bonded to each other with an adhesive layer 142. The substrate 152 is provided with a light-blocking layer 317. A solid sealing structure, a hollow sealing structure, or the like can be employed to seal the light-emitting element 60R, the light-emitting element 60G, and the light-emitting element 60B. In FIG. 56, a solid sealing structure is employed, in which a space between the substrate 152 and the protective layer 331 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting element 60R, the light-emitting element 60G, nor the light-emitting element 60B. The space may be filled with a resin other than the frame-shaped adhesive layer 142.

The protective layer 331 is provided at least in the display portion 20, and is preferably provided to cover the entire display portion 20. The protective layer 331 is preferably provided to cover not only the display portion 20 but also the connection portion 140 and the circuit 164. It is also preferable that the protective layer 331 be provided to extend to the end portion of the display apparatus 50A.

A connection portion 214 is provided in a region where the substrate 102 and the substrate 152 do not overlap with each other. In the connection portion 214, the wiring 165 is electrically connected to the FPC 172 through a conductive layer 166 and a connection layer 242. The wiring 165 can be provided in the same layer as the conductive layer 112b. Thus, the wiring 165 and the conductive layer 112b can include the same material and can be formed in the same step. For example, the conductive layer 112b and the wiring 165 can be formed by processing the same conductive film. The conductive layer 166 can be provided in the same layer as the pixel electrode 311R, the pixel electrode 311G, and the pixel electrode 311B. Thus, the conductive layer 166, the pixel electrode 311R, the pixel electrode 311G, and the pixel electrode 311B can include the same material and can be formed in the same step. For example, the pixel electrode 311R, the pixel electrode 311G, the pixel electrode 311B, and the conductive layer 166 can be formed by processing the same conductive film. On the top surface of the connection portion 214, the conductive layer 166 is exposed. Thus, the connection portion 214 and the FPC 172 can be electrically connected to each other through the connection layer 242.

The connection portion 214 includes a portion not provided with the protective layer 331 so that the FPC 172 and the conductive layer 166 can be electrically connected to each other. For example, the protective layer 331 is formed over the entire surface of the display apparatus 50A and then a region of the protective layer 331 overlapping with the conductive layer 166 is removed using a mask, so that the conductive layer 166 can be exposed.

A stacked-layer structure of at least one organic layer and a conductive layer may be provided over the conductive layer 166, and the protective layer 331 may be provided over the stacked-layer structure. Then, a separation trigger (a portion that can be a trigger of separation) may be formed in the stacked-layer structure using a laser or a sharp cutter (e.g., a needle or a utility knife) to selectively remove the stacked-layer structure and the protective layer 331 thereover, so that the conductive layer 166 may be exposed. For example, the protective layer 331 can be selectively removed by pressing an adhesive roller against the substrate 102 and then moving the roller relatively while rotating it. Alternatively, an adhesive tape may be attached to the substrate 102 and then peeled. Since the adhesion between the organic layer and the conductive layer or the adhesion between the organic layers is low, separation occurs at the interface between the organic layer and the conductive layer or in the organic layer. Thus, a region of the protective layer 331 overlapping with the conductive layer 166 can be selectively removed. When the organic layer remains over the conductive layer 166, for example, the remaining organic layer can be removed by an organic solvent or the like.

As the organic layer, it is possible to use at least one of the organic layers (a layer functioning as a light-emitting layer, a carrier-blocking layer, a carrier-transport layer, or a carrier-injection layer) used for the layer 313R, the layer 313G, or the layer 313B, for example. The organic layer may be formed at the time of forming the layer 313R, the layer 313G, or the layer 313B, or may be provided separately. The conductive layer can be formed using the same step and the same material as the common electrode 315. An ITO film is preferably formed as the common electrode 315 and the conductive layer, for example. In the case where a stacked-layer structure is employed for the common electrode 315, at least one of the layers included in the common electrode 315 is used as the conductive layer.

The top surface of the conductive layer 166 may be covered with a mask so that the protective layer 331 cannot be formed over the conductive layer 166. As the mask, a metal mask (area metal mask) may be used or a tape or a film having adhesiveness or attachability may be used, for example. The protective layer 331 is formed while the mask is placed and then the mask is removed, whereby the conductive layer 166 can be kept exposed even after the protective layer 331 is formed.

With such a method, a region not provided with the protective layer 331 can be formed in the connection portion 214, and the conductive layer 166 and the FPC 172 can be electrically connected to each other through the connection layer 242 in the region.

A conductive layer 323 is provided over the insulating layer 235 in the connection portion 140. An end portion of the conductive layer 323 is covered with the insulating layer 237. The common electrode 315 is provided over the conductive layer 323; for example, the connection portion 140 includes a region where the conductive layer 323 and the common electrode 315 are in contact with each other. The common electrode 315 is thus electrically connected to the conductive layer 323 provided in the connection portion 140. The conductive layer 323 can be provided in the same layer as the pixel electrode 311R, the pixel electrode 311G, the pixel electrode 311B, and the conductive layer 166. Thus, the conductive layer 323, the pixel electrode 311R, the pixel electrode 311G, the pixel electrode 311B, and the conductive layer 166 can include the same material and can be formed in the same step. For example, the pixel electrode 311R, the pixel electrode 311G, the pixel electrode 311B, the conductive layer 166, and the conductive layer 323 can be formed by processing the same conductive film. It is preferable that none of the layer 313R, the layer 313G, and the layer 313B be formed over the conductive layer 323.

The display apparatus 50A has a top-emission structure. Light emitted from the light-emitting element 60R, the light-emitting element 60G, and the light-emitting element 60B is emitted to the substrate 152 side. Thus, for the substrate 152, a material having a high visible-light-transmitting property is preferably used. By contrast, there is no limitation on the light-transmitting property of a material used for the substrate 102.

For the common electrode 315, a material having a high visible-light-transmitting property is used. A material reflecting visible light is preferably used for each of the pixel electrode 311R, the pixel electrode 311G, and the pixel electrode 311B.

The transistor 201 and the transistor 205 (the transistor 205R, the transistor 205G, and the transistor 205B) are each formed over the substrate 102. These transistors can be manufactured using the same material in the same process. Among the transistors included in the semiconductor device 10 or the like described in Embodiment 1, a transistor having a short channel length (the transistor 100 or the like) can be suitably used as the transistor 201, for example. Among the transistors included in the semiconductor device 10 or the like described in Embodiment 1, a transistor having a long channel length (the transistor 200 or the like) can be suitably used as the transistor 205, for example. The transistor 201 provided in the circuit 164 can be the transistor included in the scan line driver circuit 11, the signal line driver circuit 13, or the power supply circuit 15 illustrated in FIG. 2A and FIG. 3A, or the reference potential generation circuit 17 illustrated in FIG. 3A in Embodiment 1.

The transistor included in the circuit 164 and the transistor included in the display portion 20 may have the same structure or different structures. A plurality of transistors included in the circuit 164 may have the same structure or two or more kinds of structures. Similarly, a plurality of transistors included in the display portion 20 may have the same structure or two or more kinds of structures.

All of the transistors included in the display portion 20 may be OS transistors or all of the transistors included in the display portion 20 may be Si transistors; alternatively, some of the transistors included in the display portion 20 may be OS transistors and the others may be Si transistors.

When both an LTPS transistor and an OS transistor are used in the display portion 20, for example, a display apparatus with low power consumption and high driving capability can be obtained. A structure in which an LTPS transistor and an OS transistor are used in combination is referred to as LTPO in some cases. In the case where the structure of the display portion 20 is LTPO, an OS transistor can be used as the selection transistor provided in the pixel circuit, and an LTPS transistor can be used as the driving transistor, for example. With the use of an OS transistor as the selection transistor, image data in the pixel can be retained even when the frame frequency is extremely low (e.g., lower than or equal to 1 fps). Thus, power consumption of the display apparatus can be reduced by stopping the driver circuit in displaying a still image. When an LTPS transistor is used as the driving transistor, the amount of current flowing through the light-emitting element 60 can be increased.

The light-blocking layer 317 is preferably provided on the surface of the substrate 152 on the substrate 102 side. The light-blocking layer 317 can be provided between adjacent light-emitting elements 60, in the connection portion 140, and in the circuit 164, for example. The light-blocking layer 317 may be provided between the protective layer 331 and the adhesive layer 142. A variety of optical members can be placed on the outer side of the substrate 152.

As the connection layer 242, an anisotropic conductive film (ACF), an anisotropic conductive paste (ACP), or the like can be used.

### Display Apparatus 50B

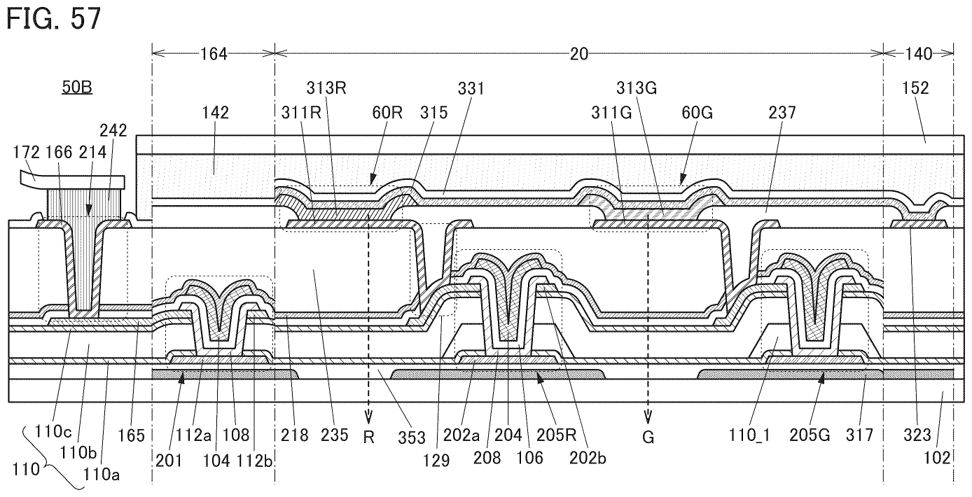

FIG. 57 is a cross-sectional view illustrating a structure example of a display apparatus 50B. The display apparatus 50B is a variation example of the display apparatus 50A and is different from the display apparatus 50A in being a bottom-emission display device, for example.

In the display apparatus 50B, light emitted from the light-emitting element 60 is emitted to the substrate 102 side. For the substrate 102, a material having a high visible-light-transmitting property is preferably used. By contrast, there is no limitation on the light-transmitting property of a material used for the substrate 152.

The light-blocking layer 317 is preferably provided between the substrate 102 and the transistor 201 and between the substrate 102 and the transistor 205. FIG. 57 illustrates an example in which the light-blocking layer 317 is provided over the substrate 102, an insulating layer 353 is provided over the light-blocking layer 317 and the substrate 102, and the transistor 201, the transistor 205, and the like are provided over the insulating layer 353.

A material having a high visible-light-transmitting property is used for each of the pixel electrode 311R, the pixel electrode 311G, and the pixel electrode 311B (not illustrated). A material reflecting visible light is preferably used for the common electrode 315.

### Display Apparatus 50C

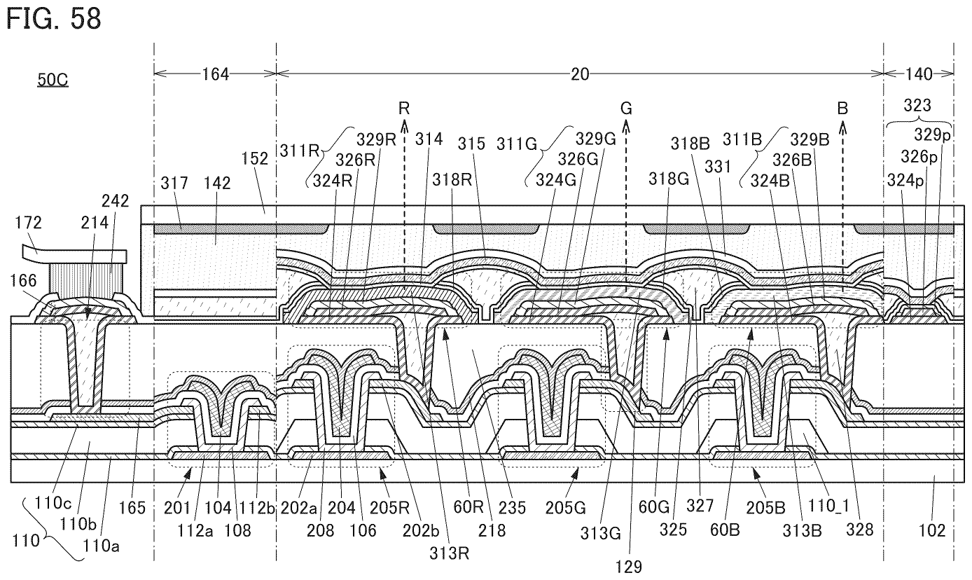

FIG. 58 is a cross-sectional view illustrating a structure example of a display apparatus 50C. The display apparatus 50C is a variation example of the display apparatus 50A and is different from the display apparatus 50A in the structures of the light-emitting element 60R, the light-emitting element 60G, and the light-emitting element 60B, for example. Furthermore, the display apparatus 50C is different from the display apparatus 50A in the structures of the pixel electrode 311R, the pixel electrode 311G, the pixel electrode 311B, the conductive layer 166, and the conductive layer 323. In addition, the display apparatus 50C is different from the display apparatus 50A in that the insulating layer 237 is not included, the layer 313 (the layer 313R, the layer 313G, and the layer 313B) covers the top surface and a side surface of the pixel electrode 311, and a layer 328, an insulating layer 325, an insulating layer 327, and a common layer 314 are included.

As illustrated in FIG. 58, the pixel electrode 311 included in the light-emitting element 60 has a stacked-layer structure including a conductive layer 324, a conductive layer 326 over the conductive layer 324, and a conductive layer 329 over the conductive layer 326. Here, the conductive layer 324, the conductive layer 326, and the conductive layer 329 included in the pixel electrode 311R are referred to as a conductive layer 324R, a conductive layer 326R, and a conductive layer 329R, respectively. The conductive layer 324, the conductive layer 326, and the conductive layer 329 included in the pixel electrode 311G are referred to as a conductive layer 324G, a conductive layer 326G, and a conductive layer 329G, respectively. The conductive layer 324, the conductive layer 326, and the conductive layer 329 included in the pixel electrode 311B are referred to as a conductive layer 324B, a conductive layer 326B, and a conductive layer 329B, respectively.

The conductive layer 324 is electrically connected to the conductive layer 202b included in the transistor 205 via the opening 129 provided in the insulating layer 106, the insulating layer 218, and the insulating layer 235.

An end portion of the conductive layer 326 is positioned inward from an end portion of the conductive layer 324 and an end portion of the conductive layer 329. In other words, the end portion of the conductive layer 326 is positioned over the conductive layer 324, and the top surface and a side surface of the conductive layer 326 are covered with the conductive layer 329.

For the conductive layer 324, no particular limitations are imposed on the properties of transmitting and reflecting visible light. As the conductive layer 324, a conductive layer having a visible-light-transmitting property or a conductive layer having a visible-light-reflecting property can be used. As the conductive layer having a visible-light-transmitting property, an oxide conductive layer can be used, for example. Specifically, an In-Si-Sn oxide (ITSO) can be suitably used for the conductive layer 324. For the conductive layer having a visible-light-reflecting property, a metal such as aluminum, magnesium, titanium, chromium, nickel, copper, yttrium, zirconium, tin, zinc, silver, platinum, gold, molybdenum, tantalum, or tungsten, or an alloy containing the metal as its main component can be used, for example. Examples of the alloy that can be used for the conductive layer 324 include an alloy containing aluminum such as an alloy of aluminum, nickel, and lanthanum (Al—Ni—La); and an alloy containing silver such as an alloy of silver and magnesium and an alloy of silver, palladium, and copper (APC: Ag—Pd—Cu). The conductive layer 324 may have a stacked-layer structure of a conductive layer having a visible-light-transmitting property and a conductive layer having a visible-light-reflecting property over the conductive layer. For the conductive layer 324, a material with high adhesion to the formation surface of the conductive layer 324 (here, the insulating layer 235) is preferably used. In that case, film separation of the conductive layer 324 can be inhibited.

As the conductive layer 326, a conductive layer having a visible-light-reflecting property can be used. The conductive layer 326 may have a stacked-layer structure of a conductive layer having a visible-light-transmitting property and a conductive layer having a visible-light-reflecting property over the conductive layer. For the conductive layer 326, a material that can be used for the conductive layer 324 can be used. Specifically, a stacked-layer structure of an In—Si—Sn oxide (ITSO) and an alloy of silver, palladium, and copper (APC) over the In—Si—Sn oxide (ITSO) can be suitably used for the conductive layer 326.

For the conductive layer 329, a material that can be used for the conductive layer 324 can be used. As the conductive layer 329, a conductive layer having a visible-light-transmitting property can be used. Specifically, an In—Si—Sn oxide (ITSO) can be used for the conductive layer 329.

In the case where a material that is easily oxidized is used for the conductive layer 326, a material that is not easily oxidized is used for the conductive layer 329 and the conductive layer 326 is covered with the conductive layer 329, whereby oxidation of the conductive layer 326 can be inhibited. In addition, precipitation of a metal component included in the conductive layer 326 can be inhibited. In the case where a material containing silver is used for the conductive layer 326, for example, an In—Si—Sn oxide (ITSO) can be suitably used for the conductive layer 329. Thus, oxidation of the conductive layer 326 can be inhibited, and precipitation of silver can be inhibited.

The conductive layer 323 can have, for example, a stacked-layer structure of a conductive layer 324p, a conductive layer 326p over the conductive layer 324p, and a conductive layer 329p over the conductive layer 326p. The conductive layer 324p can be provided in the same layer as the conductive layer 324R, the conductive layer 324G, and the conductive layer 324B. Thus, the conductive layer 324p, the conductive layer 324R, the conductive layer 324G, and the conductive layer 324B can include the same material and can be formed in the same step. For example, the conductive layer 324R, the conductive layer 324G, the conductive layer 324B, and the conductive layer 324p can be formed by processing the same conductive film. The conductive layer 326p, the conductive layer 326R, the conductive layer 326G, and the conductive layer 326B can include the same material and can be formed in the same step. For example, the conductive layer 326R, the conductive layer 326G, the conductive layer 326B, and the conductive layer 326p can be formed by processing the same conductive film. Furthermore, the conductive layer 329p, the conductive layer 329R, the conductive layer 329G, and the conductive layer 329B can include the same material and can be formed in the same step. For example, the conductive layer 329R, the conductive layer 329G, the conductive layer 329B, and the conductive layer 329p can be formed by processing the same conductive film.

FIG. 58 illustrates an example in which the thickness of the conductive layer 329p is different from the thicknesses of the conductive layer 329R, the conductive layer 329G, and the conductive layer 329B. The thicknesses of the conductive layer 329p, the conductive layer 329R, the conductive layer 329G, and the conductive layer 329B may be different depending on the resistivities of materials used for these layers. In the case of making the thicknesses different, the conductive layer 329p may be formed in a step different from a step of forming the conductive layer 329R, the conductive layer 329G, and the conductive layer 329B. Alternatively, some formation steps may be common between the conductive layer 329p and the conductive layer 329R, the conductive layer 329G, and the conductive layer 329B.

Depressed portions are formed in the conductive layer 324R, the conductive layer 324G, and the conductive layer 324B so as to cover the openings 129. The layer 328 is embedded in each of the depressed portions.

The layer 328 has a planarization function for the depressed portions of the conductive layer 324R, the conductive layer 324G, and the conductive layer 324B. The conductive layer 326R electrically connected to the conductive layer 324R is provided over the conductive layer 324R and the layer 328. The conductive layer 326G electrically connected to the conductive layer 324G is provided over the conductive layer 324G and the layer 328. The conductive layer 326B electrically connected to the conductive layer 324B is provided over the conductive layer 324B and the layer 328. Accordingly, regions overlapping with the depressed portions of the conductive layer 324R, the conductive layer 324G, and the conductive layer 324B can function as light-emitting regions, increasing the aperture ratio of the pixels.

The layer 328 may be an insulating layer or a conductive layer. A variety of inorganic insulating materials, organic insulating materials, or conductive materials can be used for the layer 328 as appropriate. Specifically, the layer 328 is preferably formed using an insulating material and is particularly preferably formed using an organic insulating material.

In the case where the layer 328 is a conductive layer, the layer 328 can function as part of a pixel electrode.

The layer 328 included in the display apparatus 50C can also be used in the display apparatus 50A and the display apparatus 50B. For example, instead of the insulating layer 237, the layer 328 can be embedded in at least part of the depressed portions in the conductive layer 324R, the conductive layer 324G, and the conductive layer 324B.

FIG. 58 illustrates an example in which an end portion of the layer 313 is positioned outward from an end portion of the pixel electrode 311. The layer 313 is formed to cover the end portion of the pixel electrode 311. Such a structure enables the entire top surface of the pixel electrode 311 to be a light-emitting region, and the aperture ratio can be increased as compared with the structure in which the end portion of the island-shaped layer 313 is positioned inward from the end portion of the pixel electrode 311. Covering the side surface of the pixel electrode 311 with the layer 313 can inhibit contact between the pixel electrode 311 and the common electrode 315, thereby inhibiting a short circuit of the light-emitting element 60.

The insulating layer 237 is not provided between the pixel electrode 311 and the layer 313. Thus, the distance between adjacent light-emitting elements 60 can be shortened. Accordingly, the display apparatus 50C can be a high-resolution or high-definition display apparatus. In addition, a mask for forming the insulating layer is not needed, which leads to a reduction in manufacturing cost of the display apparatus.

The layer 313 can be formed by a photolithography method and an etching method, for example. Specifically, the pixel electrodes 311 are formed for respective subpixels, and then a film to be the layer 313 is formed across the plurality of pixel electrodes 311. Next, a mask layer (also referred to as a sacrificial layer) is formed over the film to be the layer 313, and a resist mask is formed over the mask layer by a photolithography method. After that, the mask layer and the film to be the layer 313 are processed by an etching method, for example, and the resist mask is removed. The mask layer has a two-layer structure of a first mask layer and a second mask layer over the first mask layer, for example. In that case, a resist mask is formed over the second mask layer and the second mask layer is processed. Then, the resist mask is removed. After that, the first mask layer and the film to be the layer 313 are processed using the second mask layer as a hard mask, for example. In this manner, one island-shaped layer 313 is formed for every pixel electrode 311. Thus, the layer 313 can be divided into island-shaped layers 313 for respective subpixels. By performing a series of steps from the formation of the film to be the layer 313 to the processing of the film three times, for example, the layer 313R, the layer 313G, and the layer 313B can be separately formed.

In this specification and the like, a mask layer refers to a layer that is positioned above at least a light-emitting layer (specifically, a layer processed into an island shape among layers included in an EL layer) and has a function of protecting the light-emitting layer in the manufacturing process.

When the island-shaped layer 313 is formed without using a fine metal mask, the formed layer 313 can have a minute size. Providing the island-shaped layer 313 for each light-emitting element 60 can inhibit leakage current between the adjacent light-emitting elements 60. This can inhibit unintended light emission due to crosstalk, so that a display apparatus with extremely high contrast can be obtained. Specifically, a display apparatus having high current efficiency at low luminance can be obtained.

In this specification and the like, a device manufactured using a metal mask or a fine metal mask (FMM) is sometimes referred to as a device having an MM (metal mask) structure. In this specification and the like, a device manufactured without using a metal mask or an FMM is sometimes referred to as a device having an MML (metal maskless) structure.

In the case where the island-shaped layer 313 is formed without using a fine metal mask, a surface of the layer 313 is exposed in the manufacturing process of the display apparatus. Thus, the layer 313R, the layer 313G, and the layer 313B each preferably include a carrier-transport layer over a light-emitting layer. Alternatively, the layer 313R, the layer 313G, and the layer 313B each preferably include a carrier-blocking layer over the light-emitting layer. Alternatively, the layer 313R, the layer 313G, and the layer 313B each preferably include a carrier-blocking layer over the light-emitting layer, and a carrier-transport layer over the carrier-blocking layer. Accordingly, the light-emitting layer can be inhibited from being exposed on the outermost surface, so that damage to the light-emitting layer can be reduced. Thus, the reliability of the light-emitting element 60 can be increased.

In the case where the light-emitting element 60 has a tandem structure in which, for example, the layer 313 includes a first light-emitting unit, a charge-generation layer over the first light-emitting unit, and a second light-emitting unit over the charge-generation layer, a surface of the second light-emitting unit is exposed in the manufacturing process of the display apparatus. Thus, the second light-emitting unit preferably includes a carrier-transport layer over a light-emitting layer. Alternatively, the second light-emitting unit preferably includes a carrier-blocking layer over the light-emitting layer. Alternatively, the second light-emitting unit preferably includes a carrier-blocking layer over the light-emitting layer, and a carrier-transport layer over the carrier-blocking layer. Accordingly, the light-emitting layer can be inhibited from being exposed on the outermost surface, so that damage to the light-emitting layer can be reduced. Thus, the reliability of the light-emitting element 60 can be increased. In the case where three or more light-emitting units are included, the uppermost light-emitting unit preferably includes one or both of a carrier-transport layer and a carrier-blocking layer over the light-emitting layer.

The upper temperature limits of the compounds included in the layer 313R, the layer 313G, and the layer 313B are each preferably higher than or equal to 100° C. and lower than or equal to 180° C., further preferably higher than or equal to 120° C. and lower than or equal to 180° C., still further preferably higher than or equal to 140° C. and lower than or equal to 180° C. For example, the glass transition points (Tg) of these compounds are each preferably higher than or equal to 100° C. and lower than or equal to 180° C., further preferably higher than or equal to 120° C. and lower than or equal to 180° C., still further preferably higher than or equal to 140° C. and lower than or equal to 180° C. This inhibits a reduction in light emission efficiency and a decrease in lifetime which are due to damage to the layer 313R, the layer 313G, and the layer 313B by heat applied in the process.

In a region between adjacent light-emitting elements 60, the insulating layer 325 and the insulating layer 327 over the insulating layer 325 are provided. Although FIG. 58 illustrates a plurality of cross sections of the insulating layer 325 and the insulating layer 327, each of the insulating layer 325 and the insulating layer 327 is one continuous layer when the display apparatus 50C is seen from above. In other words, the display apparatus 50C can have a structure including one insulating layer 325 and one insulating layer 327, for example. The display apparatus 50C may include a plurality of the insulating layers 325 that are separated from each other, and may include a plurality of the insulating layers 327 that are separated from each other.

The insulating layer 325 preferably includes regions in contact with side surfaces of the layer 313R, the layer 313G, and the layer 313B. When a structure is employed in which the insulating layer 325 includes regions in contact with the layer 313R, the layer 313G, and the layer 313B, film separation of the layer 313R, the layer 313G, and the layer 313B can be inhibited. When the insulating layer 325 is closely attached to the layer 313R, the layer 313G, or the layer 313B, the effect of fixing or bonding the adjacent layers 313 by the insulating layer 325 is obtained. Thus, the reliability of the light-emitting element 60 can be increased. In addition, the yield of the light-emitting element 60 can be increased.

For the insulating layer 325, a material that can be used for the protective layer 331 can be used, and an inorganic material can be used, for example. It is particularly preferable to use aluminum oxide for the insulating layer 325 because the etching selectivity of the insulating layer 325 and the layer 313 can be increased to protect the layer 313.

The insulating layer 325 preferably has a function of a barrier insulating layer against at least one of water and oxygen. The insulating layer 325 preferably has a function of inhibiting diffusion of at least one of water and oxygen. The insulating layer 325 preferably has a function of capturing or fixing (also referred to as gettering) at least one of water and oxygen.

When the insulating layer 325 has a function of a barrier insulating layer or a gettering function, entry of impurities (typically, at least one of water and oxygen) that might diffuse into the light-emitting elements from the outside can be inhibited. With this structure, a highly reliable light-emitting element and a highly reliable display apparatus can be obtained.

The insulating layer 327 is provided over the insulating layer 325 to fill a depressed portion formed on the insulating layer 325. The insulating layer 327 can overlap with the side surface and part of the top surface of each of the layer 313R, the layer 313G, and the layer 313B with the insulating layer 325 therebetween. The insulating layer 327 preferably covers at least part of a side surface of the insulating layer 325. Providing the insulating layer 325 and the insulating layer 327 enables a gap between the adjacent island-shaped layers to be filled, whereby unevenness of the formation surface of the layers to be provided over the island-shaped layers, e.g., the common electrode 315, can be reduced and the coverage with the layers can be improved. This can inhibit a connection defect due to the step disconnection of the common electrode 315. In addition, an increase in electric resistance, which is caused by local thinning of the common electrode 315 due to the step, can be inhibited. The top surface of the insulating layer 327 preferably has a shape with higher flatness; however, it may have a projecting portion, a convex surface, a concave surface, or a depressed portion.

An insulating layer including an organic material can be suitably used as the insulating layer 327. As the organic material, a photosensitive organic resin is preferably used, and for example, a photosensitive resin composition containing an acrylic resin is preferably used. In this specification and the like, an acrylic resin refers to not only a polymethacrylic acid ester or a methacrylic resin but also all the acrylic polymer in a broad sense in some cases. The materials that can be used for the insulating layer 327 can also be used for the layer 328.

A mask layer 318R is positioned over the layer 313R included in the light-emitting element 60R, a mask layer 318G is positioned over the layer 313G included in the light-emitting element 60G, and a mask layer 318B is positioned over the layer 313B included in the light-emitting element 60B. The mask layer 318 (the mask layer 318R, the mask layer 318G, and the mask layer 318B) is provided to surround the light-emitting region. In other words, the mask layer 318 has an opening in a portion overlapping with the light-emitting region. The mask layer 318R is a remaining part of the mask layer provided over the layer 313R at the time of forming the layer 313R. Similarly, the mask layer 318G is a remaining part of the mask layer provided at the time of forming the layer 313G, and the mask layer 318B is a remaining part of the mask layer provided at the time of forming the layer 313B. As described above, the mask layer used to protect the layer 313 in manufacture of the display apparatus of one embodiment of the present invention may partly remain in the display apparatus.

Although the mask layer 318 has a single-layer structure in FIG. 58, the mask layer 318 may have a stacked-layer structure. For example, the mask layer 318 may have a two-layer structure or a stacked-layer structure of three or more layers. After the formation of the film to be the layer 313, a first mask layer and a second mask layer over the first mask layer are formed as mask layers in some cases. After that, the layer 313R, the layer 313G, and the layer 313B are formed using the mask layers, the second mask layer is removed, and then an opening reaching the layer 313 is formed in the first mask layer, in some cases. In that case, the mask layer 318 remaining in the display apparatus 50C has a single-layer structure. In other words, the number of layers included in the mask layer 318 may be smaller than the number of layers included in the mask layer formed in the manufacturing process of the display apparatus 50C.

In the display apparatus 50C, the common layer 314 is provided over the layer 313R, the layer 313G, the layer 313B, and the insulating layer 327, and the common electrode 315 is provided over the common layer 314. Like the common electrode 315, the common layer 314 is shared by the light-emitting element 60R, the light-emitting element 60G, and the light-emitting element 60B. In the case where the light-emitting element 60 includes the common layer 314, the layer 313 and the common layer 314 can be collectively referred to as an EL layer. The common layer 314 is not necessarily included in the EL layer.

The common layer 314 includes an electron-injection layer or a hole-injection layer, for example. Alternatively, the common layer 314 may include a stack of an electron-transport layer and an electron-injection layer, or may include a stack of a hole-transport layer and a hole-injection layer. Here, a structure can be employed in which the layer included in the common layer 314 is not included in the layer 313. For example, when the common layer 314 includes an electron-injection layer, the layer 313 does not necessarily include an electron-injection layer. When the common layer 314 includes a hole-injection layer, the layer 313 does not necessarily include a hole-injection layer.

In the case where the common layer 314 is provided in the display apparatus, the common electrode 315 can be formed successively after the formation of the common layer 314, without interposing a step of etching or the like. For example, after the common layer 314 is formed in a vacuum, the common electrode 315 can be formed in a vacuum without exposing the substrate 102 to the air. Accordingly, the lower surface of the common electrode 315 can be a clean surface, as compared with the case where the common layer 314 is not provided in the display apparatus. Thus, in the case where the surface of the layer 313 is exposed to, for example, the air after the formation of the layer 313, the common layer 314 is preferably provided in the display apparatus.

FIG. 58 illustrates an example in which the common layer 314 is not provided in the connection portion 140. By using a mask for specifying a formation area (also referred to as an area mask or a rough metal mask to distinguish from a fine metal mask), the common layer 314 and the common electrode 315 can be formed in different regions, for example.

Here, in the case where the electric resistance of the common layer 314 in the thickness direction is low enough to be negligible, electrical continuity between the conductive layer 323 and the common electrode 315 can be maintained even when the common layer 314 is provided between the conductive layer 323 and the common electrode 315. When the common layer 314 is provided not only in the display portion 20 but also in the connection portion 140, the common layer 314 can be formed, for example, without using a metal mask such as an area mask. Thus, the manufacturing process of the display apparatus 50C can be simplified.

Although the display apparatus 50C in FIG. 58 is a top-emission display apparatus, the display apparatus 50C may be a bottom-emission display apparatus or a dual-emission display apparatus.

The structure of the display apparatus 50C is also applicable to the display apparatus 50A and the display apparatus 50B. Specifically, at least one of the structure of the light-emitting element 60, the point where the insulating layer 237 is not included, the point where the insulating layer 325 is included, and the point where the insulating layer 327 is included can be applied to the display apparatus 50A and the display apparatus 50B.

### Display Apparatus 50D

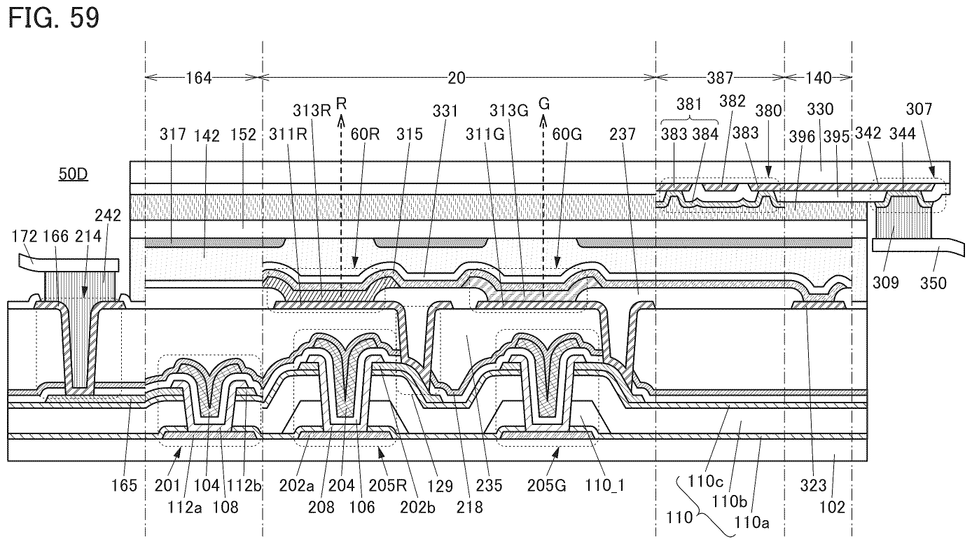

FIG. 59 is a cross-sectional view illustrating a structure example of a display apparatus 50D. The display apparatus 50D is a variation example of the display apparatus 50A and is different from the display apparatus 50A in that a touch sensor is included. FIG. 59 illustrates a structure example of a sensing portion 387 provided with a touch sensor.

In this specification and the like, a display apparatus including a touch sensor is referred to as a touch panel.

In the display apparatus 50D, an adhesive layer 396 is provided over the substrate 152, and an insulating layer 395 is provided over the adhesive layer 396. Thus, the substrate 152 and the insulating layer 395 are attached to each other with the adhesive layer 396. A substrate 330 is provided over the insulating layer 395.

In the sensing portion 387, a sensing element 380 (also referred to as a sensing device, a sensor element, or a sensor device) is provided as a touch sensor on a surface of the substrate 330 on the substrate 152 side. The sensing element 380 can sense the approach or contact of a sensing target such as a finger or a stylus to the display apparatus 50D.

The sensing element 380 includes an electrode 381 and an electrode 382. FIG. 59 illustrates an example where the electrode 381 includes an electrode 383 and an electrode 384.

The electrode 382 and the electrode 383 can be provided in the same layer. Thus, the electrode 382 and the electrode 383 can include the same material and can be formed in the same step. For example, the electrode 382 and the electrode 383 can be formed by processing the same conductive film.

In the sensing portion 387, the insulating layer 395 is provided to cover at least part of the electrode 383 and the electrode 382. The electrode 384 is electrically connected to two electrodes 383, between which the electrode 382 is provided, through openings provided in the insulating layer 395. Thus, the electrode 384 includes a region overlapping with the electrode 382.

For the electrode 382, the electrode 383, and the electrode 384, a material having a low resistivity, for specific example, a metal, is preferably used. For the electrode 382, the electrode 383, and the electrode 384, a metal mesh can be used, for example. At least one of the electrode 382, the electrode 383, and the electrode 384 may be a stack of a metal layer and a layer having low reflectance (also referred to as a dark-colored layer). Examples of the dark-colored layer include a layer including copper oxide and a layer including copper chloride or tellurium chloride. For the dark-colored layer, a metal microparticle such as an Ag particle, an Ag fiber, or a Cu particle; a carbon nanoparticle such as a carbon nanotube (CNT) or graphene; a conductive high molecule such as PEDOT, polyaniline, or polypyrrole; or the like can be used. Furthermore, for the electrode 382, the electrode 383, and the electrode 384, a material that can be used for the pixel electrode 311 can be used, for example.

The electrode 383 may include a region overlapping with the light-emitting element 60, for example. In that case, a material having a high visible-light-transmitting property is used for the electrode 383, for example. Examples of the material include a material that can be used for the common electrode 315.

A wiring 342, a conductive layer 344, a connection layer 309, and an FPC 350 are provided in a region of the substrate 330 that does not overlap with the substrate 152. The wiring 342 and the FPC 350 are electrically connected to each other through the conductive layer 344 and the connection layer 309 in a connection portion 307. The wiring 342 can be provided in the same layer as the electrode 382 and the electrode 383. Thus, the wiring 342, the electrode 382, and the electrode 383 can include the same material and can be formed in the same step. For example, the wiring 342, the electrode 382, and the electrode 383 can be formed by processing the same conductive film. The conductive layer 344 can be provided in the same layer as the electrode 384. Thus, the conductive layer 344 and the electrode 384 can include the same material and can be formed in the same step. For example, the conductive layer 344 and the electrode 384 can be formed by processing the same conductive film.

The connection portion 307 has a portion not provided with t the insulating layer 395 so that the FPC 350 and the conductive layer 344 are electrically connected to each other. For example, after the insulating layer 395 is formed over the entire substrate 330, an opening reaching the wiring 342 is formed in the insulating layer 395, whereby the wiring 342 can be exposed. After that, the conductive layer 344 is formed, and the connection layer 309 and the FPC 350 are provided to be electrically connected to the conductive layer 344. In the above manner, the wiring 342 and the FPC 350 can be electrically connected to each other via the conductive layer 344 and the connection layer 309.

For the connection layer 309, an ACF, an ACP, or the like can be used like the connection layer 242.

The sensing element 380 may be provided in the display apparatus 50B and the display apparatus 50C. As a result, the display apparatus 50B and the display apparatus 50C can each have a function of a touch panel.

The sensing element 380 included in FIG. 59 is a capacitive sensing element. Examples of the capacitive type include a surface capacitive type and a projected capacitive type. Examples of the projected capacitive type include a self-capacitive type and a mutual capacitive type. With the use of a mutual capacitive type, simultaneous sensing of multiple points can be achieved. The sensing element included in the display apparatus of one embodiment of the present invention is not limited to a capacitive type, and a variety of types such as a resistive type, a surface acoustic wave type, an infrared type, an optical type, and a pressure-sensitive type can be used.

The display apparatus 50D illustrated in FIG. 59 has a structure in which the sensing element 380 is formed over the substrate 330 and the substrate 152 is attached thereto; however, one embodiment of the present invention is not limited thereto. For example, the sensing element 380 may be formed between the substrate 102 and the substrate 152.

### Display Apparatus 50E

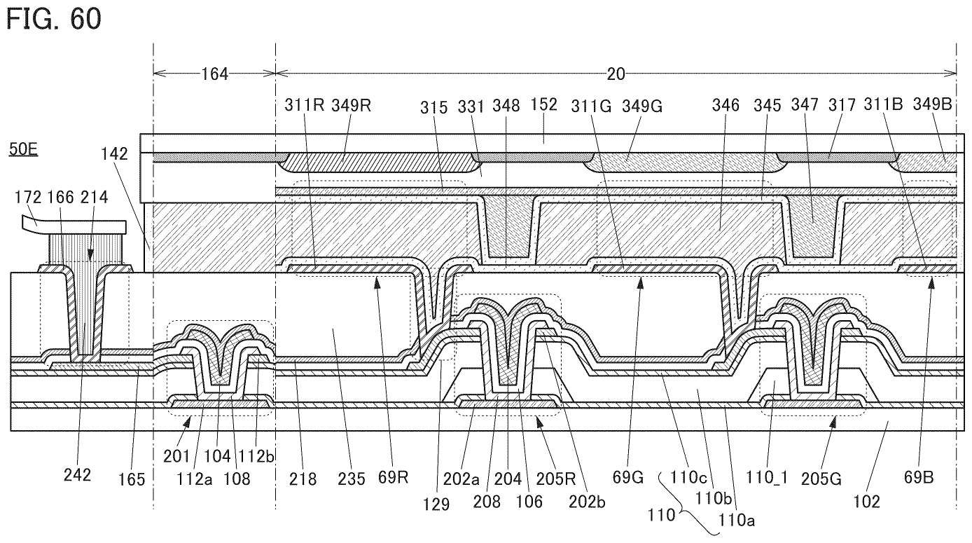

FIG. 60 is a cross-sectional view illustrating a structure example of a display apparatus 50E. The display apparatus 50E is a variation example of the display apparatus 50A and is different from the display apparatus 50A in that a liquid crystal element 69 is included as a display element. FIG. 60 illustrates a liquid crystal element 69R, a liquid crystal element 69G, and a liquid crystal element 69B as the liquid crystal elements 69.

The liquid crystal element 69 includes the pixel electrode 311 and the common electrode 315, and a liquid crystal layer 346 is provided between the pixel electrode 311 and the common electrode 315. In FIG. 60, the pixel electrode 311 included in the liquid crystal element 69R is referred to as the pixel electrode 311R, the pixel electrode 311 included in the liquid crystal element 69G is referred to as the pixel electrode 311G, and the pixel electrode 311 included in the liquid crystal element 69B is referred to as the pixel electrode 311B. An insulating layer 348 is provided between the pixel electrode 311 and the liquid crystal layer 346, and an insulating layer 345 is provided between the liquid crystal layer 346 and the common electrode 315. The insulating layer 348 and the insulating layer 345 each have a function of an alignment film.

A spacer 347 is provided between the liquid crystal elements 69. The spacer 347 is a columnar spacer obtained by selectively etching an insulating layer and is provided to control the distance (cell gap) between the pixel electrode 311 and the common electrode 315. The spacer 347 may be a spherical spacer.

The protective layer 331 is provided over the common electrode 315. The light-blocking layer 317 is provided over the protective layer 331. Furthermore, in the display portion 20, a coloring layer 349R, a coloring layer 349G, or a coloring layer 349B is provided in a region where the light-blocking layer 317 is not provided over the protective layer 331. Here, an end portion of the coloring layer 349R, an end portion of the coloring layer 349G, and an end portion of the coloring layer 349B each overlap with an end portion of the light-blocking layer 317. The substrate 152 is provided over the light-blocking layer 317, the coloring layer 349R, the coloring layer 349G, and the coloring layer 349B. The insulating layer 235 and the protective layer 331 are bonded to each other with the adhesive layer 142.

To manufacture the display apparatus 50E, components up to the common electrode 315 are formed over the substrate 102. Accordingly, the transistor 201, the transistor 205, the liquid crystal element 69, and the like are formed over the substrate 102. Furthermore, the light-blocking layer 317 is formed over the substrate 152, and then the coloring layer 349 (the coloring layer 349R, the coloring layer 349G, and the coloring layer 349B) is formed over the substrate 152. After the light-blocking layer 317 and the coloring layer 349 are formed over the substrate 152, the protective layer 331 is formed over the light-blocking layer 317 and the coloring layer 349. After that, the substrate 102 and the substrate 152 are bonded to each other with the adhesive layer 142. Specifically, the insulating layer 235 over the substrate 102 and the protective layer 331 over the substrate 152 are bonded to each other with the adhesive layer 142. In the above manner, the display apparatus 50E can be manufactured.

A backlight is provided in the display apparatus 50E. The backlight can be provided on the substrate 102 side, specifically, on the outer side of the substrate 102 (the side opposite to the formation surfaces of the transistor 201 and the transistor 205). In the case where the display apparatus 50E is a reflective liquid crystal display apparatus, the display apparatus 50E is not necessarily provided with a backlight.

The coloring layer 349R includes a region overlapping with the liquid crystal element 69R, and has a transmittance of red light higher than the transmittance of light of other colors, for example. Thus, light emitted from the liquid crystal element 69R is extracted as red light to the outside of the display apparatus 50E. The coloring layer 349G includes a region overlapping with the liquid crystal element 69G, and has a transmittance of green light higher than the transmittance of light of other colors, for example. Thus, light emitted from the liquid crystal element 69G is extracted as green light to the outside of the display apparatus 50E. Furthermore, the coloring layer 349B includes a region overlapping with the liquid crystal element 69B, and has a transmittance of blue light higher than the transmittance of light of other colors, for example. Thus, light emitted from the liquid crystal element 69B is extracted as blue light to the outside of the display apparatus 50E. Accordingly, the display apparatus 50E can perform full-color display.

Adjacent coloring layers 349 may include an overlapping region. For example, the adjacent coloring layers 349 may include an overlapping region over the spacer 347. For example, in the cross section illustrated in FIG. 60, one end portion of the coloring layer 349G may overlap with the coloring layer 349R, and the other end portion of the coloring layer 349G may overlap with the coloring layer 349B. Thus, light emitted from the liquid crystal element 69 can be inhibited from entering an adjacent coloring layer 349 to be extracted to the outside of the display apparatus 50E. For example, light emitted from the liquid crystal element 69R can be inhibited from entering the coloring layer 349G to be extracted to the outside of the display apparatus 50E. Accordingly, the display apparatus 50E can be a display apparatus with high display quality. The adjacent coloring layers 349 do not necessarily include an overlapping region. In that case, the light-blocking layer 317 is provided between the adjacent coloring layers 349 as illustrated in FIG. 60, whereby light emitted from the liquid crystal element 69 can be inhibited from entering an adjacent coloring layer 349 to be extracted to the outside of the display apparatus 50E.

Examples of a material that can be used for the coloring layer 349 include a metal material, a resin material, and a resin material containing a pigment or dye. The coloring layer 349 can be formed by an inkjet method, for example. In the case where the display apparatus 50E includes a light-blocking layer, examples of a material that can be used for the light-blocking layer include carbon black, titanium black, a metal, a metal oxide, and a composite oxide containing a solid solution of a plurality of metal oxides. The light-blocking layer can be formed by an inkjet method, for example. A stack of films including the material for the coloring layer can also be used as the light-blocking layer. For example, a stacked-layer structure of a film including a material used for a coloring layer that transmits light of a certain color and a film including a material used for a coloring layer that transmits light of another color can be used.

Although FIG. 60 illustrates an example of a display apparatus including a liquid crystal element with a vertical electric field mode, one embodiment of the present invention is not limited thereto and may be a display apparatus including a liquid crystal element with a horizontal electric field mode, for example. In the case of employing a horizontal electric field mode, a liquid crystal exhibiting a blue phase for which an alignment film is not used may be used. A blue phase is one of liquid crystal phases, which appears just before a cholesteric phase changes into an isotropic phase while the temperature of a cholesteric liquid crystal is increased. Since a blue phase appears only in a narrow temperature range, a liquid crystal composition in which a chiral material is mixed at 5 weight % or more is used for the liquid crystal layer 346 in order to improve the temperature range. A liquid crystal composition that contains a liquid crystal exhibiting a blue phase and a chiral material has a short response time and exhibits optical isotropy. In addition, the liquid crystal composition that contains a liquid crystal exhibiting a blue phase and a chiral material does not need alignment treatment and has small viewing angle dependence. Since an alignment film is not necessarily provided, rubbing treatment is unnecessary. Accordingly, electrostatic breakdown caused by rubbing treatment can be inhibited, and defects or damage of the display apparatus in the manufacturing process can be reduced.

The display apparatus 50E may include the sensing element 380 illustrated in FIG. 59 so as to have a function of a touch panel, for example.

The coloring layer 349R, the coloring layer 349G, and the coloring layer 349B included in the display apparatus 50E may be provided in a display apparatus including the light-emitting element 60, specifically, the display apparatus 50A to the display apparatus 50C, and the like. For example, the coloring layer 349R can be provided to include a region overlapping with the light-emitting element 60R, the coloring layer 349G can be provided to include a region overlapping with the light-emitting element 60G, and the coloring layer 349B can be provided to include a region overlapping with the light-emitting element 60B. In a top-emission display apparatus such as the display apparatus 50A and the display apparatus 50C, for example, the coloring layer 349 can be provided between the light-emitting element 60 and the substrate 152, specifically, the coloring layer 349 can be provided between the protective layer 331 and the substrate 152. For example, the coloring layer 349 can be provided over the protective layer 331; specifically, the coloring layer 349 can be provided to include a region in contact with the protective layer 331. In that case, the protective layer 331 is preferably planarized. Here, when the adjacent coloring layers 349 include an overlapping region, a structure in which the light-blocking layer 317 is not provided can be employed. The coloring layer 349 may be provided on the substrate 152. In that case, for example, a structure can be employed in which part of the coloring layer 349 is in contact with the light-blocking layer 317, in which case an end portion of the coloring layer 349 can overlap with the light-blocking layer 317.

In a bottom-emission display apparatus such as the display apparatus 50B, the coloring layer 349 can be provided between the light-emitting element 60 and the substrate 102. For example, the coloring layer 349 can be provided over the insulating layer 218.

Provision of the coloring layer 349R, the coloring layer 349G, and the coloring layer 349B in the display apparatus including the light-emitting element 60 enables the display portion 20 to display a full-color image even when the light-emitting element 60R, the light-emitting element 60G, and the light-emitting element 60B are light-emitting elements that emit light of the same color, e.g., light-emitting elements that emit white light. When the light-emitting element 60R, the light-emitting element 60G, and the light-emitting element 60B are light-emitting elements that emit light of the same color, the layer 313R, the layer 313G, and the layer 313B can be formed in the same step. This allows simplification of the manufacturing process of the display apparatus and an increase in the yield of the display apparatus. Thus, an inexpensive display apparatus can be achieved. By contrast, a structure without the coloring layer 349 can increase the light extraction efficiency of the display apparatus as compared to the case where the coloring layer 349 is provided. Accordingly, a bright image can be displayed on the display portion 20. In the case of displaying an image with the same luminance on the display portion 20, the emission luminance of the light-emitting element 60 can be lower and thus the power consumption of the display apparatus can be lower in the case of not providing the coloring layer 349 than in the case of providing the coloring layer 349.

Even in the case where the coloring layer 349R, the coloring layer 349G, and the coloring layer 349B are provided in the display apparatus including the light-emitting element 60, the light-emitting element 60R, the light-emitting element 60G, and the light-emitting element 60B may emit different light. For example, in the case where the red light transmittance of the coloring layer 349R is higher than the transmittance of light of other colors, the green light transmittance of the coloring layer 349G is higher than the transmittance of light of other colors, and the blue light transmittance of the coloring layer 349B is higher than the transmittance of light of other colors, the light-emitting element 60R may emit red light, the light-emitting element 60G may emit green light, and the light-emitting element 60B may emit blue light. In that case, providing the coloring layer 349 can improve the color purity of light emitted from a subpixel including the light-emitting element 60. Consequently, a display apparatus with high display quality can be obtained. By contrast, as described above, the structure without the coloring layer 349 can increase the light extraction efficiency of the display apparatus as compared to the case where the coloring layer 349 is provided.

The plurality of structure examples described in this embodiment can be combined with each other as appropriate. This embodiment can be combined with the other embodiments as appropriate.

### Embodiment 4

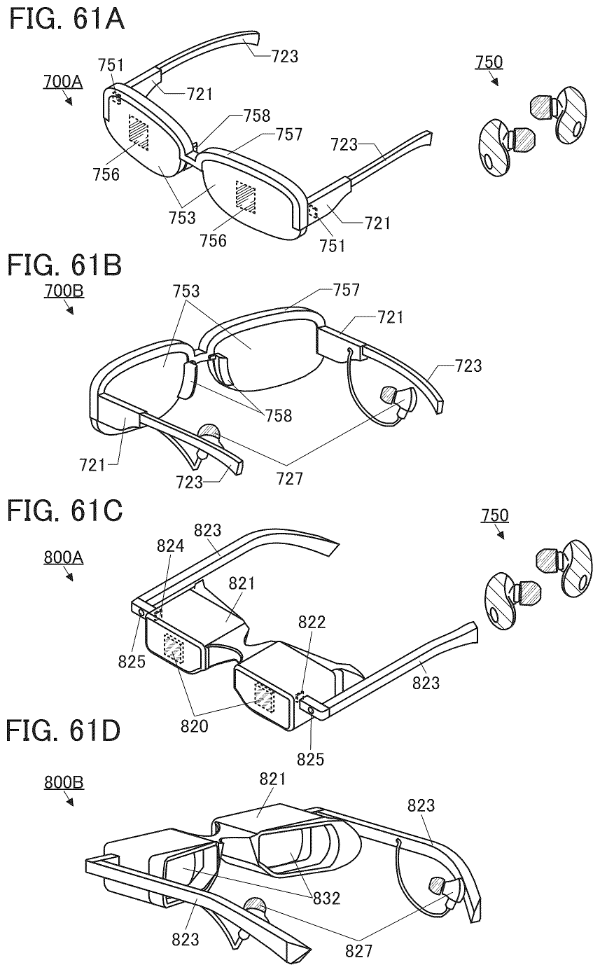

In this embodiment, electronic devices of one embodiment of the present invention will be described with reference to FIG. 61A to FIG. 63G.

Electronic devices of this embodiment each include the display apparatus of one embodiment of the present invention in a display portion. The display apparatus of one embodiment of the present invention can be easily increased in resolution and definition. Thus, the display apparatus of one embodiment of the present invention can be used for display portions of a variety of electronic devices.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have high resolution, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of such a display apparatus having one or both of high definition and high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays).

The electronic device of this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 61A to FIG. 61D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher sense of immersion.

An electronic device 700A illustrated in FIG. 61A and an electronic device 700B illustrated in FIG. 61B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device can perform display with an extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 61C and an electronic device 800B illustrated in FIG. 61D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with an extremely high resolution. This enables a user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be mounted on the user's head with the wearing portions 823. FIG. 61C or the like illustrates an example in which the wearing portions 823 have a shape like a temple (also referred to as a joint) of glasses; however, one embodiment of the present invention is not limited thereto. The wearing portions 823 can have any shape with which the user can wear the electronic device, for example, a shape of a helmet or a band.

The image capturing portion 825 has a function of obtaining information on the external environment. Data obtained by the image capturing portion 825 can be output to the display portions 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object is provided. That is, the image capturing portion 825 is one embodiment of the sensing portion. As the sensing portion, an image sensor or a distance image sensor such as LIDAR (Light Detection And Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portions 820, the housing 821, and the wearing portions 823. Thus, without additionally requiring an audio device such as headphones, earphones, or a speaker, the user can enjoy videos and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 61A has a function of transmitting information to the earphones 750 with the wireless communication function. For another example, the electronic device 800A illustrated in FIG. 61C has a function of transmitting information to the earphones 750 with the wireless communication function.

The electronic device may include earphone portions. The electronic device 700B illustrated in FIG. 61B includes earphone portions 727. For example, the earphone portions 727 and the control portion can be connected to each other by wire. Part of a wiring that connects the earphone portions 727 and the control portion may be positioned inside the housing 721 or the wearing portions 723.

Similarly, the electronic device 800B illustrated in FIG. 61D includes earphone portions 827. For example, the earphone portions 827 and the control portion 824 can be connected to each other by wire. Part of a wiring that connects the earphone portions 827 and the control portion 824 may be positioned inside the housing 821 or the wearing portions 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

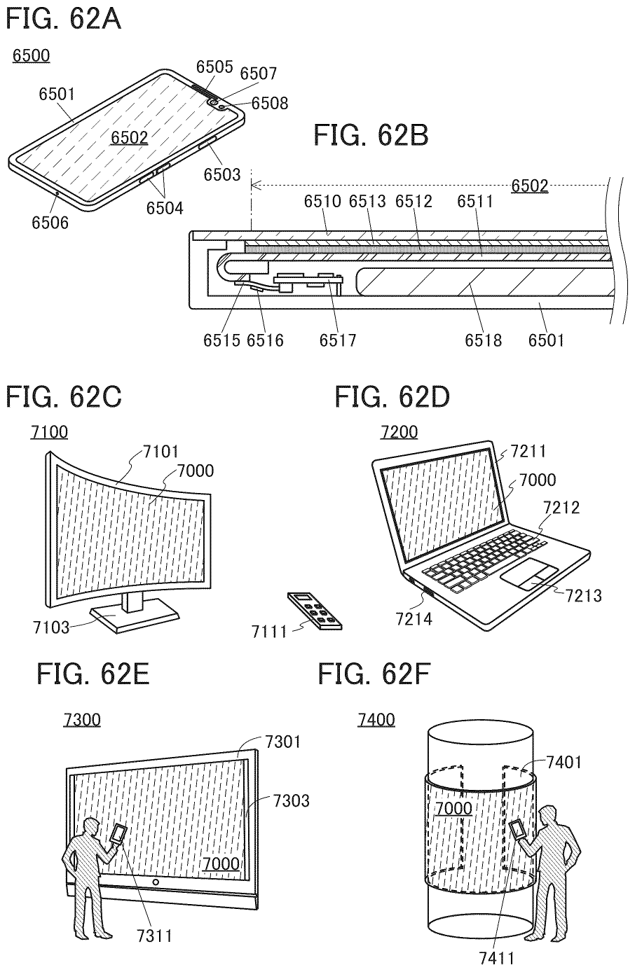

An electronic device 6500 illustrated in FIG. 62A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 62B is a schematic cross-sectional view including the end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display apparatus of one embodiment of the present invention can be used as the display panel 6511. Thus, an extremely lightweight electronic device can be obtained. Since the display panel 6511 is extremely thin, the battery 6518 with high capacity can be mounted while an increase in thickness of the electronic device is suppressed. Moreover, part of the display panel 6511 is folded back such that a connection portion with the FPC 6515 is provided on the back side of the display portion 6502, whereby an electronic device with a narrow bezel can be obtained.

FIG. 62C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

The operation of the television device 7100 illustrated in FIG. 62C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 62D illustrates an example of a laptop personal computer. A notebook personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 62E and FIG. 62F illustrate examples of digital signage.

Digital signage 7300 illustrated in FIG. 62E includes a housing 7301, the display portion 7000, a speaker 7303, and the like. Furthermore, an LED lamp, an operation key (including a power switch or an operation switch), a connection terminal, a variety of sensors, a microphone, and the like can be included.

FIG. 62F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 62E and FIG. 62F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 62E and FIG. 62F, it is preferable that the digital signage 7300 or the digital signage 7400 be capable of working with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

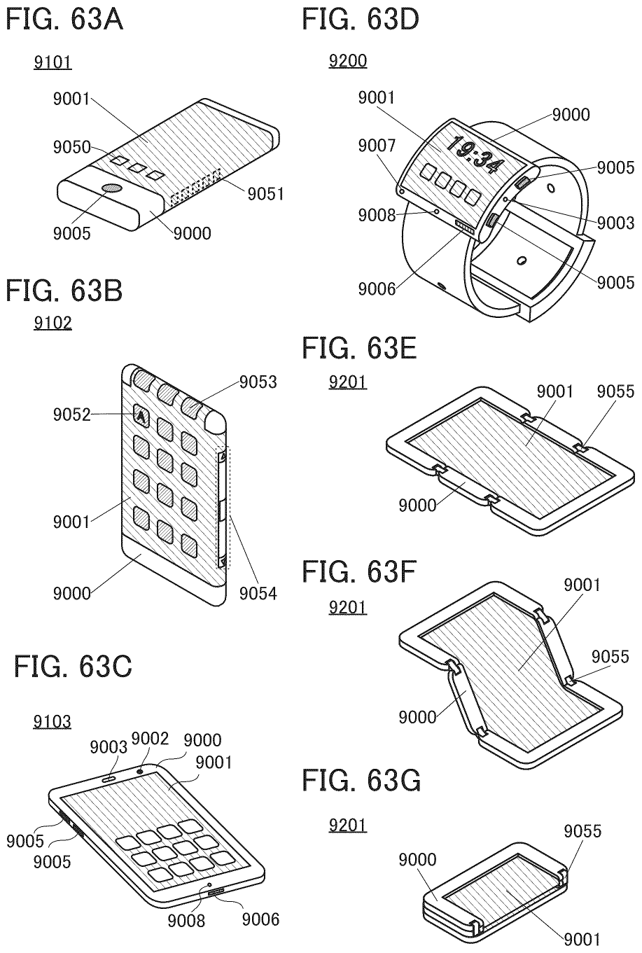

Electronic devices illustrated in FIG. 63A to FIG. 63G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays), a microphone 9008, and the like.

The display apparatus of one embodiment of the present invention can be used for the display portion 9001 in FIG. 63A to FIG. 63G.

The electronic devices illustrated in FIG. 63A to FIG. 63G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a recording medium (an external recording medium or a recording medium incorporated in the camera), a function of displaying the taken image on the display portion, or the like.

The electronic devices illustrated in FIG. 63A to FIG. 63G will be described in detail below.

FIG. 63A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display characters and image information on its plurality of surfaces. FIG. 63A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 63B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 63C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface.

FIG. 63D is a perspective view illustrating a watch-type portable information terminal 9200. The portable information terminal 9200 can be used as a Smartwatch (registered trademark), for example. The display surface of the display portion 9001 is curved, and display can be performed along the curved display surface. Furthermore, mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 63E to FIG. 63G are perspective views illustrating a foldable portable information terminal 9201. FIG. 63E is a perspective view of an opened state of the portable information terminal 9201, FIG. 63G is a perspective view of a folded state thereof, and FIG. 63F is a perspective view of a state in the middle of change from one of FIG. 63E and FIG. 63G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

10A: semiconductor device, 10B: semiconductor device, 10C: semiconductor device, 10D: semiconductor device, 10E: semiconductor device, 10F: semiconductor device, 10G: semiconductor device, 10H: semiconductor device, 10I: semiconductor device, 10J: semiconductor device, 10K: semiconductor device, 10L: semiconductor device, 10M: semiconductor device, 10N: semiconductor device, 100: semiconductor device, 10P: semiconductor device, 10Q: semiconductor device, 10R: semiconductor device, 10: semiconductor device, 11: scan line driver circuit, 13: signal line driver circuit, 15: power supply circuit, 17: reference potential generation circuit, 20: display portion, 21: pixel, 23B: subpixel, 23G: subpixel, 23R: subpixel, 23: subpixel, 30: display apparatus, 40A: pixel circuit, 40A_2: pixel circuit, 40B: pixel circuit, 40C: pixel circuit, 40D: pixel circuit, 40E: pixel circuit, 41a: wiring, 41b: wiring, 41c: wiring, 41d: wiring, 41e: wiring, 41f: wiring, 41g: wiring, 41h: wiring, 41: wiring, 43a: wiring, 43b: wiring, 43: wiring, 45: wiring, 47: wiring, 48: wiring, 49: wiring, 50A: display apparatus, 50B: display apparatus, 50C: display apparatus, 50D: display apparatus, 50E: display apparatus, 51: transistor, 52: transistor, 53: transistor, 54: transistor, 57: capacitor, 57b: capacitor, 58: capacitor, 60B: light-emitting element, 60G: light-emitting element, 60R: light-emitting element, 60: light-emitting element, 61: transistor, 62: transistor, 63: transistor, 64: transistor, 65: transistor, 66: transistor, 67: capacitor, 68: capacitor, 69B: liquid crystal element, 69G: liquid crystal element, 69R: liquid crystal element, 69: liquid crystal element, 70: memory device, 71: word line driver circuit, 73: bit line driver circuit, 75: power supply circuit, 80: memory portion, 81A: memory cell, 81B: memory cell, 81C: memory cell, 81D: memory cell, 81: memory cell, 82: region, 91: opening, 100A: transistor, 100E: transistor, 100F: transistor, 100I: transistor, 100J: transistor, 100K: transistor, 100K_1: transistor, 100K_2: transistor, 100L: transistor, 100M: transistor, 100N: transistor, 1000: transistor, 100: transistor, 102: substrate, 104f: conductive film, 104: conductive layer, 106: insulating layer, 107f: insulating film, 107: insulating layer, 108f: metal oxide film, 108_1: semiconductor layer, 108_2: semiconductor layer, 108: semiconductor layer, 110a: insulating layer, 110b: insulating layer, 110bf: insulating film, 110c: insulating layer, 110d: insulating layer, 110df: insulating film, 110e: insulating layer, 110f: insulating layer, 110g: insulating layer, 110_1: insulating layer, 110_1f: insulating film, 110_2: insulating layer, 110: insulating layer, 112a: conductive layer, 112af: conductive film, 112B: conductive layer, 112b: conductive layer, 112bf: conductive film, 112b_1: conductive layer, 112b_2: conductive layer, 112b_3: conductive layer, 112c: conductive layer, 112c_1: conductive layer, 112c_2: conductive layer, 129: opening, 140: connection portion, 141_1: opening, 141_2: opening, 141: opening, 142: adhesive layer, 143_1: opening, 143_2: opening, 143: opening, 152: substrate, 164: circuit, 165: wiring, 166: conductive layer, 172: FPC, 173: IC, 200A: transistor, 200B: transistor, 200C: transistor, 200D: transistor, 200E: transistor, 200F: transistor, 200G: transistor, 200H: transistor, 200I: transistor, 200J: transistor, 200K: transistor, 200L: transistor, 200M: transistor, 200N: transistor, 2000: transistor, 200: transistor, 201: transistor, 202a: conductive layer, 202B: conductive layer, 202b: conductive layer, 202b_1: conductive layer, 202b_2: conductive layer, 202c: conductive layer, 204: conductive layer, 205B: transistor, 205G: transistor, 205R: transistor, 205: transistor, 208: semiconductor layer, 210_1: insulating layer, 210_2: insulating layer, 214: connection portion, 218: insulating layer, 235: insulating layer, 237: insulating layer, 241: opening, 242: connection layer, 243: opening, 300A: transistor, 300B: transistor, 300: transistor, 302a: conductive layer, 302b: conductive layer, 304: conductive layer, 307: connection portion, 308: semiconductor layer, 309: connection layer, 311B: pixel electrode, 311G: pixel electrode, 311R: pixel electrode, 311: pixel electrode, 312: conductive layer, 313B: layer, 313G: layer, 313R: layer, 313: layer, 314: common layer, 315: common electrode, 317: light-blocking layer, 318B: mask layer, 318G: mask layer, 318R: mask layer, 318: mask layer, 323: conductive layer, 324B: conductive layer, 324G: conductive layer, 324p: conductive layer, 324R: conductive layer, 324: conductive layer, 325: insulating layer, 326B: conductive layer, 326G: conductive layer, 326p: conductive layer, 326R: conductive layer, 326: conductive layer, 327: insulating layer, 328: layer, 329B: conductive layer, 329G: conductive layer, 329p: conductive layer, 329R: conductive layer, 329: conductive layer, 330: substrate, 331: protective layer, 341: opening, 342: wiring, 343: opening, 344: conductive layer, 345: insulating layer, 346: liquid crystal layer, 347: spacer, 348: insulating layer, 349B: coloring layer, 349G: coloring layer, 349R: coloring layer, 349: coloring layer, 350: FPC, 353: insulating layer, 380: sensing element, 381: electrode, 382: electrode, 383: electrode, 384: electrode, 387: sensing portion, 395: insulating layer, 396: adhesive layer, 441: opening, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power supply button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a first transistor comprising:
a first conductive layer;
a second conductive layer;
a third conductive layer;
a first semiconductor layer; and
a first insulating layer,
a second transistor comprising:
a fourth conductive layer;
a fifth conductive layer;
a sixth conductive layer;
a second semiconductor layer; and
the first insulating layer,
wherein the second conductive layer is over the first conductive layer,
wherein the first semiconductor layer is in contact with a top surface of the first conductive layer and the second conductive layer,
wherein the first insulating layer is in contact with a top surface of the first semiconductor layer,
wherein the third conductive layer is over the first insulating layer to comprise a region overlapping with the first semiconductor layer,
wherein the fifth conductive layer is over the fourth conductive layer,
wherein the second semiconductor layer is in contact with a top surface of the fourth conductive layer and the fifth conductive layer,
wherein the first insulating layer is in contact with a top surface of the second semiconductor layer,
wherein the sixth conductive layer is over the first insulating layer to comprise a region overlapping with the second semiconductor layer,
wherein a second insulating layer is between the first conductive layer and the second conductive layer and between the fourth conductive layer and the fifth conductive layer, and
wherein a thickness of the second insulating layer between the first conductive layer and the second conductive layer and a thickness of the second insulating layer between the fourth conductive layer and the fifth conductive layer are different from each other.

2. The semiconductor device according to claim 1,
wherein each of the first semiconductor layer and the second semiconductor layer comprises a metal oxide.

3. The semiconductor device according to claim 1,
wherein the second insulating layer comprises a third insulating layer and a fourth insulating layer,
wherein the third insulating layer over the fourth conductive layer has an island shape, and
wherein the fourth insulating layer is over the first conductive layer and the third insulating layer.

4. The semiconductor device according to claim 1,
wherein the second insulating layer comprises a third insulating layer and a fourth insulating layer,
wherein the third insulating layer is over the first conductive layer and the fourth conductive layer, and
wherein the fourth insulating layer is over the third insulating layer to comprise an opening in a region overlapping with the first conductive layer.

5. The semiconductor device according to claim 1,
wherein the second insulating layer comprises a third insulating layer and a fourth insulating layer,
wherein the third insulating layer has an island shape,
wherein the first conductive layer is over the third insulating layer, and
wherein the fourth insulating layer is over the first conductive layer and the fourth conductive layer.

6. A method for manufacturing a semiconductor device, comprising:
forming a first conductive film;
processing the first conductive film to form a first conductive layer and a second conductive layer;
forming a first insulating film over the first conductive layer and the second conductive layer;
processing the first insulating film to form a first insulating layer overlapping with the second conductive layer;
forming a second insulating layer over the first conductive layer, the second conductive layer, and the first insulating layer;
forming a second conductive film over the second insulating layer;
processing the second conductive film to form a third conductive layer overlapping with the first conductive layer and to form a fourth conductive layer overlapping with the second conductive layer;
removing part of the third conductive layer and part of the fourth conductive layer to form a fifth conductive layer comprising a first opening and to form a sixth conductive layer comprising a second opening;
removing the second insulating layer in a region overlapping with the first opening and removing the first insulating layer and the second insulating layer in a region overlapping with the second opening to form a third opening and a fourth opening, respectively;
forming a metal oxide film in contact with a top surface of the first conductive layer, a top surface of the second conductive layer, a top surface and a side surface of the fifth conductive layer, a top surface and a side surface of the sixth conductive layer, a side surface of the first insulating layer, and a side surface of the second insulating layer so as to cover the first opening, the second opening, the third opening, and the fourth opening;
processing the metal oxide film into an island shape to form a first semiconductor layer in contact with the top surface of the first conductive layer, the side surface of the second insulating layer, and the top surface and the side surface of the fifth conductive layer and to form a second semiconductor layer in contact with the top surface of the second conductive layer, the side surface of the first insulating layer, the side surface of the second insulating layer, and the top surface and the side surface of the sixth conductive layer;
forming a third insulating layer over the first semiconductor layer, the second semiconductor layer, the fifth conductive layer, the sixth conductive layer, and the second insulating layer;
forming a third conductive film over the third insulating layer; and
processing the third conductive film to form a seventh conductive layer overlapping with the first conductive layer and the first semiconductor layer and to form an eighth conductive layer overlapping with the second conductive layer and the second semiconductor layer.

7. (canceled)

8. A method for manufacturing a semiconductor device, comprising:
forming a first insulating film;
processing the first insulating film to form a first insulating layer;
forming a first conductive film over the first insulating layer;
processing the first conductive film to form a first conductive layer over the first insulating layer and to form a second conductive layer over a region different from the first insulating layer;
forming a second insulating film over the first insulating layer, the first conductive layer, and the second conductive layer;
processing the second insulating film to form a second insulating layer having a flat or substantially flat surface;
forming a second conductive film over the second insulating layer;
processing the second conductive film to form a third conductive layer overlapping with the first conductive layer and to form a fourth conductive layer overlapping with the second conductive layer;
removing part of the third conductive layer and part of the fourth conductive layer to form a fifth conductive layer comprising a first opening and to form a sixth conductive layer comprising a second opening;
removing the second insulating layer in a region overlapping with the first opening and removing the second insulating layer in a region overlapping with the second opening to form a third opening and a fourth opening;
forming a metal oxide film in contact with a top surface of the first conductive layer, a top surface of the second conductive layer, a top surface and a side surface of the fifth conductive layer, a top surface and a side surface of the sixth conductive layer, and a side surface of the second insulating layer so as to cover the first opening, the second opening, the third opening, and the fourth opening;
processing the metal oxide film into an island shape to form a first semiconductor layer in contact with the top surface of the first conductive layer, the side surface of the second insulating layer, and the top surface and the side surface of the fifth conductive layer and to form a second semiconductor layer in contact with the top surface of the second conductive layer, the side surface of the second insulating layer, and the top surface and the side surface of the sixth conductive layer;
forming a third insulating layer over the first semiconductor layer, the second semiconductor layer, the fifth conductive layer, the sixth conductive layer, and the second insulating layer;
forming a third conductive film over the third insulating layer; and
processing the third conductive film to form a seventh conductive layer overlapping with the first conductive layer and the first semiconductor layer and to form an eighth conductive layer overlapping with the second conductive layer and the second semiconductor layer.
